(19) United States
(12) Patent Application Publication
(10) Pub. No.: US 2026/0239673 A1
(43) Pub. Date: Aug. 13, 2026

(54) METAL OXIDE FILM AND SEMICONDUCTOR DEVICE

(71) Applicant: Semiconductor Energy Laboratory Co., Ltd., Atsugi-shi, Kanagawa-ken (JP)

(72) Inventors: Tomonori NAKAYAMA, Atsugi (JP); Hitoshi KUNITAKE, Machida (JP); Shunpei YAMAZAKI, Setagaya (JP)

(21) Appl. No.: 19/153,718

(22) PCT Filed: Feb. 16, 2024
(86) PCT No.: PCT/IB2024/051466

§ 371 Date: Aug. 5, 2025

(30) Foreign Application Priority Data
Feb. 23, 2023 (JP) 2023-026808
May 12, 2023 (JP) 2023-079000

(51) Int. Cl. H10D 30/67; C30B 29/22; C30B 29/68; H10B 12/00; H10D 86/60; H10K 59/121

(52) U.S. Cl. CPC H10D 30/6755; C30B 29/22; C30B 29/68; H10D 30/6728; H10D 30/6731; H10B 12/31; H10D 30/6734; H10D 30/6735; H10D 30/6736; H10D 30/6757; H10D 86/60; H10K 59/1213

(57) ABSTRACT

A metal oxide film having high carrier mobility is provided. In the metal oxide film, a sum of a content percentage of indium and a content percentage of zinc is greater than or equal to 95%. The metal oxide film includes a crystal. The crystal includes a layered crystal structure. In the crystal, the ratio of the number of zinc atoms to the number of indium atoms is greater than 0 and less than 1.5. The electron effective mass in the crystal is smaller than the electron effective mass in an indium oxide having a cubic crystal structure. The metal oxide film may include tin, and the content percentage of tin is higher than or equal to 0.1% and lower than or equal to 3%.

### TECHNICAL FIELD

One embodiment of the present invention relates to a metal oxide film. One embodiment of the present invention relates to a semiconductor device, a memory device, a display device, and an electronic device each including a metal oxide film.

Note that one embodiment of the present invention is not limited to the above technical field. Examples of the technical field of one embodiment of the present invention include a semiconductor device, a display device, a light-emitting apparatus, a power storage device, a memory device, an electronic device, a lighting device, an input device (e.g., a touch sensor), an input/output device (e.g., a touch panel), driving methods thereof, and manufacturing methods thereof.

In this specification and the like, a semiconductor device generally means a device that can function by utilizing semiconductor properties. A semiconductor element such as a transistor, a semiconductor circuit, an arithmetic device, and a memory device are each an embodiment of a semiconductor device. A display device (e.g., a liquid crystal display device and a light-emitting display device), a projection device, a lighting device, an electro-optical device, a power storage device, a memory device, a semiconductor circuit, an imaging device, an electronic device, and the like each include a semiconductor device in some cases.

### BACKGROUND ART

As a semiconductor material usable in a transistor, an oxide semiconductor has been attracting attention. For example, Patent Document 1 discloses a semiconductor device achieving increased field-effect mobility (in some cases, simply referred to as mobility or FE) with a structure where a plurality of oxide semiconductor layers are stacked, and among the plurality of oxide semiconductor layers, the oxide semiconductor layer serving as a channel contains indium and gallium and has a higher indium content than a gallium content.

### REFERENCE

### Patent Document

[Patent Document 1] Japanese Published Patent Application No. 2014-007399

### Non-Patent Document

[Non-Patent Document 1]A. van de Walle, “Multicomponent multisublattice alloys, nonconfigurational entropy and other additions to the Alloy Theoretic Automated Toolkit”, Calphad Journal 33, pp. 266-278, (2009).

### SUMMARY OF THE INVENTION

### Problems to be Solved by the Invention

An object of one embodiment of the present invention is to provide a metal oxide film with high carrier mobility. An object of one embodiment of the present invention is to provide a novel metal oxide film.

Moreover, an object of one embodiment of the present invention is to provide a semiconductor device in which a metal oxide film is used and which has a high on-state current. An object of one embodiment of the present invention is to provide a semiconductor device in which a metal oxide film is used and which has a high operation speed. An object of one embodiment of the present invention is to provide a semiconductor device in which a metal oxide film is used and which has excellent electrical characteristics. An object of one embodiment of the present invention is to provide a highly reliable semiconductor device in which a metal oxide film is used. An object of one embodiment of the present invention is to provide a semiconductor device in which a metal oxide film is used and which has a small variation in transistor electrical characteristics. An object of one embodiment of the present invention is to provide a semiconductor device in which a metal oxide film is used and which can be miniaturized or highly integrated. An object of one embodiment of the present invention is to provide a semiconductor device in which a metal oxide film is used and which has low power consumption. An object of one embodiment of the present invention is to provide a novel semiconductor device in which a metal oxide film is used.

Furthermore, an object of one embodiment of the present invention is to provide a memory device that can be miniaturized or highly integrated. An object of one embodiment of the present invention is to provide a memory device with a large memory capacity. An object of one embodiment of the present invention is to provide a memory device with high operating speed. An object of one embodiment of the present invention is to provide a memory device with low power consumption. An object of one embodiment of the present invention is to provide a novel memory device. An object of one embodiment of the present invention is to provide a highly reliable display device. An object of one embodiment of the present invention is to provide a display device with low power consumption. An object of one embodiment of the present invention is to provide a high-resolution display device. An object of one embodiment of the present invention is to provide a novel display device.

Note that the description of these objects does not preclude the presence of other objects. One embodiment of the present invention does not necessarily achieve all of these objects. Other objects can be derived from the description of the specification, the drawings, and the claims.

### Means for Solving the Problems

One embodiment of the present invention is a metal oxide film in which the sum of a content percentage of indium and a content percentage of zinc is greater than or equal to 95%. The metal oxide film includes a crystal. The crystal includes a layered crystal structure. In the crystal, the ratio of the number of zinc atoms to the number of indium atoms is greater than 0 and less than 1.5. The electron effective mass in the crystal is smaller than the electron effective mass in an indium oxide having a cubic crystal structure.

The metal oxide film preferably includes tin, and the content percentage of tin is preferably higher than or equal to 0.1% and lower than or equal to 3%.

One embodiment of the present invention is a metal oxide film in which the sum of a content percentage of indium and a content percentage of zinc is greater than or equal to 95%. The metal oxide film includes a crystal. The crystal includes a first layer, a second layer, and a third layer positioned between the first layer and the second layer. The ratio of the number of zinc atoms to the number of indium atoms in the third layer is higher than the ratio of the number of zinc atoms to the number of indium atoms in the first layer. The ratio of the number of zinc atoms to the number of indium atoms in the third layer is higher than the ratio of the number of zinc atoms to the number of indium atoms in the second layer. The third layer includes one, two, or three layers.

In the above metal oxide film, the electron effective mass in the crystal is preferably smaller than the electron effective mass in an indium oxide having a cubic crystal structure.

The metal oxide film preferably includes tin, and the content percentage of tin is preferably higher than or equal to 0.1% and lower than or equal to 3%.

One embodiment of the present invention is a metal oxide film in which the sum of a content percentage of indium and the content percentage of zinc is greater than or equal to 95%. The metal oxide film includes a crystal. The crystal includes a first layer, a second layer, and a third layer positioned between the first layer and the second layer. In a HAADF-STEM image, a luminance of an atom included in the third layer is lower than a luminance of an atom included in the first layer. In the HAADF-STEM image, the luminance of the atom included in the third layer is lower than a luminance of an atom included in the second layer. The third layer includes one, two, or three layers.

In the above metal oxide film, the electron effective mass in the crystal is preferably smaller than the electron effective mass in an indium oxide having a cubic crystal structure.

The metal oxide film preferably includes tin, and the content percentage of tin is preferably higher than or equal to 0.1% and lower than or equal to 3%.

One embodiment of the present invention is a semiconductor device including a transistor and a first insulating layer. The transistor includes a semiconductor layer, a second insulating layer, a first conductive layer, a second conductive layer, and a third conductive layer. The first insulating layer is provided over the first conductive layer. The second conductive layer is provided over the first insulating layer. An opening portion reaching the first conductive layer is provided in the first insulating layer and the second conductive layer. At least a part of the semiconductor layer is provided in the opening portion. The second insulating layer is provided over the semiconductor layer. The third conductive layer is provided over the second insulating layer. The semiconductor layer includes the above metal oxide film.

One embodiment of the present invention is a semiconductor device including a transistor, a first insulating layer, and a second insulating layer. The transistor includes a semiconductor layer, a third insulating layer, a first conductive layer, a second conductive layer, and a third conductive layer. The first insulating layer is provided over the first conductive layer. The second conductive layer is provided over the first insulating layer. The second insulating layer is provided over the second conductive layer. The third conductive layer is provided over the second insulating layer. An opening portion reaching the first conductive layer is provided in the first insulating layer, the second conductive layer, the second insulating layer, and the third conductive layer. The third insulating layer is provided in the opening portion. In the opening portion, the third insulating layer includes a region in contact with a side surface of the first insulating layer, a side surface of the second conductive layer, a side surface of the second insulating layer, and a side surface of the third conductive layer. The semiconductor layer is provided in contact with a top surface of the third conductive layer and a side surface of the third insulating layer and a top surface of the first conductive layer in the opening portion. The semiconductor layer includes the above metal oxide film.

One embodiment of the present invention is a semiconductor device including a transistor and a first insulating layer. The transistor includes a semiconductor layer, a second insulating layer, a first conductive layer, a second conductive layer, and a third conductive layer. The first conductive layer and the second conductive layer are provided over the semiconductor layer. The first insulating layer is provided over the first conductive layer and the second conductive layer. An opening portion that is between the first conductive layer and the second conductive layer and reaches the semiconductor layer is provided in the first insulating layer. The second insulating layer is provided in the opening portion. The third conductive layer is provided over the second insulating layer. The semiconductor layer includes the above metal oxide film.

In the above semiconductor device, the transistor preferably further includes a third insulating layer, and in the opening portion, the third insulating layer preferably is provided in contact with a side surface of the first insulating layer, a side surface of the first conductive layer, and a side surface of the second conductive layer.

### Effect of the Invention

According to one embodiment of the present invention, a metal oxide film with high carrier mobility can be provided. According to one embodiment of the present invention, a novel metal oxide film can be provided.

Moreover, according to one embodiment of the present invention, a semiconductor device in which a metal oxide film is used and which has a high on-state current can be provided. According to one embodiment of the present invention, a semiconductor device in which a metal oxide film is used and which has a high operation speed can be provided. According to one embodiment of the present invention, a semiconductor device in which a metal oxide film is used and which has excellent electrical characteristics can be provided. According to one embodiment of the present invention, a highly reliable semiconductor device in which a metal oxide film is used can be provided. According to one embodiment of the present invention, a semiconductor device in which a metal oxide film is used and which has a small variation in transistor electrical characteristics can be provided. According to one embodiment of the present invention, a semiconductor device in which a metal oxide film is used and which can be miniaturized or highly integrated can be provided. According to one embodiment of the present invention, a semiconductor device in which a metal oxide film is used and which has low power consumption can be provided. According to one embodiment of the present invention, a novel semiconductor device in which a metal oxide film is used can be provided.

Furthermore, according to one embodiment of the present invention, a memory device that can be miniaturized or highly integrated can be provided. According to one embodiment of the present invention, a memory device with a large memory capacity can be provided. According to one embodiment of the present invention, a memory device with high operating speed can be provided. According to one embodiment of the present invention, a memory device with low power consumption can be provided. According to one embodiment of the present invention, a novel memory device can be provided. According to one embodiment of the present invention, a highly reliable display device can be provided. According to one embodiment of the present invention, a display device with low power consumption can be provided. According to one embodiment of the present invention, a high-resolution display device can be provided. According to one embodiment of the present invention, a novel display device can be provided.

Note that the description of these effects does not preclude the presence of other effects. One embodiment of the present invention does not necessarily have all of these effects. Other effects can be derived from the description of the specification, the drawings, and the claims.

### BRIEF DESCRIPTION OF THE DRAWINGS

FIG. 1A to FIG. 1C are diagrams each illustrating a crystal included in a metal oxide film.

FIG. 2A is a diagram illustrating a crystal included in a metal oxide film. FIG. 2B to FIG. 2D are diagrams each illustrating a polyhedron included in the crystal.

FIG. 3A and FIG. 3B are diagrams each illustrating the electron effective mass in a metal oxide.

FIG. 4A is a plan view illustrating an example of a semiconductor device. FIG. 4B to FIG. 4D are cross-sectional views illustrating examples of the semiconductor device.

FIG. 5A and FIG. 5B are cross-sectional views illustrating examples of a semiconductor device.

FIG. 6A is a plan view illustrating an example of a semiconductor device. FIG. 6B to FIG. 6D are cross-sectional views illustrating examples of the semiconductor device.

FIG. 7A is a plan view illustrating an example of a semiconductor device. FIG. 7B to FIG. 7D are cross-sectional views illustrating examples of the semiconductor device.

FIG. 8A is a plan view illustrating an example of a semiconductor device. FIG. 8B to FIG. 8D are cross-sectional views illustrating examples of the semiconductor device.

FIG. 9A is a plan view illustrating an example of a semiconductor device. FIG. 9B to FIG. 9D are cross-sectional views illustrating examples of the semiconductor device.

FIG. 10A and FIG. 10B are cross-sectional views illustrating examples of a semiconductor device.

FIG. 11A is a plan view illustrating an example of a semiconductor device. FIG. 11B to FIG. 11D are cross-sectional views illustrating examples of the semiconductor device.

FIG. 12A is a plan view illustrating an example of a semiconductor device. FIG. 12B to FIG. 12D are cross-sectional views illustrating examples of the semiconductor device.

FIG. 13A is a plan view illustrating an example of a semiconductor device. FIG. 13B to FIG. 13D are cross-sectional views illustrating examples of the semiconductor device.

FIG. 14A is a plan view illustrating an example of a semiconductor device. FIG. 14B to FIG. 14D are cross-sectional views illustrating examples of the semiconductor device.

FIG. 15A to FIG. 15D are cross-sectional views illustrating examples of a semiconductor device.

FIG. 16A is a plan view illustrating an example of a semiconductor device. FIG. 16B to FIG. 16D are cross-sectional views illustrating examples of the semiconductor device.

FIG. 17A is a plan view illustrating an example of a semiconductor device. FIG. 17B to FIG. 17D are cross-sectional views illustrating examples of the semiconductor device.

FIG. 18A to FIG. 18E are cross-sectional views illustrating examples of a semiconductor device.

FIG. 19A is a plan view illustrating an example of a semiconductor device. FIG. 19B to FIG. 19D are cross-sectional views illustrating examples of the semiconductor device.

FIG. 20A is a plan view illustrating an example of a semiconductor device. FIG. 20B to FIG. 20D are cross-sectional views illustrating examples of the semiconductor device.

FIG. 21A is a plan view illustrating an example of a semiconductor device. FIG. 21B to FIG. 21D are cross-sectional views illustrating examples of the semiconductor device.

FIG. 22 is a cross-sectional view illustrating an example of a semiconductor device.

FIG. 23A to FIG. 23E are cross-sectional views illustrating examples of a semiconductor device.

FIG. 24A is a plan view illustrating an example of a semiconductor device. FIG. 24B to FIG. 24D are cross-sectional views illustrating examples of the semiconductor device.

FIG. 25 is a block diagram illustrating an example of a memory device.

FIG. 26A is a schematic view illustrating an example of a memory device. FIG. 26B is a schematic diagram and a circuit diagram illustrating an example of the memory device.

FIG. 27A and FIG. 27B are cross-sectional views each illustrating an example of a memory device.

FIG. 28A to FIG. 28C are circuit diagrams each illustrating an example of a memory device.

FIG. 29 is a circuit diagram illustrating an example of a memory device.

FIG. 30 is a cross-sectional view illustrating an example of a memory device.

FIG. 31 is a cross-sectional view illustrating an example of a memory device.

FIG. 32 is a cross-sectional view illustrating an example of a memory device.

FIG. 33A and FIG. 33B are diagrams illustrating examples of a semiconductor device.

FIG. 34A and FIG. 34B are diagrams illustrating examples of electronic components.

FIG. 35A and FIG. 35B are diagrams illustrating examples of electronic devices, and FIG. 35C to FIG. 35E are diagrams illustrating an example of a large computer.

FIG. 36 is a diagram illustrating an example of space equipment.

FIG. 37 is a diagram illustrating an example of a storage system usable in a data center.

FIG. 38A and FIG. 38B illustrates a structure example of a display device.

FIG. 39 illustrates a structure example of a display device.

FIG. 40 illustrates a structure example of a display device.

FIG. 41 illustrates a structure example of a display device.

FIG. 42A to FIG. 42C illustrates a structure example of a display device.

FIG. 43A and FIG. 43B each illustrate structure an example of a display device.

FIG. 44A to FIG. 44D illustrate structure examples of electronic devices.

FIG. 45A to FIG. 45F illustrate structure examples of electronic devices.

FIG. 46A to FIG. 46G illustrate structure examples of electronic devices.

FIG. 47A and FIG. 47B are each a diagram showing temperature dependence of Hall mobility of a metal oxide.

FIG. 48A and FIG. 48B are each a diagram showing temperature dependence of Hall mobility of a metal oxide.

FIG. 49A and FIG. 49B each illustrate a calculation model.

FIG. 50 is a diagram showing temperature dependence of Hall mobility of a metal oxide.

### MODE FOR CARRYING OUT THE INVENTION

Embodiments will be described in detail with reference to the drawings. Note that the present invention is not limited to the following description, and it will be readily appreciated by those skilled in the art that modes and details of the present invention can be modified in various ways without departing from the spirit and scope of the present invention. Therefore, the present invention should not be construed as being limited to the description in the following embodiments.

Note that in structures of the invention described below, the same portions or portions having similar functions are denoted by the same reference numerals in different drawings, and the description thereof is not repeated. The same hatching pattern is used for portions having similar functions, and the portions are not denoted by specific reference numerals in some cases.

The position, size, range, or the like of each component illustrated in drawings does not represent the actual position, size, range, or the like in some cases for easy understanding. Therefore, the disclosed invention is not necessarily limited to the position, size, range, or the like disclosed in the drawings.

In a plan view, a perspective view, or the like, especially, some components are not illustrated for easy understanding of the invention in some cases. In addition, some hidden lines are not shown in some cases.

Note that ordinal numbers such as “first” and “second” in this specification and the like are used for convenience and do not limit the number or the order (e.g., the order of steps or the stacking order) of components. The ordinal number added to a component in a part of this specification may be different from the ordinal number added to the component in another part of this specification or the scope of claims.

Note that the terms “film” and “layer” can be used interchangeably depending on the case or the circumstances. For example, the term “conductive layer” can be replaced with the term “conductive film”. As another example, the term “insulating film” can be replaced with the term “insulating layer”. The term “conductor” can be replaced with the term “conductive layer” or “conductive film” depending on the case or the circumstances. The term “insulator” can be replaced with the term “insulating layer” or “insulating film” depending on the case or the circumstances. The term “oxide semiconductor” can be replaced with the term “oxide semiconductor layer” or “oxide semiconductor film” depending on the case or the circumstances.

In this specification and the like, the term “parallel” indicates that the angle formed between two straight lines is greater than or equal to −10′ and less than or equal to 10°. Thus, the case where the angle is greater than or equal to −5° and less than or equal to 5° is also included. The term “substantially parallel” indicates that the angle formed between two straight lines is greater than or equal to −30° and less than or equal to 30°. The term “perpendicular” indicates that the angle formed between two straight lines is greater than or equal to 80° and less than or equal to 100°. Thus, the case where the angle is greater than or equal to 85° and less than or equal to 95° is also included. In addition, the term “substantially perpendicular” indicates that the angle formed between two straight lines is greater than or equal to 60° and less than or equal to 120°.

The term “opening” includes a groove, a slit, a depressed portion, and the like. A region where an opening is formed is referred to as an opening portion in some cases.

In the drawings used in embodiments, a sidewall of an insulator in an opening portion is illustrated as being perpendicular or substantially perpendicular to a substrate surface or a formation surface, but the sidewall may have a tapered shape.

In this specification and the like, a tapered shape refers to a shape such that at least part of a side surface of a component is inclined with respect to a substrate surface or a formation surface. For example, the tapered shape preferably includes a region where the angle between the inclined side surface and the substrate surface or the formation surface (the angle is hereinafter referred to as a taper angle in some cases) is less than 90°. Note that the side surface of the component and the substrate surface are not necessarily completely flat and may be substantially flat with a slight curvature or with slight unevenness. In this specification and the like, an inverse tapered shape refers to a shape having a side portion or an upper portion protruding beyond its bottom portion in the direction parallel to a substrate.

Note that in this specification and the like, the expression “substantially level with” indicates a structure having the same level from a reference surface (e.g., a flat surface such as a substrate surface) in a cross-sectional view. For example, in a manufacturing process of a memory device, planarization treatment (typically, chemical mechanical polishing (CMP) treatment) is performed, whereby the surface(s) of a single layer or a plurality of layers are exposed in some cases. In this case, the surfaces on which the CMP treatment is performed are at the same level from a reference surface. Note that a plurality of layers are not level with each other in some cases, depending on a treatment apparatus, a treatment method, or a material of the treated surfaces on which the CMP treatment is performed. This case is also regarded as being “level with” in this specification and the like. For example, the expression “level with” also includes the case where two layers (here, given as a first layer and a second layer) have different levels with respect to the reference surface and the difference in the top-surface level between the first and second layers is less than or equal to 20 nm.

In this specification and the like, the expression “a side end portion is aligned with another side end portion” means that at least outlines of stacked layers partly overlap with each other in a plan view. For example, the case of patterning an upper layer and a lower layer with the use of the same mask pattern or partly the same mask patterns is included. The expression “a side end portion is aligned with another side end portion” also includes the case where the outlines do not exactly overlap with each other; for instance, the outline of the upper layer may be positioned inside or outside the outline of the lower layer.

In general, it is difficult to clearly differentiate “completely the same” from “substantially the same”. Thus, in this specification and the like, the expression “the same” includes both “completely the same” and “substantially the same”.

Note that in this specification and the like, the expression “the first thickness and the second thickness are the same” means that a value obtained by dividing the absolute value of the difference between the first thickness and the second thickness by the first thickness is less than or equal to 0.1. Alternatively, the expression means that a value obtained by dividing the absolute value of the difference between the first thickness and the second thickness by the second thickness is less than or equal to 0.1.

Note that in this specification and the like, the expression “the distance A and the distance B are the same” means that a value obtained by dividing the absolute value of the difference between the distance A and the distance B by the distance A is less than or equal to 0.1. Alternatively, the expression means that a value obtained by dividing the absolute value of the difference between the distance A and the distance B by the distance B is less than or equal to 0.1. In this specification and the like, a space group is represented using the short symbol of the international notation (or the Hermann-Mauguin notation).

### Embodiment 1

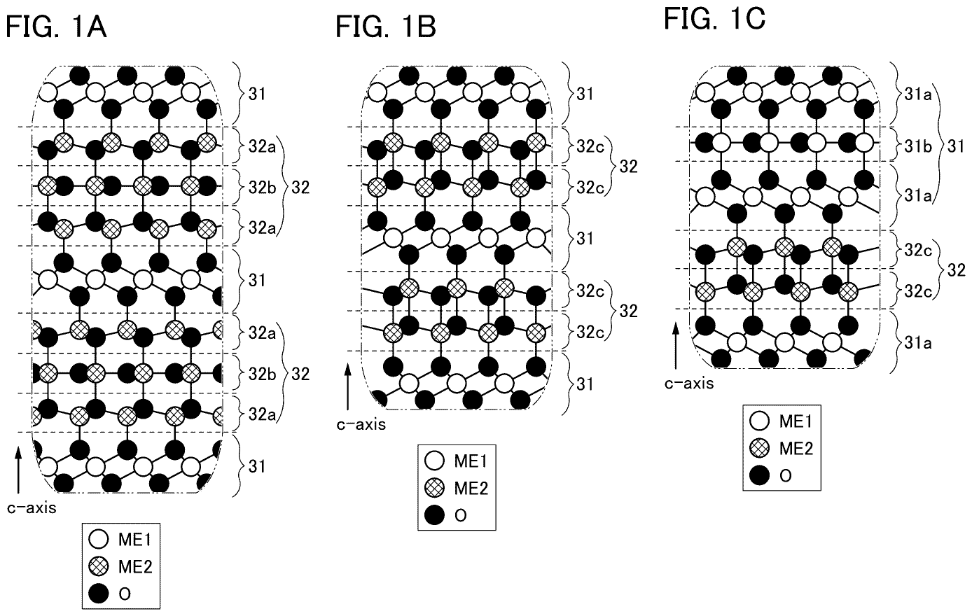

In this embodiment, a metal oxide film of one embodiment of the present invention is described with reference to FIG. 1A to FIG. 3B. The metal oxide film can be used as a semiconductor layer of a transistor. Hereinafter, a transistor using a metal oxide functioning as a semiconductor (also referred to as an oxide semiconductor) in a semiconductor layer where a channel is formed is referred to as an OS transistor. Note that the metal oxide film of one embodiment of the present invention may be used as an insulating layer or a conductive layer, without being limited to being used as a semiconductor layer of a transistor.

In order to enable a semiconductor device including a transistor to operate at higher speed, the transistor preferably has a high on-state current or a high field-effect mobility. For example, a metal oxide film used as a semiconductor layer of the transistor preferably contains indium. A transistor in which a metal oxide film containing indium is used as a semiconductor layer can have a high on-state current or a high field-effect mobility. To improve the reliability of the transistor, the metal oxide film used as the semiconductor layer of the transistor preferably contains zinc. When containing zinc, the metal oxide film can have increased crystallinity, so that the reliability of the transistor can be improved. That is, in order to achieve both high on-state current or high field-effect mobility and high reliability of an OS transistor, the composition and crystallinity of a metal oxide film need to be controlled.

Thus, one embodiment of the present invention is a metal oxide film containing indium and zinc. The metal oxide film includes a crystal, and the crystal has a layered crystal structure. Note that the ratio of the number of zinc (Zn) atoms to the number of indium (In) atoms (sometimes referred to as Zn/In) in the crystal is preferably greater than 0 and less than 1.5, further preferably greater than 0 and less than 1.0, still further preferably greater than 0 and less than 0.5.

Moreover, one embodiment of the present invention is a metal oxide film containing indium and zinc, and the metal oxide film includes a crystal. The crystal includes a first layer, a second layer, and a third layer positioned between the first layer and the second layer. The Zn/In in the third layer is higher than the Zn/In in the first layer, and the Zn/In in the third layer is higher than the Zn/In in the second layer. The third layer includes one, two, or three layers in a direction where the first layer, the second layer, and the third layer are stacked. Each of the first layer and the second layer preferably includes one or three layers in the direction in which the first layer, the second layer, and the third layer are stacked.

Specifically, as the metal oxide film, a metal oxide film with a composition of In:Zn=1:1 [atomic ratio] or in the neighborhood thereof, a composition of In:Zn=2:1 [atomic ratio] or in the neighborhood thereof, or a composition of In:Zn=4:1 [atomic ratio] or in the neighborhood thereof is used. Note that the neighborhood of the atomic ratio includes ±30% of an intended atomic ratio.

Note that as described later, the metal oxide film can contain an element other than indium and zinc. In that case, the sum of the content percentage of indium and the content percentage of zinc in the metal oxide film is preferably greater than or equal to 95%. Here, the content percentage of indium refers to the proportion of the number of indium atoms to the sum of the number of atoms of all metal elements contained in a metal oxide film. Similarly, the content percentage of zinc refers to the proportion of the number of zinc atoms to the sum of the number of atoms of all metal elements contained in a metal oxide film.

Here, a crystal structure of a crystal included in a metal oxide film will be described. Specifically, a crystal structure of a crystal included in a metal oxide film containing indium and zinc (also referred to as an In—Zn oxide film) is described. Hereinafter, a crystal structure of a crystal included in a metal oxide film is simply referred to as a crystal structure of a metal oxide in some cases. A crystal structure of a crystal included in an In—Zn oxide film is simply referred to as a crystal structure of an In—Zn oxide in some cases.

FIG. 1A to FIG. 1C are drawings illustrating the atomic arrangement in a crystal included in an In—Zn oxide film. In each of FIG. 1A to FIG. 1C, an atom is represented by a sphere (a circle) and a bond between a metal atom and an oxygen atom is represented by a line, whereby the atomic arrangement in the crystal is illustrated. In each of FIG. 1A to FIG. 1C, the arrow denotes the c-axis direction in the crystal structure of the In—Zn oxide. The direction perpendicular to the c-axis direction denoted by the arrow in each of FIG. 1A to FIG. 1C is the a-b plane direction in the crystal structure of the In—Zn oxide.

Here, atoms ME1 are indium atoms. Note that some of the atoms ME1 are zinc atoms in some cases. Atoms ME2 are indium atoms or zinc atoms.

As illustrated in FIG. 1A, the crystal included in the In—Zn oxide film has an alternating-layer structure of a layer 31 containing atoms ME1 and oxygen atoms (O) and a layer 32 containing atoms ME2 and oxygen atoms O. In the crystal structure illustrated in FIG. 1A, the layer 31 includes one layer, and the layer 32 includes three layers (two layers 32a and one layer 32b). The layer 32a is adjacent to the layer 31, and the layer 32b is positioned between the two layers 32a. Note that the crystal structure of the In—Zn oxide illustrated in FIG. 1A belongs to a space group P6₃/mmc. That is, the crystal structure can also be regarded as a hexagonal crystal structure.

Note that between the two layers 31, the two layers 32a have an inversion symmetry relationship with respect to the layer 32b (a plane including the atom M2 positioned in the layer 32b). That is, the two layers 32a are equivalent and thus are denoted by the same reference numeral.

For example, the crystal included in the In—Zn oxide film with Zn/In of 1.0 can have the crystal structure illustrated in FIG. 1A.

Here, it is assumed that the In—Zn oxide with Zn/In of 1.0 has the crystal structure illustrated in FIG. 1A and indium atoms are placed in all the sites of the atoms ME1. At this time, indium atoms are placed in ⅓ of the sites of the atoms ME2, and zinc atoms are placed in the remaining ⅔ of the sites of the atoms ME2. In other words, the indium atoms and the zinc atoms are present at an In:Zn ratio of 1:2 in the layer 32.

Note that the layer 31 corresponds to the first layer or the second layer described above, and the layer 32 corresponds to the third layer described above. Thus, the layer 31 can be rephrased as the first layer or the second layer. The layer 32 can be rephrased as the third layer.

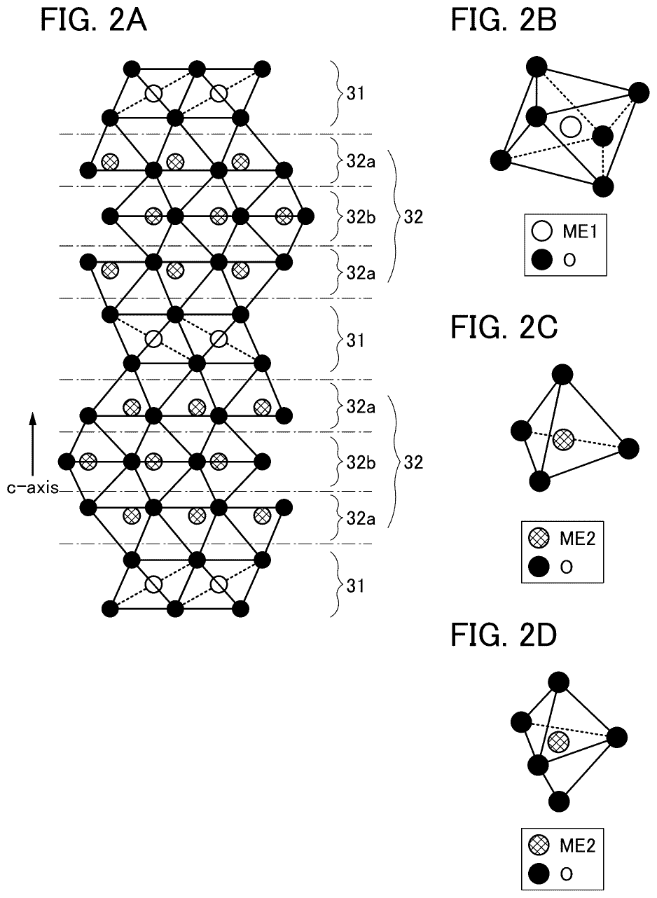

Next, the atomic arrangement in the crystal is expressed as polyhedrons. FIG. 2A is a diagram in which the atomic arrangement in the crystal illustrated in FIG. 1A is expressed as polyhedrons. Note that a polyhedron included in the layer 31 is illustrated in FIG. 2B, and polyhedrons that can be included in the layer 32 are illustrated in FIG. 2C and FIG. 2D.

The polyhedron illustrated in FIG. 2B has an octahedral structure. The octahedral structure includes an atom ME1 at the center or in the vicinity thereof and includes oxygen atoms at the vertexes. In the layer 31, such octahedral structures are edge-shared.

The polyhedron illustrated in FIG. 2C has a tetrahedral structure. The tetrahedral structure includes the atom ME2 at the center or in the vicinity thereof and oxygen atoms at the vertexes. The polyhedron illustrated in FIG. 2D is a trigonal bipyramidal structure. The trigonal bipyramidal structure includes the atom ME2 at the center or in the vicinity thereof and includes oxygen atoms at the vertexes. The tetrahedral structures are vertex-shared in the layer 32a illustrated in FIG. 2A, and the trigonal bipyramidal structures are vertex-shared in the layer 32b illustrated in FIG. 2A.

Note that a trigonal bipyramidal structure is present in the layer 32a in some cases. In this case, the trigonal bipyramidal structure is vertex-shared with the tetrahedral structure included in the layer 32a. In addition, the tetrahedral structure is present in the layer 32b in some cases. In that case, the tetrahedral structure is vertex-shared with the trigonal bipyramidal structure included in the layer 32b.

In FIG. 2A, the layer 31 and the layer 32a are vertex-shared. The layer 32a and the layer 32b are vertex-shared. Note that the structure of the layer 32 may differ depending on the number of layers being present in the layer 32. For example, in some cases, the layer 32 includes two layers 32b, and the two layers 32b are adjacent to each other. In that case, the two layers 32b are edge-shared. As described above, one layer included in the layer 32 may include a trigonal bipyramidal structure and a tetrahedral structure. In that case, two adjacent layers included in the layer 32 may be vertex-shared and edge-shared.

FIG. 1A and FIG. 2A illustrate an example of the crystal structure of the In—Zn oxide with Zn/In of 1.0. Note that the metal oxide film may be an In—Zn oxide film represented by a composition Numerical Formula In₂O₃(ZnO). (m is a positive real number), for example. At this time, Zn/In is m/2. That is, FIG. 1A and FIG. 2A show the crystal structure of the In—Zn oxide represented by the composition Numerical Formula In₂O₃(ZnO)ₘ where m is 2.

In the case where Zn/In is 0.5 (i.e., m is 1), the layer 31 includes one layer and the layer 32 includes two layers 32c in the crystal structure of the In—Zn oxide film (see FIG. 1). Note that the crystal structure of the In—Zn oxide illustrated in FIG. 1B belongs to a space group R-3m. That is, the crystal structure can be regarded as a hexagonal crystal structure (especially, a trigonal crystal structure) or a YbFe₂O₄-type structure. For example, the crystal included in the In—Zn oxide film having Zn/In of 0.5 can have the crystal structure illustrated in FIG. 1B.

Note that between the two layers 31, one of the two layers 32c is inverted with respect to a plane between the two layers 32c, and is translated parallel to the direction perpendicular to the c-axis, whereby the atomic arrangements of the two layers 32c match with each other. In other words, the two layers 32c are equivalent and thus are denoted by the same reference numeral.

In the layer 32c illustrated in FIG. 1B, the trigonal bipyramidal structures are vertex-shared. The layer 31 and the layer 32c are vertex-shared and the two layers 32c are edge-shared.

Here, it is assumed that the In—Zn oxide with Zn/In of 0.5 has the crystal structure illustrated in FIG. 1B and indium atoms are placed in all the sites of the atoms ME1. At this time, indium atoms are placed in ½ of the sites of the atoms ME2, and zinc atoms are placed in the remaining ½ of the sites of the atoms ME2. In other words, the indium atoms and the zinc atoms are present at an In:Zn ratio of 1:1 in the layer 32.

In the case where Zn/In is 0.25 (m is 0.5), the layer 31 includes three layers (two layers 31a and one layer 31b) and the layer 32 includes two layers 32c in the crystal included in the In—Zn oxide film (see FIG. 1C). The layer 31a is adjacent to the layer 32, and the layer 31b is positioned between the two layers 31a. Note that the crystal structure of the In—Zn oxide illustrated in FIG. 1C belongs to a space group P6₃/mmc. That is, the crystal structure can also be regarded as a hexagonal crystal structure or a Yb₂Fe₃O₇-type structure.

Note that between the two layers 32, the two layers 31a have an inversion symmetry relationship with respect to the layer 31b (a plane including the atom M1 positioned in the layer 31b). That is, the two layers 31a are equivalent and thus are denoted by the same reference numeral.

For example, the crystal included in the In—Zn oxide film with Zn/In of 0.25 can have the crystal structure illustrated in FIG. 1C. Note that the In—Zn oxide film with Zn/In of 0.25 can be referred to also as a metal oxide film having a composition with an atomic ratio of In:Zn=4:1 or in the neighborhood thereof.

The octahedral structures are edge-shared in the layer 31a illustrated in FIG. 1C, and the trigonal bipyramidal structures are vertex-shared in the layer 31b illustrated in FIG. 1C. The layer 31a and the layer 32c are vertex-shared, and the layer 31a and the layer 31b are vertex-shared.

Here, it is assumed that the In—Zn oxide with Zn/In of 0.25 has the crystal structure illustrated in FIG. 1C and indium atoms are placed in all the sites of the atoms ME1. At this time, indium atoms are placed in ½ of the sites of the atoms ME2, and zinc atoms are placed in the remaining ½ of the sites of the atoms ME2. In other words, the indium atoms and the zinc atoms are present at an In:Zn ratio of 1:1 in the layer 32.

In the layer 31b, zinc atoms are placed in some of the sites of the atoms ME1 in some cases.

Note that in the case where Zn/In is greater than 0 and less than 0.5 (m is greater than 0 and less than 1), the crystal included in the In—Zn oxide film may include the layer 31 including one layer, the layer 31 including three layers, and the layer 32 including two layers. In the case where Zn/In is greater than 0.5 and less than 1.0 (m is greater than 1 and less than 2), the crystal included in the In—Zn oxide film may include the layer 31 including one layer, the layer 32 including two layers, and the layer 32 including three layers.

Note that the relationship between the stacked-layer structure of the layer 31 and the layer 32 and the Zn/In in the metal oxide film is not limited to the above. For example, even when the Zn/In is 0.25 or a value in the neighborhood thereof, the layer 31 including one layer or the layer 32 including three or more layers may be present. Furthermore, even when the Zn/In is 0.5 or a value in the neighborhood thereof, the layer 31 including three layers or the layer 32 including three or more layers may be present. Furthermore, even when the Zn/In is 1.0 or a value in the neighborhood thereof, the layer 32 including two layers or the layer 32 including four or more layers may be present.

Note that a crystal of indium oxide corresponding to the case where m is 0 has a cubic crystal structure (bixbyite structure). Note that the crystal structure belongs to a space group Ia-3.

The above is the description of the crystal structure of the crystal included in the metal oxide film.

A crystal structure of a metal oxide can be evaluated by observation of a high-angle annular dark field scanning transmission electron microscope (HAADF-STEM) image, for example. Note that in a HAADF-STEM image, a contrast proportional to the square of the atomic number is obtained. Specifically, an atom can be observed with a luminance proportional to the square of the atomic number. Accordingly, the brighter the point is, the larger the atomic number of the atom is.

The atomic number of indium is 49 and the atomic number of zinc is 30. Therefore, in a HAADF-STEM image of an In—Zn oxide, the luminance of indium is high and the luminance of zinc is low. Specifically, the ratio of the luminance of zinc to the luminance of indium is approximately 0.37.

As described above, the atom ME1 included in the layer 31 is an indium atom, and the atom ME2 included in the layer 32 is an indium atom or a zinc atom. Thus, in the HAADF-STEM image, the layer 31 is observed as an arrangement of atoms with high luminance, and the layer 32 is observed as an arrangement of atoms with low luminance. That is, in the HAADF-STEM image, the arrangement of atoms with high luminance can be regarded as the layer 31, and the arrangement of atoms with low luminance can be regarded as the layer 32. Thus, the metal oxide film of one embodiment of the present invention includes a region where the arrangement of atoms with high luminance and the arrangement of atoms with low luminance are alternately observed in the HAADF-STEM image.

For example, since indium atoms and zinc atoms are present at the In:Zn ratio of 1:2 in the layer 32 in the In—Zn oxide (FIG. 1A) having Zn/In of 1.0, the luminance ratio of the layer 32 to the layer 31 is approximately 0.58. For example, since indium atoms and zinc atoms are present at the In:Zn ratio of 1:1 in the layer 32 in the In—Zn oxide (FIG. 1B) having Zn/In of 0.5, the luminance ratio of the layer 32 to the layer 31 is approximately 0.69. For another example, since indium atoms and zinc atoms are present at the In:Zn ratio of 1:1 in the layer 32 in the In—Zn oxide (FIG. 1C) having Zn/In of 0.25, the luminance ratio of the layer 32 to the layer 31 is approximately 0.69.

With reference to the above, the number of layers included in the layer 31 and the number of layers included in the layer 32 can be confirmed.

Note that in the case where an In—Zn oxide has a cubic crystal structure, zinc forms a solid solution with indium oxide. That is, the regularity of the arrangement of zinc atoms and indium atoms is not seen. Thus, a contrast difference in luminance of a cubic crystal structure observed in the HAADF-STEM image is small.

The crystal structure of the metal oxide film can be evaluated from an electron diffraction (ED) pattern, for example. Note that when FFT (Fast Fourier Transform) analysis is performed on a transmission electron microscope (TEM) image, an FFT pattern having a pattern reflecting reciprocal lattice space information similar to an electron diffraction pattern can be obtained. For example, in the case of a cross-sectional TEM image of a metal oxide having a layered crystal structure taken from the direction perpendicular to the c-axis, two spots having high intensity are observed in the FFT pattern in some cases. Furthermore, a line segment connecting these two spots represents the direction of the c-axis.

In the above-described manner, the crystal structure of the metal oxide can be evaluated.

Thus, it is preferable to use a semiconductor material having high carrier mobility as the semiconductor layer of the transistor. When a semiconductor material having a high carrier mobility is used as the semiconductor layer, the on-state current or the field-effect mobility of the transistor can be increased. Accordingly, the semiconductor device including the transistor can operate faster.

The carrier mobility has a relationship with the carrier effective mass, as represented by a numerical formula (1) below.

$$\begin{matrix}[ Numerical Formula 1 ] & \\ μ = \frac{q τ}{{m}^{*}} & ( 1 )\end{matrix}$$

In the numerical formula (1) above, μ is the carrier mobility, m* is the carrier effective mass, τ is the carrier relaxation time, and q is elementary charge.

An OS transistor is an accumulation transistor in which electrons are majority carriers. That is, carriers in an OS transistor are electrons. Assuming that the carrier relaxation time is constant, the electron (carrier) mobility is higher as the electron (carrier) effective mass is smaller. That is, a transistor in which a metal oxide film with a small electron effective mass is used as a semiconductor layer can have a high on-state current or a high field-effect mobility.

Thus, the electron effective mass in the metal oxide film of one embodiment of the present invention is preferably small. For example, the electron effective mass in the metal oxide film of one embodiment of the present invention is preferably smaller than the electron effective mass in indium oxide. Note that in the case where the metal oxide film includes a crystal, the electron effective mass in the crystal may be regarded as the electron effective mass in the metal oxide film. That is, the electron effective mass in the crystal included in the metal oxide film of one embodiment of the present invention is preferably small. For example, the electron effective mass in the crystal included in the metal oxide film of one embodiment of the present invention is preferably smaller than the electron effective mass in indium oxide having a cubic crystal structure.

Here, the electron effective mass in the metal oxide film (the electron effective mass in the crystal included in the metal oxide film) is described.

The electron effective mass can be calculated in such a manner that a calculation model is prepared and band edges in an E-k dispersion curve are fitted with a quadratic function, for example. Note that the E-k dispersion curve can also be referred to as a band diagram. For example, a band diagram of a calculation model can be created using first-principles calculation to calculate the electron effective mass. Note that the electron effective mass described in this specification and the like may refer to an effective mass obtained by dividing the electron effective mass by the electron rest mass.

Here, calculation models of a metal oxide are prepared to calculate the electron effective mass.

First, the calculation models of a metal oxide used for first-principles calculation are described. Metal oxides with Zn/In of 0.25, 0.5, 1.0, and 1.5 have the above-described layered crystal structures. Specifically, the metal oxide with Zn/In of 0.25 has the crystal structure illustrated in FIG. 1C, the metal oxide with Zn/In of 0.5 has the crystal structure illustrated in FIG. 1, and the metal oxide with Zn/In of 1.0 has the crystal structure illustrated in FIG. 1A. In addition, the metal oxide with Zn/In of 1.5 has a crystal structure in which the layer 32 including four layers is present (crystal structure belonging to the space group R-3m). The calculation models including crystals having the above crystal structures are prepared. For reference, a calculation model of indium oxide is also prepared. As described above, indium oxide has a cubic crystal structure.

As described above, the atom ME2 in the layer 32 is an indium atom or a zinc atom. In order to perform the first-principles calculation, an indium atom or a zinc atom needs to be placed in each of the sites of the atoms ME2. Thus, in this embodiment, the arrangement search in the layer 32 is performed with the use of ATAT (Alloy Theoretic Automated Toolkit) software disclosed in Non-Patent Document 1. The ATAT is software for efficiently searching structures with the use of a combination of first-principles calculation and a cluster expansion method. In this embodiment, as first-principles calculation software, VASP Package (Vienna Ab initio Simulation) is used.

By performing the above arrangement search, an energetically stable calculation model is obtained. Then, a band diagram is created using the obtained calculation model to calculate the electron effective mass. For creation of a band diagram and calculation of the electron effective mass, atomic-scale simulation software “QuantumATK” produced by Synopsys, Inc. is used.

Note that in the calculation using “QuantumATK”, a density functional theory (DFT) method using Linear Combination of Atomic Orbitals (LCAO) expansion is used. The cut-off energy is set to 125 Hartree (3.40×10³ eV).

In the calculation for optimizing the structure of the calculation model, Generalized Gradient Approximation (GGA) is used as a functional. In the calculation of the band diagram and the electron effective mass, a DFT+½ method is used as a band gap correction method in addition to GGA. Hereinafter, the calculation condition is Condition 1. Note that in the calculation for optimizing the structure of the calculation model, the band diagram calculation, and the calculation of the electron effective mass, a Heyd-Scuseria-Ernzerhof (HSE) hybrid functional (HSE06) may be used as an exchange-correlation functional. Hereinafter, the calculation condition is Condition 2. In addition, as a calculation condition at the time of calculating the electron effective mass in both Condition 1 and Condition 2, the number of points (stencil_order parameter) used in a stencil of the second-order differential method is set to 5, and the distance between neighboring points in the stencil (delta parameter) is set to 0.0001 nm⁻¹.

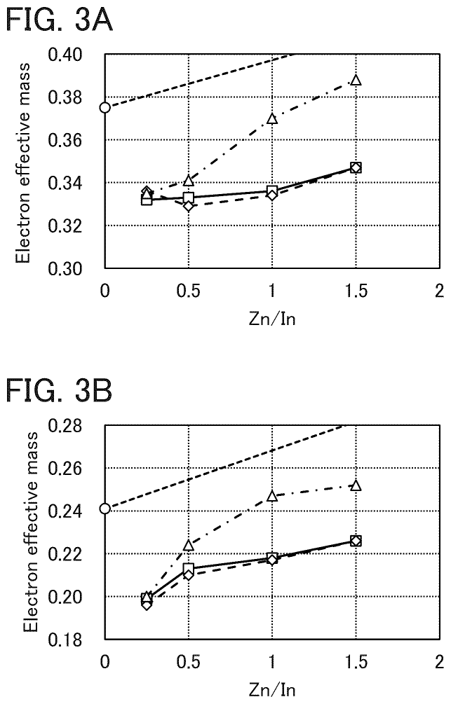

The electron effective mass in the metal oxide is shown in FIG. 3A and FIG. 3B. In FIG. 3A and FIG. 3B, the vertical axis represents the electron effective mass and the horizontal axis represents Zn/In. The quadrangles illustrated in FIG. 3A and FIG. 3B show the result of the electron effective mass along the a-axis direction of the In—Zn oxide, the rhombuses illustrated in FIG. 3A and FIG. 3B show the result of the electron effective mass along the b-axis direction of the In—Zn oxide, the triangles illustrated in FIG. 3A and FIG. 3B show the result of the electron effective mass along the c-axis direction of the In—Zn oxide, and the circles illustrated in FIG. 3A and FIG. 3B show the result of the electron effective mass in indium oxide. Note that indium oxide has a cubic crystal structure and has the same electron effective mass along the a-axis, the b-axis, and the c-axis; thus, the electron effective mass along the c-axis is shown in FIG. 3A and FIG. 3B. FIG. 3A shows the results in the case of using Condition 1, and FIG. 3B shows the results in the case of using Condition 2.

As illustrated in FIG. 3A and FIG. 3B, the electron effective mass in the In—Zn oxide having a layered crystal structure increases with an increase of Zn/In. Conversely, the lower Zn/In becomes, the smaller the electron effective mass becomes. The In—Zn oxide having a layered crystal structure has a smaller electron effective mass than indium oxide. Specifically, in Condition 1, the electron effective mass in the In—Zn oxide whose Zn/In is higher than 0 and lower than 1.5 is smaller than the electron effective mass (0.375) in indium oxide along all of the a-axis, the b-axis, and the c-axis. In Condition 2, the electron effective mass in the In—Zn oxide whose Zn/In is higher than 0 and lower than 1.0 is smaller than the electron effective mass (0.241) in indium oxide in all of the a-axis, the b-axis, and the c-axis.

Although the details will be described in Embodiment 2, the electron effective mass along the c-axis of a crystal included in the metal oxide film may be larger than the electron effective mass in indium oxide in some cases. That is, the In—Zn oxide may have a Zn/In of higher than 1.0 in some cases. Moreover, the Zn/In may be higher than 1.5 in some cases.

Indium oxide has a cubic crystal structure. Note that in an In—Zn oxide with low Zn/In, zinc forms a solid solution with indium oxide in some cases. In the case where the above tendency (the electron effective mass increases as Zn/In increases) is observed in the In—Zn oxide in which zinc forms a solid solution with indium oxide, the electron effective mass in the In—Zn oxide is presumably larger than that of indium oxide (see dashed lines starting from the circles in FIG. 3A and FIG. 3B). Note that the slope of the dashed line illustrated each of in FIG. 3A and FIG. 3B is equal to the slope of an approximate straight line of the average value of the a-axis, the b-axis, and the c-axis in the electron effective mass in the In—Zn oxide.

Accordingly, the metal oxide in which the Zn/In is higher than 0 and lower than 1.5 preferably has a layered crystal structure. When the In—Zn oxide has a layered crystal structure, the electron effective mass can be smaller than that in indium oxide. In other words, the In—Zn oxide can have high electron mobility (carrier mobility).

By the above method, the band edges in the E-k dispersion curve are fitted with a quadratic function to calculate the electron effective mass. Note that the method for calculating the electron effective mass is not limited to the above method. The electron effective mass may be calculated without using the E-k dispersion curve (band diagram).

Next, another method for calculating the electron effective mass in the metal oxide film is described.

In the case where the metal oxide film is a degenerated semiconductor or in the case where the conduction band of the metal oxide is degenerated with an increase in the carrier concentration of the metal oxide film, the light absorption edge is shifted toward blue due to the Burstein-Moss effect (hereinafter referred to as a BM effect). In other words, the light absorption edge is shifted in the direction in which an apparent band gap is increased.

The amount of shift in the band gap due to the BM effect (also referred to as the amount of BM shift), the carrier concentration n, and the carrier effective mass m* have a relationship represented by a numerical formula (2) below.

$$\begin{matrix}[ Numerical Formula 2 ] & \\ ΔE = \frac{{𝒽}^{2}}{2 {m}^{*}} {( 3 {π}^{2} n )}^{\frac{2}{3}} & ( 2 )\end{matrix}$$

In the above numerical formula (2), ΔE is the amount of BM shift. In addition, h with a bar is a reduced Planck constant (also referred to as Dirac's constant) and is a value obtained by dividing the Planck constant by 2π. From the above numerical formula (2), the carrier effective mass can be calculated from the amount of BM shift and the carrier concentration.

Note that the amount of BM shift can be calculated by a method capable of evaluating the band gap. The carrier concentration can be calculated by Hall effect measurement, for example.

The bandgap of the metal oxide film can be evaluated by optical evaluation with a spectrophotometer, spectroscopic ellipsometry, a photoluminescence method, X-ray photoelectron spectroscopy (XPS: X-ray Photoelectron Spectrometry or ESCA: Electron Spectrometry for Chemical Analysis)), an X-ray Absorption Fine Structure (XAFS), or the like. Alternatively, these methods may be combined to be employed for analysis.

The Hall effect measurement is a method for measuring electric properties such as carrier concentration, mobility, and resistivity with the use of the Hall effect, which is the production of an electromotive force in a direction perpendicular to both current and magnetic field when the magnetic field is applied to a sample in which current flows, perpendicularly to the direction of current flow.

The above is the description of the electron effective mass in the metal oxide film (the electron effective mass in the crystal included in the metal oxide film).

Note that the metal oxide film of one embodiment of the present invention may further contain an element M in addition to indium and zinc. The element M is aluminum, gallium, yttrium, or tin. Other examples that can be used as the element M include boron, titanium, silicon, iron, nickel, germanium, zirconium, molybdenum, lanthanum, cerium, neodymium, hafnium, tantalum, tungsten, magnesium, and cobalt. Note that a combination of two or more of the above elements may be used as the element M.

The content percentage of the element M in the metal oxide film (the proportion of the number of element M atoms to the sum of the number of atoms of all the metal elements contained) is preferably greater than or equal to 0.1% and less than or equal to 10%, further preferably greater than or equal to 0.1% and less than or equal to 5%, further preferably greater than or equal to 0.1% and less than or equal to 3%, still further preferably greater than or equal to 0.1% and less than or equal to 2%. Here, the sum of the content percentage of indium and the content percentage of zinc is higher than or equal to 90%, higher than or equal to 95%, higher than or equal to 97%, or higher than or equal to 98% and lower than 100%.

Aluminum, gallium, or tin is preferably used as the element M. These elements each have a higher bond energy with oxygen than indium and zinc do. Accordingly, generation of oxygen vacancies in the metal oxide film can be inhibited. Accordingly, a transistor with favorable electrical characteristics can be provided.

In particular, tin is preferable as the element M. When tin is added to the metal oxide film, carrier mobility can be increased.

Specifically, as the metal oxide film, a metal oxide having an atomic ratio of In:M:Zn=40:2:10 or in the neighborhood thereof, or In:M:Zn=40:1:10 or in the neighborhood thereof can be used.

In the case where a calculation model of an In—Sn—Zn oxide with an atomic ratio of In:Sn:Zn=40:1.3:12 is prepared, which is an example of a metal oxide having a composition with an atomic ratio of In:M:Zn=40:1:10 or in the neighborhood thereof, and the electron effective mass is calculated using Condition 2 described above, the electron effective masses along the a-axis, the b-axis, and the c-axis are 0.213, 0.211, and 0.231, respectively and each smaller than the electron effective mass in indium oxide (0.241).

Analysis of the composition of the metal oxide film can be performed by Energy Dispersive X-ray Spectrometry (EDX), XPS, Inductively Coupled Plasma-Mass Spectrometry (ICP-MS), or Inductively Coupled Plasma-Atomic Emission Spectrometry (ICP-AES). Alternatively, these methods may be combined and employed for analysis. It is preferable that peak separation of a spectrum obtained by the analysis be performed to identify and quantify an element. As for an element whose content percentage is low, the actual content percentage may be different from the content percentage obtained by analysis because of the influence of the analysis accuracy. In the case where the content percentage of the element M is low, for example, the content percentage of the element M obtained by analysis is lower than the actual content percentage, the content percentage of the element M may be difficult to quantify, or the element M is below the lower detection limit in some cases.

That is, by using a metal oxide film of one embodiment of the present invention as a semiconductor layer, the on-state current or the field-effect mobility of the transistor can be increased. Consequently, the electrical characteristics of the transistor can be increased.

This embodiment can be implemented in an appropriate combination with any of the structures described in the other embodiments and the like.

### Embodiment 2

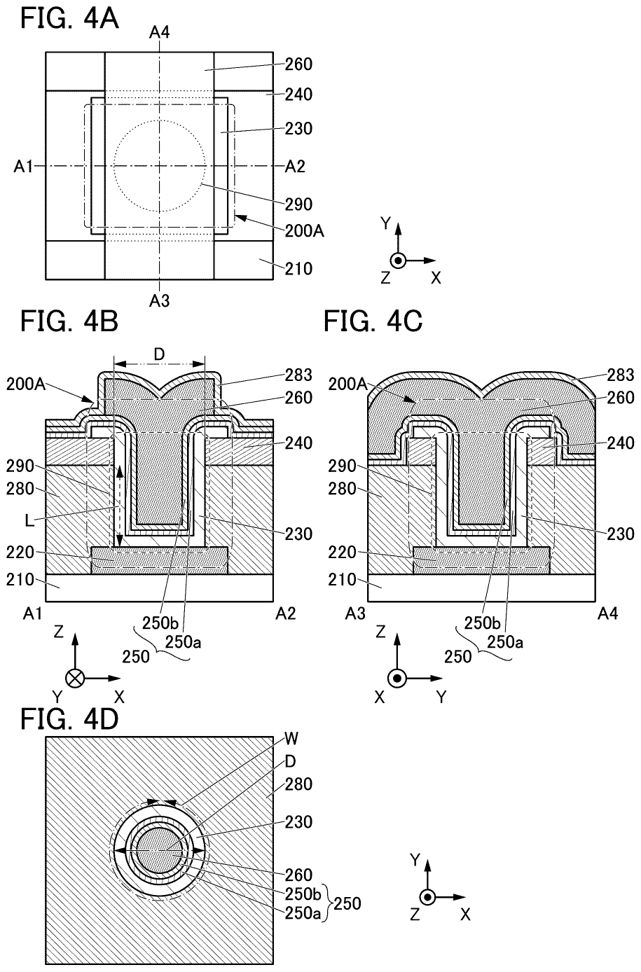

In this embodiment, an example of a semiconductor device of one embodiment of the present invention will be described with reference to FIG. 4A to FIG. 16D.

### Structure Example 1 of Semiconductor Device

An example of a structure of a semiconductor device of one embodiment of the present invention will be described with reference to FIG. 4A to FIG. 4D. FIG. 4A to FIG. 4D is a plan view and cross-sectional views of a semiconductor device including a transistor 200A. FIG. 4A is a plan view of the semiconductor device. FIG. 4B to FIG. 4D are the cross-sectional views of the semiconductor device. Here, FIG. 4B is the cross-sectional view taken along the dashed-dotted line A1-A2 in FIG. 4A. FIG. 4C is a cross-sectional view taken along the dashed-dotted line A3-A4 in FIG. 4A.

In the drawings for this specification and the like, arrows indicating an X direction, a Y direction, and a Z direction are illustrated in some cases. In this specification and the like, the “X direction” is a direction along the X axis, and unless otherwise specified, the forward direction and the reverse direction are not distinguished in some cases. The same applies to the “Y direction” and the “Z direction”. The X direction, the Y direction, and the Z direction are directions intersecting with each other. For example, the X direction, the Y direction, and the Z direction are directions orthogonal to each other. In this specification and the like, one of the X direction, the Y direction, and the Z direction is referred to as a “first direction” in some cases. Another one of the directions is referred to as a “second direction” in some cases. The remaining one of the directions is referred to as a “third direction” in some cases.

The semiconductor device illustrated in FIG. 4A to 4D includes an insulating layer 210 over a substrate (not illustrated), the transistor 200A over the insulating layer 210, the insulating layer 280 over the insulating layer 210, and an insulating layer 283 over the transistor 200A. The insulating layer 210 functions as an interlayer film.

The transistor 200A includes a conductive layer 220, a conductive layer 240 over the insulating layer 280, a semiconductor layer 230, an insulating layer 250 over the semiconductor layer 230, and a conductive layer 260 over the insulating layer 250. Note that in FIG. 4B to FIG. 4D, the insulating layer 250 includes an insulating layer 250a and an insulating layer 250b over the insulating layer 250a.

As illustrated in FIG. 4B and FIG. 4C, the insulating layer 280 is provided over the conductive layer 220. The opening portion 290 reaching the conductive layer 220 is provided in the insulating layer 280 and the conductive layer 240. That is, the opening portion 290 is provided in a region overlapping with the conductive layer 220 in the plan view. Here, the bottom portion of the opening portion 290 is also the top surface of the conductor layer 220, and the sidewall of the opening portion 290 is also the side surface of the insulating layer 280 and the side surface of the conductive layer 240. The opening portion 290 includes an opening portion included in the insulating layer 280 and an opening portion included in the conductive layer 240. The opening portion included in the conductive layer 240 includes a region overlapping with the opening portion included in the insulating layer 280.

At least part of the components of the transistor 200A is placed in the opening portion 290. Specifically, at least part of each of the semiconductor layer 230, the insulating layer 250, and the conductive layer 260 is placed in the opening portion 290.

Therefore, the semiconductor layer 230 is provided so as to cover the bottom portion and the sidewall of the opening portion 290, the insulating layer 250 is provided to cover the semiconductor layer 230, and the conductive layer 260 is provided so as to be embedded in the depression, which reflects the shape of the opening portion 290, of the insulating layer 250. Thus, portions of the semiconductor layer 230, the insulating layer 250, and the conductive layer 260 which are placed in the opening portion 290 reflect the shape of the opening portion 290.

In the transistor 200A, the semiconductor layer 230 functions as a semiconductor layer where a channel is formed, the conductive layer 260 functions as a gate electrode, the insulating layer 250 functions as a gate insulating layer, the conductive layer 220 functions as one of a source electrode and a drain electrode, and the conductive layer 240 functions as the other of the source electrode and the drain electrode. Note that the gate insulating layer is also referred to as a gate insulating film or a gate insulator in some cases.

The semiconductor layer 230 is provided inside the opening portion included in the insulating layer 280. The transistor 200A has a structure in which current flows in the vertical direction since one of the source electrode and the drain electrode (here, the conductive layer 220) is positioned on the lower side and the other of the source electrode and the drain electrode (here, the conductive layer 240) is positioned on the upper side. That is, a channel is formed along the side surface of the opening portion included in the insulating layer 280.

In the transistor 200A, as the semiconductor layer 230 including the channel formation region, a metal oxide (also referred to as an oxide semiconductor) functioning as a semiconductor is preferably used. The semiconductor layer 230 is particularly preferably formed using the metal oxide film described in Embodiment 1. When the semiconductor layer 230 is formed using the metal oxide film described in Embodiment 1, the on-state current or the field-effect mobility of the transistor can be increased. Consequently, the electrical characteristics of the transistor can be increased.

In a transistor using oxide semiconductor for its semiconductor layer (OS transistor), when oxygen vacancies (V_{O}) and impurities are in the channel formation region of the oxide semiconductor, the electrical characteristics of the OS transistor easily vary and the reliability thereof may worsen in some cases. In some cases, a defect that is an oxygen vacancy into which hydrogen enters (hereinafter also referred to as V_{O}H in some cases) generates an electron serving as a carrier. Thus, when the channel formation region of the oxide semiconductor includes oxygen vacancies, the OS transistor tends to have normally-on characteristics. Therefore, the oxygen vacancies and the impurities are preferably reduced as much as possible in the channel formation region of the oxide semiconductor. In other words, the oxide semiconductor preferably includes an i-type (intrinsic) or substantially i-type channel formation region with a low carrier concentration.

Note that “normally-on characteristics” in this specification and the like mean a state where a channel exists without voltage application to a gate and a current flows through a transistor. Furthermore, “normally-off characteristics” mean a state where a current does not flow through a transistor when no potential or a ground potential is applied to a gate.

Meanwhile, preferably, the source region and the drain region of the OS transistor include more oxygen vacancies, include more V_{O}H, or have a higher concentration of an impurity such as hydrogen, nitrogen, or a metal element than the channel formation region, and thus are low-resistance regions with high carrier concentrations. In other words, the source region and the drain region of the OS transistor are preferably n-type regions having higher carrier concentrations and lower resistances than the channel formation region.

For the insulating layer 280, any of the barrier insulators against hydrogen described in [Insulator] below is preferably used. When the insulating layer 280 provided outside the semiconductor layer 230 has a barrier property against hydrogen, diffusion of hydrogen into the semiconductor layer 230 can be inhibited.

Silicon nitride is preferably used for the insulating layer 280, for example. In that case, the insulating layer 280 contains silicon and nitrogen.

As described later, in the case where the insulating layer 280 has a barrier property against hydrogen, the insulating layer 280 also has a barrier property against oxygen. The insulating layer 280 includes a region in contact with the semiconductor layer 230. Accordingly, when the insulating layer 280 has a barrier property against oxygen, oxygen extraction from the semiconductor layer 230 and formation of oxygen vacancies in the semiconductor layer 230 can be inhibited.

For the insulating layer 250a, any of the insulators having a function of capturing or fixing hydrogen described in [Insulator] below is preferably used. When the insulating layer 250a provided in contact with the semiconductor layer 230 has a function of capturing or fixing hydrogen, the hydrogen concentration in the semiconductor layer 230 positioned inside the insulating layer 280 can be reduced. At this time, hydrogen in the semiconductor layer 230 is captured or fixed by the insulating layer 250a, so that the hydrogen concentration in the insulating layer 250a becomes high. For example, the hydrogen concentration in the insulating layer 250a is higher than the hydrogen concentration in the semiconductor layer 230. In other words, the semiconductor layer 230 includes a region where the hydrogen concentration is lower than the hydrogen concentration in the insulating layer 250a.

In an example, in the case where the hydrogen concentration in the semiconductor layer 230 obtained by secondary ion mass spectrometry (SIMS) is lower than 1×10¹⁹ atoms/cm³ in the channel formation region, the hydrogen concentration in at least a region of the insulating layer 250a obtained by SIMS is higher than or equal to 1×10¹⁹ atoms/cm³ or higher than or equal to 1×10²⁰ atoms/cm³.

For the insulating layer 250a, hafnium oxide is preferably used, for example. Here, the insulating layer 250a contains hafnium and oxygen.

Hafnium oxide may have an amorphous structure depending on deposition conditions. In addition, hafnium oxide partly includes a crystal region in some cases. In addition, hafnium oxide includes a crystal grain boundary in some cases. Thus, hafnium oxide has a property of capturing or fixing hydrogen and thus is suitable for the insulating layer 250a.

Note that addition of silicon to hafnium oxide can inhibit polycrystallization of hafnium oxide. That is, an oxide containing hafnium and silicon is likely to have an amorphous structure. Thus, an oxide containing hafnium and silicon has a property of capturing or fixing hydrogen and thus is suitable for the insulating layer 250a. Note that inhibiting polycrystallization can increase the planarity of the film. Thus, the thickness distribution of a film provided on the insulating layer 250a can be uniform. In the oxide containing hafnium and silicon, the atomic ratio of silicon to hafnium is preferably greater than 0 and less than 2, further preferably greater than 0 and less than 1, still further preferably greater than 0 and less than 0.5.

In addition, hafnium oxide is also a high permittivity (high-k) material. The oxide containing hafnium and silicon is a high permittivity (high-k) material depending on the silicon content. Accordingly, a high-k material is used for an insulating layer functioning as a gate insulating layer, and thereby a gate potential applied during operation of the transistor can be reduced while the physical thickness is maintained. Furthermore, the equivalent oxide thickness (EOT) of the insulator functioning as the gate insulating layer can be reduced.

The film thickness of the insulator layer 250a is preferably greater than or equal to 0.5 nm and less than or equal to 15 nm, further preferably greater than or equal to 0.5 nm and less than or equal to 12 nm, still further preferably greater than or equal to 0.5 nm and less than or equal to 10 nm. Note that the insulating layer 250a at least partly has a region with the above thickness.

As the insulating layer 250b, a barrier insulator against hydrogen is preferably used. With such a structure, the semiconductor layer 230 can be sandwiched between the barrier insulators against hydrogen. For example, hydrogen contained in the conductive layer 260 can be inhibited from diffusing into the semiconductor layer 230. Thus, diffusion of hydrogen into the semiconductor layer 230 can be further inhibited.

Silicon nitride is preferably used for the insulating layer 250b, for example. In that case, the insulating layer 250b contains silicon and nitrogen.

Silicon nitride that can be used for the insulating layer 250b has a barrier property against hydrogen when having a film thickness of 2 nm or more, for example. In order to have a higher barrier property against hydrogen, silicon nitride preferably has a film thickness of 3 nm or more, further preferably 5 nm or more. Note that silicon nitride has a barrier property against oxygen when having a film thickness of 1 nm or more, for example. In order to have a higher barrier property against oxygen, silicon nitride preferably has a film thickness of 2 nm or more. That is, silicon nitride formed with a film thickness enabling a barrier property against hydrogen also has a barrier property against oxygen.

The insulating layer 250b preferably has a barrier property against hydrogen; thus, in the case where silicon nitride is used as the insulating layer 250b, the film thickness of the insulating layer 250b is preferably 2 nm or more, further preferably 3 nm or more. Although there is no particular limitation on the upper limit of the film thickness of the insulating layer 250b, for miniaturization or high integration of the semiconductor device, increased productivity of the semiconductor device, and the like, the film thickness of the insulating layer 250b is preferably 20 nm or less, 10 nm or less, or 5 nm or less. Thus, the insulating layer 250b preferably includes a region with a film thickness greater than or equal to 2 nm and less than or equal to 10 nm, further preferably includes a region with a film thickness greater than or equal to 2 nm and less than or equal to 5 nm. The insulating layer 250b preferably includes a region with a film thickness greater than or equal to 3 nm and less than or equal to 10 nm, further preferably includes a region with a thickness greater than or equal to 3 nm and less than or equal to 5 nm.

As described above, in the case where the insulating layer 250b has a barrier property against hydrogen, the insulating layer 250b also has a barrier property against oxygen. The insulating layer 250b includes a region in contact with the conductive layer 260. Accordingly, when the insulating layer 250b has a barrier property against oxygen, oxygen contained in the semiconductor layer 230 or the insulating layer 250a can be inhibited from diffusing into the conductive layer 260 and oxidizing the conductive layer 260. Furthermore, diffusion of oxygen contained in the semiconductor layer 230 into the conductive layer 260 can be inhibited, and accordingly formation of oxygen vacancies in the semiconductor layer 230 can be inhibited.

Note that diffusion of hydrogen into the semiconductor layer 230 is inhibited by the insulating layer 280; thus, the film thickness of the insulating layer 250b is not limited to the above. For example, the film thickness of the insulating layer 250b may be greater than or equal to 0.1 nm and less than 3 nm, or greater than or equal to 0.1 nm and less than 2 nm.

With the above structure, formation of oxygen vacancies in the channel formation region and diffusion of hydrogen into the channel formation region can be inhibited. Therefore, a semiconductor device having favorable electrical characteristics can be provided. A highly reliable semiconductor device can be provided. A semiconductor device with a small variation in transistor electrical characteristics can be provided. A semiconductor device that has a high on-state current can be provided.

For one or both of the insulating layer 250a and the insulating layer 250b, any of the insulators described in [Insulator] described later may be used as a single layer or stacked layers.

The sidewall of the opening portion 290 is preferably perpendicular to the top surface of the insulating layer 210. This structure enables miniaturization or high integration of the semiconductor device.

Although the opening portion 290 is provided so that the sidewall of the opening portion 290 is perpendicular to the top surface of the insulating layer 210 in FIG. 4B and FIG. 4C, the present invention is not limited thereto. For example, the sidewall of the opening portion 290 may have a tapered shape. When the sidewall of the opening portion 290 has a tapered shape, the coverage with the semiconductor layer 230, the insulating layer 250, and the like can be improved, so that defects such as voids can be reduced. In the case where the sidewall of the opening portion 290 has a tapered shape, the angle between the sidewall of the insulating layer 280 in the opening portion 290 and the top surface of the insulating layer 210 is preferably greater than or equal to 45° and less than 90°, for example. Alternatively, the angle is preferably greater than or equal to 45° and less than or equal to 75°. Alternatively, the angle is preferably greater than or equal to 45° and less than or equal to 65°.

Alternatively, for example, the sidewall of the opening portion 290 may have an inverse tapered shape. In other words, the angle between the side surface of the insulating layer 280 in the opening portion 290 and the top surface of the insulating layer 210 may be larger than 90 degrees in some cases.

The semiconductor layer 230 includes a region in contact with the side surface of the conductive layer 240 in the opening portion 290 and a region in contact with at least part of the top surface of the conductive layer 240. When the semiconductor layer 230 is in contact with not only the side surface but also the top surface of the conductive layer 240 in this manner, the area where the semiconductor layer 230 and the conductive layer 240 are in contact with each other can be increased. The semiconductor layer 230 also includes a region in contact with the top surface of the conductive layer 220 that is exposed in the opening portion 290 and a region in contact with the side surface of the insulating layer 280 in the opening portion 290.

As illustrated in FIG. 4B and FIG. 4C, part of the semiconductor layer 230 is positioned outside the opening portion 290, that is, over the conductive layer 240. Although FIG. 4B illustrates the structure in which the semiconductor layer 230 is divided in the X direction, the present invention is not limited thereto. For example, the semiconductor layer 230 may be provided to extend in the X direction. Also in this case, the semiconductor layer 230 is divided in the Y direction.

FIG. 4C illustrates a structure in which the side end portion of the semiconductor layer 230 is positioned on the opening portion 290 side from the side end portion of the conductive layer 240, outside the opening portion 290. Note that the present invention is not limited thereto. For example, the side end portion of the semiconductor layer 230 and the side end portion of the conductive layer 240 may be aligned with each other. Alternatively, the side end portion of the semiconductor layer 230 may be positioned outward from the side end portion of the conductive layer 240. In that case, the semiconductor layer 230 covers the side end portion of the conductive layer 240 outside the opening portion 290.

The insulating layer 250a is provided in contact with the top surface of the semiconductor layer 230. The insulating layer 250a includes a region in contact with the top surface of the conductive layer 240, a region in contact with the side surface of the conductive layer 240, and a region in contact with the insulating layer 280.

As illustrated in FIG. 4B and FIG. 4C, part of the insulating layer 250 is positioned outside the opening portion 290, that is, over the conductive layer 240 and the insulating layer 280. In that case, the insulating layer 250 preferably covers the side end portion of the semiconductor layer 230. This can prevent a short circuit between the conductive layer 260 and the semiconductor layer 230. The insulating layer 250 preferably covers the side end portion of the conductive layer 240. This can prevent a short circuit between the conductive layer 260 and the conductive layer 240.

The conductive layer 260 is provided in contact with the top surface of the insulating layer 250.

As illustrated in FIG. 4B and FIG. 4C, part of the conductive layer 260 is positioned outside the opening portion 290, that is, over the conductive layer 240 and the insulating layer 280. In that case, the side end portion of the conductive layer 260 is preferably positioned inward from the side end portion of the semiconductor layer 230 as illustrated in FIG. 4B. This can prevent a short circuit between the conductive layer 260 and the semiconductor layer 230. The side end portion of the conductive layer 260 may be aligned with the side end portion of the semiconductor layer 230 or positioned outward from the side end portion of the semiconductor layer 230.

Although the conductive layer 260 is provided to fill the opening portion 290 in FIG. 4B and FIG. 4C, the present invention is not limited thereto. For example, a depressed portion reflecting the shape of the opening portion 290 is formed in the conductive layer 260 and part of the depressed portion is positioned in the opening portion 290 in some cases. In that case, the depressed portion may be filled with an inorganic insulating material or the like.

The conductive layer 240 has the opening portion in a region overlapping with the conductive layer 220. It is preferable that the conductive layer 240 not be provided in the opening portion included in the insulating layer 280. That is, it is preferable that the conductive layer 240 not include a region in contact with the side surface of the insulating layer 280 in the opening portion 290. With such a structure, the opening portion included in the conductive layer 240 and the opening portion included in the insulating layer 280 can be collectively formed. When the side surface of the conductive layer 240 in the opening portion 290 is flush with the side surface of the insulating layer 280 in the opening portion 290, the thickness distribution of the semiconductor layer 230 provided in the opening portion 290 can be uniform. In addition, the semiconductor layer 230 can be inhibited from being divided by a step between the conductive layer 240 and the insulating layer 280.

Although FIG. 4B and FIG. 4C illustrate the structure in which the side surface of the conductive layer 240 in the opening portion 290 is flush with the side surface of the insulating layer 280 in the opening portion 290, the present invention is not limited thereto. For example, the side surface of the conductive layer 240 in the opening portion 290 and the side surface of the insulating layer 280 in the opening portion 290 may be discontinuous. The inclination of the side surface of the conductive layer 240 in the opening portion 290 and the inclination of the side surface of the insulating layer 280 in the opening portion 290 may be different from each other. In that case, for example, the angle between the side surface of the conductive layer 240 in the opening portion 290 and the top surface of the insulating layer 210 is preferably smaller than the angle between the side surface of the insulating layer 280 in the opening portion 290 and the top surface of the insulating layer 210. With such a structure, the coverage of the side surface of the conductive layer 240 with the semiconductor layer 230 in the opening portion 290 is improved, so that defects such as voids can be reduced.

The semiconductor layer 230 includes a first region, and a second region and a third region that are provided such that the first region is sandwiched therebetween.

The second region is a region of the semiconductor layer 230 that is in contact with the conductive layer 220. At least part of the second region functions as one of the source region and the drain region of the transistor 200A. The third region is a region of the semiconductor layer 230 that is in contact with the conductive layer 240. At least part of the third region functions as the other of the source region and the drain region of the transistor 200A.

In the semiconductor layer 230, the first region is a region between the second region and the third region. At least part of the first region functions as the channel formation region of the transistor 200A. That is, the channel formation region of the transistor 200A is positioned in a region of the semiconductor layer 230 that is between the conductive layer 220 and the conductive layer 240. It can be said that the channel formation region of the transistor 200A is positioned in a region of the semiconductor layer 230 that is in contact with the insulating layer 280 or a region in the vicinity thereof.

Here, a cross-sectional view along the XY plane including the insulating layer 280 is illustrated in FIG. 4D. As illustrated in FIG. 4D, the insulating layer 280 is in contact with the entire outer circumference of the semiconductor layer 230. Thus, the channel formation region of the transistor 200A can be formed in the entire outer circumference of a portion of the semiconductor layer 230 that is formed in the same layer as the insulating layer 280. Note that FIG. 4D can be regarded as a cross-sectional view along the XY plane including the channel formation region of the semiconductor layer 230.

The channel length of the transistor 200A is a distance between the source region and the drain region. That is, it can be said that the channel length of the transistor 200A is determined by the film thickness of the insulating layer 280 over the conductive layer 220. In FIG. 4B, the channel length L of the transistor 200A is indicated by a dashed double-headed arrow. In a cross-sectional view, the channel length L is a distance between an end portion of a region where the semiconductor layer 230 is in contact with the conductive layer 220 and an end portion of a region where the semiconductor layer 230 is in contact with the conductive layer 240. That is, the channel length L corresponds to the length of the side surface of the insulating layer 280 on the opening portion 290 side in a cross-sectional view.

The minimum value of the channel length of a planar transistor is limited by the light exposure limit of photolithography, and further Miniaturization is difficult. By contrast, in the present invention, the channel length can be determined by the film thickness of the insulating layer 280. Thus, the transistor 200A can have an extremely small channel length below the light exposure limit of photolithography (e.g., less than or equal to 60 nm, less than or equal to 50 nm, less than or equal to 40 nm, less than or equal to 30 nm, less than or equal to 20 nm, or less than or equal to 10 nm, and greater than or equal to 0.1 nm, greater than or equal to 1 nm, or greater than or equal to 5 nm). Accordingly, the transistor 200A can have a higher on-state current and improved frequency characteristics.

As described above, the channel formation region, the source region, and the drain region can be formed in the opening portion 290. Thus, the area occupied by the transistor 200A can be smaller than the area occupied by a planar transistor in which a channel formation region, a source region, and a drain region are provided separately on the XY plane. Accordingly, high integration of the semiconductor device can be achieved. In the case where the semiconductor device of one embodiment of the present invention is used for a memory device, the memory capacity per unit area can be increased.

As illustrated in FIG. 4D, the semiconductor layer 230, the insulating layer 250 and the conductive layer 260 are provided concentrically. Thus, the side surface of the conductive layer 260 provided at the center faces the side surface of the semiconductor layer 230 with the insulating layer 250 therebetween. That is, in a plan view, the entire circumference of the semiconductor layer 230 serves as the channel formation region. In that case, for example, the channel width of the transistor 200A is determined by the length of the outer circumference of the semiconductor layer 230. That is, it can be said that the channel width of the transistor 200A is determined by the maximum width of the opening portion 290 (the maximum diameter in the case where the opening portion 290 is circular in a plan view). In FIG. 4B and FIG. 4D, a maximum width D of the opening portion 290 is indicated by a dashed double-dotted double-headed arrow. In FIG. 4D, the channel width W of the transistor 200A is indicated by a dashed-dotted double-headed arrow. By increasing the maximum width D of the opening portion 290, the channel width per unit area can be increased and the on-state current can be increased.

In the case where the opening portion 290 is formed by a photolithography method, the maximum width D of the opening portion 290 is determined by the light exposure limit of photolithography. In addition, the maximum width D of the opening portion 290 is determined by the thicknesses of the semiconductor layer 230, the insulating layer 250, and the conductive layer 260 provided in the opening portion 290. The maximum width D of the opening portion 290 is preferably, for example, greater than or equal to 5 nm, greater than or equal to 10 nm, or greater than or equal to 20 nm and less than or equal to 100 nm, less than or equal to 60 nm, less than or equal to 50 nm, less than or equal to 40 nm, or less than or equal to 30 nm. In the case where the opening portion 290 is circular in a plan view, the maximum width D of the opening portion 290 corresponds to the diameter of the opening portion 290, and the channel width W can be calculated by “D×π”.

In the semiconductor device of one embodiment of the present invention, the channel length L of the transistor 200A is preferably smaller than at least the channel width W of the transistor 200A. The channel length L of the transistor 200A of one embodiment of the present invention is greater than or equal to 0.1 times and less than or equal to 0.99 times, preferably greater than or equal to 0.5 times and less than or equal to 0.8 times the channel width W of the transistor 200A. This structure enables the transistor to have excellent electrical characteristics and high reliability.

In the case where the opening portion 290 is formed to be circular in a plan view, the semiconductor layer 230, the insulating layer 250, and the conductive layer 260 are provided concentrically. This makes the distance between the conductive layer 260 and the semiconductor layer 230 substantially uniform, so that a gate electric field can be substantially uniformly applied to the semiconductor layer 230.

Although this embodiment describes the example in which the opening portion 290 is circular in a plan view, the present invention is not limited thereto. For example, the opening portion 290 in a plan view may have an almost circular shape such as an elliptical shape, a polygonal shape such as a quadrangular shape, or a polygonal shape such as a quadrangular shape with rounded corners. In that case, the maximum width of the opening portion 290 can be calculated as appropriate in accordance with the shape of the uppermost portion of the opening portion 290. For example, in the case where the opening portion is quadrangular in a plan view, the maximum width of the opening portion 290 can be the length of a diagonal line of the uppermost portion of the opening portion 290.

As described above, the metal oxide film described in Embodiment 1 is preferably used as the semiconductor layer 230. Note that for the semiconductor layer 230, one or more selected from the metal oxide film described in Embodiment 1 and the metal oxide films described in [Metal oxide] described later may be used as a single layer or stacked layers.

A sputtering method or an atomic layer deposition (ALD) method can be suitably used for forming the metal oxide film. In the case where the metal oxide film is formed by a sputtering method, the composition of the formed metal oxide film may be different from the composition of a sputtering target. In particular, the content percentage of zinc in the formed metal oxide film may be reduced to approximately 50% of that in the sputtering target.

Examples of an ALD method include a thermal ALD method, in which a precursor and a reactant react with each other only by a thermal energy, and a plasma ALD (PEALD: Plasma Enhanced ALD) method, in which a reactant excited by plasma is used.

An ALD method enables atomic layers to be deposited one by one, and has advantages such as formation of an extremely thin film, formation of a film on a component with a high aspect ratio or on a surface with a large step, formation of a film with few defects such as pinholes, formation of a film with excellent coverage, and low-temperature film formation. The use of plasma in a PEALD method is sometimes preferable because it enables film formation at a lower temperature. Note that a precursor used in an ALD method sometimes contains an element such as carbon or chlorine. Thus, in some cases, a film provided by an ALD method contains a larger amount of an element such as carbon or chlorine than a film provided by another film formation method. Note that these elements can be quantified by XPS or SIMS. When the metal oxide film is formed by an ALD method, one or both of a film formation condition with a high substrate temperature and impurity removal treatment, can sometimes form a film with smaller amounts of carbon and chlorine than a method employing an ALD method without the film formation condition with a high substrate temperature or the impurity removal treatment.

Unlike a film formation method in which particles ejected from a target or the like are deposited, an ALD method is a film formation method in which a film is formed by reaction at a surface of an object. Thus, an ALD method is a film formation method that enables good step coverage almost regardless of the shape of an object. In particular, an ALD method enables excellent step coverage and excellent thickness uniformity and thus is suitable for covering a surface of an opening portion with a high aspect ratio, for example. On the other hand, an ALD method has a relatively low film formation rate, and thus is preferably used in combination with another film formation method with a high film formation rate, such as a sputtering method or a chemical vapor deposition (CVD) method, in some cases. In the case where a metal oxide film has a stacked-layer structure of a first metal oxide film and a second metal oxide film, a method in which the first metal oxide film is formed by a sputtering method and the second metal oxide film is formed by an ALD method over the first metal oxide film can be given as an example. For example, in the case where the first metal oxide film has a crystal part, crystal growth sometimes occurs in the second metal oxide film with the use of the crystal part as a nucleus.

When an ALD method is employed, the composition of a film to be formed can be controlled with the amount of introduced source gases. For example, a film with an arbitrary composition can be formed by adjusting the amount of introduced source gases, the number of times of introduction (also referred to as the number of pulses), and the time required for one pulse (also referred to as the pulse time) in an ALD method. Moreover, for example, when the source gas is changed during the film formation in an ALD method, a film having a continuously-changed composition can be formed. In the case where the film is formed while the source gas is changed, as compared to the case where a film is formed using a plurality of film formation chambers, the time taken for the film formation can be shortened because the time taken for transfer and pressure adjustment is omitted. Thus, the productivity of the semiconductor device can be increased in some cases.

Note that there is no particular limitation on a method for forming a metal oxide film to be the semiconductor layer 230. The metal oxide film may be formed by a chemical vapor deposition (CVD) method, a molecular beam epitaxy (MBE) method, a pulsed laser deposition (PLD) method, or the like.

The semiconductor layer 230 preferably has crystallinity. Examples of the oxide semiconductor having crystallinity include a CAAC-OS (c-axis aligned crystalline oxide semiconductor), an nc-OS (nanocrystalline oxide semiconductor), a polycrystalline oxide semiconductor, and a single-crystal oxide semiconductor. As the semiconductor layer 230, the CAAC-OS or the nc-OS is preferably used, and the CAAC-OS is particularly preferably used.

It is preferable that the CAAC-OS include a plurality of layered crystal regions and a c-axis be aligned in a normal direction of a formation surface. For example, the semiconductor layer 230 preferably includes a layered crystal that is substantially parallel to the sidewall of the opening portion 290, particularly the side surface of the insulating layer 280. With this structure, the layered crystals of the semiconductor layer 230 are formed in parallel with or substantially in parallel with the channel length direction of the transistor, so that the on-state current of the transistor can be increased.

The CAAC-OS is a metal oxide having a dense structure with high crystallinity and small numbers of impurities and defects (e.g., oxygen vacancies). In particular, after the formation of a metal oxide film, heat treatment is performed at a temperature at which the metal oxide does not become a polycrystal (e.g., higher than or equal to 400° C. and lower than or equal to 600° C.), whereby a CAAC-OS having a dense structure with higher crystallinity can be obtained. When the density of the CAAC-OS is increased in such a manner, diffusion of impurities or oxygen in the CAAC-OS can be further reduced.

A clear crystal grain boundary is difficult to observe in the CAAC-OS; thus, it can be said that a reduction in electron mobility due to the crystal grain boundary is less likely to occur. Thus, a metal oxide including the CAAC-OS is physically stable. Therefore, the metal oxide including the CAAC-OS is resistant to heat and has high reliability.

When an oxide having crystallinity, such as a CAAC-OS, is used as the semiconductor layer 230, oxygen extraction from the semiconductor layer 230 by the source electrode or the drain electrode can be inhibited. This can inhibit oxygen extraction from the semiconductor layer 230 even when heat treatment is performed; thus, the transistor is stable with respect to high temperatures in a manufacturing process (what is called thermal budget).

The crystal included in the metal oxide film described in Embodiment 1 has a layered crystal structure. Thus, the metal oxide film is likely to have a CAAC structure, and thus can be suitably used as the semiconductor layer 230.

In the case where the crystal included in the metal oxide film has a layered crystal structure and the c-axis of the layered crystal structure is perpendicular or substantially perpendicular to a formation surface or a surface of the metal oxide film, the plane of the layered crystal structure including the a-axis and the b-axis (also referred to as an a-b plane) extends in the channel length direction of the transistor 200. Thus, the electron effective masses along the a-axis and the b-axis of the crystal included in the metal oxide film are preferably small. Meanwhile, there is no limitation on the magnitude relationship between the electron effective mass along the c-axis of the crystal included in the metal oxide film and the electron effective mass in indium oxide in some cases. In other words, the electron effective mass along the c-axis of the crystal included in the metal oxide film may be larger than the electron effective mass in indium oxide in some cases.

The crystallinity of the semiconductor layer 230 can be analyzed with X-ray diffraction (XRD), TEM, or electron diffraction (ED), for example. Alternatively, these methods may be combined and employed for analysis.

When the semiconductor layer 230 and the conductive layer 220 are in contact with each other, a metal compound is formed or oxygen vacancies are formed, so that the resistance of the second region in the semiconductor layer 230 is reduced. The reduction in the resistance of the semiconductor layer 230 in contact with the conductive layer 220 can reduce the contact resistance between the semiconductor layer 230 and the conductive layer 220. Similarly, when the semiconductor layer 230 and the conductive layer 240 are in contact with each other, the resistance of the third region in the semiconductor layer 230 is reduced. Accordingly, the contact resistance between the semiconductor layer 230 and the conductive layer 240 can be reduced.

Although FIG. 4B and FIG. 4C illustrate the semiconductor layer 230 as a single layer, the present invention is not limited thereto. The semiconductor layer 230 may have a stacked-layer structure of a plurality of metal oxide films with different compositions. For example, a structure may be employed in which a plurality of kinds of metal oxide films selected from the metal oxide film described in Embodiment 1 and films of the metal oxides described in [Metal oxide] below are stacked as appropriate.

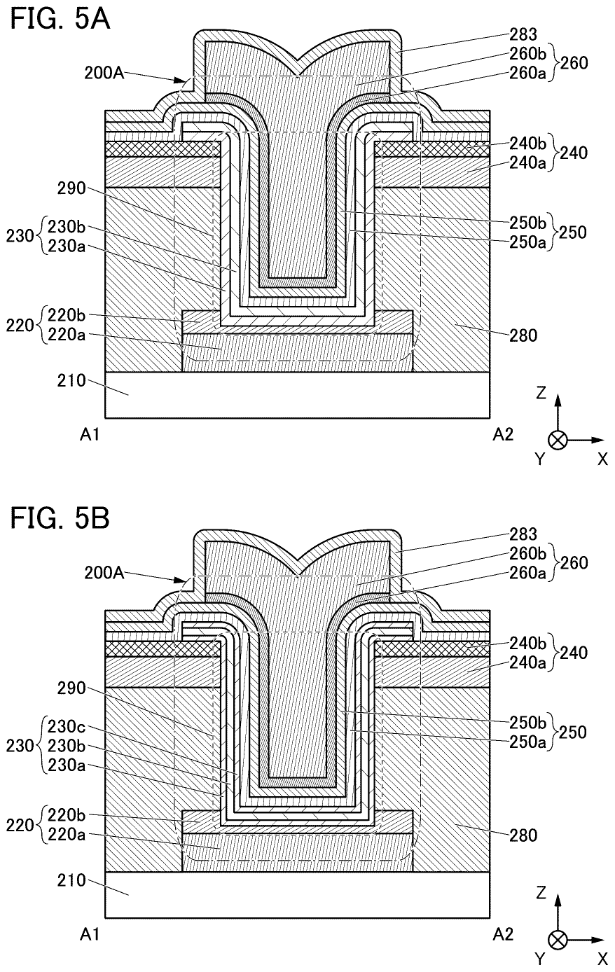

For example, as illustrated in FIG. 5A, the semiconductor layer 230 may have a stacked-layer structure of a semiconductor layer 230a and a semiconductor layer 230b over the semiconductor layer 230a.

The conductivity of a material used for the semiconductor layer 230a is preferably different from the conductivity of a material used for the semiconductor layer 230b.

For example, a material having higher conductivity than a material for the semiconductor layer 230b can be used for the semiconductor layer 230a. The use of the material having high conductivity for the semiconductor layer 230a, which is in contact with the conductive layer 220 and the conductive layer 240 functioning as the source electrode and the drain electrode, can reduce the contact resistance between the semiconductor layer 230 and the conductive layer 220 and the contact resistance between the semiconductor layer 230 and the conductive layer 240, and thus the transistor can have a high on-state current.

Here, in the case where a material having high conductivity is used for the semiconductor layer 230b provided on the side of the conductive layer 260 functioning as the gate electrode, the threshold voltage of the transistor shifts and drain current flowing when the gate voltage is 0 V (hereinafter, also referred to as cutoff current) increases in some cases. Specifically, the threshold voltage may be low when the transistor 200A is an n-channel transistor. Thus, a material having lower conductivity than a material for the semiconductor layer 230a is preferably used for the semiconductor layer 230b. Accordingly, the transistor 200A can have a high threshold voltage in the case where the transistor 200A is an n-channel transistor, in which case the transistor 200A can have a low cutoff current. Note that a low cutoff current is sometimes referred to as normally-off.

When the semiconductor layer 230 has the stacked-layer structure and the material having higher conductivity than the material for the semiconductor layer 230b is used for the semiconductor layer 230a as described above, the transistor can have normally-off characteristics and a high on-state current. Consequently, the semiconductor device can have both low power consumption and high performance.

The carrier concentration of the semiconductor layer 230a is preferably higher than the carrier concentration of the semiconductor layer 230b. Increasing the carrier concentration of the semiconductor layer 230a results in higher conductivity thereof, which can reduce the contact resistance between the semiconductor layer 230 and the conductive layer 220 and the contact resistance between the semiconductor layer 230 and the conductive layer 240, and thus the transistor can have a high on-state current. When the carrier concentration of the semiconductor layer 230b is reduced, the conductivity is reduced, and thus the transistor can have normally-off characteristics.

Although the example in which a material having higher conductivity than a material for the semiconductor layer 230b is used for the semiconductor layer 230a is described here, the present invention is not limited thereto. A material having lower conductivity than a material for the semiconductor layer 230b may be used for the semiconductor layer 230a. The carrier concentration of the semiconductor layer 230a can be lower than the carrier concentration of the semiconductor layer 230b.

The band gap of a first metal oxide used for the semiconductor layer 230a and the band gap of a second metal oxide used for the semiconductor layer 230b are preferably different from each other. For example, the difference between the band gap of the first metal oxide and the band gap of the second metal oxide is preferably greater than or equal to 0.1 eV, further preferably greater than or equal to 0.2 eV, still further preferably greater than or equal to 0.3 eV.

The band gap of the first metal oxide used for the semiconductor layer 230a can be smaller than the band gap of the second metal oxide used for the semiconductor layer 230b. Thus, the contact resistance between the semiconductor layer 230 and the conductive layer 220 and the contact resistance between the semiconductor layer 230 and the conductive layer 240 can be reduced, and thus the transistor can have a high on-state current. Furthermore, the transistor 200A can have a high threshold voltage in the case where the transistor 200A is an n-channel transistor; accordingly, the transistor 200A can be a normally-off transistor.

Although the example in which the band gap of the first metal oxide is smaller than the band gap of the second metal oxide is described here, the present invention is not limited thereto. The band gap of the first metal oxide can be larger than the band gap of the second metal oxide. As described above, the band gap of the first metal oxide used for the semiconductor layer 230a can be smaller than the band gap of the second metal oxide used for the semiconductor layer 230b. The composition of the first metal oxide is preferably different from that of the second metal oxide. When the compositions of the first metal oxide and the second metal oxide are different from each other, the band gap can be controlled. For example, the first metal oxide may have a structure not containing the element M and the second metal oxide may have a structure containing the element M. For example, the first metal oxide used as the semiconductor layer 230a can be an In—Zn oxide, and the second metal oxide used as the semiconductor layer 230b can be an In-M-Zn oxide. Specifically, the first metal oxide can be an In—Zn oxide, and the second metal oxide can be an In—Ga—Zn oxide. More specifically, the first metal oxide can be the metal oxide film described in Embodiment 1, and the second metal oxide can have a composition with an atomic ratio of In:Ga:Zn=1:1:1 or in the neighborhood thereof.

One embodiment of the present invention is not limited to the example described here in which the element M is not contained in the first metal oxide and the element M is contained in the second metal oxide. The content percentage of the element M in the first metal oxide may be lower than that of the element M in the second metal oxide or may be higher than that of the element M in the second metal oxide. As long as the compositions of the first metal oxide and the second metal oxide are different from each other, the content percentages of elements other than the element M may be different from each other.

The film thickness of the semiconductor layer 230 is preferably greater than or equal to 1 nm, greater than or equal to 3 nm, or greater than or equal to 5 nm and less than or equal to 20 nm, less than or equal to 15 nm, less than or equal to 12 nm, or less than or equal to 10 nm.

The film thicknesses of the layers included in the semiconductor layer 230 (here, the semiconductor layer 230a and the semiconductor layer 230b) are determined such that the film thickness of the semiconductor layer 230 is within the above-described range. The film thickness of the semiconductor layer 230a can be determined such that the contact resistance between the semiconductor layer 230a and the conductive layer 220 and the contact resistance between the semiconductor layer 230a and the conductive layer 240 are within required ranges. The film thickness of the semiconductor layer 230b can be determined such that the threshold voltage of the transistor is within a required range. Note that the film thickness of the semiconductor layer 230a may be the same as or different from the film thickness of the semiconductor layer 230b.

In the semiconductor layer 230, the film thickness of a portion formed over the top surface of the conductive layer 240 and the film thickness of a portion formed along the side surface of the conductive layer 240 and the side surface of the insulating layer 280 are different in some cases.

Although FIG. 5A illustrates the structure in which the semiconductor layer 230 has the stacked-layer structure of the two layers of the semiconductor layer 230a and the semiconductor layer 230b, the present invention is not limited thereto. The semiconductor layer 230 may have a stacked-layer structure of three or more layers.

For example, as illustrated in FIG. 5B, the semiconductor layer 230 may have a stacked-layer structure of the semiconductor layer 230a, the semiconductor layer 230b over the semiconductor layer 230a, and a semiconductor layer 230c over the semiconductor layer 230b. In other words, in the structure illustrated in FIG. 5A, the semiconductor layer 230c may be provided between the insulating layer 250 and the semiconductor layer 230b.

The atomic ratio of the element M to In in the metal oxide used for the semiconductor layer 230a is preferably greater than the atomic ratio of the element M to In in the metal oxide used for the semiconductor layer 230b. With such a structure, impurities and oxygen can be inhibited from diffusing into the semiconductor layer 230b from the components formed outside the semiconductor layer 230a. In addition, diffusion of an element contained in the insulating layer 280, the conductive layer 220, or the conductive layer 240 into the semiconductor layer 230b can be inhibited.

Since the insulating layer 280 has a function of inhibiting diffusion of hydrogen and oxygen, a structure not including the semiconductor layer 230a may be employed. In that case, the semiconductor layer 230 may have a stacked-layer structure of the semiconductor layer 230b and the semiconductor layer 230c over the semiconductor layer 230b.

For example, in the case where an oxide semiconductor film is formed by a formation method that causes less damage to the insulating layer 280, a structure not including the semiconductor layer 230a may be employed. For example, in the case where an oxide semiconductor film to be the semiconductor layer 230b is formed by an ALD method or a CVD method, a structure not including the semiconductor layer 230a may be employed. In the case where the oxide semiconductor film is formed by an ALD method or a CVD method, damage to the insulating layer 280 is reduced, so that diffusion of an element contained in the insulating layer 280 into the oxide semiconductor film can be inhibited.

In the case where a material having high conductivity is used for the semiconductor layer 230c provided on the side of the conductive layer 260 functioning as the gate electrode, the threshold voltage of the transistor 200A shifts and cutoff current increases in some cases. Specifically, the threshold voltage may be low when the transistor 200A is an n-channel transistor. Thus, a material having lower conductivity than a material for the semiconductor layer 230b is preferably used for the semiconductor layer 230c. Accordingly, the transistor 200A can have a high threshold voltage in the case where the transistor 200A is an n-channel transistor, in which case the transistor 200A can have a low cutoff current.

As described above, when the material having higher conductivity than the material for the semiconductor layer 230c is used for the semiconductor layer 230b, the transistor can have normally-off characteristics and a high on-state current. Consequently, the semiconductor device can have both low power consumption and high performance.

The carrier concentration of the semiconductor layer 230b is preferably higher than the carrier concentration of the semiconductor layer 230c. Increasing the carrier concentration of the semiconductor layer 230b results in higher conductivity thereof, which enables the transistor to have a high on-state current. When the carrier concentration of the semiconductor layer 230c is reduced, the conductivity is reduced, and thus the transistor can have normally-off characteristics.

Although the example in which a material having higher conductivity than a material for the semiconductor layer 230c is used for the semiconductor layer 230b is described here, one embodiment of the present invention is not limited thereto. A material having lower conductivity than a material for the semiconductor layer 230c may be used for the semiconductor layer 230b. The carrier concentration of the semiconductor layer 230b may be lower than the carrier concentration of the semiconductor layer 230c.

The band gap of the second metal oxide used for the semiconductor layer 230b and the band gap of a third metal oxide used for the semiconductor layer 230c are preferably different from each other. For example, the difference between the band gap of the second metal oxide and the band gap of the third metal oxide is preferably greater than or equal to 0.1 eV, further preferably greater than or equal to 0.2 eV, still further preferably greater than or equal to 0.3 eV.

The band gap of the second metal oxide used for the semiconductor layer 230b can be smaller than the band gap of the third metal oxide used for the semiconductor layer 230c. This enables the transistor to have a high on-state current. Furthermore, the transistor 200A can have a high threshold voltage in the case where the transistor 200A is an n-channel transistor; accordingly, the transistor 200A can be a normally-off transistor.

Although the example in which the band gap of the second metal oxide is smaller than the band gap of the third metal oxide is described here, one embodiment of the present invention is not limited thereto. The band gap of the second metal oxide may be larger than the band gap of the third metal oxide.

The first metal oxide used for the semiconductor layer 230a and the third metal oxide used for the semiconductor layer 230c may have the same composition or different compositions.

For example, a metal oxide having a composition with an atomic ratio of In:Ga:Zn=1:1:1 or in the neighborhood thereof may be used as the semiconductor layer 230a and the semiconductor layer 230c, and the metal oxide film described in Embodiment 1 may be used as the semiconductor layer 230b. With this structure, the on-state current of the transistor 200A can be increased, and the transistor can have high reliability with small variations.

For the conductive layer 260, any of conductors described in [Conductor] below can be used as a single layer or stacked layers. For example, a conductive material with high conductivity such as tungsten can be used for the conductive layer 260.

In addition, a conductive material that is less likely to be oxidized, a conductive material having a function of inhibiting diffusion of oxygen, or the like is preferably used for the conductive layer 260. Examples of the conductive material include a conductive material containing nitrogen (e.g., titanium nitride or tantalum nitride) and a conductive material containing oxygen (e.g., ruthenium oxide). Thus, a decrease in the conductivity of the conductive layer 260 can be inhibited.

Although FIG. 4B and FIG. 4C illustrate the conductive layer 260 as a single layer, the present invention is not limited thereto. The conductive layer 260 may have a stacked-layer structure. For example, as illustrated in FIG. 5A, the conductive layer 260 may have a stacked-layer structure of a conductive layer 260a and a conductive layer 260b over the conductive layer 260a. In that case, titanium nitride may be used for the conductive layer 260a, and tungsten may be used for the conductive layer 260b, for example. When a layer containing tungsten is provided in this manner, the conductive layer 260 can have improved conductivity and can serve well as a wiring.

Although FIG. 5A illustrates the structure in which the conductive layer 260 has the stacked-layer structure of the two layers of the conductive layer 260a and the conductive layer 260b, the present invention is not limited thereto. The conductive layer 260 may have a stacked-layer structure of three or more layers.

For the conductive layer 220, any of the conductors described in [Conductor] below can be used as a single layer or stacked layers. A conductive material that is less likely to be oxidized, a conductive material having a function of inhibiting diffusion of oxygen, or the like is preferably used for the conductive layer 220. For example, titanium nitride, tantalum nitride, or the like can be used.

The conductive layer 220 includes a region in contact with the semiconductor layer 230 and thus is preferably formed using a conductive material containing oxygen described in [Conductor] below. When a conductive material containing oxygen is used for the conductive layer 220, the conductive layer 220 can maintain its conductivity even when absorbing oxygen. In addition, even in the case where an insulator containing oxygen, e.g., hafnium oxide, is used as the insulating layer 210, the conductive layer 220 can maintain its conductivity, which is preferable. As the conductive layer 220, a single layer or stacked layers of indium tin oxide (also referred to as ITO), indium tin oxide to which silicon is added (also referred to as ITSO), indium zinc oxide (also referred to as IZO (registered trademark)), or the like can be used, for example.

Although FIG. 4B and FIG. 4C illustrate the conductive layer 220 as a single layer, the present invention is not limited thereto. The conductive layer 220 may have a stacked-layer structure. For example, as illustrated in FIG. 5A, the conductive layer 220 may have a stacked-layer structure of a conductive layer 220a and a conductive layer 220b over the conductive layer 220a.

At this time, titanium nitride may be used for the conductive layer 220a, and tantalum nitride may be used for the conductive layer 220b, for example. In that case, titanium nitride is in contact with the insulating layer 210 and tantalum nitride is in contact with the semiconductor layer 230. Such a structure can inhibit excessive oxidation of the conductive layer 220 due to the semiconductor layer 230. In the case where an oxide insulator is used as the insulating layer 210, such a structure can inhibit excessive oxidation of the conductive layer 220 due to the insulating layer 210. For another example, titanium nitride may be used for the conductive layer 220a, and tungsten may be used for the conductive layer 220b.

The conductive layer 220 may have a stacked-layer structure of three or more layers in which a conductor containing a material having high conductivity is sandwiched between conductors each containing a metal element different from that of the conductor. Examples of the material having high conductivity include a conductive material containing tungsten, copper, or aluminum as its main component. For the conductors between which the conductor containing the material having high conductivity is sandwiched, a conductive material that is less likely to be oxidized, a conductive material having a function of inhibiting diffusion of oxygen, or a conductive material containing oxygen is preferably used. Specifically, tungsten can be used as the material having high conductivity, titanium nitride can be used as the conductive material that is less likely to be oxidized or the conductive material having a function of inhibiting diffusion of oxygen, and ITSO can be used as the conductive material containing oxygen. In that case, the conductive layer 220 has a structure in which titanium nitride, tungsten over the titanium nitride, and ITSO over the tungsten are stacked.

Although FIG. 4B and FIG. 4C illustrate the structure in which the top surface of the conductive layer 220 is flat, the present invention is not limited thereto. For example, as illustrated in FIG. 5A, the top surface of the conductive layer 220 may have a depressed portion overlapping with the opening portion 290. When at least parts of the semiconductor layer 230, the insulating layer 250, and the conductive layer 260 are formed to fill the depressed portion, the gate electric field of the conductive layer 260 can be easily applied to a portion of the semiconductor layer 230 close to the conductive layer 220.

As the conductive layer 240, any of the conductors described in [Conductor] below can be used as a single layer or stacked layers. For example, ruthenium is preferably used for the conductive layer 240. Ruthenium is a material having favorable contact resistance with the semiconductor layer 230 and thus can be suitably used. Since an oxide of ruthenium also has conductivity, ruthenium has high conductivity and thus can be suitably used even in the case where its surface is oxidized in a manufacturing process, for example.

For another example, a conductive material having high conductivity such as tungsten may be used for the conductive layer 240.

For another example, a conductive material that is less likely to be oxidized, a conductive material having a function of inhibiting diffusion of oxygen, or the like may be used for the conductive layer 240. For example, titanium nitride, tantalum nitride, or the like can be used. Such a structure can inhibit excessive oxidation of the conductive layer 240 due to the semiconductor layer 230.

Although FIG. 4B and FIG. 4C illustrate the conductive layer 240 as a single layer, the present invention is not limited thereto. The conductive layer 240 may have a stacked-layer structure. For example, as illustrated in FIG. 5A, the conductive layer 240 may have a stacked-layer structure of a conductive layer 240a and a conductive layer 240b over the conductive layer 240a.

In that case, ruthenium may be used for the conductive layer 240a, and titanium nitride or tantalum nitride may be used for the conductive layer 240b, for example. When a layer including titanium nitride or tantalum nitride is provided in this manner, the contact resistance of the semiconductor layer 230 in a region in contact with the layer is sometimes lowered. Furthermore, the carrier concentration sometimes increases. Thus, the semiconductor layer 230 in the region in contact with the conductive layer 240 can have lower resistance in a self-aligned manner. This enables the transistor to have a high on-state current.

For another example, ruthenium may be used for the conductive layer 240a, and indium zinc oxide may be used for the conductive layer 240b. When a layer containing indium zinc oxide is provided in this manner, the contact resistance of the semiconductor layer 230 in a region in contact with the layer is sometimes lowered. Furthermore, the carrier concentration sometimes increases. Thus, the semiconductor layer 230 in the region in contact with the conductive layer 240 can have lower resistance in a self-aligned manner. This enables the transistor to have a high on-state current.

For another example, titanium nitride or tantalum nitride may be used for the conductive layer 240a, and tungsten may be used for the conductive layer 240b. When a layer containing tungsten is provided in this manner, the conductive layer 240 can have improved conductivity and can serve well as a wiring.

For another example, the conductive layer 240a may be formed using a conductive material having high conductivity and the conductive layer 240b may be formed using a conductive material containing oxygen. When a conductive material containing oxygen is used for the conductive layer 240b that is in contact with the insulating layer 250a, oxygen in the insulating layer 250a can be inhibited from diffusing into the conductive layer 240a. For example, it is preferable that tungsten be used for the conductive layer 240a and ITSO be used for the conductive layer 240b.

The insulating layer 210, which functions as an interlayer film, preferably has a low relative permittivity. When a material with a low relative permittivity is used for an interlayer film, the parasitic capacitance generated between wirings can be reduced. As the insulating layer 210, any of insulators each containing a material with a low relative permittivity described in [Insulator] below can be used as a single layer or stacked layers. Silicon oxide and silicon oxynitride are preferable because they are thermally stable. The concentration of impurities such as water and hydrogen in the insulating layer 210 is preferably reduced. This can inhibit entry of impurities such as water and hydrogen into the channel formation region of the semiconductor layer 230.

As described above, a barrier insulator against hydrogen is preferably used as the insulating layer 280. Such a structure can inhibit diffusion of hydrogen into the semiconductor layer 230. The concentration of impurities such as water and hydrogen in the insulating layer 280 is preferably reduced. This can inhibit entry of impurities such as water and hydrogen into the channel formation region of the semiconductor layer 230. For the insulating layer 280, any of the insulators described in [Insulator] below may be used as a single layer or stacked layers.

For the insulating layer 283, a barrier insulator against hydrogen is preferably used. This can inhibit diffusion of hydrogen from above the insulating layer 283 into the semiconductor layer 230. A silicon nitride film and a silicon nitride oxide film can be suitably used as the insulating layer 283 because they release fewer impurities (e.g., water and hydrogen) and are less likely to transmit oxygen and hydrogen.

Silicon nitride formed by a sputtering method is particularly preferably used for the insulating layer 283. In that case, the insulating layer 283 contains silicon and nitrogen. Since a sputtering method does not need to use a molecule containing hydrogen in a film formation gas, the hydrogen concentration in the insulating layer 283 can be reduced. When the insulating layer 283 is formed by a sputtering method, high-density silicon nitride can be formed.

As the insulating layer 283, an insulator having a function of capturing hydrogen or fixing hydrogen may be used. With such a structure, diffusion of hydrogen from above the insulating layer 283 into the semiconductor layer 230 can be inhibited, and hydrogen contained in the semiconductor layer 230 can be captured or fixed. Thus, the hydrogen concentration in the semiconductor layer 230 can be reduced.

The insulating layer 283 may have a stacked-layer structure of an insulator having a function of capturing hydrogen or fixing hydrogen and a barrier insulator against hydrogen. For example, a stacked-layer film of aluminum oxide and silicon nitride over the aluminum oxide may be used as the insulating layer 283.

Although FIG. 4B to FIG. 4D illustrate the structure in which the insulating layer 280 and the semiconductor layer 230 are in contact with each other in the opening portion 290, the present invention is not limited thereto. For example, an insulator having a function of capturing or fixing hydrogen may be provided between the insulating layer 280 and the semiconductor layer 230.

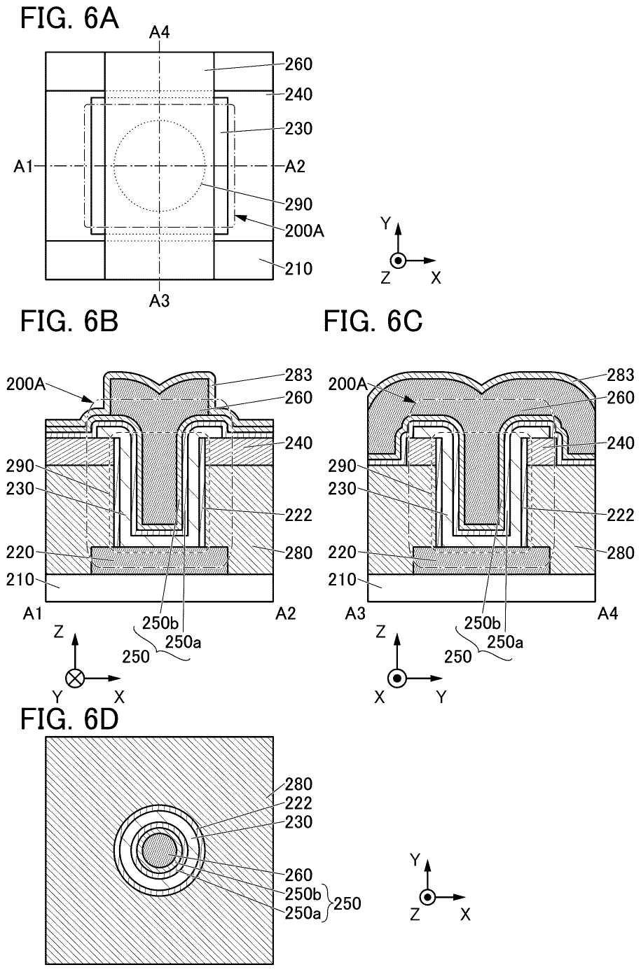

FIG. 6A to FIG. 6D illustrate another example of the semiconductor device of one embodiment of the present invention. FIG. 6A is a plan view of the semiconductor device. FIG. 6B to FIG. 6D are cross-sectional views of the semiconductor device. Here, FIG. 6B is a cross-sectional view taken along the dashed-dotted line A1-A2 in FIG. 6A. FIG. 6C is a cross-sectional view taken along the dashed-dotted line A3-A4 in FIG. 6A. FIG. 6D is a cross-sectional view along XY plane including the insulating layer 280.

The semiconductor device illustrated in FIG. 6A to FIG. 6D is different from the semiconductor device illustrated in FIG. 4A to FIG. 4D in including an insulating layer 222. Portions different from the description with reference to FIG. 4A to FIG. 4D are mainly described below; and common portions, for which the description is referred to, are not described in some cases.

As illustrated in FIG. 6B to FIG. 6D, the insulating layer 222 is provided between the semiconductor layer 230 and the insulating layer 280 and conductive layer 240. Portions of the insulating layer 222, the semiconductor layer 230, the insulating layer 250, and the conductive layer 260 which are placed in the opening portion 290 are provided, reflecting the shape of the opening portion 290. Thus, the insulating layer 222 is provided to cover the sidewall of the opening portion 290, the semiconductor layer 230 is provided to cover the side surface of the insulating layer 222 and the bottom portion of the opening portion 290, the insulating layer 250 is provided to cover the semiconductor layer 230, and the conductive layer 260 is provided to fill a depressed portion of the insulating layer 250 reflecting the shape of the opening portion 290.

An insulator having a function of capturing or fixing hydrogen is preferably used as the insulating layer 222. With such a structure, the semiconductor layer 230 can be sandwiched between insulators that capture or fix hydrogen (here, the insulating layer 250a and the insulating layer 222). Furthermore, the semiconductor layer 230 sandwiched between the insulators that capture or fix hydrogen can be surrounded by barrier insulators against hydrogen (here, the insulating layer 280 and the insulating layer 250b). Thus, the hydrogen concentration in the semiconductor layer 230 can be further lowered. At this time, part of hydrogen in the semiconductor layer 230 is captured or fixed by the insulating layer 250a. Another part of hydrogen in the semiconductor layer 230 is captured or fixed by the insulating layer 222. Thus, the hydrogen concentration in the insulating layer 250a and the hydrogen concentration in the insulating layer 222 are increased. For example, the hydrogen concentration in the insulating layer 250a and the hydrogen concentration in the insulating layer 222 are higher than the hydrogen concentration in the semiconductor layer 230.

With the above structure, oxygen vacancies and impurities in the semiconductor layer 230 can be reduced. Thus, the electrical characteristics and reliability of the transistor can be improved. Furthermore, a variation in the electrical characteristics of the transistor can be reduced.

The film thickness of the insulating layer 222 is preferably within the range of the film thickness of the insulating layer 250a.

FIG. 6B and FIG. 6C each illustrate a structure in which the insulating layer 222 is provided between the semiconductor layer 230 and the insulating layer 280 and conductive layer 240. Note that the present invention is not limited to the structure, as long as the insulating layer 222 is provided in contact with the semiconductor layer 230 or in the vicinity of the semiconductor layer 230.

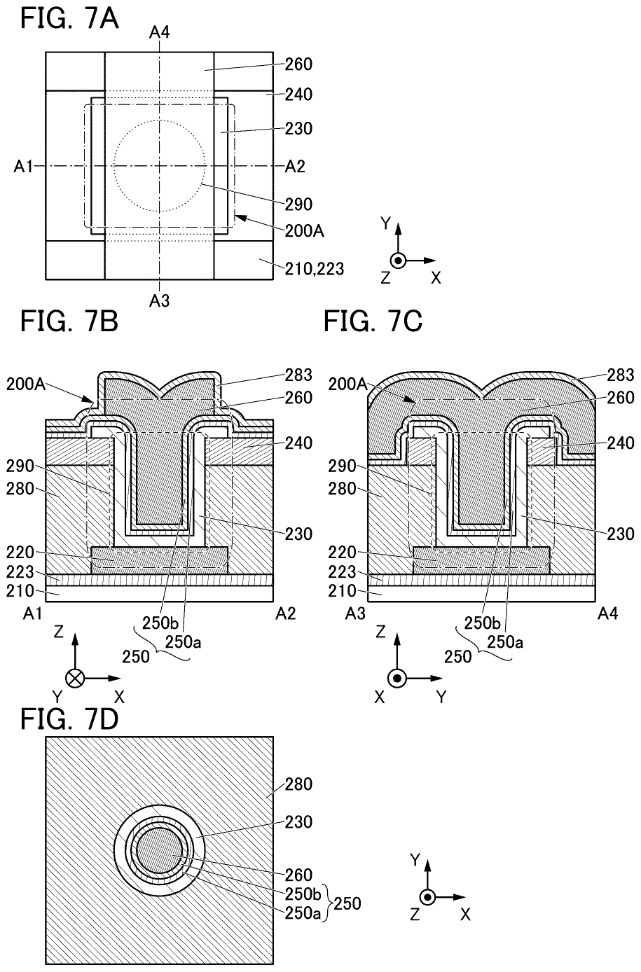

FIG. 7A to FIG. 7D illustrate another example of a semiconductor device of one embodiment of the present invention. FIG. 7A is a plan view of the semiconductor device. FIG. 7B to FIG. 7D are cross-sectional views of the semiconductor device. Here, FIG. 7B is the cross-sectional view taken along the dashed-dotted line A1-A2 in FIG. 7A. FIG. 7C is the cross-sectional view taken along the dashed-dotted line A3-A4 in FIG. 7A. FIG. 7D is the cross-sectional view along the XY plane including the insulating layer 280.

The semiconductor device illustrated in FIG. 7A to FIG. 7D is different from the semiconductor device illustrated in FIG. 6A to FIG. 6D in that the insulating layer 222 is not provided and an insulating layer 223 is provided below the insulating layer 280 and the conductive layer 220. The semiconductor device illustrated in FIG. 7A to FIG. 7D is different from the semiconductor device illustrated in FIG. 4A to FIG. 4D in that the insulating layer 223 is provided between the insulating layer 210 and the insulating layer 280 and conductive layer 220. Portions different from the description with reference to FIG. 4A to FIG. 4D or FIG. 6A to FIG. 6D are mainly described below, and common portions, for which the description is referred to, are not described in some cases.

As illustrated in FIG. 7B and FIG. 7C, the insulating layer 223 is provided over the insulating layer 210 and below the insulating layer 280 and the conductive layer 220. In other words, the insulating layer 223 is provided over the insulating layer 210, and the conductive layer 220 and the insulating layer 280 are provided over the insulating layer 223. With such a structure, hydrogen in the semiconductor layer 230 can diffuse into the insulating layer 223 through the conductive layer 220, and the hydrogen can be captured or fixed. Thus, the hydrogen concentration in the semiconductor layer 230 can be reduced.

Although FIG. 6B to FIG. 6D illustrate the structure in which the insulating layer 222 is provided between the insulating layer 280 and the semiconductor layer 230, the present invention is not limited thereto. For example, an insulator having a function of capturing or fixing hydrogen and a barrier insulator against hydrogen may be provided between the insulating layer 280 and the semiconductor layer 230.

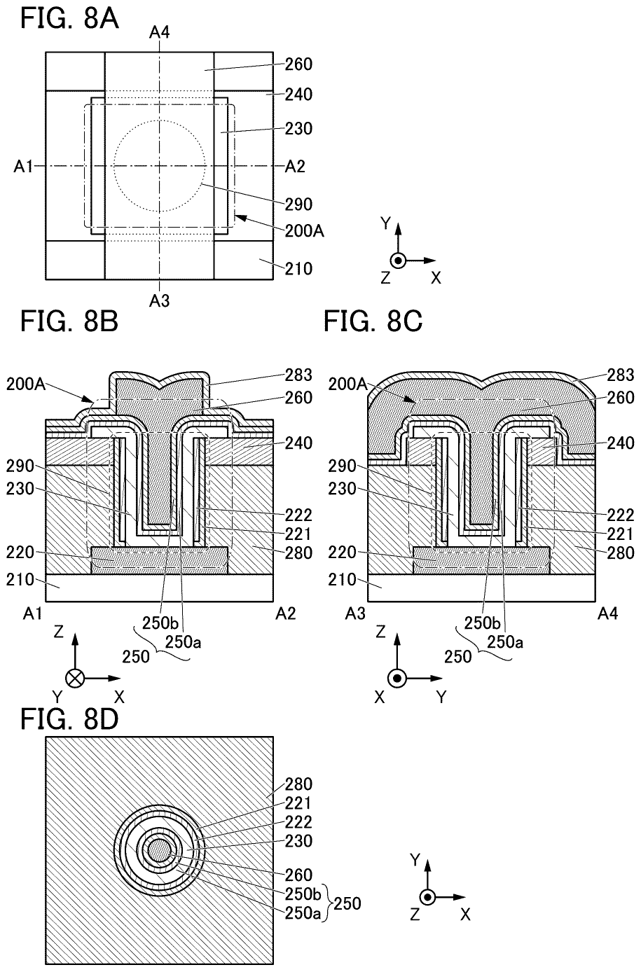

FIG. 8A to FIG. 8D illustrate another example of the semiconductor device of one embodiment of the present invention. FIG. 8A is a plan view of the semiconductor device. FIG. 8B to FIG. 8D are cross-sectional views of the semiconductor device. Here, FIG. 8B is the cross-sectional view taken along the dashed-dotted line A1-A2 in FIG. 8A. FIG. 8C is the cross-sectional view taken along the dashed-dotted line A3-A4 in FIG. 8A. FIG. 8D is the cross-sectional view along the XY plane including the insulating layer 280.

The semiconductor device illustrated in FIG. 8A to FIG. 8D is different from the semiconductor device illustrated in FIG. 6A to FIG. 6D in including an insulating layer 221. The semiconductor device illustrated in FIG. 8A to FIG. 8D is different from the semiconductor device illustrated in FIG. 4A to FIG. 4D in including the insulating layer 221 and the insulating layer 222. Portions different from the description with reference to FIG. 4A to FIG. 4D or FIG. 6A to FIG. 6D are mainly described below, and common portions, for which the description is referred to, are not described in some cases.

As illustrated in FIG. 8B and FIG. 8C, the insulating layer 221 is provided between the insulating layer 280 and conductive layer 240 and the insulating layer 222. Portions of the insulating layer 221, the insulating layer 222, the semiconductor layer 230, the insulating layer 250, and the conductive layer 260 that are positioned in the opening portion 290 are provided, reflecting the shape of the opening portion 290. Thus, the insulating layer 221 is provided to cover the sidewall of the opening portion 290, the insulating layer 222 is provided to cover the side surface of the insulating layer 221, the semiconductor layer 230 is provided to cover the side surface of the insulating layer 222 and the bottom portion of the opening portion 290, the insulating layer 250 is provided to cover the semiconductor layer 230, and the conductive layer 260 is provided to fill the depressed portion of the insulating layer 250 that reflects the shape of the opening portion 290.

As the insulating layer 221, a barrier insulator against hydrogen is preferably used. Thus, the semiconductor layer 230 can be sandwiched between insulators having a function of capturing or fixing hydrogen (here, the insulating layer 250a and the insulating layer 222), and a barrier insulator against hydrogen (here, the insulating layer 221) can be provided on the outside of the insulators. With this structure, diffusion of hydrogen into the semiconductor layer 230 can be inhibited and the hydrogen concentration in the semiconductor layer 230 can be further reduced.

The film thickness of the insulating layer 221 is preferably within the range of the film thickness of the insulating layer 250b.

Note that the insulating layer 221 has a barrier property against hydrogen in the structure illustrated in FIG. 8A to FIG. 8D; thus, a material used for the insulating layer 280 is not limited to the materials described above. In other words, the range of choices for the material used for the insulating layer 280 can be expanded. For example, the insulating layer 280 may be formed using a material with a low relative permittivity. The insulating layer 280 formed using a material with a low relative permittivity can function as an interlayer film. Thus, the parasitic capacitance generated between wirings can be reduced.

By contrast, when the structure illustrated in FIG. 6B and the like is employed, an insulator (here, the insulating layer 280) having an opening portion where the semiconductor layer 230 and the like are provided has a barrier property against hydrogen, and thus, a barrier insulator against hydrogen does not need to be provided additionally. Thus, the manufacturing process of the semiconductor device can be simplified and the productivity can be improved.

Although FIG. 8B and FIG. 8C illustrate the insulating layer 280 as a single layer, the present invention is not limited thereto. The insulating layer 280 may have a stacked-layer structure.

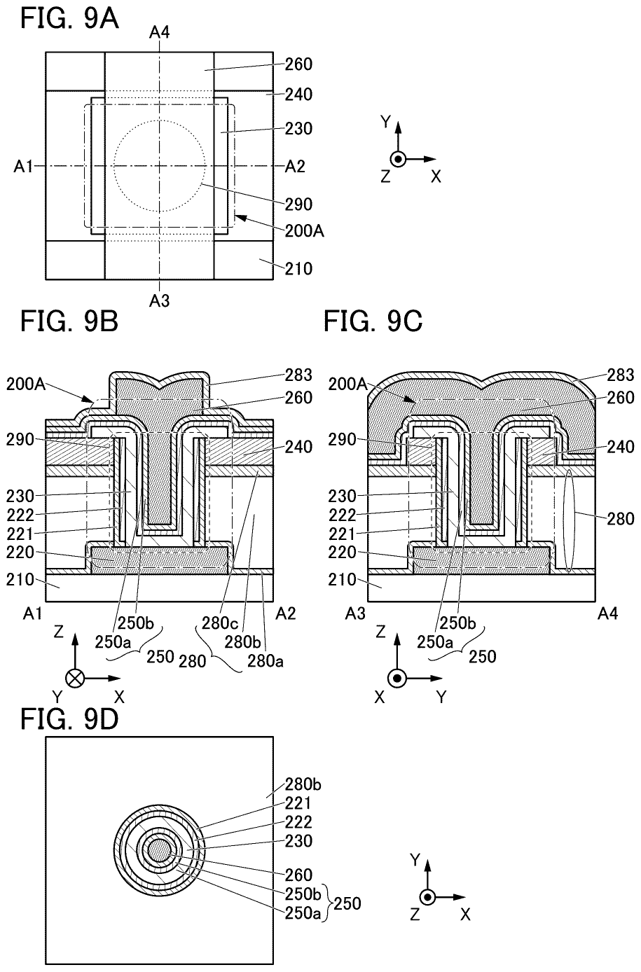

FIG. 9A to FIG. 9D illustrate another example of the semiconductor device of one embodiment of the present invention. FIG. 9A is a plan view of the semiconductor device. FIG. 9B to FIG. 9D are cross-sectional views of the semiconductor device. Here, FIG. 9B is the cross-sectional view taken along the dashed-dotted line A1-A2 in FIG. 9A. FIG. 9C is the cross-sectional view taken along the dashed-dotted line A3-A4 in FIG. 9A.

For example, as illustrated in FIG. 9B and FIG. 9C, the insulating layer 280 may have a stacked-layer structure of an insulating layer 280a, an insulating layer 280b over the insulating layer 280a, and an insulating layer 280c over the insulating layer 280b. FIG. 9D is the cross-sectional view along the XY plane including the insulating layer 280b.

The insulating layer 280a includes a region in contact with the top surface of the insulating layer 210, a region in contact with the side surface and the top surface of the conductive layer 220. The insulating layer 280c includes a region in contact with the bottom surface of the conductive layer 240.

The insulating layer 221 having a barrier property against hydrogen is provided between the insulating layer 280 and the insulating layer 222 in FIG. 9B and FIG. 9C; thus, the insulating layer 280b may be formed using a material with a low relative permittivity, for example. When the insulating layer 280b is formed using a material with a low relative permittivity, the parasitic capacitance generated between wirings can be reduced. Specifically, silicon oxide or silicon oxynitride can be used for the insulating layer 280b.

In the case where an insulator containing oxygen is used as the insulating layer 280b, any of barrier insulators against oxygen described in [Insulator] below is preferably used as each of the insulating layer 280a and the insulating layer 280c. The insulating layer 280a provided between the insulating layer 280b and the conductive layer 220 can inhibit oxidation of the conductive layer 220 and an increase in the resistance of the conductive layer 220. The insulating layer 280c provided between the insulating layer 280b and the conductive layer 240 can inhibit oxidation of the conductive layer 240 and an increase in the resistance of the conductive layer 240.

As each of the insulating layer 280a and the insulating layer 280c, any of barrier insulators against hydrogen described later in [Insulator] may be used. Thus, the insulating layer 280b can be surrounded by barrier insulators against hydrogen (here, the insulating layer 280a, the insulating layer 280c, and the insulating layer 221). This can inhibit diffusion of hydrogen contained in the insulating layer 280b into the semiconductor layer 230. A silicon nitride film and a silicon nitride oxide film can be suitably used as the insulating layer 280a and the insulating layer 280c because they release fewer impurities (e.g., water and hydrogen) and are less likely to transmit oxygen and hydrogen. For the insulating layer 280a and the insulating layer 280c, the same material or different materials may be used.

For the insulating layer 280a, an insulator having a function of capturing or fixing hydrogen may be used. With such a structure, diffusion of hydrogen from below the insulating layer 280a into the semiconductor layer 230 can be inhibited, and hydrogen contained in the semiconductor layer 230 can be captured or fixed. Thus, the hydrogen concentration in the semiconductor layer 230 can be reduced. For another example, a stacked-layer film of aluminum oxide and silicon nitride over the aluminum oxide may be used as the insulating layer 280a. In addition, an insulator having a function of capturing or fixing hydrogen may be used as the insulating layer 280c.

For example, silicon nitride can be used for the insulating layer 280a and the insulating layer 280c, and silicon oxide or silicon oxynitride can be used for the insulating layer 280b. In that case, each of the insulating layer 280a and the insulating layer 280c contains at least silicon and nitrogen. The insulating layer 280b contains at least silicon and oxygen.

Although FIG. 9B and FIG. 9C illustrate the structure in which the insulating layer 280c is provided over the planarized insulating layer 280b, the present invention is not limited thereto. For example, the insulating layer 280c may be formed without performing planarization treatment on the insulating layer 280b. When planarization treatment is not performed, the manufacturing cost can be reduced and the production yield can be increased. In addition, the insulating layer 280a, the insulating layer 280b, and the insulating layer 280c can be successively formed without exposure to the air. By the formation without exposure to the air, impurities or moisture from the atmospheric environment can be prevented from being attached onto the insulating layer 280a to the insulating layer 280c, so that the vicinity of the interface between the insulating layer 280a and the insulating layer 280b and the vicinity of the interface between the insulating layer 280b and the insulating layer 280c can be kept clean.

Although FIG. 9B and FIG. 9C illustrate the structure in which the insulating layer 280 has a stacked-layer structure of three layers, the present invention is not limited thereto. The insulating layer 280 may have a stacked-layer structure of two layers or four or more layers.

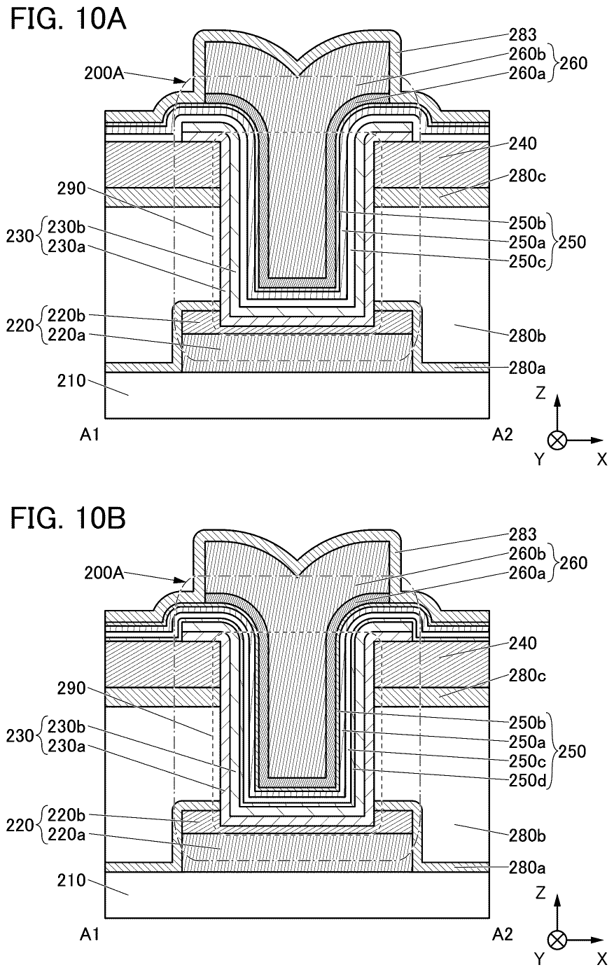

Note that the insulating layer 250a having a function of capturing or fixing hydrogen is provided in contact with the semiconductor layer 230 in FIG. 9B and FIG. 9C. Thus, in the case where the insulating layer 280a, the insulating layer 280c, and the insulating layer 250b each have a barrier property against hydrogen and the hydrogen concentration in the insulating layer 280b is sufficiently reduced, the insulating layer 221 and the insulating layer 222 are not necessarily provided as illustrated in FIG. 10A.

In that case, the insulating layer 280b is in contact with at least part of the semiconductor layer 230. For the insulating layer 280b, an insulator containing oxygen is preferably used. The insulating layer 280b preferably includes a region having a higher oxygen content than at least one of the insulating layer 280a and the insulating layer 280c. In particular, the insulating layer 280b preferably includes a region having a higher oxygen content than each of the insulating layer 280a and the insulating layer 280c. When the insulating layer 280b has a high oxygen content, an i-type region can be easily formed in the semiconductor layer 230 in the vicinity of the insulating layer 280b.

It is further preferable that a film from which oxygen is released by heating be used as the insulating layer 280b. When the insulating layer 280b releases oxygen by being heated during the manufacturing process of the transistor 200A, the oxygen can be supplied to the semiconductor layer 230. Supply of oxygen from the insulating layer 280b to the semiconductor layer 230, particularly to the channel formation region in the semiconductor layer 230, can reduce oxygen vacancies and V_{O}H in the semiconductor layer 230, so that the transistor can have excellent electrical characteristics and high reliability.

Particularly in the case where the channel length of the transistor 200A is short, oxygen vacancies and V_{O}H in the channel formation region significantly affect the electrical characteristics and reliability. Accordingly, when the hydrogen concentration in the semiconductor layer 230 is sufficiently reduced and the amount of oxygen supplied to the semiconductor layer 230 is optimized, a transistor with a short channel length, excellent electrical characteristics, and high reliability can be provided.

The insulating layer 280b is preferably formed by a film formation method such as a sputtering method or a plasma-enhanced chemical vapor deposition (PECVD) method. In particular, a film is formed by a sputtering method as a film formation method that does not use a hydrogen gas as a film formation gas, so that a film with an extremely low hydrogen content can be formed. Thus, supply of hydrogen to the semiconductor layer 230 can be inhibited and the electrical characteristics of the transistor 200A can be stabilized.

In the case where the amount of oxygen supplied to the semiconductor layer 230 is increased, heat treatment in an oxygen-containing atmosphere or plasma treatment in an oxygen-containing atmosphere is preferably performed after formation of the insulating layer 280b, for example. Alternatively, an oxide film may be formed over the top surface of the insulating layer 280b by a sputtering method in an oxygen atmosphere to supply oxygen. After that, the oxide film may be removed. Such treatment can supply oxygen to the insulating layer 280b and increase the amount of oxygen supplied to the semiconductor layer 230.

By contrast, in the case where the amount of oxygen supplied to the semiconductor layer 230 is reduced, it is preferable to provide one or both of the insulating layer 221 and the insulating layer 222. Such a structure can inhibit supply of an excess amount of oxygen to the semiconductor layer 230 even in the case where a large amount of oxygen is released from the insulating layer 280b.

A region of the semiconductor layer 230 that is in contact with the insulating layer 280a and a region of the semiconductor layer 230 that is in contact with the insulating layer 280c are supplied with a smaller amount of oxygen than a region of the semiconductor layer 230 that is in contact with the insulating layer 280b. Thus, the region of the semiconductor layer 230 that is in contact with the insulating layer 280a and the region of the semiconductor layer 230 that is in contact with the insulating layer 280c each have a low resistance in some cases. That is, by adjusting the film thickness of the insulating layer 280a, the range of the second region functioning as one of the source region and the drain region can be controlled. Similarly, by adjusting the film thickness of the insulating layer 280c, the range of the third region functioning as the other of the source region and the drain region can be controlled. Accordingly, the film thicknesses of the insulating layer 280a and the insulating layer 280c are preferably set as appropriate in accordance with the characteristics required for the transistor 200A.

Although the structure illustrated in FIG. 4B and FIG. 4C illustrates that the insulating layer 250 has a two-layer-stacked structure of the insulating layer 250a and the insulating layer 250b, the present invention is not limited thereto. The insulating layer 250 may have a stacked-layer structure of three or more layers.

For example, as illustrated in FIG. 10A, the insulating layer 250 may have a stacked-layer structure of an insulating layer 250c, the insulating layer 250a over the insulating layer 250c, and the insulating layer 250b over the insulating layer 250a. In this case, the insulating layer 250c is provided between the semiconductor layer 230 and the insulating layer 250a.

For the insulating layer 250c, any of the materials each having a low relative permittivity described in [Insulator] below is preferably used. In particular, silicon oxide and silicon oxynitride, which are thermally stable, are preferable. In that case, the insulating layer 250c contains at least oxygen and silicon. With such a structure, the parasitic capacitance between the conductive layer 260 and the conductive layer 240 can be reduced. Furthermore, the concentration of impurities such as water and hydrogen in the insulating layer 250c is preferably reduced.

In the case where the insulating layer 250c is provided, the insulating layer 250b preferably further has a barrier property against oxygen. The insulating layer 250b is provided between the insulating layer 250c and the conductive layer 260. Thus, diffusion of oxygen contained in the insulating layer 250c into the conductive layer 260 can be prevented, so that oxidation of the conductive layer 260 can be inhibited. It is also possible to inhibit a reduction in the amount of oxygen supplied to the first region of the semiconductor layer 230.

In another example, as illustrated in FIG. 10B, the insulating layer 250 may have a stacked-layer structure of an insulating layer 250d, the insulating layer 250c over the insulating layer 250d, the insulating layer 250a over the insulating layer 250c, and the insulating layer 250b over the insulating layer 250a. In this case, the insulating layer 250d is provided between the semiconductor layer 230 and the insulating layer 250c.

As the insulating layer 250d, any of the barrier insulators against oxygen described in [Insulator] below is preferably used. The insulating layer 250d includes a region in contact with the semiconductor layer 230. When the insulating layer 250d has a barrier property against oxygen, release of oxygen from the semiconductor layer 230 at the time of performing heat treatment or the like can be inhibited. This can inhibit formation of oxygen vacancies in the semiconductor layer 230. Accordingly, the transistor 200A can have excellent electrical characteristics and higher reliability. As the insulating layer 250d, aluminum oxide is preferably used, for example. In that case, the insulating layer 250d contains at least oxygen and aluminum. Note that aluminum oxide has a function of capturing or fixing hydrogen and is thus suitable for the insulating layer 250d in contact with the semiconductor layer 230.

The film thickness of each of the insulating layer 250c and the insulating layer 250d is preferably small for miniaturization of the transistor 200A. The film thickness of each of the insulating layer 250c and the insulating layer 250d is preferably greater than or equal to 0.1 nm and less than or equal to 10 nm, further preferably greater than or equal to 0.1 nm and less than or equal to 5 nm, still further preferably greater than or equal to 0.5 nm and less than or equal to 5 nm, yet further preferably greater than or equal to 1 nm and less than 5 nm, yet still further preferably greater than or equal to 1 nm and less than or equal to 3 nm. Note that at least part of each of the insulating layer 250c and the insulating layer 250d includes a region having the above-described film thickness.

Typically, the thicknesses of the insulating layer 250d, the insulating layer 250c, the insulating layer 250a, and the insulating layer 250b are 1 nm, 2 nm, 2 nm, and 1 nm, respectively. This structure enables the transistor 200A to have excellent electrical characteristics even when the transistor 200A is miniaturized or highly integrated.

In order to form the insulating layer 250a to the insulating layer 250d each having a small film thickness as described above, an ALD method is preferably employed. In the case where the insulating layer 250a to the insulating layer 250d are provided in the opening portion 290, the layers are preferably formed by an ALD method.

FIG. 4B and FIG. 4C illustrate a structure in which the gate insulating layer has a stacked-layer structure of two layers of the insulating layer 250a and the insulating layer 250b, FIG. 10A illustrates a structure in which the gate insulating layer has a stacked-layer structure of three layers of the insulating layer 250a to the insulating layer 250c, and FIG. 10B illustrates a structure in which the gate insulating layer has a stacked-layer structure of four layers of the insulating layer 250a to the insulating layer 250d; however, the present invention is not limited to these structures. The gate insulating layer may have a single-layer structure or a stacked-layer structure of five or more layers. In that case, the layers included in the gate insulating layer can be selected as appropriate from the insulating layer 250a to the insulating layer 250d.

A structure example of a semiconductor device whose structure is partly different from that of <Structure example 1 of semiconductor device> described above will be described below. Note that description of the same portions as those in <Structural example 1 of semiconductor device> described above is omitted in some cases. In the drawings described later, the same hatching pattern is applied to portions having functions similar to those in <Structural example 1 of semiconductor device> described above, and the portions are not denoted by reference numerals in some cases.

### Structure Example 2 of Semiconductor Device

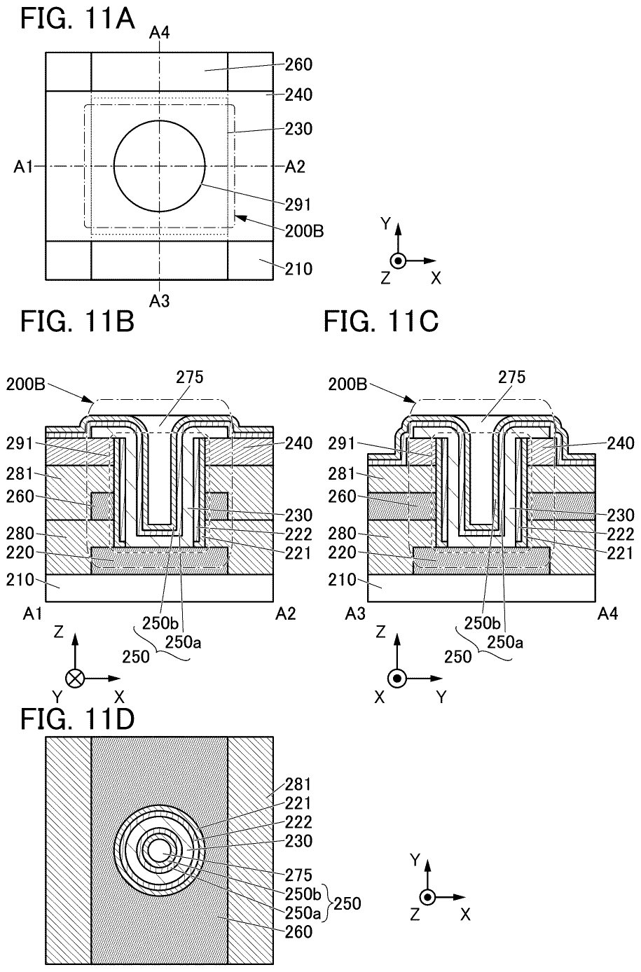

Another structure example of the semiconductor device is described with reference to FIG. 11A to FIG. 11D. FIG. 11A to FIG. 11D are a plan view and cross-sectional views of the semiconductor device including a transistor 200B. FIG. 11A is the plan view of the semiconductor device. FIG. 11B to FIG. 11D are the cross-sectional views of the semiconductor device. Here, FIG. 11B is the cross-sectional view taken along the dashed-dotted line A1-A2 in FIG. 11A. FIG. 11C is the cross-sectional view taken along the dashed-dotted line A3-A4 in FIG. 11A.

The semiconductor device illustrated in FIG. 11A to FIG. 11D includes the insulating layer 210 over a substrate (not illustrated), the transistor 200B over the insulating layer 210, the insulating layer 280 over the insulating layer 210, an insulating layer 281 over the insulating layer 280, the insulating layer 250 (the insulating layer 250a and the insulating layer 250b) over the transistor 200B, and an insulating layer 275 over the insulating layer 250.

The transistor 200B includes the conductive layer 220, the conductive layer 260 over the insulating layer 280, the conductive layer 240 over the insulating layer 281, and the insulating layer 221, the insulating layer 222, and the semiconductor layer 230 over the conductive layer 220. The insulating layer 280 is provided over the conductive layer 220, and the insulating layer 281 is provided over the conductive layer 260.

As illustrated in FIG. 11B and FIG. 11C, the opening portion 291 reaching the conductive layer 220 is provided in the insulating layer 280, the conductive layer 260, the insulating layer 281, and the conductive layer 240. That is, the opening portion 291 is provided in a region overlapping with the conductive layer 220 in the plan view. Here, the bottom portion of the opening portion 291 is the top surface of the conductive layer 220, and the sidewall of the opening portion 291 is the side surface of the insulating layer 280, the side surface of the conductive layer 260, the side surface of the insulating layer 281, and the side surface of the conductive layer 240. Furthermore, the opening portion 291 includes an opening portion included in the insulating layer 280, an opening portion included in the conductive layer 260, an opening portion included in the insulating layer 281, and an opening portion included in the conductive layer 240. The opening portion included in the conductive layer 260 includes a region overlapping with the opening portion included in the insulating layer 280, the opening portion included in the insulating layer 281 includes a region overlapping with the opening portion included in the conductive layer 260 and the opening portion included in the insulating layer 280, and the opening portion included in the conductive layer 240 includes a region overlapping with the opening portion included in the insulating layer 281, the opening portion included in the conductive layer 260, and the opening portion included in the insulating layer 280.

At least parts of the components of the transistor 200B are positioned in the opening portion 291. Specifically, at least part of each of the insulating layer 221, the insulating layer 222, and the semiconductor layer 230 is positioned in the opening portion 291.

The insulating layer 221 is provided to cover the sidewall of the opening portion 291, the insulating layer 222 is provided to cover the side surface of the insulating layer 221, and the semiconductor layer 230 is provided to cover the side surface of the insulating layer 222 and the bottom portion of the opening portion 291. Thus, portions of the insulating layer 221, the insulating layer 222, and the semiconductor layer 230 that are placed in the opening portion 291 are provided to reflect the shape of the opening portion 291.

At least part of each of the insulating layer 250 and the insulating layer 275 is positioned in the opening portion 291. In addition, the insulating layer 250 is provided to cover the semiconductor layer 230, and the insulating layer 275 is provided to fill a depressed portion of the insulating layer 250 that reflects the shape of the opening portion 291. Portions of the insulating layer 250 and the insulating layer 275 which are placed in the opening portion 291 reflect the shape of the opening portion 291.

In the transistor 200B, the semiconductor layer 230 functions as a semiconductor layer, the conductive layer 260 functions as a gate electrode, the insulating layer 221 and the insulating layer 222 function as gate insulators, the conductive layer 220 functions as one of a source electrode and a drain electrode, and the conductive layer 240 functions as the other of the source electrode and the drain electrode. The transistor 200B has a structure in which current flows in the vertical direction since one of the source electrode and the drain electrode is positioned on the lower side and the other of the source electrode and the drain electrode is positioned on the upper side. That is, a channel is formed along the side surface of the opening portion 291.

Here, FIG. 11D is a cross-sectional view along the XY plane including the conductive layer 260. As illustrated in FIG. 11D, a channel formation region of the transistor 200B can be formed in the semiconductor layer 230 positioned inward from the conductive layer 260. In other words, the channel formation region of the transistor 200B can be formed in the semiconductor layer 230 facing the conductive layer 260. Note that FIG. 11D can be regarded as a cross-sectional view along the XY plane including the channel formation region of the semiconductor layer 230.

With the above structure, the semiconductor layer 230 can be sandwiched between insulators that capture or fix hydrogen (here, the insulating layer 222 and the insulating layer 250a). Furthermore, the semiconductor layer 230 sandwiched between the insulators that capture or fix hydrogen can be sandwiched between the barrier insulators against hydrogen (here, the insulating layer 221 and the insulating layer 250b). Thus, the hydrogen concentration in the semiconductor layer 230 can be lowered. At this time, part of hydrogen in the semiconductor layer 230 is captured or fixed by the insulating layer 250a. Another part of hydrogen in the semiconductor layer 230 is captured or fixed by the insulating layer 222. Thus, the hydrogen concentration in the insulating layer 250a and the hydrogen concentration in the insulating layer 222 are increased. For example, the hydrogen concentration in the insulating layer 250a and the hydrogen concentration in the insulating layer 222 are higher than the hydrogen concentration in the semiconductor layer 230.

The insulating layer 275 includes a region in contact with the insulating layer 250b. As the insulating layer 275, any of the insulators described in [Insulator] below can be used as a single layer or stacked layers.

For the insulating layer 281, a barrier insulator against hydrogen is preferably used. Thus, the semiconductor layer 230 can be sandwiched between barrier insulators against hydrogen (here, the insulating layer 281 and the insulating layer 250b) also in a region other than the inside of the opening portion 291.

With such a structure, a semiconductor device having excellent electrical characteristics can be provided. A highly reliable semiconductor device can be provided. A semiconductor device with a small variation in transistor electrical characteristics can be provided. A semiconductor device with a high on-state current can be provided.

Note that the semiconductor layer 230 is sandwiched between insulators having a function of capturing or fixing hydrogen (here, the insulating layer 222 and the insulating layer 250a) in the opening portion 291 in FIG. 11B to FIG. 11D. Since the semiconductor layer 230 is sandwiched between barrier insulators against hydrogen (here, the insulating layer 221 and the insulating layer 250b), the present invention is not limited thereto. The semiconductor device of one embodiment of the present invention may have a structure in which one of the insulating layer 222 and the insulating layer 250a is provided. In other words, a structure may be employed in which the other of the insulating layer 222 and the insulating layer 250a is not provided.

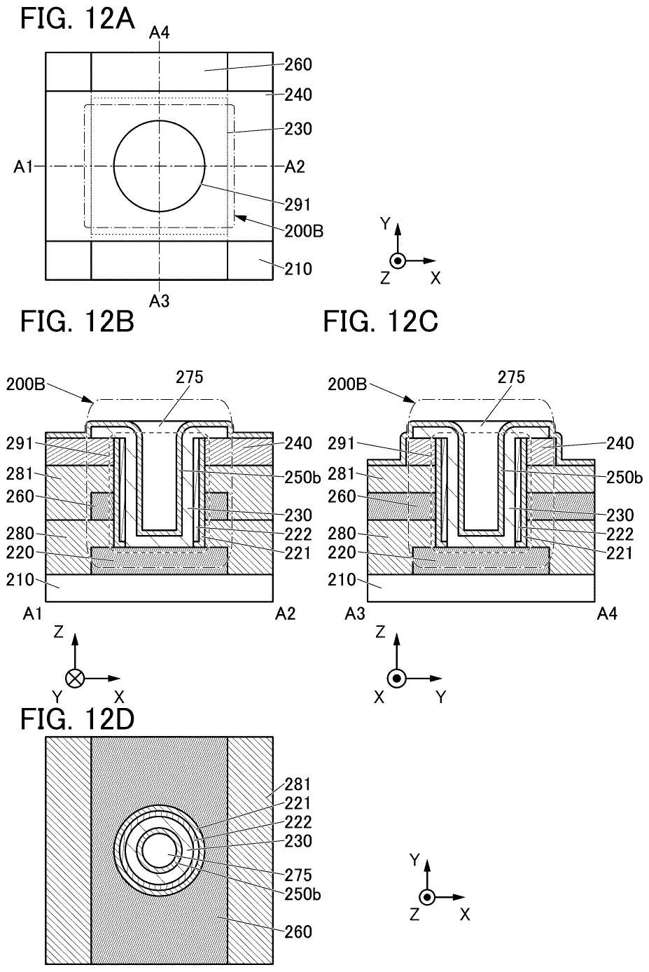

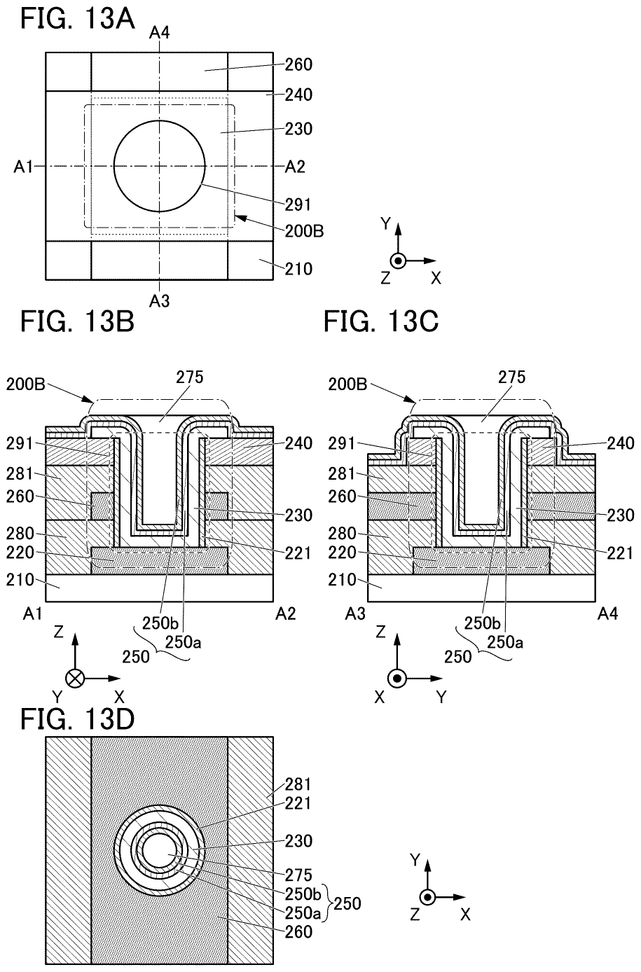

For example, the semiconductor device may have a structure in which the insulating layer 222 is provided and the insulating layer 250a is not provided as illustrated in FIG. 12A to FIG. 12D. In that case, the semiconductor layer 230 includes a region in contact with the insulating layer 250b. For another example, the semiconductor device may have a structure in which the insulating layer 222 is not provided and the insulating layer 250a is provided as illustrated in FIG. 13A to FIG. 13D. In that case, the semiconductor layer 230 includes a region in contact with the insulating layer 221. With these structures, the manufacturing process of the semiconductor device can be simplified and the productivity can be improved.

The semiconductor device illustrated in FIG. 11A to FIG. 11D has the structure in which the semiconductor layer 230 is in contact with part of the top surface of the conductive layer 240 and the side surface of the conductive layer 240 in the opening portion 291. Note that the present invention is not limited thereto. For example, the semiconductor device of one embodiment of the present invention may have a structure in which the semiconductor layer 230 is in contact with the bottom surface of the conductive layer 240.

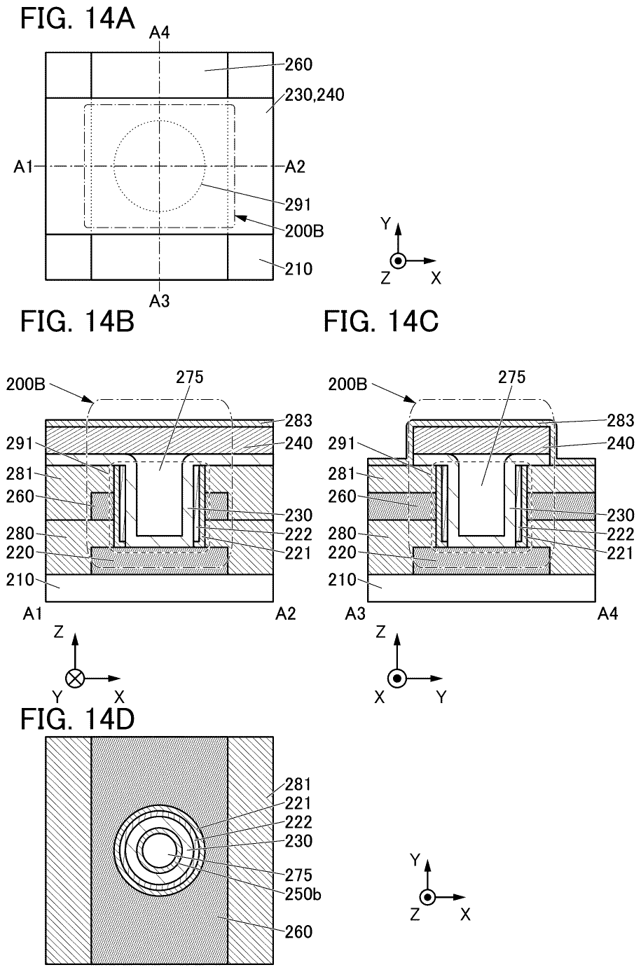

FIG. 14A to FIG. 14D are a plan view and cross-sectional views of a semiconductor device including the transistor 200B. FIG. 14A is the plan view of the semiconductor device. FIG. 14B to FIG. 14D are the cross-sectional views of the semiconductor device. Here, FIG. 14B is the cross-sectional view taken along the dashed-dotted line A1-A2 in FIG. 14A. FIG. 14C is the cross-sectional view taken along the dashed-dotted line A3-A4 in FIG. 14A. FIG. 14D is the cross-sectional view along the XY plane including the conductive layer 260.

The semiconductor device illustrated in FIG. 14A to FIG. 14D includes the insulating layer 210 over a substrate (not illustrated), the transistor 200B over the insulating layer 210, the insulating layer 280 over the insulating layer 210, the insulating layer 281 over the insulating layer 280, and the insulating layer 283 over the transistor 200B.

The transistor 200B includes the conductive layer 220, the conductive layer 260 over the insulating layer 280, the conductive layer 240 over the insulating layer 281, the insulating layer 221, the insulating layer 222, and the semiconductor layer 230 over the conductive layer 220, the insulating layer 275 over the semiconductor layer 230, and the conductive layer 240 over the semiconductor layer 230 and the insulating layer 275.

The conductive layer 240 is provided above the insulating layer 281. The conductive layer 240 includes a region in contact with the top surface of the semiconductor layer 230 and a region in contact with the top surface of the insulating layer 275 above the insulating layer 281. Note that the opening portion reaching the conductive layer 220 is not provided in the conductive layer 240. That is, the opening portion 291 includes the opening portion provided in the insulating layer 280, the opening portion provided in the conductive layer 260, and the opening portion provided in the insulating layer 281.

The semiconductor layer 230 includes a region in contact with the top surface of the insulating layer 281, a region in contact with the side surface of the insulating layer 222, a region in contact with the side surface of the insulating layer 275, a region in contact with the top surface of the conductive layer 220, and a region in contact with the bottom surface of the conductive layer 240. The semiconductor layer 230 has a depressed portion reflecting the shape of the opening portion 291.

The insulating layer 275 is provided between the semiconductor layer 230 and the conductive layer 240. The insulating layer 275 is provided to fill the depressed portion of the semiconductor layer 230. The insulating layer 275 includes a region in contact with the depressed portion of the semiconductor layer 230.

A film from which oxygen is released by heating is preferably used as the insulating layer 275. When the insulating layer 275 releases oxygen by being heated during the manufacturing process of the transistor 200B, the oxygen can be supplied to the semiconductor layer 230. Supply of oxygen from the insulating layer 275 to the semiconductor layer 230, particularly to the channel formation region in the semiconductor layer 230, can reduce oxygen vacancies and V_{O}H in the semiconductor layer 230, so that the transistor can have excellent electrical characteristics and high reliability.

With such a structure, a semiconductor device having excellent electrical characteristics can be provided. A highly reliable semiconductor device can be provided. A semiconductor device with a small variation in transistor electrical characteristics can be provided. A semiconductor device with a high on-state current can be provided.

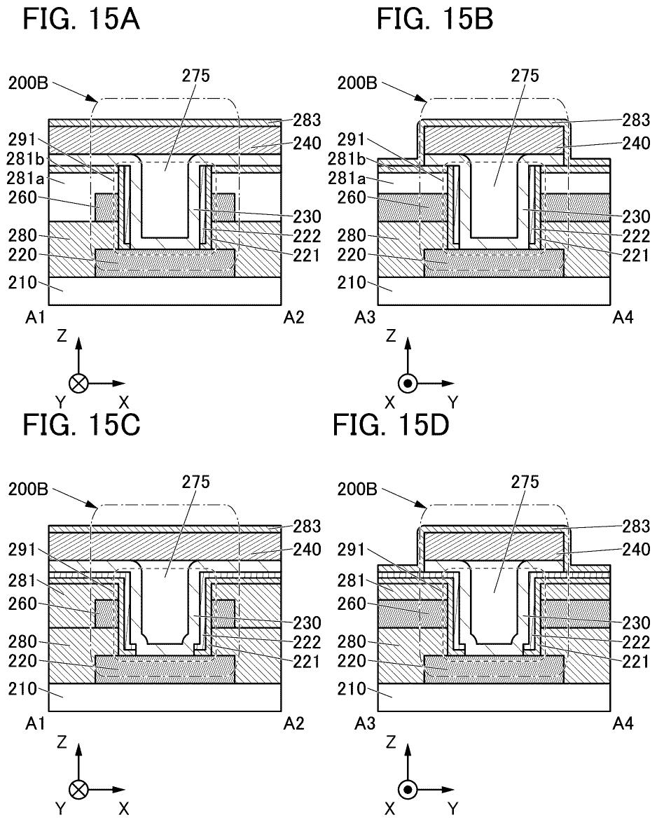

Although FIG. 14B and FIG. 14C illustrate the insulating layer 281 as a single layer, the present invention is not limited thereto. For example, the insulating layer 281 may have a stacked-layer structure. For example, as illustrated in FIG. 15A and FIG. 15B, the insulating layer 281 may have a stacked-layer structure of an insulating layer 281a and an insulating layer 281b over the insulating layer 281a. In that case, a barrier insulator against hydrogen is preferably used as the insulating layer 281b. Thus, the semiconductor layer 230 can be sandwiched between barrier insulators against hydrogen (here, the insulating layer 281b and the insulating layer 283) above the insulating layer 281a. At this time, any of the insulators described in [Insulator] below can be used as the insulating layer 281a. For example, when an insulating film to be the insulating layer 281a is formed by a method with a high film formation rate (e.g., a sputtering method or a CVD method), the productivity of the semiconductor device can be improved.

Although the insulating layer 221 is provided in contact with the sidewall of the opening portion 291 in FIG. 14B and FIG. 14C, the present invention is not limited thereto. For example, the insulating layer 221 may include a region in contact with the top surface of the insulating layer 281. As illustrated in FIG. 15C and FIG. 15D, the insulating layer 221 may be provided in contact with the top surface of the insulating layer 281, the side surface of the insulating layer 281 in the opening portion 291, the side surface of the conductive layer 260 in the opening portion 291, and the side surface of the insulating layer 280 in the opening portion 291, for example. In that case, the insulating layer 221 preferably has an opening portion reaching the conductive layer 220 in the opening portion 291. The insulating layer 222 is preferably provided in contact with the top surface of the insulating layer 221. In that case, the insulating layer 222 preferably has an opening portion reaching the conductive layer 220 in the opening portion 291. Accordingly, the semiconductor layer 230 is in contact with the insulator that captures or fixes hydrogen above the insulating layer 281, so that the hydrogen concentration in the semiconductor layer 230 can be reduced.

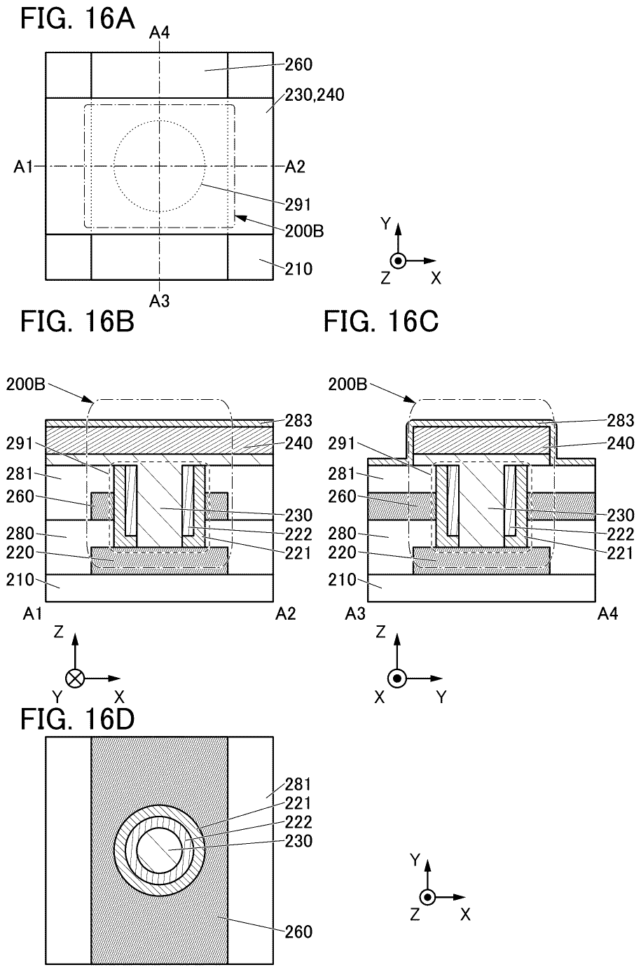

Although FIG. 14B to FIG. 14D illustrate the structure in which the insulating layer 275 is provided in the depressed portion of the semiconductor layer 230, the present invention is not limited thereto. For example, when the area of the opening portion 291 in a plan view is reduced in order to reduce the size of the transistor 200B, the semiconductor layer 230 does not have a depressed portion in some cases (see FIG. 16A to FIG. 16D). In that case, the insulating layer 275 need not be provided.

In a plan view, as the area of the opening portion 291 is smaller, the area of the depressed portion provided in the semiconductor layer 230 becomes smaller. In the case where the area of the depressed portion provided in the semiconductor layer 230 is small in a plan view, a gap is sometimes provided between the semiconductor layer 230 and the conductive layer 240. In that case, the insulating layer 275 is not provided. The gap contains, for example, any one or more selected from air, nitrogen, oxygen, carbon dioxide, and Group 18 elements.

### <Component Materials for Semiconductor Device>

Component materials that can be used for the semiconductor device will be described below.

### [Substrate]

As a substrate where a transistor is formed, an insulator substrate, a semiconductor substrate, or a conductor substrate is used, for example. Examples of the insulator substrate include a glass substrate, a quartz substrate, a sapphire substrate, a stabilized zirconia substrate (e.g., an yttria-stabilized zirconia substrate), and a resin substrate. Examples of the semiconductor substrate include a semiconductor substrate using silicon or germanium as a material and a compound semiconductor substrate including silicon carbide, silicon germanium, gallium arsenide, indium phosphide, zinc oxide, or gallium oxide. Another example is a semiconductor substrate in which an insulator region is included in the semiconductor substrate described above, e.g., an SOI (Silicon On Insulator) substrate. Examples of the conductor substrate include a graphite substrate, a metal substrate, an alloy substrate, and a conductive resin substrate. Other examples include a substrate containing a metal nitride and a substrate containing a metal oxide. Other examples include an insulator substrate provided with a conductor or a semiconductor, a semiconductor substrate provided with a conductor or an insulator, and a conductor substrate provided with a semiconductor or an insulator. Alternatively, these substrates provided with elements may be used. Examples of the element provided for the substrate include a capacitor, a resistor, a switching element, a light-emitting element, and a memory element.

### [Insulator]

Examples of an insulator include an insulating oxide, an insulating nitride, an insulating oxynitride, an insulating nitride oxide, an insulating metal oxide, an insulating metal oxynitride, and an insulating metal nitride oxide.

Note that in this specification and the like, oxynitride refers to a material in which an oxygen content is higher than a nitrogen content, and nitride oxide refers to a material in which a nitrogen content is higher than an oxygen content. For example, silicon oxynitride refers to a material that contains more oxygen than nitrogen, and silicon nitride oxide refers to a material that contains more nitrogen than oxygen.

As miniaturization and high integration of transistors progress, for example, a problem such as leakage current may arise because of a thinner gate insulator. When a high-k material is used for an insulator functioning as a gate insulating layer, the voltage at the time of the operation of the transistor can be reduced while the physical thickness is maintained. In addition, the equivalent oxide thickness (EOT) of the insulator functioning as the gate insulating layer can be reduced. By contrast, when a material with a low relative permittivity is used for an insulator functioning as an interlayer film, the parasitic capacitance generated between wirings can be reduced. Thus, a material is preferably selected in accordance with the function of the insulator. Note that the material with a low relative permittivity is a material with high dielectric strength.

Examples of the material with a high relative permittivity (high-k material) include aluminum oxide, gallium oxide, hafnium oxide, tantalum oxide, zirconium oxide, hafnium zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with a low relative permittivity include inorganic insulating materials such as silicon oxide, silicon oxynitride, and silicon nitride oxide, and resins such as polyester, polyolefin, polyamide (e.g., nylon and aramid), polyimide, polycarbonate, and acrylic. Other examples of an inorganic insulating material with a low relative permittivity include silicon oxide to which fluorine is added, silicon oxide to which carbon is added, and silicon oxide to which carbon and nitrogen are added. Another example is porous silicon oxide. These silicon oxides can contain nitrogen.

When a transistor using a metal oxide is surrounded by an insulator having a function of inhibiting passage of oxygen and impurities, the transistor can have stable electrical characteristics. As the insulator having a function of inhibiting passage of oxygen and impurities, a single layer or stacked layers including an insulator containing, for example, boron, carbon, nitrogen, oxygen, fluorine, magnesium, aluminum, silicon, phosphorus, chlorine, argon, gallium, germanium, yttrium, zirconium, lanthanum, neodymium, hafnium, or tantalum can be used. Specifically, as the insulator having a function of inhibiting passage of oxygen and impurities, a metal oxide such as aluminum oxide, magnesium oxide, gallium oxide, germanium oxide, yttrium oxide, zirconium oxide, lanthanum oxide, neodymium oxide, hafnium oxide, or tantalum oxide; or a metal nitride such as aluminum nitride, silicon nitride oxide, or silicon nitride can be used.

An insulating layer that is in contact with a semiconductor layer or provided in the vicinity of a semiconductor layer, such as a gate insulator, preferably includes a region containing oxygen (hereinafter, sometimes referred to as excess oxygen) released by heating. For example, when an insulating layer including a region containing excess oxygen is in contact with a semiconductor layer or provided in the vicinity of the semiconductor layer, oxygen vacancies in the semiconductor layer can be reduced. Examples of an insulator in which a region containing excess oxygen is easily formed include silicon oxide, silicon oxynitride, and porous silicon oxide.

Examples of a barrier insulator against oxygen include an oxide containing one or both of aluminum and hafnium, an oxide containing hafnium and silicon (hafnium silicate), magnesium oxide, gallium oxide, gallium zinc oxide, silicon nitride, and silicon nitride oxide. Examples of the oxide containing one or both of aluminum and hafnium include aluminum oxide, hafnium oxide, and an oxide containing aluminum and hafnium (hafnium aluminate).

Examples of a material for the barrier insulator against hydrogen include aluminum oxide, magnesium oxide, hafnium oxide, gallium oxide, silicon nitride, and silicon nitride oxide.

A barrier insulator against oxygen and a barrier insulator against hydrogen can each be regarded as a barrier insulator against one or both of oxygen and hydrogen.

Note that a function of capturing or fixing a target substance can also be referred to as a property that does not easily allow diffusion of a target substance. Thus, the function of capturing or fixing a target substance can be rephrased as a barrier property.

Examples of an insulator having a function of capturing or fixing hydrogen include an oxide containing magnesium and an oxide containing one or both of aluminum and hafnium. Examples of the oxide containing one or both of aluminum and hafnium include aluminum oxide, hafnium oxide, and an oxide containing aluminum and hafnium (hafnium aluminate). Silicon oxide may be added to these oxides. Examples of an insulator having a function of capturing or fixing hydrogen include an oxide containing magnesium and silicon, an oxide containing aluminum and silicon, and an oxide containing hafnium and silicon (hafnium silicate).

Each of the above-described oxides preferably contains an oxygen atom having a dangling bond. Such an oxide may have a property of capturing or fixing hydrogen with the dangling bond. For example, each of the above-described oxides preferably has an amorphous structure. This is because some oxygen atoms in an oxide having an amorphous structure have dangling bonds. Note that each of the above-described oxides preferably has an amorphous structure, but a crystal region may be partly formed. Each of the above-described oxides may have a crystal grain boundary. This is because, in an oxide having a crystal grain boundary, some oxygen atoms in the vicinity of the crystal grain boundary have dangling bonds in some cases.

In this specification and the like, a barrier insulator refers to an insulator having a barrier property. In addition, the barrier property refers to a property that does not easily allow diffusion of a target substance (also referred to as a property that does not easily allow transmission of a target substance, a property with low permeability of a target substance, or a function of inhibiting diffusion of a target substance). Note that hydrogen described as a target substance refers to at least one of a hydrogen atom, a hydrogen molecule, and a substance bonded to hydrogen, such as a water molecule or OH—, for example. Unless otherwise specified, an impurity described as a target substance refers to an impurity in a channel formation region or a semiconductor layer, and for example, refers to at least one of a hydrogen atom, a hydrogen molecule, a water molecule, a nitrogen atom, a nitrogen molecule, a nitrogen oxide molecule (e.g., N₂O, NO, or NO₂), and a copper atom. Oxygen described as a target substance refers to, for example, at least one of an oxygen atom and an oxygen molecule.

### [Conductor]

As a conductor, it is preferable to use a metal element selected from aluminum, chromium, copper, silver, gold, platinum, tantalum, nickel, titanium, molybdenum, tungsten, hafnium, vanadium, niobium, manganese, magnesium, zirconium, beryllium, indium, ruthenium, iridium, strontium, lanthanum, and the like; an alloy containing any of the above metal elements as its component; an alloy containing a combination of the above metal elements; or the like. As the alloy containing any of the above metal elements as its component, a nitride of the alloy or an oxide of the alloy may be used. For example, it is preferable to use tantalum nitride, titanium nitride, tungsten, a nitride containing titanium and aluminum, a nitride containing tantalum and aluminum, ruthenium oxide, ruthenium nitride, an oxide containing strontium and ruthenium, an oxide containing lanthanum and nickel, or the like. A semiconductor having high electrical conductivity, typified by polycrystalline silicon containing an impurity element such as phosphorus, or silicide such as nickel silicide may also be used.

A conductive material containing nitrogen, such as a nitride containing tantalum, a nitride containing titanium, a nitride containing molybdenum, a nitride containing tungsten, a nitride containing ruthenium, a nitride containing tantalum and aluminum, or a nitride containing titanium and aluminum; a conductive material containing oxygen, such as ruthenium oxide, an oxide containing strontium and ruthenium, or an oxide containing lanthanum and nickel; or a material containing a metal element such as titanium, tantalum, or ruthenium is preferable because it is a conductive material that is not easily oxidized, a conductive material having a function of inhibiting diffusion of oxygen, or a material maintaining its conductivity even after absorbing oxygen. Examples of the conductive material containing oxygen include indium oxide containing tungsten oxide, indium oxide containing titanium oxide, ITO, indium tin oxide containing titanium oxide, ITSO, indium zinc oxide, and indium zinc oxide containing tungsten oxide. In this specification and the like, a conductive film formed using the conductive material containing oxygen may be referred to as an oxide conductive film.

A conductive material containing tungsten, copper, or aluminum as its main component is preferable because it has high conductivity.

A stack of a plurality of conductive layers formed of the above-described materials may be used. For example, a stacked-layer structure combining a material containing the above metal element and a conductive material containing oxygen may be employed. A stacked-layer structure combining a material containing the above metal element and a conductive material containing nitrogen may be employed. A stacked-layer structure combining a material containing the above metal element, a conductive material containing oxygen, and a conductive material containing nitrogen may be employed.

In the case where a metal oxide is used for a channel formation region of a transistor, a conductive layer functioning as a gate electrode preferably has a stacked-layer structure combining a material containing the above metal element and a conductive material containing oxygen. In that case, the conductive material containing oxygen is preferably provided on the channel formation region side. When the conductive material containing oxygen is provided on the channel formation region side, oxygen released from the conductive material is easily supplied to the channel formation region.

It is particularly preferable to use, for the conductive layer functioning as the gate electrode, a conductive material containing oxygen and a metal element contained in a metal oxide where a channel is formed. A conductive material containing the above metal element and nitrogen may be used. For example, a conductive material containing nitrogen, such as titanium nitride or tantalum nitride, may be used. One or more of ITO, indium oxide containing tungsten oxide, indium zinc oxide containing tungsten oxide, indium oxide containing titanium oxide, indium tin oxide containing titanium oxide, indium zinc oxide, and ITSO may be used. Indium gallium zinc oxide containing nitrogen may be used. With the use of such a material, hydrogen contained in the metal oxide where the channel is formed can be captured in some cases. Alternatively, hydrogen entering from an external insulator or the like can be captured in some cases.

### [Metal Oxide]

A metal oxide sometimes includes a lattice defect. Examples of a lattice defect include point defects such as an atomic vacancy and an exotic atom, a line defect such as dislocation, a plane defect such as a crystal grain boundary, and a volume defect such as a void. Examples of a factor in generating a lattice defect include the deviation of the proportion of the number of atoms in constituent elements (excess or deficiency of constituent atoms) and an impurity.

When a metal oxide is used for a semiconductor layer of a transistor, a lattice defect in the metal oxide might cause generation, capture, or the like of a carrier. Thus, the use of a metal oxide with many lattice defects for a semiconductor layer of a transistor may cause unstable electrical characteristics of the transistor. Hence, a metal oxide used for a semiconductor layer of a transistor preferably has a small number of lattice defects.

The kind of a lattice defect that is likely to be present in a metal oxide and the number of lattice defects that are present vary depending on the structure of the metal oxide, a method for forming the metal oxide, or the like.

Structures of metal oxides are classified into a single crystal structure and other structures (non-single-crystal structures). Examples of non-single-crystal structures include a CAAC structure, a polycrystalline structure, an nc structure, an amorphous-like (a-like) structure, and an amorphous structure. The a-like structure has a structure between the nc structure and the amorphous structure. Note that the classification of crystal structures will be described later.

A metal oxide having an a-like structure and a metal oxide having an amorphous structure each include a void or a low-density region. That is, the metal oxide having the a-like structure and the metal oxide having the amorphous structure have lower crystallinity than a metal oxide having an nc structure and a metal oxide having a CAAC structure. Moreover, the metal oxide having the a-like structure has a higher hydrogen concentration in the metal oxide than the metal oxide having the nc structure and the metal oxide having the CAAC structure. Thus, a lattice defect is easily formed in the metal oxide having the a-like structure and the metal oxide having the amorphous structure.

Thus, a metal oxide with high crystallinity is preferably used for a semiconductor layer of a transistor. For example, it is preferable to use the metal oxide having the CAAC structure or the metal oxide having the single crystal structure. The use of such a metal oxide for a transistor enables the transistor to have excellent electrical characteristics. In addition, a transistor with high reliability can be achieved.

For a channel formation region of a transistor, a metal oxide that increases the on-state current of the transistor is preferably used. To increase the on-state current of the transistor, the carrier mobility of the metal oxide used for the transistor is preferably increased. To increase the carrier mobility of the metal oxide, the transfer of carriers (electrons in the case of an n-channel transistor) needs to be facilitated or scattering factors that affect the carrier transfer need to be reduced. The carriers flow from the source to the drain through the channel formation region. Hence, the on-state current of the transistor can be increased by providing a channel formation region through which carriers can easily flow in the channel length direction.

Here, it is preferable to use a metal oxide with high crystallinity as a metal oxide including a channel formation region. The crystal preferably has a crystal structure in which a plurality of layers (e.g., a first layer, a second layer, and a third layer) are stacked. That is, the crystal has a layered crystal structure (also referred to as a layered crystal or a layered structure). At this time, the direction of the c-axis of the crystal is the direction in which the plurality of layers are stacked. Examples of a metal oxide including the crystal include a single crystal oxide semiconductor and a CAAC-OS.

The c-axis of the above crystal is preferably aligned in the normal direction with respect to the formation surface or the film surface of the metal oxide. This enables the plurality of layers to be placed parallel or substantially parallel to the formation surface or the film surface of the metal oxide. That is, the plurality of layers extend in the channel length direction.

The above layered crystal structure including three layers is as follows, for example. The first layer has a coordination geometry of atoms that has an octahedral structure of oxygen in which a metal included in the first layer is positioned at the center. The second layer has a coordination geometry of atoms that has a trigonal bipyramidal or tetrahedral structure of oxygen in which a metal included in the second layer is positioned at the center. The third layer has a coordination geometry of atoms that has a trigonal bipyramidal or tetrahedral structure of oxygen in which a metal included in the third layer is positioned at the center.

Examples of the crystal structure of the above crystal include a YbFe₂O₄ type structure, a Yb₂Fe₃O₇ type structure, and variant structures of these structures.

Each of the first layer to the third layer is preferably composed of oxygen and one metal element or a plurality of metal elements with the same valence. The valences of the one or plurality of metal elements included in the first layer are preferably equal to the valences of the one or plurality of metal elements included in the second layer. The first layer and the second layer may include the same metal element. The valences of the one or plurality of metal elements included in the first layer are preferably different from the valences of the one or plurality of metal elements included in the third layer.

The above structure can increase the crystallinity of the metal oxide, which leads to an increase in the carrier mobility of the metal oxide. Thus, the use of the metal oxide for the channel formation region of the transistor increases the on-state current of the transistor, leading to an improvement in the electrical characteristics of the transistor.

Examples of the metal oxide usable for the semiconductor layer of the transistor include indium oxide, gallium oxide, and zinc oxide. The metal oxide of one embodiment of the present invention preferably contains at least indium (In) or zinc (Zn). The metal oxide preferably contains two or three elements selected from indium, the element M, and zinc. Note that the element M is a metal element or metalloid element that has a high bonding energy with oxygen, e.g., a metal element or metalloid element whose bonding energy with oxygen is higher than that of indium. Specific examples of the element M include aluminum, gallium, tin, yttrium, titanium, vanadium, chromium, manganese, iron, cobalt, nickel, zirconium, molybdenum, hafnium, tantalum, tungsten, lanthanum, cerium, neodymium, magnesium, calcium, strontium, barium, boron, silicon, germanium, and antimony. The element M contained in the metal oxide is preferably one or more kinds of the above elements, further preferably one or more kinds selected from aluminum, gallium, tin, and yttrium, still further preferably gallium. When the element M contained in the metal oxide is gallium, the metal oxide of one embodiment of the present invention preferably contains one or more selected from indium, gallium, and zinc. In this specification and the like, a metal element and a metalloid element may be collectively referred to as a “metal element”, and a “metal element” in this specification and the like may include a metalloid element.

For example, as the metal oxide, indium zinc oxide (In—Zn oxide), indium tin oxide (In—Sn oxide, also referred to as ITO), indium titanium oxide (In—Ti oxide), indium gallium oxide (In—Ga oxide), indium gallium aluminum oxide (In—Ga—Al oxide), indium gallium tin oxide (In—Ga—Sn oxide, also referred to as IGTO), gallium zinc oxide (Ga—Zn oxide, also referred to as GZO), aluminum zinc oxide (Al—Zn oxide, also referred to as AZO), indium aluminum zinc oxide (In—Al—Zn oxide, also referred to as IAZO), indium tin zinc oxide (In—Sn—Zn oxide), indium titanium zinc oxide (In—Ti—Zn oxide), indium gallium zinc oxide (In—Ga—Zn oxide, also referred to as IGZO), indium gallium tin zinc oxide (In—Ga—Sn—Zn oxide, also referred to as IGZTO), or indium gallium aluminum zinc oxide (In—Ga—Al—Zn oxide, also referred to as IGAZO or IAGZO) can be used. Alternatively, indium tin oxide containing silicon, gallium tin oxide (Ga—Sn oxide), aluminum tin oxide (Al—Sn oxide), or the like can be used.

When the proportion of the number of indium atoms in the total number of atoms of all the metal elements contained in the metal oxide is increased, the field-effect mobility of the transistor can be increased.

Note that the metal oxide may contain, instead of indium, one or more kinds of metal elements with large period numbers in the periodic table of the elements. Alternatively, the metal oxide may contain, in addition to indium, one or more kinds of metal elements with large period numbers in the periodic table of the elements. The larger the overlap between orbits of metal elements is, the more likely it is that the metal oxide will have high carrier conductivity. Thus, a transistor containing a metal element with a large period number in the periodic table of the elements can have high field-effect mobility in some cases. Examples of the metal element with a large period number in the periodic table of the elements include metal elements belonging to Period 5 and metal elements belonging to Period 6. Specific examples of the metal element include yttrium, zirconium, silver, cadmium, tin, antimony, barium, lead, bismuth, lanthanum, cerium, praseodymium, neodymium, promethium, samarium, and europium. Note that lanthanum, cerium, praseodymium, neodymium, promethium, samarium, and europium are called light rare-earth elements.

The metal oxide may contain one or more kinds of nonmetallic elements. A transistor including the metal oxide containing a nonmetallic element can have higher field-effect mobility in some cases. Examples of the nonmetallic element include carbon, nitrogen, phosphorus, sulfur, selenium, fluorine, chlorine, bromine, and hydrogen.

By increasing the proportion of the number of zinc atoms in the total number of atoms of all the metal elements contained in the metal oxide, the metal oxide has high crystallinity, so that diffusion of impurities in the metal oxide can be inhibited. Consequently, a change in electrical characteristics of the transistor can be inhibited, and the reliability of the transistor can be increased.

By increasing the proportion of the number of atoms of the element M in the total number of atoms of all the metal elements contained in the metal oxide, oxygen vacancies can be inhibited from being formed in the metal oxide. Accordingly, generation of carriers due to oxygen vacancies is inhibited, which makes the off-state current of the transistor low. Furthermore, a change in electrical characteristics of the transistor can be inhibited, and the reliability of the transistor can be increased.

By increasing the proportion of the number of In atoms in the total number of atoms of all the metal elements contained in the metal oxide, the transistor can have a high on-state current and high frequency characteristics.

As the semiconductor layer of the transistor, a metal oxide film with a composition of In:M:Zn=1:3:2 [atomic ratio] or in the neighborhood thereof, a metal oxide with a composition of In:M:Zn=1:3:4 [atomic ratio] or in the neighborhood thereof, a metal oxide with a composition of In:M:Zn=1:1:0.5 [atomic ratio] or in the neighborhood thereof, a metal oxide with a composition of In:M:Zn=1:1:1 [atomic ratio] or in the neighborhood thereof, a metal oxide with a composition of In:M:Zn=1:1:1.2 [atomic ratio] or in the neighborhood thereof, a metal oxide with a composition of In:M:Zn=1:1:2 [atomic ratio] or in the neighborhood thereof, or a metal oxide with a composition of In:M:Zn=4:2:3 [atomic ratio] or in the neighborhood thereof may be specifically used. Note that the neighborhood of the atomic ratio includes ±30% of an intended atomic ratio. Gallium is preferably used as the element M.

The semiconductor layer of the transistor may have a structure not containing the element M. For example, an In—Zn oxide film may be used as the semiconductor layer. Alternatively, for example, an indium oxide film may be used as the semiconductor layer.

In the description of this embodiment, In—Ga—Zn oxide is sometimes taken as an example of the metal oxide.

For the formation of a metal oxide having the layered crystal structure, atomic layers are preferably deposited one by one. Since an ALD method is employed as the film formation method of the metal oxide of one embodiment of the present invention, a metal oxide having the layered crystal structure is easily formed.

### [[Transistor Including Metal Oxide]]

Next, the case where a metal oxide (oxide semiconductor) is used for a transistor will be described. Hereinafter, a transistor using an oxide semiconductor for a semiconductor layer is sometimes referred to as an OS transistor, and a transistor using silicon for a semiconductor layer is sometimes referred to as a Si transistor.

When a metal oxide (oxide semiconductor) of one embodiment of the present invention is used for a transistor, the transistor can have high field-effect mobility. In addition, the transistor can have high reliability. Furthermore, the transistor can be miniaturized or highly integrated. For example, the transistor with a channel length greater than or equal to 2 nm and less than or equal to 30 nm can be formed.

An oxide semiconductor having a low carrier concentration is preferably used for a channel formation region of a transistor. For example, the carrier concentration in a channel formation region of an oxide semiconductor is lower than or equal to 1×10¹⁸ cm³, preferably lower than or equal to 1×10¹⁷ cm⁻³, further preferably lower than or equal to 1×10¹⁵ cm⁻³, still further preferably lower than or equal to 1×10¹³ cm⁻³, yet further preferably lower than or equal to 1×10¹¹ cm³, yet still further preferably lower than 1×10¹⁰ cm³, and higher than or equal to 1×10⁻⁹ cm³. In order to reduce the carrier concentration in an oxide semiconductor film, the impurity concentration in the oxide semiconductor film is preferably reduced so that the density of defect states can be reduced. In this specification and the like, a state with a low impurity concentration and a low density of defect states is referred to as a highly purified intrinsic or substantially highly purified intrinsic state. Note that an oxide semiconductor having a low carrier concentration may be referred to as a highly purified intrinsic or substantially highly purified intrinsic oxide semiconductor.

A highly purified intrinsic or substantially highly purified intrinsic oxide semiconductor film has a low density of defect states and thus has a low density of trap states in some cases.

Charge trapped by the trap states in the oxide semiconductor takes a long time to disappear and sometimes behaves like fixed charge. Thus, a transistor whose channel formation region is formed in an oxide semiconductor with a high density of trap states has unstable electrical characteristics in some cases.

Accordingly, in order to obtain stable electrical characteristics of a transistor, reducing the impurity concentration in an oxide semiconductor is effective. In order to reduce the impurity concentration in the oxide semiconductor, it is preferable that the impurity concentration in an adjacent film be also reduced. Examples of impurities include hydrogen, carbon, and nitrogen. Note that an impurity in an oxide semiconductor refers to, for example, an element other than the main components of the oxide semiconductor. For example, an element with a concentration lower than 0.1 atomic % can be regarded as an impurity.

The band gap of the oxide semiconductor is preferably larger than the band gap of silicon (typically 1.1 eV), further preferably larger than or equal to 2 eV, still further preferably larger than or equal to 2.5 eV, yet still further preferably larger than or equal to 3.0 eV. With the use of an oxide semiconductor having a larger band gap than silicon, the off-state current (also referred to as Ioff) of the transistor can be reduced.

In a Si transistor, a short-channel effect (also referred to as SCE) appears as miniaturization of the transistor proceeds. For this reason, it is difficult to miniaturize the Si transistor. One factor that causes the short-channel effect is a small band gap of silicon. By contrast, the OS transistor includes an oxide semiconductor that is a semiconductor material having a large band gap, and thus the short-channel effect can be suppressed. In other words, the OS transistor is a transistor in which the short-channel effect does not appear or the short-channel effect hardly appears.

Note that the short-channel effect refers to degradation of electrical characteristics which becomes apparent along with miniaturization (a decrease in channel length) of a transistor. Specific examples of the short-channel effect include a decrease in threshold voltage, an increase in a subthreshold swing value (sometimes referred to as an S value), and an increase in leakage current. Here, the S value means the amount of change in gate voltage in the subthreshold region when the drain voltage keeps constant and the drain current changes by one order of magnitude.

The characteristic length is widely used as an indicator of resistance to the short-channel effect. The characteristic length is an indicator of curving of potential in a channel formation region. When the characteristic length is shorter, the potential rises more sharply, which means that the resistance to the short-channel effect is high.

The OS transistor is an accumulation-type transistor and the Si transistor is an inversion-type transistor. Accordingly, the OS transistor has a shorter characteristic length between a source region and a channel formation region and a shorter characteristic length between a drain region and the channel formation region than the Si transistor. Thus, the OS transistor has higher resistance to the short-channel effect than the Si transistor. That is, in the case where a transistor with a short channel length is to be fabricated, the OS transistor is more suitable than the Si transistor.

Even in the case where the carrier concentration in the oxide semiconductor is reduced until the channel formation region becomes an i-type or substantially i-type region, the conduction band minimum of the channel formation region in a short-channel transistor decreases because of the Conduction-Band-Lowering (CBL) effect; thus, the energy difference between the conduction band minimum of the source region or the drain region and that of the channel formation region may decrease to greater than or equal to 0.1 eV and less than or equal to 0.2 eV. Accordingly, the OS transistor can be regarded as having an n⁺/n⁻/n⁺ accumulation-type junction-less transistor structure or an n⁺/n⁻/n⁺ accumulation-type non-junction transistor structure in which the channel formation region becomes an n⁻-type region and the source and drain regions become n⁺-type regions.

The above-described structure enables the OS transistor to have excellent electrical characteristics even when the OS transistor is miniaturized or highly integrated. For example, excellent electrical characteristics can be obtained even when the OS transistor has a channel length or a gate length less than or equal to 20 nm, less than or equal to 15 nm, less than or equal to 10 nm, less than or equal to 7 nm, or less than or equal to 6 nm and greater than or equal to 1 nm, greater than or equal to 3 nm, or greater than or equal to 5 nm. By contrast, it is sometimes difficult for the Si transistor to have a gate length less than or equal to 20 nm or less than or equal to 15 nm because of the appearance of the short-channel effect. Thus, the OS transistor can be used as a transistor having a short channel length more suitably than the Si transistor. Note that the gate length refers to the length of a gate electrode in a direction in which carriers move inside a channel formation region during an operation of the transistor.

Miniaturization of the OS transistor can improve the high-frequency characteristics of the transistor. Specifically, the cutoff frequency of the transistor can be improved. When the gate length of the OS transistor is within the above range, the cutoff frequency of the transistor can be greater than or equal to 50 GHz, preferably greater than or equal to 100 GHz, further preferably greater than or equal to 150 GHz in a room temperature environment, for example.

The above comparison of the OS transistor with the Si transistor demonstrates that the OS transistor is advantageous over the Si transistor in that the off-state current is low and a transistor having a short channel length can be fabricated.

### [Impurity in Metal Oxide]

Here, the influence of impurities in the metal oxide (oxide semiconductor) will be described.

When silicon or carbon, which is one of Group 14 elements, is contained in the oxide semiconductor, defect states are formed in the oxide semiconductor. Thus, the carbon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³. The silicon concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 3×10¹⁹ atoms/cm³, still further preferably lower than or equal to 1×10¹⁹ atoms/cm³, yet further preferably lower than or equal to 3×10¹⁸ atoms/cm³, yet still further preferably lower than or equal to 1×10¹⁸ atoms/cm³.

When the oxide semiconductor contains nitrogen, the oxide semiconductor easily becomes n-type by generation of electrons serving as carriers and an increase in carrier concentration. As a result, a transistor using an oxide semiconductor that contains nitrogen as a semiconductor is likely to have normally-on characteristics. When nitrogen is contained in the oxide semiconductor, trap states are sometimes formed. This might make the electrical characteristics of the transistor unstable. Thus, the nitrogen concentration in the channel formation region of the oxide semiconductor, which is measured by SIMS, is lower than or equal to 1×10²⁰ atoms/cm³, preferably lower than or equal to 5×10¹⁹ atoms/cm³, further preferably lower than or equal to 1×10¹⁹ atoms/cm³, still further preferably lower than or equal to 5×10¹⁸ atoms/cm³, yet further preferably lower than or equal to 1×10¹⁸ atoms/cm³, yet still further preferably lower than or equal to 5×10¹⁷ atoms/cm³.

Hydrogen contained in the oxide semiconductor reacts with oxygen bonded to a metal atom to be water, and thus an oxygen vacancy is formed in some cases. Entry of hydrogen into the oxygen vacancy generates an electron serving as a carrier in some cases. Furthermore, bonding of part of hydrogen to oxygen bonded to a metal atom causes generation of an electron serving as a carrier in some cases. Thus, a transistor using an oxide semiconductor that contains hydrogen is likely to have normally-on characteristics. For this reason, hydrogen in the channel formation region of the oxide semiconductor is preferably reduced as much as possible. Specifically, the hydrogen concentration in the channel formation region of the oxide semiconductor, which is measured by SIMS, is lower than 1×10²⁰ atoms/cm³, preferably lower than 5×10¹⁹ atoms/cm³, further preferably lower than 1×10¹⁹ atoms/cm³, still further preferably lower than 5×10¹⁸ atoms/cm³, yet further preferably lower than 1×10¹⁸ atoms/cm³, yet still further preferably lower than 1×10¹⁷ atoms/cm³.

When the oxide semiconductor contains an alkali metal or an alkaline earth metal, defect states are formed and carriers are generated in some cases. Thus, a transistor using an oxide semiconductor that contains an alkali metal or an alkaline earth metal is likely to have normally-on characteristics. Thus, the concentration of an alkali metal or an alkaline earth metal in the channel formation region of the oxide semiconductor, which is measured by SIMS, is lower than or equal to 1×10¹⁸ atoms/cm³, preferably lower than or equal to 2×10¹⁶ atoms/cm³.

When an oxide semiconductor with sufficiently reduced impurities is used for the channel formation region of the transistor, stable electrical characteristics can be given.

This embodiment can be combined with any of the other embodiments as appropriate. In this specification, in the case where a plurality of structure examples are shown in one embodiment, the structure examples can be combined as appropriate.

### Embodiment 3

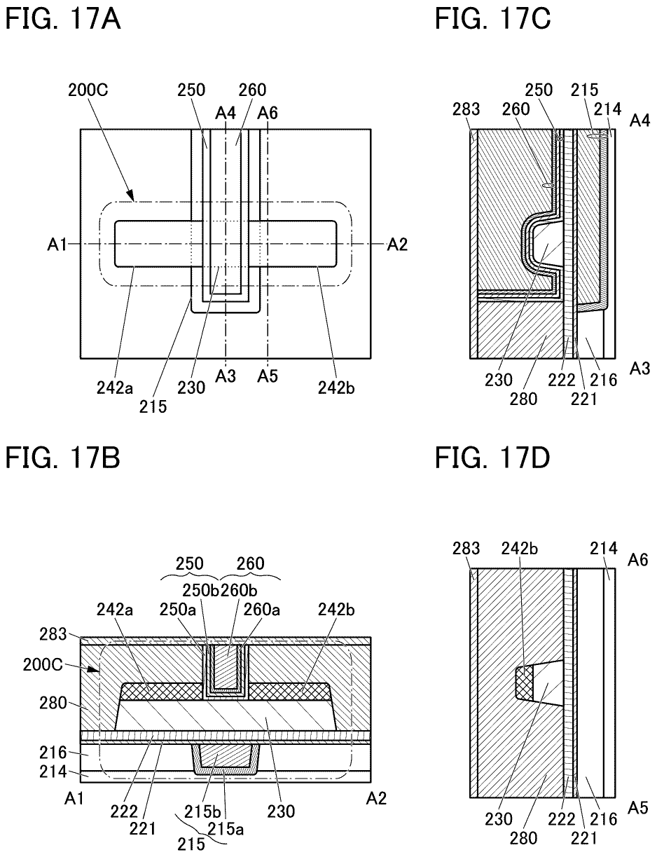

In this embodiment, structure examples of semiconductor devices of one embodiment of the present invention will be described with reference to FIG. 17A to FIG. 24D.

In the semiconductor devices illustrated in FIG. 17A to FIG. 24D, components having the same functions as the components of the semiconductor device described in Embodiment 2 are denoted by the same reference numerals. Note that in this embodiment, portions similar to those in Embodiment 1 or Embodiment 2 are not described in some cases. In addition, the materials described in detail in Embodiment 1 or Embodiment 2 can be used as component materials for the semiconductor device.

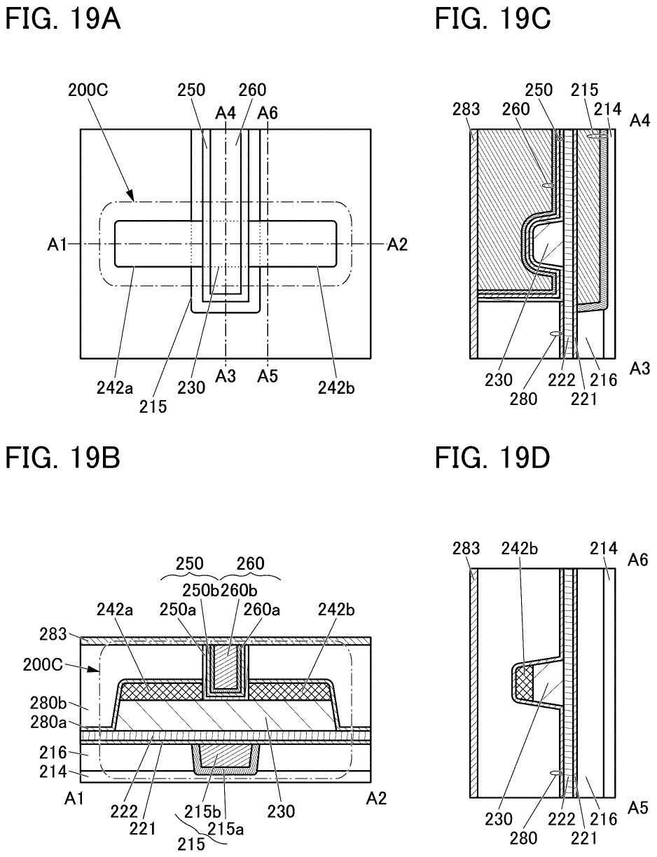

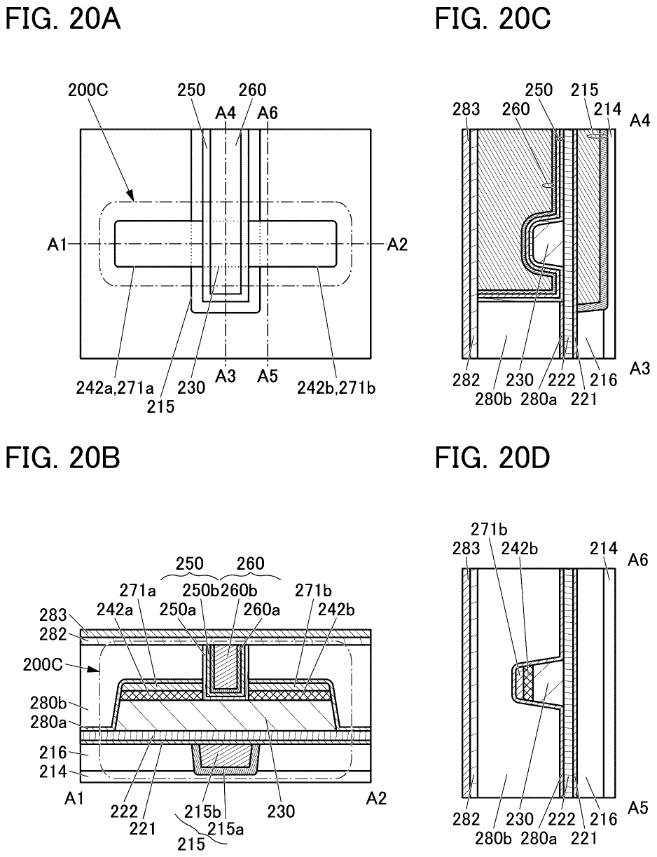

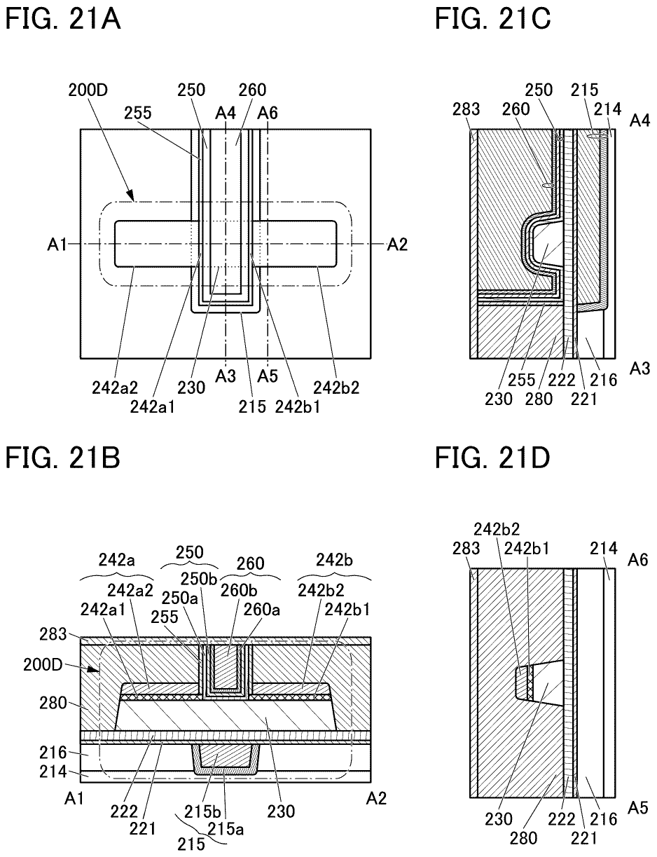

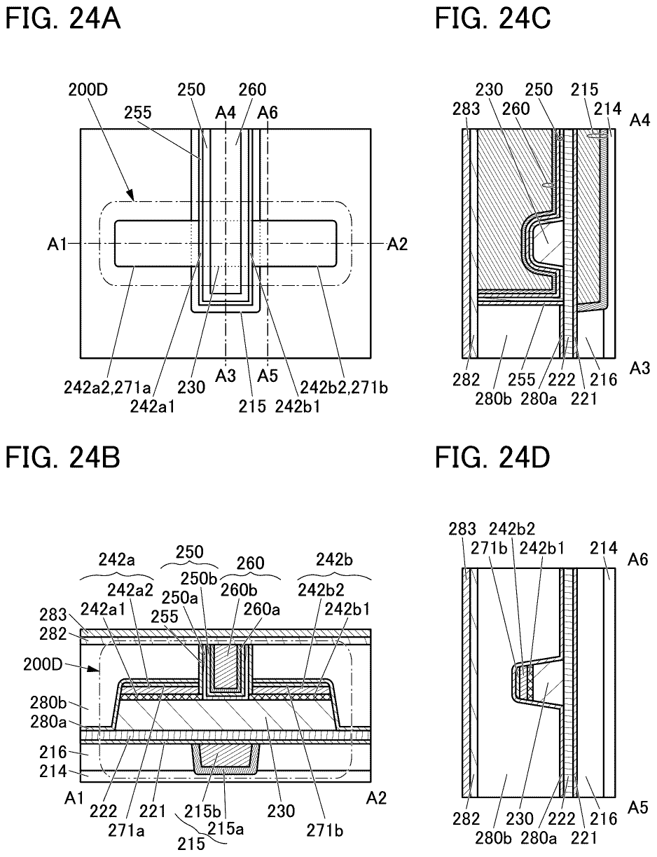

In FIG. 17, FIG. 19, FIG. 20, FIG. 21, and FIG. 24, A of each drawing is a plan view of a semiconductor device. Moreover, B of each drawing is a cross-sectional view corresponding to a portion indicated by the dashed-dotted line A1-A2 in A of each drawing, and is also a cross-sectional view in the channel length direction of a transistor. Furthermore, C of each drawing is a cross-sectional view corresponding to a portion indicated by the dashed-dotted line A3-A4 in A of each drawing, and is also a cross-sectional view in the channel width direction of the transistor. Furthermore, D of each drawing is a cross-sectional view corresponding to a portion indicated by the dashed-dotted line A5-A6 in A of each drawing. Here, the dashed-dotted line A1-A2 is orthogonal to the dashed-dotted line A3-A4 and the dashed-dotted line A5-A6, and the dashed-dotted line A3-A4 is parallel to the dashed-dotted line A5-A6.

### Structure Example 3 of Semiconductor Device

Other structure examples of the semiconductor device are described with reference to FIG. 17A to FIG. 21D. FIG. 17A to FIG. 17D are a plan view and cross-sectional views of a semiconductor device including a transistor 200C.

The semiconductor device illustrated in FIG. 17A to FIG. 17D includes an insulating layer 214, an insulating layer 216 over the insulating layer 214, the transistor 200C over the insulating layer 216, the insulating layer 280 over the insulating layer 216, and the insulating layer 283 over the insulating layer 280 and the transistor 200C.

The transistor 200C includes a conductive layer 215 provided to be embedded in the insulating layer 216, the insulating layer 221 over the insulating layer 216 and the conductive layer 215, the insulating layer 222 over the insulating layer 221, the semiconductor layer 230 over the insulating layer 222, a conductive layer 242a and a conductive layer 242b over the semiconductor layer 230, the insulating layer 250 (the insulating layer 250a and the insulating layer 250b) over the semiconductor layer 230, and the conductive layer 260 over the insulating layer 250.

In the transistor 200C, the semiconductor layer 230 functions as a semiconductor layer, the conductive layer 260 functions as a first gate electrode (an upper gate electrode), the insulating layer 250 functions as a first gate insulating layer, the conductive layer 215 functions as a second gate electrode (a lower gate electrode), the insulating layer 221 and the insulating layer 222 function as a second gate insulating layer, the conductive layer 242a functions as one of a source electrode and a drain electrode, and the conductive layer 242b functions as the other of the source electrode and the drain electrode.

In the semiconductor layer 230, a channel formation region and a source region and a drain region between which the channel formation region is sandwiched are formed. At least part of the channel formation region overlaps with the conductive layer 260. The source region overlaps with the conductive layer 242a, and the drain region overlaps with the conductive layer 242b. Note that the source region and the drain region can be interchanged with each other.

In the semiconductor layer 230, it is sometimes difficult to clearly observe the boundaries between the regions. The concentrations of a metal element and impurity elements such as hydrogen and nitrogen, which are detected in each region, may be not only gradually changed between the regions but also continuously changed in each region. That is, the region closer to the channel formation region may have lower concentrations of impurity elements such as hydrogen and nitrogen.

In the transistor 200C, a metal oxide functioning as a semiconductor is preferably used as the semiconductor layer 230 including a channel formation region. The semiconductor layer 230 is particularly preferably formed using the metal oxide film described in Embodiment 1. When the semiconductor layer 230 is formed using the metal oxide film described in Embodiment 1, the on-state current or the field-effect mobility of the transistor can be increased. Consequently, the electrical characteristics of the transistor can be increased.

The insulating layer 250a in contact with the top surface and the side surface of the channel formation region of the semiconductor layer 230 preferably has a function of capturing or fixing hydrogen. Thus, the hydrogen concentration in the channel formation region of the semiconductor layer 230 can be reduced. Accordingly, V_{O}H in the channel formation region can be reduced, so that the channel formation region can be an i-type or substantially i-type region.

Note that the insulating layer 250a is not in contact with the source region or the drain region of the semiconductor layer 230; thus, the source region and the drain region each have a higher hydrogen concentration or more V_{O}H than the channel formation region. Thus, the source region and the drain region can each have a higher carrier concentration and a lower resistance than the channel formation region.

The insulating layer 222 in contact with the bottom surface of the channel formation region of the semiconductor layer 230 preferably has a function of capturing or fixing hydrogen. Thus, the hydrogen concentration in the channel formation region of the semiconductor layer 230 can be reduced. Accordingly, V_{O}H in the channel formation region can be reduced, so that the channel formation region can be an i-type or substantially i-type region.

For the insulating layer 250a and the insulating layer 222, hafnium oxide or an oxide containing hafnium and silicon can be used, for example. Hafnium oxide is a high permittivity (high-k) material, and an oxide containing hafnium and silicon becomes a high permittivity (high-k) material depending on the silicon content. Thus, a first gate potential applied during the operation of the transistor can be reduced while the physical thickness of the first gate insulating layer is maintained. In addition, the equivalent oxide thickness (EOT) of the insulator functioning as the first gate insulating layer can be reduced. Similarly, a second gate potential applied during the operation of the transistor can be reduced while the physical thickness of the second gate insulating layer is maintained. In addition, the equivalent oxide thickness (EOT) of the insulator functioning as the second gate insulating layer can be reduced.

The film thickness of the insulating layer 222 preferably falls within the range of the film thickness of the insulating layer 250b, which is described in Embodiment 2. Note that an insulator having a function of capturing or fixing hydrogen can capture or fix more hydrogen as its film thickness is larger. Thus, the film thickness of the insulating layer 222 is not limited to the above. For example, the film thickness of the insulating layer 222 may be greater than or equal to 2 nm and less than or equal to 30 nm, or greater than or equal to 3 nm and less than or equal to 30 nm. At least part of the insulating layer 222 has a region with the above-described film thickness.

A barrier insulator against hydrogen is preferably used as the insulating layer 250b positioned above the channel formation region of the semiconductor layer 230. This can inhibit diffusion of hydrogen contained in a structure body provided above the insulating layer 250b into the channel formation region of the semiconductor layer 230. Accordingly, V_{O}H in the channel formation region can be reduced, so that the channel formation region can be an i-type or substantially i-type region.

A barrier insulator against hydrogen is preferably used as the insulating layer 221 positioned below the channel formation region of the semiconductor layer 230. As the insulating layer 221, a barrier insulator against oxygen is preferably used. For example, the insulating layer 221 preferably has a function of inhibiting diffusion of one or both of hydrogen and oxygen more than the insulating layer 216.

In the case where the insulating layer 221 is formed using such a material, the insulating layer 221 functions as a layer that inhibits release of oxygen from the semiconductor layer 230 to the substrate side and diffusion of impurities such as hydrogen from the periphery of the transistor 200C into the semiconductor layer 230. Thus, providing the insulating layer 221 can inhibit diffusion of impurities such as hydrogen into the transistor 200C and inhibit generation of oxygen vacancies in the semiconductor layer 230. Moreover, the conductive layer 215 can be inhibited from reacting with oxygen contained in the semiconductor layer 230.

The insulating layer 280 is provided over the conductive layer 242a and the conductive layer 242b. That is, the insulating layer 280 is provided over the semiconductor layer 230. The insulating layer 250 and the conductive layer 260 are embedded in an opening portion provided in the insulating layer 280. The insulating layer 283 is provided over the insulating layer 280, the insulating layer 250, and the conductive layer 260.

As illustrated in FIG. 17B, it is preferable that one side end portion of the conductive layer 242a be aligned with one side end portion of the semiconductor layer 230 and one side end portion of the conductive layer 242b be aligned with the other side end portion of the semiconductor layer 230 in the cross-sectional view of the transistor 200C. In order to obtain such a structure, the semiconductor layer 230 and a conductive layer to be the conductive layer 242a and the conductive layer 242b are preferably processed into an island shape at a time. Accordingly, the semiconductor device of one embodiment of the present invention can be manufactured with high productivity.

The conductive layer 215 is placed to overlap with the semiconductor layer 230 and the conductive layer 260. The conductive layer 215 is preferably provided to extend in the channel width direction as illustrated in FIG. 17A and FIG. 17C. With such a structure, the conductive layer 215 functions as a wiring when a plurality of transistors are provided.

The conductive layer 215 may have a single-layer structure or a stacked-layer structure. In FIG. 17B and FIG. 17C, the conductive layer 215 includes a conductive layer 215a and a conductive layer 215b. The conductive layer 215a is provided in contact with the bottom surface and the sidewall of the opening portion formed in the insulating layer 216. The conductive layer 215b is provided to fill a depressed portion that is formed by the conductive layer 215a along the opening portion. Here, the top surface of the conductive layer 215 is level with the top surface of the insulating layer 216.

As illustrated in FIG. 17B, the conductive layer 215 is preferably provided to be larger than a region of the semiconductor layer 230 that overlaps with neither the conductive layer 242a nor the conductive layer 242b. As illustrated in FIG. 17C, it is preferable that the conductive layer 215 extend to a region outside the end portion of the semiconductor layer 230 in the channel width direction. That is, the conductive layer 215 and the conductive layer 260 preferably overlap with each other with the insulators therebetween outside the side surface of the semiconductor layer 230 in the channel width direction. With such a structure, the channel formation region of the semiconductor layer 230 can be electrically surrounded by the electric field of the conductive layer 260 functioning as the first gate electrode and the electric field of the conductive layer 215 functioning as the second gate electrode.

In this specification and the like, a transistor structure in which a channel formation region is electrically surrounded by at least the electric field of the first gate electrode is referred to as a surrounded channel (S-channel) structure. The S-channel structure disclosed in this specification and the like is different from a Fin-type structure or a planar structure. Meanwhile, the S-channel structure disclosed in this specification and the like can be regarded as a kind of the Fin-type structure. In this specification and the like, the Fin-type structure refers to a structure in which a gate electrode is provided to cover at least two or more surfaces (specifically, two surfaces, three surfaces, four surfaces, or the like) of a channel. With the Fin-type structure and the S-channel structure, resistance to a short-channel effect can be increased, that is, a transistor in which a short-channel effect is less likely to occur can be provided.

When the transistor 200C has the above-described S-channel structure, the channel formation region can be electrically surrounded. Since the S-channel structure is a structure in which the channel formation region is electrically surrounded, the S-channel structure is, in a sense, equivalent to a GAA (Gate All Around) structure or an LGAA (Lateral Gate All Around) structure. When the transistor 200C has the S-channel structure, the GAA structure, or the LGAA structure, the channel formation region that is formed at the interface between the semiconductor layer 230 and the gate insulating layer or in the vicinity of the interface can correspond to the entire bulk of the semiconductor layer 230. Accordingly, the density of current flowing through the transistor can be increased, which can be expected to increase the on-state current of the transistor or increase the field-effect mobility of the transistor.

As illustrated in FIG. 17C, the conductive layer 215 is extended to function as a wiring as well. However, without limitation to this structure, a structure in which a conductor functioning as a wiring is provided below the conductive layer 215 may be employed. In addition, the conductive layer 215 is not necessarily provided in each transistor. For example, the conductive layer 215 may be shared by a plurality of transistors.

The conductive layer 215 sometimes functions as the second gate electrode. In that case, by changing a potential applied to the conductive layer 215 not in conjunction with and independently of a potential applied to the conductive layer 260, the threshold voltage (Vth) of the transistor 200C can be controlled. In particular, by applying a negative potential or a potential lower than a source potential to the conductive layer 215, Vth of the transistor 200C can be higher and its off-state current can be reduced. Thus, drain current at the time when a potential applied to the conductive layer 260 is 0 V can be lower in the case where a negative potential or a potential lower than a source potential is applied to the conductive layer 215 than in the case where the negative potential or the potential lower than the source potential is not applied to the conductive layer 215.

Alternatively, the conductive layer 215 may be connected to the conductive layer 260. By applying the same potential to the conductive layer 215 and the conductive layer 260 that are connected to each other, the on-state current can be increased, variations in the initial characteristics can be reduced, degradation in electric characteristics in −GBT stress test, and a change in the current onset voltage at different drain voltages can be suppressed.

The electrical resistivity of the conductive layer 215 is designed in consideration of the potential applied to the conductive layer 215, and the film thickness of the conductive layer 215 is determined in accordance with the electrical resistivity. The film thickness of the insulating layer 216 is substantially equal to that of the conductive layer 215. Here, the conductive layer 215 and the insulating layer 216 are preferably as thin as possible in the allowable range of the design of the conductive layer 215. When the film thickness of the insulating layer 216 is reduced, the absolute amount of impurities such as hydrogen contained in the insulating layer 216 can be reduced, inhibiting diffusion of the impurities into the semiconductor layer 230.

The insulating layer 216, which functions as an interlayer film, preferably has a lower relative permittivity than the insulating layer 222. When a material with a low relative permittivity is used for an interlayer film, the parasitic capacitance generated between wirings can be reduced. As the insulating layer 216, a single layer or stacked layers of insulators containing any of the materials with low relative permittivities described in [Insulator] in Embodiment 2 can be used. Silicon oxide and silicon oxynitride are preferable because they are thermally stable. The top surface of the insulating layer 216 may be planarized.

The concentration of impurities such as water and hydrogen in the insulating layer 216 is preferably reduced. This can inhibit entry of impurities such as water and hydrogen into the channel formation region of the semiconductor layer 230.

The conductive layer 260 may have a single-layer structure or a stacked-layer structure.

As illustrated in FIG. 17B and FIG. 17C, the conductive layer 260 is placed in the opening portion formed in the insulating layer 280. The conductive layer 260 is provided in the opening portion to cover the top surface of the insulating layer 222, the side surface of the semiconductor layer 230, and the top surface of the semiconductor layer 230 with the insulating layer 250 therebetween. The top surface of the conductive layer 260 is level with the top surface of the insulating layer 250 and the top surface of the insulating layer 280.

The conductive layer 260 is preferably provided to extend in the channel width direction as illustrated in FIG. 17A and FIG. 17C. With such a structure, the conductive layer 260 functions as a wiring when a plurality of transistors are provided.

In the case where the above-described structure is employed, a curved surface may be provided between the side surface of the semiconductor layer 230 and the top surface of the semiconductor layer 230 in the cross-sectional view of the transistor 200C in the channel width direction, as illustrated in FIG. 17C. That is, an end portion of the side surface and an end portion of the top surface may be curved (hereinafter, also referred to as rounded). Such a shape can improve the coverage of the semiconductor layer 230 with the insulating layer 250 and the conductive layer 260.

FIG. 17B and the like illustrate the conductive layer 260 having a two-layer structure. Here, the conductive layer 260 preferably includes the conductive layer 260a and the conductive layer 260b placed over the conductive layer 260a. For example, the conductive layer 260a is preferably placed to cover the bottom surface and the side surface of the conductive layer 260b. In that case, a conductive material that is less likely to be oxidized or a conductive material having a function of inhibiting diffusion of oxygen is preferably used for the conductive layer 260a.

As each of the conductive layer 242a and the conductive layer 242b, any of the conductors described in [Conductor] in Embodiment 2 can be used as a single layer or stacked layers. For example, a conductive material with high conductivity such as tungsten can be used for the conductive layer 242a and the conductive layer 242b.

The conductive layer 242a and the conductive layer 242b are preferably formed using a conductive material that is less likely to be oxidized or a conductive material having a function of inhibiting diffusion of oxygen, for example, like the conductive layer 260. For example, titanium nitride, tantalum nitride, or the like can be used. In that case, the conductive layer 242a and the conductive layer 242b each contain at least a metal and nitrogen. Such a structure can inhibit excessive oxidation of the conductive layer 242a and the conductive layer 242b due to the semiconductor layer 230.

Although the conductive layer 242a and the conductive layer 242b each have a single-layer structure in FIG. 17B and FIG. 17C, the present invention is not limited thereto. Each of the conductive layer 242a and the conductive layer 242b may have a stacked-layer structure.

In the case where the conductive layer 242a and the conductive layer 242b each have a two-layer structure, a conductive material that is less likely to be oxidized, such as a metal nitride, or a conductive material having a function of inhibiting diffusion of oxygen is preferably used for the lower layer (a layer in contact with the semiconductor layer 230) of each of the conductive layer 242a and the conductive layer 242b. This can prevent excessive oxidation of the conductive layer 242a and the conductive layer 242b due to oxygen contained in the semiconductor layer 230. Thus, a reduction in the conductivity of the conductive layer 242a and the conductive layer 242b can be inhibited.

The upper layers of the conductive layer 242a and the conductive layer 242b are preferably conductors, such as metal layers, that have higher conductivity than the lower layers of the conductive layer 242a and the conductive layer 242b. For example, the thicknesses of the upper layers of the conductive layer 242a and the conductive layer 242b are preferably larger than the thicknesses of the lower layers of the conductive layer 242a and the conductive layer 242b. As the upper layers of the conductive layer 242a and the conductive layer 242b, a conductor that can be used as the conductive layer 215b is used. Accordingly, the conductive layer 242a and the conductive layer 242b can each function as a wiring or an electrode with high conductivity. In this manner, a semiconductor device in which the conductive layer 242a and the conductive layer 242b which function as wirings or electrodes are provided in contact with the top surface of the semiconductor layer 230 can be provided.

For example, titanium nitride or tantalum nitride may be used for the lower layers of the conductive layer 242a and the conductive layer 242b, and tungsten may be used for the upper layers of the conductive layer 242a and the conductive layer 242b. When a layer containing tungsten is provided in this manner, the conductive layer 242a and the conductive layer 242b can have improved conductivity and can serve well as wirings.

Although FIG. 17B and FIG. 17C illustrate the structure in which the insulating layer 250 has a stacked structure of two layers, the insulating layer 250a and the insulating layer 250b, the present invention is not limited thereto. The insulating layer 250 may have a stacked-layer structure of three or more layers.

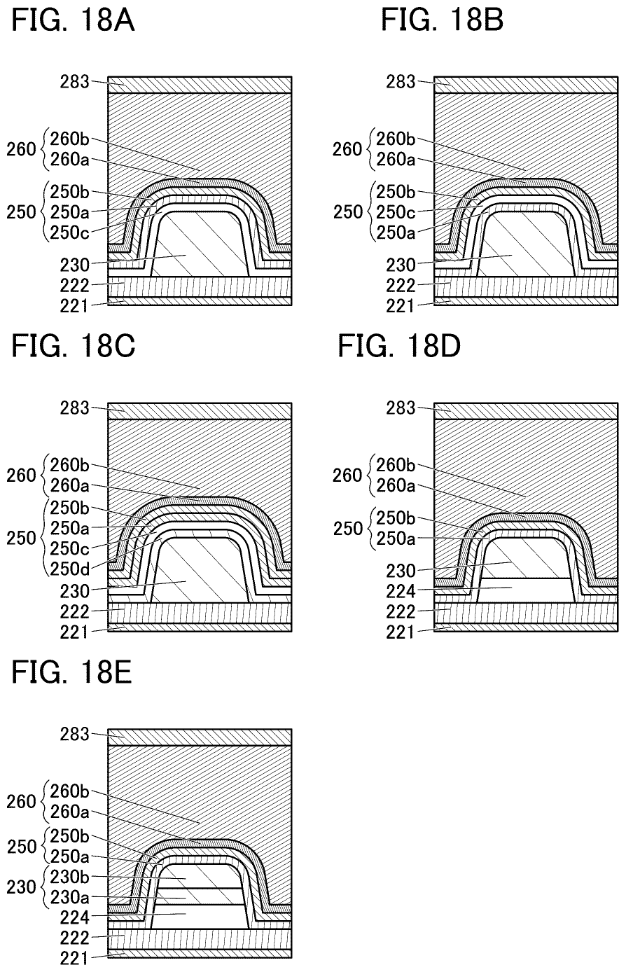

In an example, as illustrated in FIG. 18A, the insulating layer 250 may have a stacked-layer structure of the insulating layer 250c, the insulating layer 250a over the insulating layer 250c, and the insulating layer 250b over the insulating layer 250a. In that case, the insulating layer 250c is provided between the insulating layer 250a and the semiconductor layer 230 and insulating layer 222. FIG. 18A is an enlarged cross-sectional view of the transistor 200C in the channel width direction.

For the insulating layer 250c, a material having a low relative permittivity is preferably used. With such a structure, the parasitic capacitance generated between the conductive layer 260 and the conductive layer 242a or the conductive layer 242b can be reduced. Furthermore, the concentration of impurities such as water and hydrogen in the insulating layer 250c is preferably reduced.

In the case where the insulating layer 250c is provided, the insulating layer 250b preferably further has a barrier property against oxygen. The insulating layer 250b is provided between the insulating layer 250c and the conductive layer 260. Thus, diffusion of oxygen contained in the insulating layer 250c into the conductive layer 260 can be prevented, so that oxidation of the conductive layer 260 can be inhibited. It is also possible to inhibit diffusion of oxygen contained in the channel formation region of the semiconductor layer 230 into the conductive layer 260 and formation of oxygen vacancies in the channel formation region.

Note that the insulating layer 250c may be provided between the insulating layer 250a and the insulating layer 250b as illustrated in FIG. 18B. FIG. 18B is an enlarged cross-sectional view of the transistor 200C in the channel width direction.

In another example, as illustrated in FIG. 18C, the insulating layer 250 may have a stacked-layer structure of the insulating layer 250d, the insulating layer 250c over the insulating layer 250d, the insulating layer 250a over the insulating layer 250c, and the insulating layer 250b over the insulating layer 250a. In that case, the insulating layer 250d is provided between the insulating layer 250c and the semiconductor layer 230 and insulating layer 222. FIG. 18C is an enlarged cross-sectional view of the transistor 200C in the channel width direction.

As the insulating layer 250d, a barrier insulator against oxygen is preferably used. The insulating layer 250d includes a region in contact with the semiconductor layer 230. When the insulating layer 250d has a barrier property against oxygen, release of oxygen from the semiconductor layer 230 at the time of performing heat treatment or the like can be inhibited. This can inhibit formation of oxygen vacancies in the semiconductor layer 230. Accordingly, the transistor 200C can have excellent electrical characteristics and higher reliability. The insulating layer 250d is in contact with the side surfaces of the conductive layer 242a and the conductive layer 242b; thus, oxidation of the side surfaces of the conductive layer 242a and the conductive layer 242b and formation of oxide films on the side surfaces can be inhibited. This can inhibit a decrease in on-state current or the field-effect mobility of the transistor 200C.

The insulating layer 250a to the insulating layer 250d function as part of the gate insulating layer. The insulating layer 250a to the insulating layer 250d are provided in the opening portion formed in the insulating layer 280, together with the conductive layer 260. The film thicknesses of the insulating layer 250a to the insulating layer 250d are preferably small for miniaturization of the transistor 200C.

The film thickness of each of the insulating layer 250c and the insulating layer 250d is preferably greater than or equal to 0.1 nm and less than or equal to 10 nm, further preferably greater than or equal to 0.1 nm and less than or equal to 5 nm, still further preferably greater than or equal to 0.5 nm and less than or equal to 5 nm, yet further preferably greater than or equal to 1 nm and less than 5 nm, yet still further preferably greater than or equal to 1 nm and less than or equal to 3 nm. Note that at least part of each of the insulating layer 250c and the insulating layer 250d includes a region having the above-described thickness.

In order to form the insulating layer 250a to the insulating layer 250d each having a small film thickness as described above, they are preferably formed by an ALD method.

Although the case where the first gate insulating layer has the two-layer structure of the insulating layer 250a and the insulating layer 250b, the three-layer structure of the insulating layer 250a to the insulating layer 250c, or the four-layer structure of the insulating layer 250a to the insulating layer 250d is described above, the present invention is not limited thereto. The first gate insulating layer can have a structure including at least one of the insulating layer 250a to the insulating layer 250d. When the first gate insulating layer is formed of one layer, two layers, or three layers of the insulating layer 250a to the insulating layer 250d, the manufacturing process of the semiconductor device can be simplified and the productivity can be increased.

In FIG. 17C, the channel formation region of the semiconductor layer 230 is sandwiched between insulators having a barrier property against hydrogen (here, the insulating layer 221 and the insulating layer 250b); thus, an insulator may be provided between the semiconductor layer 230 and the insulating layer 221.

For example, as illustrated in FIG. 18D, an insulating layer 224 may be provided between the semiconductor layer 230 and the insulating layer 222. In that case, the insulating layer 224 is in contact with at least part of the semiconductor layer 230. The insulating layer 224 includes a region facing the insulating layer 250a with the semiconductor layer 230 therebetween. The semiconductor layer 230 is provided over the insulating layer 224. FIG. 18D is an enlarged cross-sectional view of the transistor 200C in the channel width direction.

As the insulating layer 224, an insulator containing oxygen is preferably used, and a film from which oxygen is released by heating is further preferably used. When the insulating layer 224 releases oxygen by being heated during the manufacturing process of the transistor 200C, the oxygen can be supplied to the semiconductor layer 230. Supply of oxygen from the insulating layer 224 to the semiconductor layer 230, particularly to the channel formation region in the semiconductor layer 230, can reduce oxygen vacancies and V_{O}H in the semiconductor layer 230, so that the transistor can have excellent electrical characteristics and high reliability. For the insulating layer 224, any of the materials that can be used for the insulating layer 280b described in Embodiment 2 is preferably used.

Although FIG. 17B to FIG. 17D illustrate the semiconductor layer 230 as a single layer, the present invention is not limited thereto. The semiconductor layer 230 may have a stacked-layer structure of a plurality of oxide layers with different compositions. For example, a structure may be employed in which a plurality of kinds of metal oxide films selected from the metal oxide films described in Embodiment 1 and the metal oxide films described in [Metal oxide] in Embodiment 2 are stacked as appropriate.

For example, as illustrated in FIG. 18E, the semiconductor layer 230 may have a stacked-layer structure of the semiconductor layer 230a over the insulating layer 222 and the semiconductor layer 230b over the semiconductor layer 230a. When the semiconductor layer 230a is provided below the semiconductor layer 230b, diffusion of impurities into the semiconductor layer 230b from the components formed below the semiconductor layer 230a can be inhibited. FIG. 18E is an enlarged cross-sectional view of the transistor 200C in the channel width direction.

Although FIG. 18E illustrates the example in which the semiconductor layer 230 has the two-layer structure of the semiconductor layer 230a and the semiconductor layer 230b, the present invention is not limited thereto. For example, the semiconductor layer 230 may have a stacked-layer structure of three or more layers.

In this embodiment, microwave treatment is preferably performed in an oxygen-containing atmosphere in a state where the conductive layer 242a and the conductive layer 242b are provided over the semiconductor layer 230.

In this specification and the like, the microwave treatment refers to treatment using an apparatus including a power source that generates high-density plasma with the use of a microwave. In this specification and the like, a microwave refers to an electromagnetic wave having a frequency greater than or equal to 300 MHz and less than or equal to 300 GHz. The microwave treatment can also be referred to as microwave excitation high-density plasma treatment.

The microwave treatment in an oxygen-containing atmosphere can convert an oxygen gas into plasma using a high-frequency wave such as a microwave or RF and activate the oxygen plasma. At this time, the channel formation region can be irradiated with the high-frequency wave such as a microwave or RF. By the effect of the plasma, the microwave, or the like, V_{O}H in the channel formation region can be divided into an oxygen vacancy (V_{O}) and hydrogen (H); the hydrogen can be removed from the channel formation region and the oxygen vacancy can be filled with oxygen. Accordingly, the hydrogen concentration, oxygen vacancies, and V_{O}H in the channel formation region can be reduced to lower the carrier concentration.

In the microwave treatment in an oxygen-containing atmosphere, the effect of the high-frequency wave such as the microwave or RF, the oxygen plasma, or the like is blocked by the conductive layer 242a and the conductive layer 242b and does not reach the source region and the drain region. In addition, the effect of the oxygen plasma can be reduced by the insulating layer 280 provided to cover the semiconductor layer 230, the conductive layer 242a, and the conductive layer 242b. This prevents a reduction in V_{O}H and supply of an excess amount of oxygen in the source region and the drain region in the microwave treatment, so that the carrier concentration can be prevented from being lowered.

After an insulating film to be the insulating layer 250a is formed, microwave treatment is preferably performed in an oxygen-containing atmosphere. By performing the microwave treatment in an oxygen-containing atmosphere through the insulating layer 250a in such a manner, oxygen can be efficiently implanted into the channel formation region. In addition, the insulating layer 250a is placed to be in contact with the side surface of the conductive layer 242a, the side surface of the conductive layer 242b, and the surface of the channel formation region, thereby inhibiting oxygen more than necessary from being implanted into the channel formation region and inhibiting the side surfaces of the conductive layer 242a and the conductive layer 242b from being oxidized.

The oxygen implanted into the channel formation region is in any of a variety of forms such as an oxygen atom, an oxygen molecule, an oxygen ion (a charged oxygen atom or a charged oxygen molecule), and an oxygen radical (an oxygen atom, an oxygen molecule, or an oxygen ion having an unpaired electron). Note that the oxygen implanted into the channel formation region preferably has any one or more of the above forms, particularly suitably an oxygen radical. Furthermore, the film quality of the insulating layer 250a can be improved, leading to higher reliability of the transistor 200C.

In the above manner, oxygen vacancies and V_{O}H can be selectively removed from the channel formation region, whereby the channel formation region can be an i-type or substantially i-type region. Furthermore, supply of an excess amount of oxygen to the source region or the drain region can be inhibited and the state of the n-type region before the microwave treatment is performed can be maintained. As a result, a change in the electrical characteristics of the transistor 200C can be inhibited, and thus a variation in the electrical characteristics of the transistor 200C in the substrate plane can be inhibited.

The above structure enables oxygen to be supplied to the channel formation region efficiently, so that the channel formation region can be an i-type region. Furthermore, the source region and the drain region are supplied with a smaller amount of oxygen than the channel formation region; thus, the carrier concentrations in the source region and the drain region can be prevented from being reduced.

For the insulating layer 280, a barrier insulator against hydrogen is preferably used. The insulating layer 280 includes a region in contact with the source region of the semiconductor layer 230 and a region in contact with the drain region thereof, thus, diffusion of hydrogen contained in the source region and the drain region of the semiconductor layer 230 to the outside can be inhibited and a reduction in the hydrogen concentration in each of the source region and the drain region can be inhibited. Accordingly, the source region and the drain region can be n-type regions.

Silicon nitride can be used for the insulating layer 280, for example. In that case, the insulating layer 280 contains silicon and nitrogen. Since the side surfaces and the top surfaces of the conductive layer 242a and the conductive layer 242b are in contact with the insulating layer 280, the use of silicon nitride for the insulating layer 280 can inhibit an increase in resistivity due to oxidation of the conductive layer 242a and the conductive layer 242b and a reduction in on-state current.

The concentration of impurities such as water and hydrogen in the insulating layer 280 is preferably reduced.

Although FIG. 17B to FIG. 17D illustrate the insulating layer 280 as a single layer, the present invention is not limited thereto. The insulating layer 280 may have a stacked-layer structure. For example, as illustrated in FIG. 19A to FIG. 19D, the insulating layer 280 may have a stacked-layer structure of the insulating layer 280a and the insulating layer 280b over the insulating layer 280a.

For the insulating layer 280a, silicon nitride is preferably used, for example, silicon nitride formed by an ALD method is further preferably used, and silicon nitride formed by a PEALD method is still further preferably used. An ALD method provides excellent step coverage and excellent thickness uniformity and thus is suitable for forming a thin film or covering a surface with a high aspect ratio.

For example, in the case where a silicon nitride film is formed by a PEALD method, a precursor containing a halogen such as fluorine, chlorine, bromine, or iodine is suitably used. After the precursor is introduced, plasma treatment is performed in an atmosphere to which a nitriding agent such as N₂, N₂O, NH₃, NO, NO₂, or N₂O₂ is introduced, so that a high-quality silicon nitride film can be formed.

Silicon nitride formed by a sputtering method is preferably used for the insulating layer 280b. A sputtering method, which enables a higher deposition rate than an ALD method, can improve the productivity.

As described above, silicon nitride has a barrier property against hydrogen when the film thickness is greater than or equal to 2 nm, and has a high barrier property against hydrogen when the film thickness is greater than or equal to 3 nm, for example. Thus, in the case where the insulating layer 280a is formed using a silicon nitride film with a film thickness greater than or equal to 2 nm, preferably greater than or equal to 3 nm, the material that can be used for the insulating layer 280b may be a material other than a barrier insulator against hydrogen.

For example, the insulating layer 280b may be formed using an insulator containing oxygen. The insulating layer 280b preferably includes a region having a higher oxygen content than the insulating layer 280a. In particular, the insulating layer 280b preferably includes a region having a higher oxygen content than the insulating layer 280a. When the insulating layer 280b has a high oxygen content, an i-type region can be easily formed in the semiconductor layer 230 in the vicinity of the insulating layer 280b.

Note that the insulating layer 280a is provided between the insulating layer 280b and the source and drain regions; thus, even in the case where an insulator containing oxygen is used as the insulating layer 280b, the amount of oxygen supplied to the source region or the drain region of the semiconductor layer 230 can be small.

In addition to the above structure, the semiconductor device of this embodiment preferably has a structure that inhibits entry of hydrogen into the transistor 200C. For example, an insulator having a function of inhibiting diffusion of hydrogen is preferably provided to cover one or both of the upper portion and the lower portion of the transistor 200C. In the semiconductor device described in this embodiment, the insulator corresponds to the insulating layer 214, the insulating layer 283, and the like, for example. The insulating layer 214 provided below the transistor 200C may have a structure similar to that of the insulating layer 283.

One or both of the insulating layer 214 and the insulating layer 283 preferably function as a barrier insulator that inhibits diffusion of impurities such as water and hydrogen into the transistor 200C from the substrate side or from above the transistor 200C. Thus, one or both of the insulating layer 214 and the insulating layer 283 preferably contain an insulating material having a function of inhibiting diffusion of impurities such as a hydrogen atom, a hydrogen molecule, a water molecule, a nitrogen atom, a nitrogen molecule, a nitrogen oxide molecule (e.g., N₂O, NO, and NO₂), and a copper atom (i.e., the insulating material through which the impurities are less likely to pass). Alternatively, it is preferable to contain an insulating material having a function of inhibiting diffusion of oxygen (e.g., at least one of an oxygen atom, an oxygen molecule, and the like) (i.e., the insulating material through which the oxygen is less likely to pass).

For each of the insulating layer 214 and the insulating layer 283, an insulator having a function of inhibiting diffusion of oxygen and impurities such as water and hydrogen is preferably used. For example, the insulating layer 283 preferably has a high barrier property against hydrogen. Thus, impurities such as water and hydrogen can be inhibited from diffusing into the transistor 200C from an interlayer insulating film and the like that are provided above the insulating layer 283. Moreover, oxygen contained in the insulating layer 280 and the like can be inhibited from diffusing to a region above the transistor 200C. When the insulating layer 214 has a structure similar to that of the insulating layer 283, it is possible to inhibit diffusion of impurities such as water and hydrogen into the transistor 200C from the substrate side. Oxygen contained in the semiconductor layer 230 and the like can be inhibited from diffusing to a region below the transistor 200C. With such a structure in which the transistor 200C is surrounded by upper and lower insulators having a function of inhibiting diffusion of oxygen and impurities such as water and hydrogen, an excess amount of oxygen and hydrogen can be inhibited from diffusing into the oxide semiconductor. Thus, the semiconductor device can have improved electrical characteristics and reliability.

Although the insulating layer 283 is provided in contact with the top surface of the insulating layer 280b, the top surface of the insulating layer 250, and the top surface of the conductive layer 260 in FIG. 19B to FIG. 19D, the present invention is not limited thereto. For example, as illustrated in FIG. 20A to FIG. 20D, an insulating layer 282 may be provided between the insulating layer 283 and the insulating layer 280b, insulating layer 250, and conductive layer 260.

For the insulating layer 282, an insulator that can add oxygen to the insulating layer 280 is preferably used. For example, aluminum oxide is preferably used as the insulating layer 282. In that case, the insulating layer 282 contains at least oxygen and aluminum. The insulating layer 282 or an insulating film to be the insulating layer 282 is preferably formed by a sputtering method and further preferably formed by a sputtering method in an oxygen-containing atmosphere. The insulating layer 282 is formed by a sputtering method in an oxygen-containing atmosphere, whereby oxygen can be added to the insulating layer 280 during the film formation. Thus, excess oxygen can be contained in the insulating layer 280.

As the insulating layer 282, a metal oxide having an amorphous structure is preferably used. A metal oxide having an amorphous structure has an oxygen atom with a dangling bond and sometimes has a property of capturing or fixing hydrogen with the dangling bond. When such a metal oxide having an amorphous structure is used as a component of the transistor 200C or provided around the transistor 200C, hydrogen contained in the transistor 200C can be captured or fixed. In particular, hydrogen contained in the channel formation region of the transistor 200C is preferably captured or fixed. With this structure, the transistor 200C with excellent characteristics and high reliability can be fabricated.

Note that the insulating layer 282 preferably has an amorphous structure but may partly include a region having a polycrystalline structure. Alternatively, the insulating layer 282 may have a multilayer structure in which a layer having an amorphous structure and a layer having a polycrystalline structure are stacked. For example, a stacked-layer structure in which a layer having a polycrystalline structure is formed over a layer having an amorphous structure may be employed.

Although FIG. 20B to FIG. 20D illustrate the insulating layer 282 as a single layer, the present invention is not limited thereto. The insulating layer 282 may have a stacked-layer structure.

Although the insulating layer 280 is provided in contact with the top surface of the conductive layer 242a and the top surface of the conductive layer 242b in FIG. 17B to FIG. 17D, the present invention is not limited thereto. For example, as illustrated in FIG. 20B and FIG. 20D, an insulating layer 271a may be provided between the conductive layer 242a and the insulating layer 280, and an insulating layer 271b may be provided between the conductive layer 242b and the insulating layer 280. In other words, the insulating layer 271a may be provided over the conductive layer 242a, and the insulating layer 271b may be provided over the conductive layer 242b.

The insulating layer 271a and the insulating layer 271b function as etching stoppers for protecting the conductive layer 242a and the conductive layer 242b, respectively. Accordingly, as illustrated in FIG. 20B and FIG. 20D, it is preferable that the side end portion of the insulating layer 271a be aligned with the side end portion of the conductive layer 242a and the side end portion of the insulating layer 271b be aligned with the side end portion of the conductive layer 242b in the cross-sectional view of the transistor 200C.

The insulating layer 271a and the insulating layer 271b are inorganic insulators for protecting the conductive layer 242a and the conductive layer 242b, respectively. Since the insulating layer 271a and the insulating layer 271b are respectively in contact with the conductive layer 242a and the conductive layer 242b, they are preferably inorganic insulators that are less likely to oxidize the conductive layer 242a and the conductive layer 242b. Thus, the insulating layer 271a and the insulating layer 271b each preferably have a stacked-layer structure of a first insulator and a second insulator over the first insulator. Here, the first insulator of the insulating layer 271a and the first insulator of the insulating layer 271b are each preferably formed using any of the nitride insulators that can be used as the insulating layer 250b so that the conductive layer 242a and the conductive layer 242b are not easily oxidized. Any of the oxide insulators that can be used as the insulating layer 250c is preferably used for the second insulator of the insulating layer 271a and the second insulator of the insulating layer 271b. For example, silicon nitride can be used for the first insulator of the insulating layer 271a and the first insulator of the insulating layer 271b, and silicon oxide can be used for the second insulator of the insulating layer 271a and the second insulator of the insulating layer 271b.

An insulating layer to be the insulating layer 271a and the insulating layer 271b functions as a mask for the conductive layer to be the conductive layer 242a and the conductive layer 242b, and thus the conductive layer does not have a curved surface between the side surface and the top surface. Thus, the end portions at the intersections of the side surfaces and the top surfaces of the conductive layer 242a and the conductive layer 242b are angular. The cross-sectional area of each of the conductive layer 242a and the conductive layer 242b is larger in the case where the end portion at the intersection of the side surface and the top surface of each of the conductive layer 242a and the conductive layer 242b is angular than in the case where the end portion has a curved surface. Furthermore, when a nitride insulator that is less likely to oxidize a metal is used as the first insulator of the insulating layer 271a and the first insulator of the insulating layer 271b, excessive oxidation of the conductive layer 242a and the conductive layer 242b can be prevented. Accordingly, the resistance of the conductive layer 242a and the conductive layer 242b is reduced, so that the on-state current of the transistor can be increased.

With the above structure, the channel formation region can be an i-type or substantially i-type region and the source region and the drain region can be n-type regions; thus, a semiconductor device with excellent electrical characteristics can be provided. The semiconductor device with the above structure can have excellent electrical characteristics even when miniaturized or highly integrated. Miniaturization of the transistor 200C can improve the high-frequency characteristics. Specifically, the cutoff frequency can be improved.

### Modification Example

In FIG. 17A to FIG. 17D, the insulating layer 250a is in contact with the side surface of the insulating layer 280 in the opening portion provided in the insulating layer 280; however, the present invention is not limited to this structure. For example, an insulator may be provided between the insulating layer 250a and the insulating layer 280 in the opening portion.

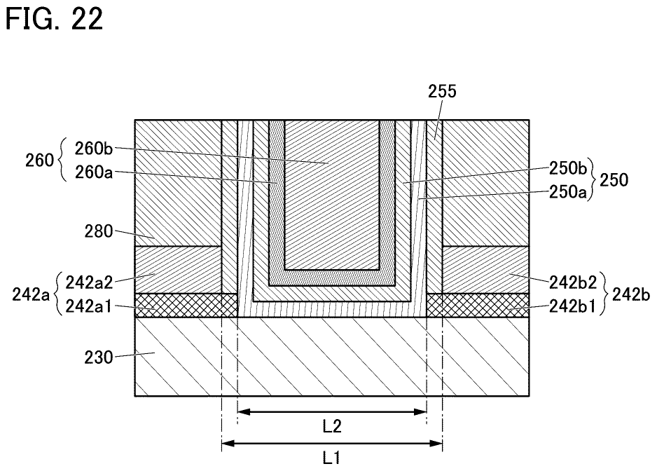

A modification example of the semiconductor device described in <Structure example 3 of semiconductor device> will be described with reference to FIG. 21A to FIG. 24D. FIG. 21A to FIG. 21D are a plan view and cross-sectional views of a semiconductor device including a transistor 200D. FIG. 22 is an enlarged cross-sectional view of the transistor 200D in the channel length direction.

The transistor 200D illustrated in FIG. 21A to FIG. 21D is also a modification example of the transistor 200C illustrated in FIG. 17A to FIG. 17D. Specifically, the transistor 200D illustrated in FIG. 21A to FIG. 21D is different from the transistor 200C illustrated in FIG. 17A to FIG. 17D mainly in including an insulating layer 255. Portions different from the above description in <Structure example 3 of semiconductor device> are mainly described below, and common portions, for which the description is referred to, are not described in some cases.

In FIG. 21B and FIG. 21D, the conductive layer 242a and the conductive layer 242b each have a two-layer structure. The conductive layer 242a has a stacked-layer structure of a conductive layer 242al and a conductive layer 242a2 over the conductive layer 242al. The conductive layer 242b has a stacked-layer structure of a conductive layer 242b1 and a conductive layer 242b2 over the conductive layer 242b1. The conductive layer 242al and the conductive layer 242b1 correspond to the lower layers of the conductive layer 242a and the conductive layer 242b described in <Structure example 3 of semiconductor device>, and the conductive layer 242a2 and the conductive layer 242b2 correspond to the upper layers of the conductive layer 242a and the conductive layer 242b described in <Structure example 3 of semiconductor device>.

As illustrated in FIG. 21B and FIG. 21C, the insulating layer 255 is placed in the opening portion formed in the insulating layer 280, and is in contact with the side surface of the insulating layer 280, the side surface of the conductive layer 242a2, the side surface of the conductive layer 242b2, the top surface of the conductive layer 242al, the top surface of the conductive layer 242b1, and the top surface of the insulating layer 222 in the opening portion. In other words, the insulating layer 255 is formed in a sidewall shape to be in contact with the sidewall of the opening portion formed in the insulating layer 280. The insulating layer 255 can be formed by anisotropic etching, for example. Here, the sidewall of the opening portion corresponds to, for example, the side surface of the insulating layer 280 or the like in the opening portion.

The opening portion provided in the insulating layer 280 overlaps with a region between the conductive layer 242a2 and the conductive layer 242b2. In a top view, the side surface of the insulating layer 280 in the opening portion is aligned with the side surface of the conductive layer 242a2 and the side surface of the conductive layer 242b2. The conductive layer 242al and the conductive layer 242b1 are formed to partly extend toward the inside of the opening portion. In other words, a part of the conductive layer 242al that has a top surface on which the insulating layer 255 is formed extends beyond the conductive layer 242a2 toward the conductive layer 260 side. Similarly, a part of the conductive layer 242b1 that has a top surface on which the insulating layer 255 is formed extends beyond the conductive layer 242b2 toward the conductive layer 260 side.

Here, part of the top surface of the conductive layer 242al is in contact with the conductive layer 242a2, and part of the top surface of the conductive layer 242b1 is in contact with the conductive layer 242b2. Thus, in the opening portion, the insulating layer 255 is in contact with another part of the top surface of the conductive layer 242al, another part of the top surface of the conductive layer 242b1, the side surface of the conductive layer 242a2, and the side surface of the conductive layer 242b2. The insulating layer 255 has a function of protecting the conductive layer 242a2 and the conductive layer 242b2. The insulating layer 250a is in contact with the top surface of the semiconductor layer 230, the side surface of the conductive layer 242al, the side surface of the conductive layer 242b1, and the side surface of the insulating layer 255.

The insulating layer 255 preferably has the barrier property against oxygen described in [Insulator] in Embodiment 2. When the insulating layer 255 has a barrier property against oxygen, oxidation of the side surfaces of the conductive layer 242a and the conductive layer 242b and formation of oxide films on the side surfaces can be inhibited. Accordingly, a decrease in the on-state current or the field-effect mobility of the transistor 200D can be inhibited.

The insulating layer 255 functions as a mask at the time of dividing the conductor into the conductive layer 242al and the conductive layer 242b1. Accordingly, as illustrated in FIG. 22, it is preferable that the side end portion of the insulating layer 255 be aligned with the side end portion of the conductive layer 242al and the side end portion of the conductive layer 242b1 in the cross-sectional view of the transistor 200D.

Note that heat treatment in an oxygen-containing atmosphere is preferably performed after the division into the conductive layer 242al and the conductive layer 242b1 and before the formation of the insulating layer 250a. At this time, since the insulating layer 255 is formed in contact with the side surface of the conductive layer 242a2 and the side surface of the conductive layer 242b2, excessive oxidation of the conductive layer 242a2 and the conductive layer 242b2 can be prevented. Furthermore, also in the case where microwave treatment is performed after the division into the conductive layer 242al and the conductive layer 242b1, formation of oxide films on the side surfaces of the conductive layer 242a and the conductive layer 242b can be inhibited.

Portions of the insulating layer 255, the insulating layer 250, and the conductive layer 260 that are positioned in the opening portion provided in the insulating layer 280 reflect the shape of the opening portion. Thus, the insulating layer 255 is provided to cover the sidewall of the opening portion, the insulating layer 250 is provided to cover the bottom portion of the opening portion and the insulating layer 255, and the conductive layer 260 is provided to fill a depressed portion of the insulating layer 250.

The film thickness of the insulating layer 255 is preferably greater than or equal to 0.5 nm and less than or equal to 20 nm, further preferably greater than or equal to 0.5 nm and less than or equal to 10 nm, still further preferably greater than or equal to 0.5 nm and less than or equal to 3 nm. When the insulating layer 255 has a film thickness in the above range, excessive oxidation of the conductive layer 242a2 and the conductive layer 242b2 can be inhibited. Note that at least part of the insulating layer 255 has a region with the above-described film thickness. Since the insulating layer 255 is provided in contact with the sidewall of the opening formed in the insulating layer 280, the insulating layer 255 is preferably formed by an ALD method or the like that provides good coverage. When the film thickness of the insulating layer 255 is excessively large, the time for forming the insulating layer 255 by an ALD method becomes long, which decreases the productivity; for this reason, the film thickness of the insulating layer 255 is preferably in the above range.

As illustrated in FIG. 22, in the cross-sectional view of the transistor 200D in the channel length direction, a distance L2 between the conductive layer 242al and the conductive layer 242b1 is smaller than a distance L1 between the conductive layer 242a2 and the conductive layer 242b2. Specifically, the difference between the distance L1 and the distance L2 is equal to the double of the film thickness of the insulating layer 255. In other words, the distance L1 is equal to the sum of the distance L2 and the double of the film thickness of the insulating layer 255. Here, the film thickness of the insulating layer 255 corresponds to the width in the A1-A2 direction of at least part of the insulating layer 255. With such a structure, the distance between the source and the drain can be shortened, and the channel length can be accordingly shortened. Thus, the frequency characteristics of the transistor 200D can be improved. In this manner, Miniaturization of the semiconductor device enables the semiconductor device to have a higher operating speed.

The insulating layer 255 may have a stacked-layer structure of two or more layers. In that case, for at least one of the layers, the above-described inorganic insulator that is less likely to be oxidized is preferably used. In the case where the insulating layer 255 has a stacked-layer structure of a first insulator and a second insulator over the first insulator, for example, the above-described inorganic insulator that is less likely to be oxidized is used as the first insulator of the insulating layer 255, and any of the insulators that can be used as the insulating layer 250c (e.g., silicon oxide) is used as the second insulator of the insulating layer 255. The second insulator of the insulating layer 255 preferably has a lower permittivity than the first insulator of the insulating layer 255. When the insulating layer 255 has the two-layer structure to have a large thickness in this manner, the distance between the conductive layer 260 and the conductive layer 242a or the conductive layer 242b can be increased, so that the parasitic capacitance can be reduced.

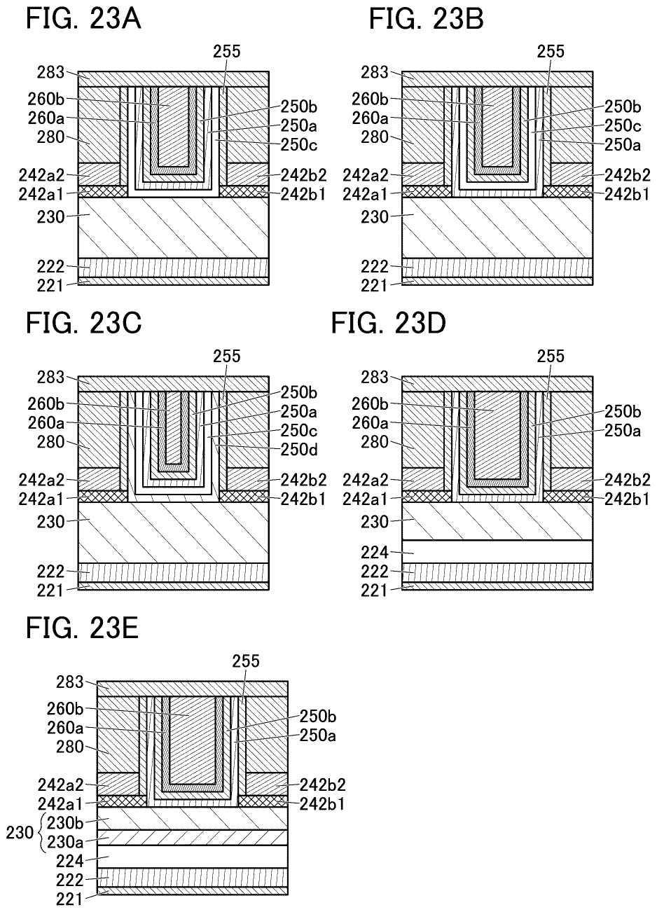

As in the structure illustrated in FIG. 18A, the insulating layer 250c may be provided between the insulating layer 250a and the semiconductor layer 230 and insulating layer 222 (see FIG. 23A).

As in the structure illustrated in FIG. 18B, the insulating layer 250c may be provided between the insulating layer 250a and the insulating layer 250b (see FIG. 23B).

As in the structure illustrated in FIG. 18C, the insulating layer 250c and the insulating layer 250d may be provided between the insulating layer 250a and the semiconductor layer 230 and insulating layer 222 (see FIG. 23C).

As in the structure illustrated in FIG. 18D, the insulating layer 224 may be provided between the semiconductor layer 230 and the insulating layer 222 (see FIG. 23D).

As in the structure illustrated in FIG. 18E, the semiconductor layer 230 may have a stacked-layer structure of the semiconductor layer 230a over the insulating layer 222 and the semiconductor layer 230b over the semiconductor layer 230a (see FIG. 23E).

Although FIG. 21B to FIG. 21D illustrate the insulating layer 280 as a single layer, the present invention is not limited thereto. The insulating layer 280 may have a stacked-layer structure. For example, as illustrated in FIG. 24A to FIG. 24D, the insulating layer 280 may have a stacked-layer structure of the insulating layer 280a and the insulating layer 280b over the insulating layer 280a.

In the structure illustrated in FIG. 21B to FIG. 21D, in the case where the insulating layer 280 has a stacked-layer structure of the insulating layer 280a and the insulating layer 280b over the insulating layer 280a, a region of the insulating layer 280a that does not overlap with the semiconductor layer 230 is preferably in contact with the insulating layer 222, and a sidewall of an opening portion included in the insulating layer 280a is preferably in contact with the insulating layer 255. The upper end portion of the insulating layer 255, the upper end portion of the insulating layer 250a, and the upper end portion of the insulating layer 250b are preferably in contact with the insulating layer 283. With the above structure, in a region sandwiched between the insulating layer 283 and the insulating layer 222, the insulating layer 280b is separated from the semiconductor layer 230 by the insulating layer 280a, the insulating layer 280b is separated from the insulating layer 250a by the insulating layer 255, the conductive layer 260 is separated from the insulating layer 250a by the insulating layer 250b, and the conductive layer 242a2 and the conductive layer 242b2 are separated from the insulating layer 250a by the insulating layer 255.

As illustrated in FIG. 24B to FIG. 24D, the insulating layer 282 may be provided between the insulating layer 283 and the insulating layer 280b, insulating layer 250, and conductive layer 260.

As illustrated in FIG. 24B and FIG. 24D, the insulating layer 271a may be provided between the conductive layer 242a and the insulating layer 280, and the insulating layer 271b may be provided between the conductive layer 242b and the insulating layer 280.

The semiconductor device of this embodiment includes an OS transistor. Since the off-state current of the OS transistor is low, a semiconductor device with low power consumption can be provided. Since the OS transistor has excellent frequency characteristics, a semiconductor device with a high operating speed can be provided. With the use of the OS transistor, a semiconductor device having excellent electrical characteristics, a semiconductor device with a small variation in transistor electrical characteristics, a semiconductor device with a high on-state current, or a highly reliable semiconductor device can be provided.

This embodiment can be combined with any of the other embodiments as appropriate. In this specification, in the case where a plurality of structure examples are shown in one embodiment, the structure examples can be combined as appropriate.

### Embodiment 4

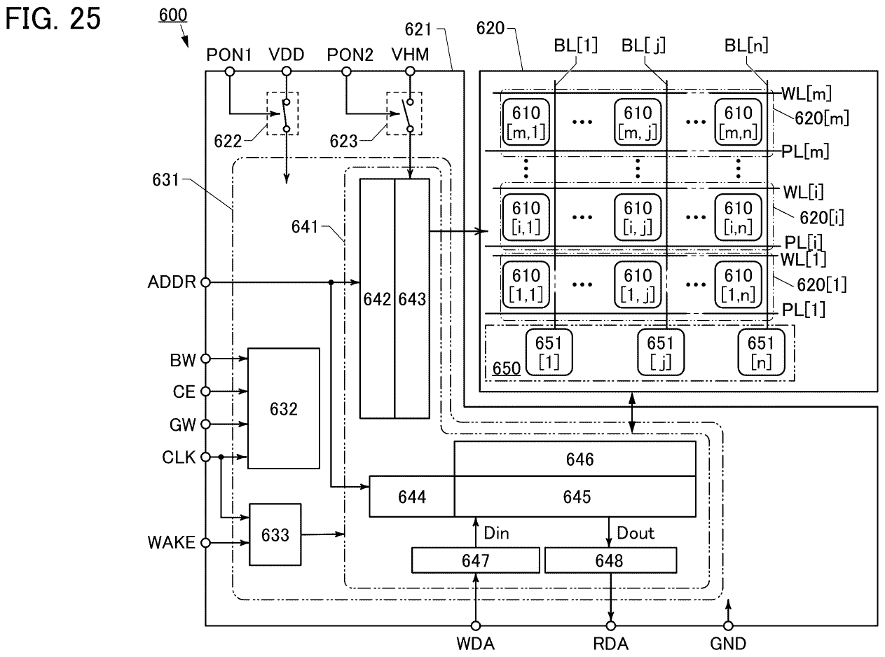

In this embodiment, a memory device using the transistor of one embodiment of the present invention will be described with reference to FIG. 25 to FIG. 32.

In this embodiment, a structure example of a memory device using a memory cell including the transistor described in the above embodiment will be described. In this embodiment, a structure example of a memory device in which a layer including a functional circuit having functions of amplifying and outputting a data potential retained in a memory cell is provided between stacked layers including memory cells will be described.

### Structure Example of Memory Device

FIG. 25 is a block diagram of the memory device of one embodiment of the present invention.

A memory device 600 illustrated in FIG. 25 includes a driver circuit 621 and a memory array 620. The memory array 620 includes a plurality of memory cells 610 and a functional layer 650 including a plurality of functional circuits 651.

FIG. 25 illustrates an example in which the memory array 620 includes the plurality of memory cells 610 arranged in a matrix of m rows and n columns (m and n are each independently an integer greater than or equal to 2). In the example illustrated in FIG. 25, the functional circuit 651 is provided for each wiring BL functioning as a bit line, and the functional layer 650 includes the plurality of functional circuits 651 that are provided to correspond to n wirings BL.

In FIG. 25, the memory cell 610 in the first row and the first column is referred to as a memory cell 610[1,1], and the memory cell 610 in the m-th row and the n-th column is referred to as a memory cell 610[m,n]. In this embodiment and the like, a given row is denoted as an i-th row in some cases. A given column is denoted as a j-th column in some cases. Thus, i is an integer greater than or equal to 1 and less than or equal to m, and j is an integer greater than or equal to 1 and less than or equal to n. In this embodiment and the like, the memory cell 610 in the i-th row and the j-th column is denoted as a memory cell 610[i,j]. Note that in this embodiment and the like, “i+α” (ais a positive or negative integer) is not below 1 and does not exceed m. Similarly, “j+α” is not below 1 and does not exceed n.

The memory array 620 includes m wirings WL extending in the row direction, m wirings PL extending in the row direction, and the n wirings BL extending in the column direction. In this embodiment and the like, a first wiring WL (provided in the first row) is denoted as a wiring WL[1], and an m-th wiring WL (provided in the m-th row) is denoted as a wiring WL[m]. Similarly, a first wiring PL (provided in the first row) is denoted as a wiring PL[1], and an m-th wiring PL (provided in the m-th row) is denoted as a wiring PL[m]. Similarly, a first wiring BL (provided in the first column) is denoted as a wiring BL[1], and an n-th wiring BL (provided in the n-th column) is denoted as a wiring BL[n].

The plurality of memory cells 610 provided in the i-th row are electrically connected to the wiring WL in the i-th row (wiring WL[i]) and the wiring PL in the i-th row (wiring PL[i]). The plurality of memory cells 610 provided in the j-th column are electrically connected to the wiring BL in the j-th column (wiring BL[j]).

A DOSRAM (registered trademark) (Dynamic Oxide Semiconductor Random Access Memory) can be used for the memory array 620. A DOSRAM is a RAM including a 1T (transistor) 1C (capacitor) memory cell and refers to a memory in which an access transistor is an OS transistor. Current flowing between a source and a drain in an off state, that is, leakage current, is extremely low in an OS transistor. A DOSRAM can retain charge corresponding to data stored in a capacitor for a long time by turning off an access transistor (by bringing the access transistor into a non-conduction state). For this reason, the refresh operation frequency of a DOSRAM can be lower than that of a DRAM formed with a transistor containing silicon in its channel formation region (a Si transistor). As a result, power consumption can be reduced. An OS transistor also has excellent frequency characteristics and thus enables high-speed reading and writing of the memory device. Hence, a memory device that can operate at high speed can be provided.

Using an OS transistor having a low off-state current in the memory cell enables long-term retention of stored contents. That is, such a memory device does not require refresh operation or has extremely low frequency of the refresh operation, which leads to a sufficient reduction in power consumption of the memory device. Note that the frequency of refresh operation in a general DRAM needs to be approximately once per 60 msec, whereas the frequency of refresh operation in the memory device of one embodiment of the present invention can be approximately once per 10 sec, which is 10 times or more or 100 times or more lower than the frequency of refresh operation in the general DRAM. In the memory device of one embodiment of the present invention, the frequency of refresh operation can be once per period of more than or equal to 1 sec and less than or equal to 100 sec, preferably once per period of more than or equal to 5 sec and less than or equal to 50 sec.

In the memory array 620 illustrated in FIG. 25, a plurality of memory arrays 620[1] to 620[m] can be stacked. When the memory arrays 620[1] to 620[m] included in the memory array 620 are placed in the direction perpendicular to the surface of a substrate provided with the driver circuit 621, the memory density of the memory cells 610 can be increased.

The wiring BL functions as a bit line for writing and reading data. The wiring WL functions as a word line for controlling on or off (a conduction state or a non-conduction state) of an access transistor functioning as a switch. The wiring PL has a function of a constant potential line connected to a capacitor. Note that a wiring CL (not illustrated) can be additionally provided as a wiring having a function of supplying a back gate potential to a back gate of an OS transistor serving as the access transistor. Alternatively, the wiring PL may also have a function of supplying the back gate potential.

The memory cell 610 included in each of the memory arrays 620[1] to 620[m] is connected to the functional circuit 651 through the wiring BL. The wiring BL can be placed in the direction perpendicular to the surface of the substrate provided with the driver circuit 621. Since the wiring BL provided to extend from the memory cells 610 included in the memory arrays 620[1] to 620[m] is provided in the direction perpendicular to the surface of the substrate, the length of the wiring between the memory array 620 and the functional circuit 651 can be shortened. Accordingly, a signal transmission distance between the two circuits connected to the bit line can be shortened, and the resistance and parasitic capacitance of the bit line can be significantly reduced; thus, power consumption and signal delays can be reduced. Moreover, even when the capacitance of the capacitors included in the memory cells 610 is reduced, operation is possible.

The functional circuit 651 has functions of amplifying a data potential retained in the memory cell 610 and outputting the amplified data potential to a sense amplifier 646 included in the driver circuit 621 through a later-described wiring GBL (not illustrated). With this structure, a slight difference in the potential of the wiring BL can be amplified at the time of data reading. Like the wiring BL, the wiring GBL can be placed in the direction perpendicular to the surface of the substrate provided with the driver circuit 621. Since the wiring BL and the wiring GBL provided to extend from the memory cells 610 included in the memory arrays 620[1] to 620[m] are provided in the direction perpendicular to the surface of the substrate, the length of the wiring between the functional circuit 651 and the sense amplifier 646 can be shortened. Accordingly, a signal transmission distance between the two circuits connected to the wiring GBL can be shortened, and the resistance and parasitic capacitance of the wiring GBL can be significantly reduced; thus, power consumption and signal delays can be reduced.

In addition, the wiring BL is provided in contact with a semiconductor layer of the transistor included in the memory cell 610. Alternatively, the wiring BL is provided in contact with a region functioning as a source or a drain in the semiconductor layer of the transistor included in the memory cell 610. Alternatively, the wiring BL is provided in contact with a conductor provided in contact with the region functioning as the source or the drain in the semiconductor layer of the transistor included in the memory cell 610. That is, it can be said that the wiring BL is a wiring for electrically connecting one of the source and the drain of the transistor included in the memory cell 610 in each layer of the memory array 620 to the functional circuit 651 in the perpendicular direction.

The memory array 620 can be provided over and overlap with the driver circuit 621. When the driver circuit 621 and the memory array 620 are provided to overlap with each other, a signal transmission distance between the driver circuit 621 and the memory array 620 can be shortened. Accordingly, the resistance and parasitic capacitance between the driver circuit 621 and the memory array 620 are reduced, so that power consumption and signal delays can be reduced. In addition, the memory device 600 can be downsized.

The functional circuit 651 can be placed at any desired position, e.g., over a circuit that is formed using Si transistors, in a manner similar to that of the memory arrays 620[1] to 620[m] when being formed with an OS transistor like the transistor included in the memory cell 610 of the DOSRAM, whereby integration can be easily performed. With the structure in which a signal is amplified by the functional circuit 651, a circuit in a subsequent stage, such as the sense amplifier 646, can be downsized; hence, the memory device 600 can be downsized.

The driver circuit 621 includes a PSW 622 (power switch), a PSW 623, and a peripheral circuit 631. The peripheral circuit 631 includes a peripheral circuit 641, a control circuit 632, and a voltage generation circuit 633.

In the memory device 600, each circuit, each signal, and each voltage can be appropriately selected as needed. Alternatively, another circuit or another signal may be added. A signal BW, a signal CE, a signal GW, a signal CLK, a signal WAKE, a signal ADDR, a signal WDA, a signal PON1, and a signal PON2 are signals input from the outside, and a signal RDA is a signal output to the outside. The signal CLK is a clock signal.

The signal BW, the signal CE, and the signal GW are control signals. The signal CE is a chip enable signal, the signal GW is a global write enable signal, and the signal BW is a byte write enable signal. The signal ADDR is an address signal. The signal WDA is write data, and the signal RDA is read data. The signal PON1 and the signal PON2 are power gating control signals. Note that the signal PON1 and the signal PON2 may be generated in the control circuit 632.

The control circuit 632 is a logic circuit having a function of controlling the entire operation of the memory device 600. For example, the control circuit performs a logical operation on the signal CE, the signal GW, and the signal BW to determine an operation mode (e.g., a writing operation or a reading operation) of the memory device 600. Alternatively, the control circuit 632 generates a control signal for the peripheral circuit 641 so that the operation mode is executed.

The voltage generation circuit 633 has a function of generating a negative voltage. The signal WAKE has a function of controlling the input of the signal CLK to the voltage generation circuit 633. For example, when an H-level signal is supplied as the signal WAKE, the signal CLK is input to the voltage generation circuit 633, and the voltage generation circuit 633 generates a negative voltage.

The peripheral circuit 641 is a circuit for performing writing and reading of data to/from the memory cells 610. Moreover, the peripheral circuit 641 is a circuit that outputs signals for controlling the functional circuits 651. The peripheral circuit 641 includes a row decoder 642, a row driver 643, a column decoder 644, a column driver 645, the sense amplifier 646, an input circuit 647, and an output circuit 648.

The row decoder 642 and the column decoder 644 have a function of decoding the signal ADDR. The row decoder 642 is a circuit for specifying a row to be accessed, and the column decoder 644 is a circuit for specifying a column to be accessed. The row driver 643 has a function of selecting the wiring WL specified by the row decoder 642. The column driver 645 has a function of writing data to the memory cells 610, a function of reading data from the memory cells 610, a function of retaining the read data, and the like.

The input circuit 647 has a function of retaining the signal WDA. Data retained by the input circuit 647 is output to the column driver 645. Data output from the input circuit 647 is data (Din) to be written to the memory cells 610. Data (Dout) read from the memory cells 610 by the column driver 645 is output to the output circuit 648. The output circuit 648 has a function of retaining Dout. In addition, the output circuit 648 has a function of outputting Dout to the outside of the memory device 600. Data output from the output circuit 648 is the signal RDA.

The PSW 622 has a function of controlling supply of VDD to the peripheral circuit 631. The PSW 623 has a function of controlling supply of VHM to the row driver 643. Here, in the memory device 600, a high power supply potential is VDD and a low power supply potential is GND (a ground potential). In addition, VHM is a high power supply potential used to set the word line at a high level and is higher than VDD. The on/off state of the PSW 622 is controlled by the signal PON1, and the on/off state of the PSW 623 is controlled by the signal PON2. The number of power domains to which VDD is supplied is one in the peripheral circuit 631 in FIG. 25 but can be more than one. In that case, a power switch is provided for each power domain.

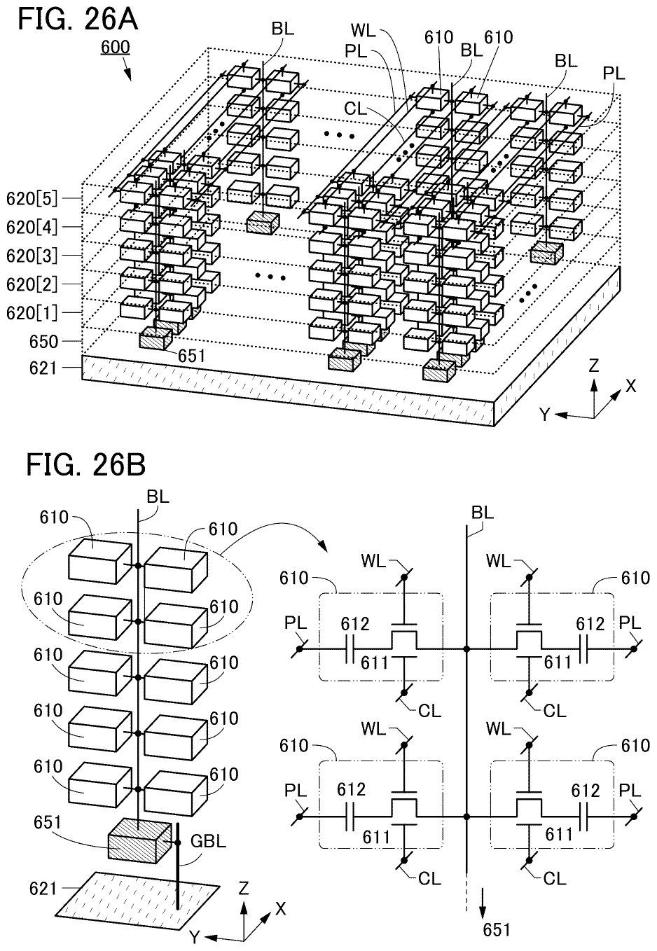

In the memory array 620 including the memory arrays 620[1] to 620[m] (m is an integer greater than or equal to 2) and the functional layer 650, the plurality of layers of memory arrays 620 can be stacked over the driver circuit 621. Stacking the plurality of layers of memory arrays 620 can increase the memory density of the memory cells 610. FIG. 26A is a perspective view of the memory device 600 that includes the functional layer 650 and five layers (m=5) of memory arrays 620[1] to 620[5], which overlap with each other, over the driver circuit 621.

In FIG. 26A, the memory array 620 provided in the first layer is denoted as the memory array 620[1], the memory array 620 provided in the second layer is denoted as a memory array 620[2], and the memory array 620 provided in the fifth layer is denoted as the memory array 620[5]. FIG. 26A also illustrates the wiring WL, the wiring CL, and the wiring PL provided to extend in the X direction and the wiring BL provided to extend in the Z direction (the direction perpendicular to the surface of the substrate provided with the driver circuit). For easy viewing of the drawing, the wirings WL and the wirings PL included in the memory arrays 620 are partly omitted.

FIG. 26B is a schematic view for describing a structure example of the functional circuit 651, which is connected to the wiring BL, and the memory cells 610 included in the memory arrays 620[1] to 620[5], which are connected to the wiring BL, illustrated in FIG. 26A. FIG. 26B illustrates the wiring GBL provided between the functional circuit 651 and the driver circuit 621. Note that a structure in which a plurality of memory cells (memory cells 610) are electrically connected to one wiring BL is also referred to as “memory string”. In the drawings, the wiring GBL is sometimes represented by a bold line for higher visibility.

FIG. 26B illustrates an example of a circuit structure of the memory cell 610 connected to the wiring BL. The memory cell 610 includes a transistor 611 and a capacitor 612. As for the transistor 611, the capacitor 612, and the wirings (the wiring BL, the wiring WL, and the like), for example, the wiring BL[1] and the wiring WL[1] are referred to as the wiring BL and the wiring WL in some cases. Here, the transistor 611 corresponds to any of the transistor 200A to the transistor 200D described in the above embodiment. Although the transistor 611 illustrated in FIG. 26B includes a back gate, the transistor 611 does not necessarily include the back gate in some cases.

In the memory cell 610, one of a source and a drain of the transistor 611 is connected to the wiring BL. The other of the source and the drain of the transistor 611 is connected to one electrode of the capacitor 612. The other electrode of the capacitor 612 is connected to the wiring PL. A gate of the transistor 611 is connected to the wiring WL. The back gate of the transistor 611 is connected to the wiring CL.

The wiring PL is a wiring for supplying a constant potential for retaining the potential of the capacitor 612. The wiring CL has a constant potential for controlling the threshold voltage of the transistor 611. The wiring PL and the wiring CL may have the same potential. In that case, the number of wirings connected to the memory cell 610 can be reduced by connecting the two wirings.

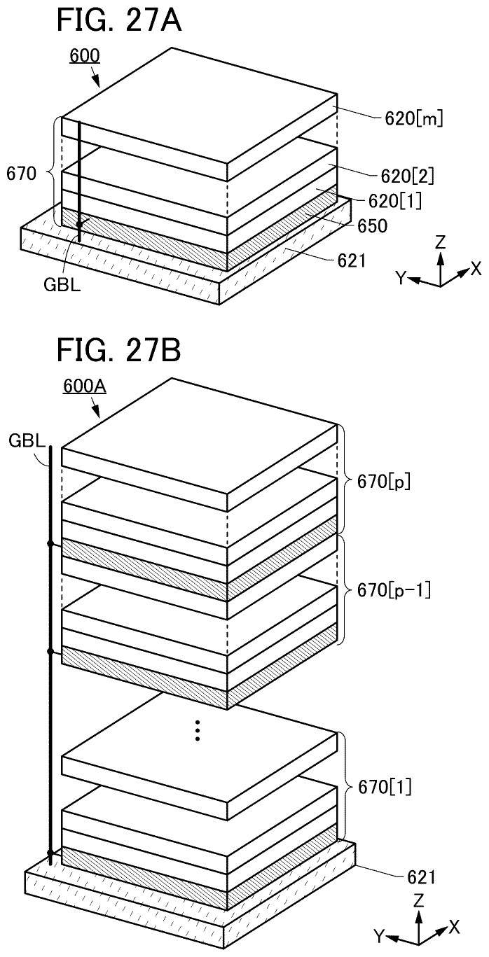

The wiring GBL illustrated in FIG. 26B is provided to electrically connect the driver circuit 621 and the functional layer 650. FIG. 27A is a schematic view of the memory device 600 in which the functional circuit 651 and the memory arrays 620[1] to 620[m] are regarded as a structure body 670. Although FIG. 27A illustrates one wiring GBL, the wiring GBL is provided as appropriate according to the number of functional circuits 651 provided in the functional layer 650.

Note that the wiring GBL is provided in contact with a semiconductor layer of the transistor included in the functional circuit 651. Alternatively, the wiring GBL is provided in contact with a region functioning as a source or a drain in the semiconductor layer of the transistor included in the functional circuit 651. Alternatively, the wiring GBL is provided in contact with a conductor provided in contact with the region functioning as the source or the drain in the semiconductor layer of the transistor included in the functional circuit 651. That is, it can be said that the wiring GBL is a wiring for electrically connecting one of the source and the drain of the transistor included in the functional circuit 651 in the functional layer 650 to the driver circuit 621 in the perpendicular direction.

The structure body 670 including the functional circuit 651 and the memory arrays 620[1] to 620[m] may have a stacked-layer structure. A memory device 600A of one embodiment of the present invention can include structure bodies 670[1] to 670[p] (p is an integer greater than or equal to 2) as illustrated in FIG. 27B. The wiring GBL is connected to the functional layers 650 included in the structure bodies 670. The wiring GBL is provided as appropriate according to the number of functional circuits 651.

In one embodiment of the present invention, OS transistors are provided to be stacked and a wiring functioning as a bit line is placed in the direction perpendicular to the surface of the substrate provided with the driver circuit 621. Since the wiring that is provided to extend from the memory array 620 and functions as a bit line is provided in the direction perpendicular to the surface of the substrate, the length of the wiring between the memory array 620 and the driver circuit 621 can be shortened. Thus, the parasitic capacitance of the bit line can be significantly reduced.

In one embodiment of the present invention, the functional layer 650 including the functional circuit 651 having functions of amplifying and outputting a data potential retained in the memory cell 610 is provided in a layer where the memory array 620 is provided. With this structure, a slight difference in the potential of the wiring BL functioning as a bit line can be amplified at the time of data reading to drive the sense amplifier 646 included in the driver circuit 621. A circuit such as a sense amplifier can be downsized, so that the memory device 600 can be downsized. Moreover, even when the capacitance of the capacitors 612 included in the memory cells 610 is reduced, operation is possible.

Although the memory device including the memory arrays 620[1] to 620[m] is described above, the semiconductor device of the present invention can also be used for a single-layer memory device including only the memory array 620[1].

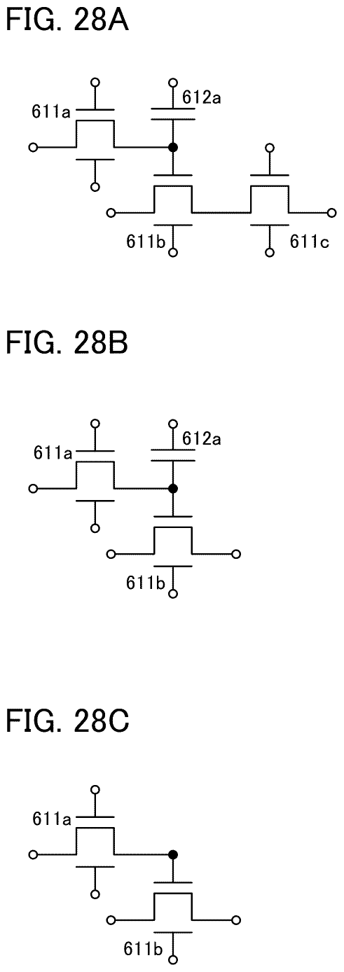

Although an example in which the memory cell 610 has a 1T (transistor) 1C (capacitor) structure is described above, the present invention is not limited thereto. For example, as illustrated in FIG. 28A, a 3T1C memory cell may be used for a memory device. The memory cell illustrated in FIG. 28A includes transistors 611a, 611b, and 611c and a capacitor 612a. Here, the transistors 611a, 611b, and 611c can have the same structure as the transistor 611, and the capacitor 612a can have the same structure as the capacitor 612. A RAM with such a structure is sometimes referred to as a NOSRAM (registered trademark) (Nonvolatile Oxide Semiconductor RAM).

As illustrated in FIG. 28A, one of a source and a drain of the transistor 611a is electrically connected to one electrode of the capacitor 612a and a first gate of the transistor 611b. One of a source and a drain of the transistor 611b is electrically connected to one of a source and a drain of the transistor 611c. Note that wirings are provided as appropriate for a first gate of the transistor 611a, the other of the source and the drain of the transistor 611a, a second gate of the transistor 611a, the other of the source and the drain of the transistor 611b, a second gate of the transistor 611b, a first gate of the transistor 611c, the other of the source and the drain of the transistor 611c, a second gate of the transistor 611c, and the other electrode of the capacitor 612a. The structure of the memory device can be changed as appropriate in accordance with these wirings.

As illustrated in FIG. 28B, a structure may be employed in which the transistor 611c is not provided and only the transistors 611a and 611b and the capacitor 612a are provided.

In the case where the parasitic capacitances of the transistor 611a and the transistor 611b are sufficiently large, the capacitor 612a may be omitted as illustrated in FIG. 28C. In that case, the memory cell is composed only of the transistor 611a and the transistor 611b.

### Structure Example of Memory Array 620 and Functional Circuit 651

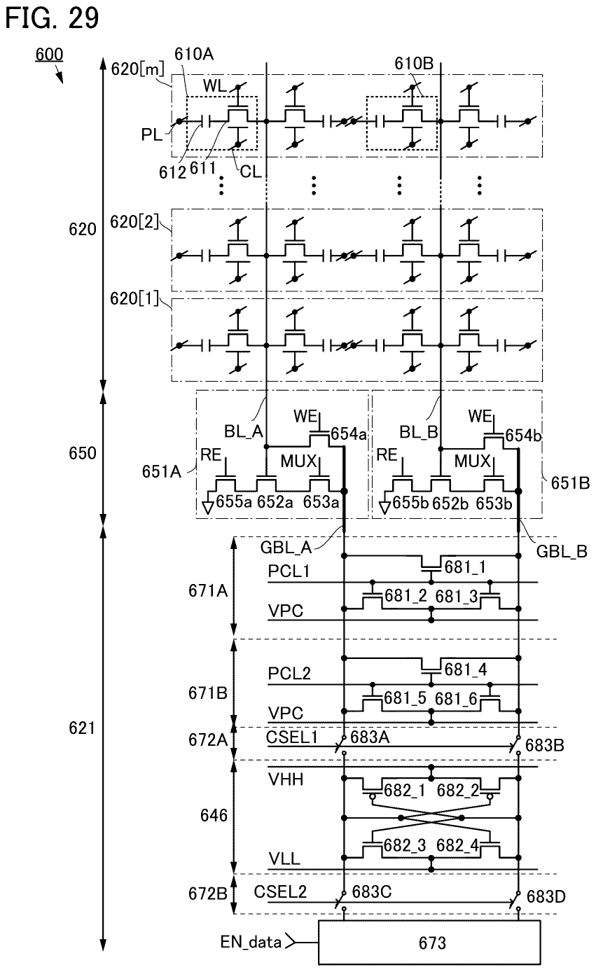

A structure example of the functional circuit 651 and structure examples of the memory array 620 and the sense amplifier 646 included in the driver circuit 621, which are described with reference to FIG. 25 to FIG. 27B, are described with reference to FIG. 29. FIG. 29 illustrates the driver circuit 621 connected to the wirings GBL (a wiring GBL_A and a wiring GBL_B) connected to the functional circuits 651 (a functional circuit 651A and a functional circuit 651B) connected to the memory cells 610 (a memory cell 610A and a memory cell 610B) connected to different wirings BL (a wiring BL_A and a wiring BL_B). FIG. 29 also illustrates, as the driver circuit 621, a precharge circuit 671A, a precharge circuit 671B, a switch circuit 672A, a switch circuit 672B, and a write/read circuit 673 in addition to the sense amplifier 646.

As the functional circuits 651A and 651B, transistors 652a, 652b, 653a, 653b, 654a, 654b, 655a, and 655b are illustrated. The transistors 652a, 652b, 653a, 653b, 654a, 654b, 655a, and 655b illustrated in FIG. 29 are OS transistors like the transistor 611 included in the memory cell 610. The functional layer 650 including the functional circuits 651 can be provided in stacked layers like the memory arrays 620[1] to 620[m].

The wiring BL_A is connected to a gate of the transistor 652a, and the wiring BL_B is connected to a gate of the transistor 652b. One of a source and a drain of each of the transistors 653a and 654a is connected to the wiring GBL_A. One of a source and a drain of each of the transistors 653b and 654b is connected to the wiring GBL_B. The wirings GBL_A and GBL_B are provided in the perpendicular direction like the wirings BL_A and BL_B and connected to transistors included in the driver circuit 621. As illustrated in FIG. 29, a selection signal MUX, a control signal WE, or a control signal RE is supplied to gates of the transistors 653a, 653b, 654a, 654b, 655a, and 655b.

Transistors 681_1 to 681_6 and 682_1 to 682_4 included in the sense amplifier 646, the precharge circuit 671A, and the precharge circuit 671B illustrated in FIG. 29 are Si transistors. Switches 683A to 683D included in the switch circuit 672A and the switch circuit 672B can also be Si transistors. The one of the source and the drain of each of the transistors 653a, 653b, 654a, and 654b is connected to transistors or switches included in the precharge circuit 671A, the precharge circuit 671B, the sense amplifier 646, and the switch circuit 672A.

The precharge circuit 671A includes the n-channel transistors 681_1 to 681_3. The precharge circuit 671A is a circuit for precharging the wiring BL_A and the wiring BL_B with an intermediate potential VPC corresponding to a potential VDD/2 between a high power supply potential (VDD) and a low power supply potential (VSS) in accordance with a precharge signal supplied to a precharge line PCL1.

The precharge circuit 671B includes the n-channel transistors 681_4 to 681_6. The precharge circuit 671B is a circuit for precharging the wiring GBL_A and the wiring GBL_B with the intermediate potential VPC corresponding to the potential VDD/2 between VDD and VSS in accordance with a precharge signal supplied to a precharge line PCL2.

The sense amplifier 646 includes the p-channel transistors 682_1 and 682_2 and the n-channel transistors 682_3 and 682_4, which are connected to a wiring VHH or a wiring VLL. The wiring VHH or the wiring VLL is a wiring having a function of supplying VDD or VSS. The transistors 682_1 to 682_4 are transistors that form an inverter loop. The potentials of the wiring BL_A and the wiring BL_B precharged are changed by selecting the memory cells 610A and 610B, and the potentials of the wiring GBL_A and the wiring GBL_B are set to VDD or VSS in accordance with the changes. The potentials of the wiring GBL_A and the wiring GBL_B can be output to the outside through the switch 683C, the switch 683D, and the write/read circuit 673. The wiring BL_A and the wiring BL_B correspond to a bit line pair, and the wiring GBL_A and the wiring GBL_B correspond to a bit line pair. Data signal writing of the write/read circuit 673 is controlled in accordance with a signal EN_data.

The switch circuit 672A is a circuit for controlling electrical continuity between the sense amplifier 646 and each of the wiring GBL_A and the wiring GBL_B. The on and off states of the switch circuit 672A are switched under the control of a switch signal CSEL1. In the case where the switches 683A and 683B are n-channel transistors, the switches 683A and 683B are turned on and off when the switch signal CSEL1 is at a high level and a low level, respectively. The switch circuit 672B is a circuit for controlling electrical continuity between the write/read circuit 673 and the bit line pair connected to the sense amplifier 646. The on and off states of the switch circuit 672B are switched under the control of a switch signal CSEL2. The switches 683C and 683D can be similar to the switches 683A and 683B.

As illustrated in FIG. 29, the memory device 600 can have a structure in which the memory cell 610, the functional circuit 651, and the sense amplifier 646 are connected to each other through the wiring BL and the wiring GBL provided in the perpendicular direction which is the shortest distance. Despite the addition of the functional layer 650 including transistors included in the functional circuit 651, the writing time can be shortened and data reading can be facilitated by reducing the load of the wiring BL.

As illustrated in FIG. 29, the transistors included in the functional circuits 651A and 651B are controlled in accordance with the control signals WE and RE and the selection signal MUX. The transistors can output the potential of the wiring BL through the wiring GBL to the driver circuit 621 in accordance with the control signals and the selection signal. The functional circuits 651A and 651B can function as a sense amplifier formed with OS transistors. With this structure, a slight difference in the potential of the wiring BL can be amplified at the time of reading to drive the sense amplifier 646 formed using Si transistors.

### Structure Example 1 of Memory Cell

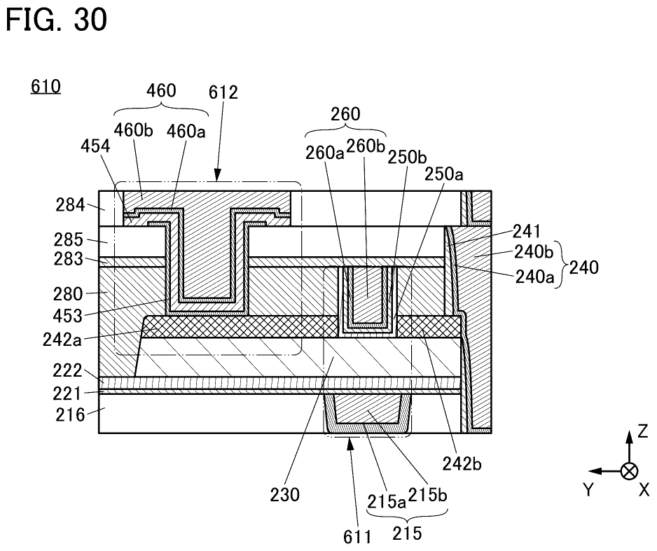

A structure example of the memory cell 610 used in the above-described memory device will be described with reference to FIG. 30.

Note that in FIG. 30, the X direction is parallel to the channel width direction of an illustrated transistor, the Y direction is perpendicular to the X direction, and the Z direction is perpendicular to the X direction and the Y direction.

As illustrated in FIG. 30, the memory cell 610 includes the transistor 611 and the capacitor 612. An insulating layer 285 is provided over the transistor 611, and an insulating layer 284 is provided over the insulating layer 285. An insulator that can be used as the insulating layer 216 can be used as the insulating layer 285 and the insulating layer 284. Note that the transistor 611 has the same structure as the transistor 200C described in the above embodiment, and the same components are denoted by the same reference numerals. The above embodiment can be referred to for the details of the transistor 200C. The conductive layer 240 (the conductive layer 240a and the conductive layer 240b) is provided in contact with one of the source electrode and the drain electrode of the transistor 611 (the conductive layer 242b). The conductive layer 240 is provided to extend in the Z direction and functions as the wiring BL.

The capacitor 612 includes a conductive layer 453 over the conductive layer 242a, an insulating layer 454 over the conductive layer 453, and a conductive layer 460 (a conductive layer 460a and a conductive layer 460b) over the insulating layer 454.

At least part of each of the conductive layer 453, the insulating layer 454, and the conductive layer 460 is positioned in an opening portion provided in the insulating layer 280, the insulating layer 283, and the insulating layer 285. The end portions of the conductive layer 453, the insulating layer 454, and the conductive layer 460 are positioned at least over the insulating layer 283, and preferably positioned over the insulating layer 285. The insulating layer 454 is provided to cover the end portion of the conductive layer 453. This enables the conductive layer 453 and the conductive layer 460 to be electrically insulated from each other.

The deeper the opening portion provided in the insulating layer 280, the insulating layer 283, and the insulating layer 285 is (i.e., the larger the film thickness of one or more of the insulating layer 280, the insulating layer 283, and the insulating layer 285 is), the larger the electrostatic capacitance of the capacitor 612 can be. Increasing the electrostatic capacitance per unit area of the capacitor 612 can achieve miniaturization or higher integration of the memory device.

The conductive layer 453 includes a region functioning as one electrode (a lower electrode) of the capacitor 612. The insulating layer 454 includes a region functioning as a dielectric of the capacitor 612. The conductive layer 460 includes a region functioning as the other electrode (an upper electrode) of the capacitor 612. An upper portion of the conductive layer 260 can be extended to function as the wiring PL illustrated in FIG. 26A and FIG. 26B. The capacitor 612 forms an MIM (Metal-Insulator-Metal) capacitor.

The conductive layer 242a provided to be over and overlap with the semiconductor layer 230 functions as an electrode electrically connected to the conductive layer 453 of the capacitor 612.

Each of the conductive layer 453 and the conductive layer 460 included in the capacitor 612 can be formed using any of a variety of conductors that can be used as the conductive layer 215 and the conductive layer 260. The conductive layer 453 and the conductive layer 460 are each preferably formed by a film formation method that enables excellent coverage, such as an ALD method or a CVD method. For example, titanium nitride or tantalum nitride formed by an ALD method or a CVD method can be used for the conductive layer 453.

The top surface of the conductive layer 242a is in contact with the bottom surface of the conductive layer 453. Here, the use of a conductive material with high conductivity for the conductive layer 242a can reduce the contact resistance between the conductive layer 453 and the conductive layer 242a.

Titanium nitride formed by an ALD method or a CVD method can be used for the conductive layer 460a, and tungsten formed by a CVD method can be used for the conductive layer 460b. Note that in the case where the adhesion of tungsten to the insulating layer 454 is sufficiently high, a single-layer structure of tungsten formed by a CVD method may be used for the conductive layer 460.

The insulating layer 454 included in the capacitor 612 is preferably formed using a material with a high relative permittivity (high-k material) described in the above embodiment. Using such a high-k material allows the insulating layer 454 to be thick enough to inhibit leakage current and the capacitor 612 to have sufficiently large electrostatic capacitance. The insulating layer 454 is preferably formed by a film formation method that enables excellent coverage, such as an ALD method or a CVD method.

It is preferable to use stacked insulators formed of any of the above materials, and it is preferable to use a stacked-layer structure of a material with a high relative permittivity (a high-k material) and a material having higher dielectric strength than the material with a high relative permittivity (the high-k material). As the insulating layer 454, an insulator in which zirconium oxide, aluminum oxide, and zirconium oxide are stacked in this order can be used, for example. For another example, an insulator in which zirconium oxide, aluminum oxide, zirconium oxide, and aluminum oxide are stacked in this order can be used. For another example, an insulating film in which hafnium zirconium oxide, aluminum oxide, hafnium zirconium oxide, and aluminum oxide are stacked in this order can be used. The stacking of such an insulator having relatively high dielectric strength, such as aluminum oxide, can increase the dielectric strength and inhibit the electrostatic breakdown of the capacitor 612.

Alternatively, a material that can have ferroelectricity may be used for the insulating layer 454. Examples of the material that can have ferroelectricity include metal oxides such as hafnium oxide, zirconium oxide, and HfZrO_{X} (X is a real number greater than 0). Examples of the material that can have ferroelectricity also include a material in which an element J1 (the element J1 here is one or more selected from zirconium, silicon, aluminum, gadolinium, yttrium, lanthanum, strontium, and the like) is added to hafnium oxide. Here, the ratio of the number of hafnium atoms to the number of atoms of the element J1 can be set as appropriate; the ratio of the number of hafnium atoms to the number of atoms of the element J1 is preferably, for example, 1:1 or the neighborhood thereof. Examples of the material that can have ferroelectricity also include a material in which an element J2 (the element J2 here is one or more selected from hafnium, silicon, aluminum, gadolinium, yttrium, lanthanum, strontium, and the like) is added to zirconium oxide. The ratio of the number of zirconium atoms to the number of atoms of the element J2 can be set as appropriate; the ratio of the number of zirconium atoms to the number of atoms of the element J2 is preferably, for example, 1:1 or the neighborhood thereof. As the material that can have ferroelectricity, a piezoelectric ceramic having a perovskite structure, such as lead titanate (PbTiO_{X}), barium strontium titanate (BST), strontium titanate, lead zirconate titanate (PZT), strontium bismuth tantalate (SBT), bismuth ferrite (BFO), or barium titanate, may be used.

Examples of the material that can have ferroelectricity also include a metal nitride containing an element M1, an element M2, and nitrogen. Here, the element M1 is one or more selected from aluminum, gallium, indium, and the like. The element M2 is one or more selected from boron, scandium, yttrium, lanthanum, cerium, neodymium, europium, titanium, zirconium, hafnium, vanadium, niobium, tantalum, chromium, and the like. Note that the ratio of the number of atoms of the element M1 to the number of atoms of the element M2 can be set as appropriate. A metal oxide containing the element M1 and nitrogen has ferroelectricity in some cases even though the metal oxide does not contain the element M2. Examples of the material that can have ferroelectricity also include a material in which an element M3 is added to the above metal nitride. Note that the element M3 is one or more selected from magnesium, calcium, strontium, zinc, cadmium, and the like. Here, the ratio between the number of atoms of the element M1, the number of atoms of the element M2, and the number of atoms of the element M3 can be set as appropriate.

Examples of the material that can have ferroelectricity also include perovskite-type oxynitrides such as SrTaO₂N and BaTaO₂N and GaFeO₃ with a κ-alumina-type structure.

Although metal oxides and metal nitrides are given as examples in the above description, one embodiment of the present invention is not limited thereto. For example, a metal oxynitride in which nitrogen is added to any of the above metal oxides, a metal nitride oxide in which oxygen is added to any of the above metal nitrides, or the like may be used.

As the material that can have ferroelectricity, a mixture or compound containing a plurality of materials selected from the above-listed materials can be used, for example. Alternatively, the insulating layer 454 can have a stacked-layer structure of a plurality of materials selected from the above-listed materials. Note that the crystal structures (properties) of the above-listed materials and the like can be changed depending on the processes as well as the film formation conditions; thus, a material that exhibits ferroelectricity is referred to not only as a ferroelectric but also as a material that can have ferroelectricity in this specification and the like.

A ferroelectric is an insulator having a property of causing internal polarization by application of an electric field from the outside and maintaining the polarization even after the electric field is made zero. Thus, with the use of a capacitor that uses this material as a dielectric (hereinafter, the capacitor may be referred to as a ferroelectric capacitor), a nonvolatile memory element can be formed. A nonvolatile memory element using a ferroelectric capacitor is sometimes referred to as an FeRAM (Ferroelectric Random Access Memory), a ferroelectric memory, or the like. For example, a ferroelectric memory includes a transistor and a ferroelectric capacitor, and one of a source and a drain of the transistor is electrically connected to one terminal of the ferroelectric capacitor. Thus, in the case of using a ferroelectric capacitor as the capacitor 612, the memory device described in this embodiment functions as a ferroelectric memory.

The deeper the opening portion provided in the insulating layer 280, the insulating layer 283, and the insulating layer 285 is (i.e., the larger the film thickness of one or more of the insulating layer 280, the insulating layer 283, and the insulating layer 285 is), the larger the electrostatic capacitance of the capacitor 612 can be. Here, since the insulating layer 280 and the insulating layer 283 function as barrier insulators, their film thicknesses are preferably set in accordance with a barrier property required for the semiconductor device. The film thickness of the conductive layer 260 functioning as a gate electrode depends on the film thickness of the insulating layer 280; thus, the film thickness of the insulating layer 280 is preferably set in accordance with the film thickness of the conductive layer 260 required for the semiconductor device.

Accordingly, the electrostatic capacitance of the capacitor 612 is preferably set by adjusting the film thickness of the insulating layer 285. For example, the film thickness of the insulating layer 285 can be set within the range from 50 nm to 250 nm inclusive, and the depth of the opening portion is approximately greater than or equal to 150 nm and less than or equal to 350 nm. When the capacitor 612 is formed within the above range, the capacitor 612 can have adequate electrostatic capacitance, and the height of one layer can be prevented from being excessively large in a semiconductor device in which a plurality of memory cell layers are stacked. Note that capacitors provided in memory cells may have different electrostatic capacitances in the plurality of memory cell layers. In this structure, the film thicknesses of the insulating layers 285 provided in the memory cell layers vary, for example.

Note that the sidewall of an opening portion in which the capacitor 612 is placed and which is provided in the insulating layer 285 and the like may be perpendicular or substantially perpendicular to the top surface of the insulating layer 222 or may have a tapered shape. The tapered shape of the sidewall can improve the coverage with the conductive layer 453 and the like provided in the opening portion in the insulating layer 285 and the like; as a result, the number of defects such as voids can be reduced.

The conductive layer 242b provided to be over and overlap with the semiconductor layer 230 functions as a wiring electrically connected to the conductive layer 240. In FIG. 30, for example, the top surface and the side end portion of the conductive layer 242b are electrically connected to the conductive layer 240 extending in the Z direction. Specifically, in FIG. 30, the top surface and the side end portion of the conductive layer 242b are in contact with the conductive layer 240.

When the conductive layer 240 is in direct contact with at least one of the top surface and the side end portion of the conductive layer 242b, an electrode for connection does not need to be provided additionally, so that the area occupied by the memory arrays can be reduced. In addition, the integration degree of the memory cells is increased, and the memory capacity of the memory device can be increased. Note that the conductive layer 240 is preferably in contact with the side end portion and part of the top surface of the conductive layer 242b. When the conductive layer 240 is in contact with a plurality of surfaces of the conductive layer 242b, the contact resistance between the conductive layer 240 and the conductive layer 242b can be reduced.

The conductive layer 240 is provided in an opening formed in the insulating layer 216, the insulating layer 221, the insulating layer 222, the insulating layer 280, the insulating layer 283, the insulating layer 285, and the insulating layer 284.

As illustrated in FIG. 30, an insulating layer 241 is preferably provided in contact with the side surface of the conductive layer 240. Specifically, the insulating layer 241 is provided in contact with the inner wall of the opening portion in the insulating layer 216, the insulating layer 221, the insulating layer 222, the insulating layer 280, the insulating layer 283, the insulating layer 285, and the insulating layer 284. The insulating layer 241 is formed also along the side surface of the semiconductor layer 230 that is formed to protrude inside the opening portion. Here, at least part of the conductive layer 242b is exposed from the insulating layer 241 and is in contact with the conductive layer 240. That is, the conductive layer 240 is provided to fill the opening portion with the insulating layer 241 therebetween.

As illustrated in FIG. 30, the uppermost portion of the insulating layer 241 formed below the conductive layer 242b is preferably positioned below the top surface of the conductive layer 242b. With this structure, the conductive layer 240 can be in contact with at least part of the side end portion of the conductive layer 242b. Note that the insulating layer 241 formed below the conductive layer 242b preferably includes a region in contact with the side surface of the semiconductor layer 230. With this structure, impurities such as water and hydrogen contained in the insulating layer 280 and the like can be inhibited from entering the semiconductor layer 230 through the conductive layer 240.

Note that the sidewall of the opening portion in which the conductive layer 240 and the insulating layer 241 are placed may be perpendicular or substantially perpendicular to the top surface of the insulating layer 222 or may have a tapered shape. The tapered shape of the sidewall can improve the coverage with the insulating layer 241 and the like provided in the opening portion.

### Structure Example of Memory Device 600

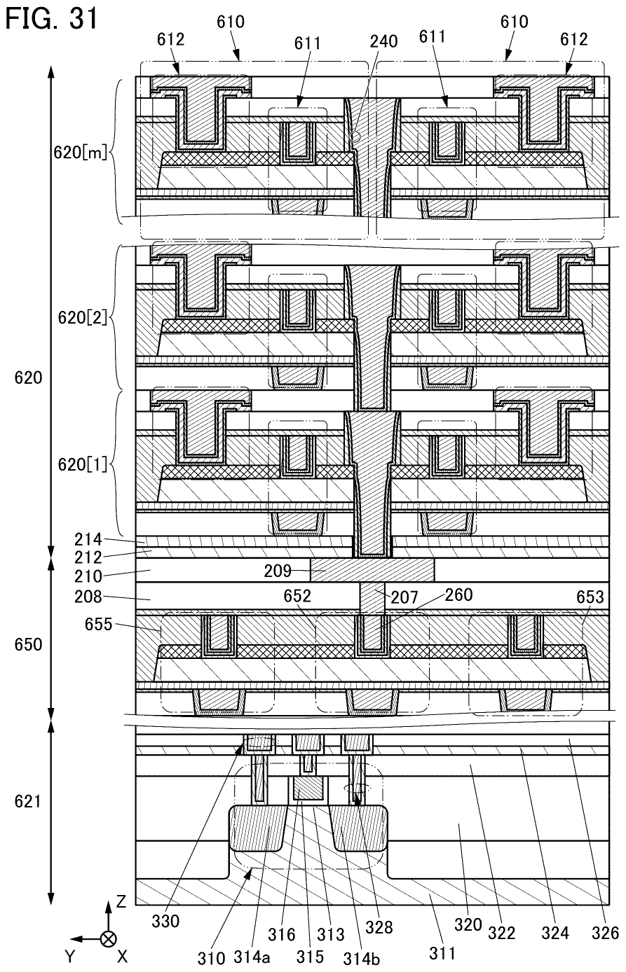

A structure example of the memory device 600 will be described with reference to FIG. 31.

The memory device 600 includes the driver circuit 621 that is a layer including a transistor 310 and the like, the functional layer 650 that is over the driver circuit 621 and is a layer including transistors 652, 653, and 655 and the like, and the memory arrays 620[1] to 620[m] over the functional layer 650. Note that the transistor 652 corresponds to the transistors 652a and 652b, the transistor 653 corresponds to the transistors 653a and 653b, and the transistor 655 corresponds to the transistors 655a and 655b.

FIG. 31 illustrates the transistor 310 included in the driver circuit 621 as an example. The transistor 310 is provided on a substrate 311 and includes a conductive layer 316 functioning as a gate, an insulating layer 315 functioning as a gate insulator, a semiconductor region 313 including part of the substrate 311, and a low-resistance region 314a and a low-resistance region 314b functioning as a source region and a drain region. The transistor 310 may be either a p-channel transistor or an n-channel transistor. As the substrate 311, a single crystal silicon substrate can be used, for example.

Here, in the transistor 310 illustrated in FIG. 31, the semiconductor region 313 (part of the substrate 311) where a channel is formed has a protruding shape. The conductive layer 316 is provided to cover the side surface and the top surface of the semiconductor region 313 with the insulating layer 315 therebetween. Note that the conductive layer 316 may be formed using a material for adjusting the work function. The transistor 310 is also referred to as a FIN-type transistor because it utilizes a protruding portion of the semiconductor substrate. Note that an insulator functioning as a mask for forming the protruding portion may be provided in contact with the upper portion of the protruding portion. Although the case where the protruding portion is formed by processing part of the semiconductor substrate is described here, a semiconductor film having a protruding shape may be formed by processing an SOI substrate.

Note that the transistor 310 illustrated in FIG. 31 is an example and the structure is not limited thereto; an appropriate transistor can be used in accordance with a circuit structure or a driving method.

A wiring layer provided with an interlayer film, a wiring, a plug, and the like may be provided between the components. A plurality of wiring layers can be provided in accordance with the design. Here, a plurality of conductors functioning as plugs or wirings are collectively denoted by the same reference numeral in some cases. In this specification and the like, a wiring and a plug electrically connected to the wiring may be a single component. That is, part of a conductor functions as a wiring in some cases and part of the conductor functions as a plug in other cases.

For example, an insulating layer 320, an insulating layer 322, an insulating layer 324, and an insulating layer 326 are stacked in this order over the transistor 310 as interlayer films. A conductive layer 328 and the like are embedded in the insulating layer 320 and the insulating layer 322. A conductive layer 330 and the like are embedded in the insulating layer 324 and the insulating layer 326. Note that the conductive layer 328 and the conductive layer 330 function as a contact plug or a wiring.

The insulator functioning as an interlayer film may function as a planarization film that covers an uneven shape thereunder. For example, the top surface of the insulating layer 322 may be planarized by CMP treatment to increase the level of planarity.

Examples of an insulator that can be used as an interlayer film include an insulating oxide, an insulating nitride, an insulating oxynitride, an insulating nitride oxide, an insulating metal oxide, an insulating metal oxynitride, and an insulating metal nitride oxide.

For example, when a material with a low relative permittivity is used for the insulator functioning as an interlayer film, the parasitic capacitance generated between wirings can be reduced. Thus, a material is preferably selected in accordance with the function of the insulator.

FIG. 31 illustrates the transistors 652, 653, and 655 included in the functional layer 650 as an example. Each of the transistors 652, 653, and 655 has the same structure as the transistor 611 included in the memory cell 610. Sources and drains of the transistors 652, 653, and 655 are connected in series.

An insulating layer 208 is provided over the transistors 652, 653, and 655, and a conductive layer 207 is provided in an opening formed in the insulating layer 208. Furthermore, the insulating layer 210 is provided over the insulating layer 208, and a conductive layer 209 is provided in an opening formed in the insulating layer 210. Moreover, an insulating layer 212 is provided over the insulating layer 210, and the insulating layer 214 is provided over the insulating layer 212. Part of the conductive layer 240 provided in the memory array 620[1] is embedded in an opening formed in the insulating layer 212 and the insulating layer 214. Here, as the insulating layer 208 and the insulating layer 210, the insulator that can be used as the insulating layer 216 can be used. As the insulating layer 212, the insulator that can be used as the insulating layer 283 can be used. As the insulating layer 214, the insulator that can be used as the insulating layer 282 can be used.

The bottom surface of the conductive layer 207 is provided in contact with the top surface of the conductive layer 260 of the transistor 652. The top surface of the conductive layer 207 is provided in contact with the bottom surface of the conductive layer 209. The top surface of the conductive layer 209 is provided in contact with the bottom surface of the conductive layer 240 provided in the memory array 620[1]. With such a structure, the conductive layer 240 corresponding to the wiring BL and a gate of the transistor 652 can be electrically connected to each other.

Each of the memory arrays 620[1] to 620[m] includes the plurality of memory cells 610. The conductive layer 240 included in each of the memory cells 610 is electrically connected to the conductive layer 240 in an upper layer and the conductive layer 240 in a lower layer.

As illustrated in FIG. 31, the conductive layer 240 is shared between the adjacent memory cells 610. In the adjacent memory cells 610, the components in the right memory cell and the components in the left memory cell are placed symmetrically about the conductive layer 240.

In the above-described memory array 620, the plurality of memory arrays 620[1] to 620[m] can be provided to be stacked. When the memory arrays 620[1] to 620[m] included in the memory array 620 are placed in the direction perpendicular to the surface of the substrate provided with the driver circuit 621, the memory density of the memory cells 610 can be increased. Moreover, the memory array 620 can be formed by repeating the same manufacturing process in the perpendicular direction. The manufacturing cost of the memory array 620 in the memory device 600 can be reduced.

### Structure Example 2 of Memory Cell

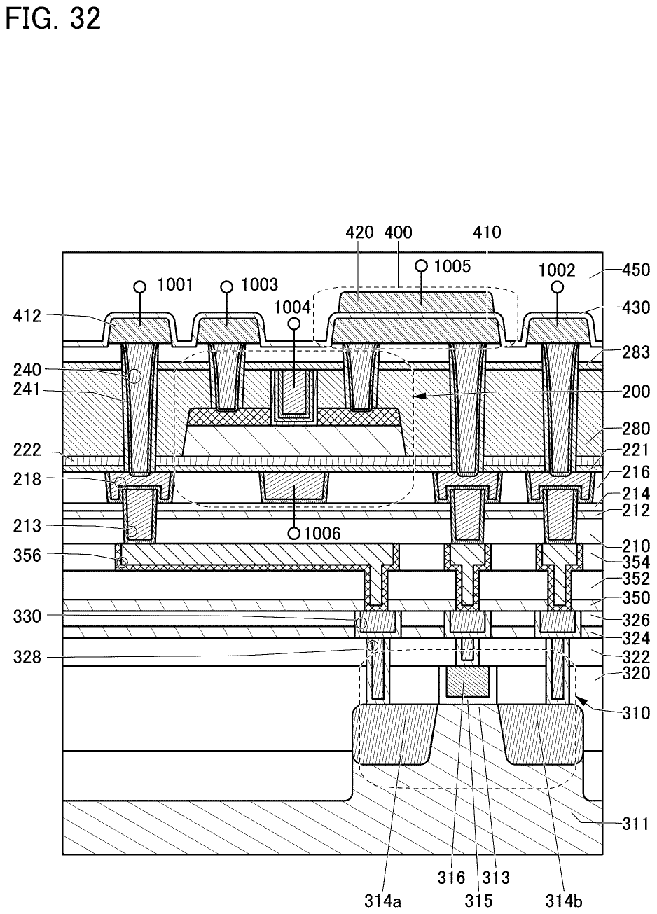

A structure example of a memory cell having a 2T (transistor) 1C (capacitor) structure will be described with reference to FIG. 32.

The memory cell illustrated in FIG. 32 includes the transistor 310, a transistor 200 provided above the transistor 310, and a capacitor 400 provided above the transistor 310 and the transistor 200. Note that any of the transistor 200A to the transistor 200D described in the above embodiments can be used as the transistor 200.

The transistor 200 is a transistor in which a channel is formed in a semiconductor layer including an oxide semiconductor. Since the transistor 200 has a low off-state current, a memory device that uses the transistor 200 can retain stored contents for a long time. That is, such a memory device does not require refresh operation or has extremely low frequency of the refresh operation, which leads to a sufficient reduction in power consumption of the memory device.

In the memory cell illustrated in FIG. 32, a wiring 1001 is electrically connected to the source of the transistor 310, and a wiring 1002 is electrically connected to the drain of the transistor 310. A wiring 1003 is electrically connected to one of a source and a drain of the transistor 200, a wiring 1004 is electrically connected to a first gate of the transistor 200, and a wiring 1006 is electrically connected to a second gate of the transistor 200. The gate of the transistor 310 and the other of the source and the drain of the transistor 200 are electrically connected to one electrode of the capacitor 400, and a wiring 1005 is electrically connected to the other electrode of the capacitor 400.

When the memory devices, illustrated in FIG. 32, are arranged in a matrix, a memory cell array can be formed.

For the structure of the transistor 310, the above description in <Structure example of memory device 600> can be referred to. Note that the transistor 310 illustrated in FIG. 32 is an example and the structure is not limited thereto; an appropriate transistor can be used in accordance with a circuit structure or a driving method.

The capacitor 400 includes a conductive layer 410 functioning as a first electrode, a conductive layer 420 functioning as a second electrode, and an insulating layer 430 functioning as a dielectric.

As each of the conductive layer 410 and the conductive layer 420, any of the conductors described in [Conductor] in the above embodiment can be used as a single layer or stacked layers.

The conductive layer 412 can be formed at the same time as the conductive layer 410, for example. Note that the conductive layer 412 functions as a plug or a wiring that is electrically connected to the capacitor 400, the transistor 200, or the transistor 310.

The conductive layer 412 and the conductive layer 410 each have a single-layer structure in FIG. 32, but may have a stacked-layer structure of two or more layers without being limited to the above structure. For example, between a conductor having a barrier property and a conductor having high conductivity, a conductor that is highly adhesive to the conductor having a barrier property and the conductor having high conductivity may be formed.

As the insulating layer 430, the insulator that can be used as the insulating layer 283 described in the above embodiment is preferably used. The insulating layer 430 can be formed to have a stacked-layer structure or a single-layer structure using, for example, silicon oxide, silicon oxynitride, silicon nitride oxide, silicon nitride, aluminum oxide, aluminum oxynitride, aluminum nitride oxide, aluminum nitride, hafnium oxide, hafnium oxynitride, hafnium nitride oxide, hafnium nitride, or the like.

For another example, for the insulating layer 430, a stacked-layer structure of a material with high dielectric strength such as silicon oxynitride and a high permittivity (high-k) material is preferably used. In the capacitor 400 having this structure, a sufficient capacitance can be ensured owing to the high permittivity (high-k) insulator, and the dielectric strength can be increased owing to the insulator with high dielectric strength, so that the electrostatic breakdown of the capacitor 400 can be inhibited.

Examples of the high permittivity (high-k) material (a material with a high relative permittivity) include gallium oxide, hafnium oxide, zirconium oxide, an oxide containing aluminum and hafnium, an oxynitride containing aluminum and hafnium, an oxide containing silicon and hafnium, an oxynitride containing silicon and hafnium, and a nitride containing silicon and hafnium.

Examples of the material with high dielectric strength (a material with a low relative permittivity) include silicon oxide, silicon oxynitride, silicon nitride oxide, silicon nitride, silicon oxide to which fluorine is added, silicon oxide to which carbon is added, silicon oxide to which carbon and nitrogen are added, porous silicon oxide, and a resin.

A wiring layer provided with an interlayer film, a wiring, a plug, and the like may be provided between the components. A plurality of wiring layers can be provided in accordance with the design.

For example, the insulating layer 320, the insulating layer 322, the insulating layer 324, and the insulating layer 326 are stacked in this order over the transistor 310 as interlayer films. The conductive layer 328, the conductive layer 330, and the like that are electrically connected to the capacitor 400 or the transistor 200 are embedded in the insulating layer 320, the insulating layer 322, the insulating layer 324, and the insulating layer 326. For these insulators and these conductors, the above description in <Structure example of memory device 600> can be referred to.

A wiring layer may be provided over the insulating layer 326 and the conductive layer 330. For example, in FIG. 32, an insulating layer 350, an insulating layer 352, and an insulating layer 354 are stacked in this order. A conductive layer 356 is formed in the insulating layer 350, the insulating layer 352, and the insulating layer 354. The conductive layer 356 functions as a plug or a wiring.

Similarly, a conductive layer 213 is embedded in the insulating layer 210, the insulating layer 212, the insulating layer 214, and the insulating layer 216. Note that the conductive layer 213 has a function of a plug or a wiring that is electrically connected to the capacitor 400 or the transistor 310.

A conductive layer 218 is embedded in the insulating layer 216. The conductive layer 218 is preferably provided in contact with the top surface and part of the side surface of the conductive layer 213. In other words, the conductive layer 218 is preferably provided in contact with a portion of the conductive layer 213 that is exposed from the insulating layer 214. In such a structure, the conductive layer 218 can be formed concurrently with the conductor (the conductive layer 215) included in the transistor 200, for example. Accordingly, the manufacturing process of the memory device can be simplified and the productivity can be improved.

Note that the conductive layer 218 functions as a plug or a wiring that is electrically connected to the capacitor 400, the transistor 200, or the transistor 310. In addition, an insulating layer 450 is provided over the conductive layer 420 and the insulating layer 430.

This embodiment can be combined with any of the other embodiments as appropriate.

### Embodiment 5

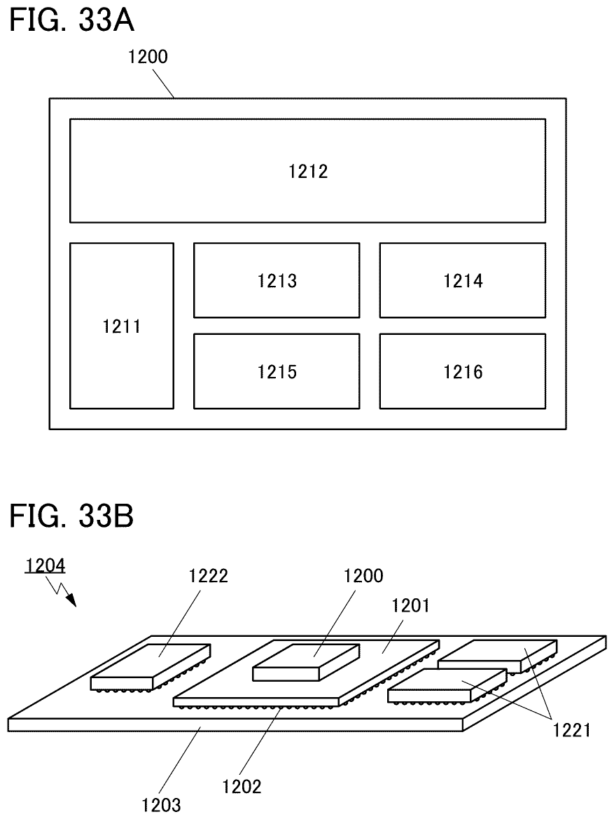

In this embodiment, an example of a chip on which a memory device of one embodiment of the present invention is mounted will be described with reference to FIG. 33A and FIG. 33B.

A plurality of circuits (systems) are mounted on a chip 1200 illustrated in FIG. 33A and FIG. 33B. A technique for integrating a plurality of circuits (systems) into one chip is referred to as system on chip (SoC) in some cases.

As illustrated in FIG. 33A, the chip 1200 includes a CPU 1211, a GPU 1212, one or a plurality of analog arithmetic units 1213, one or a plurality of memory controllers 1214, one or a plurality of interfaces 1215, one or a plurality of network circuits 1216, and the like.

The chip 1200 is provided with a bump (not illustrated) and is connected to a first surface of a package substrate 1201 as illustrated in FIG. 33B. A plurality of bumps 1202 are provided on a rear side of the first surface of the package substrate 1201, and the package substrate 1201 is connected to a motherboard 1203.

Memory devices such as a DRAM 1221 and a flash memory 1222 may be provided over the motherboard 1203. For example, the DOSRAM described in the above embodiment can be used as the DRAM 1221. This can make the DRAM 1221 have low power consumption, operate at high speed, and have a high capacity.

The CPU 1211 preferably includes a plurality of CPU cores. The GPU 1212 preferably includes a plurality of GPU cores. The CPU 1211 and the GPU 1212 may each include a memory for temporarily storing data. Alternatively, a common memory for the CPU 1211 and the GPU 1212 may be provided in the chip 1200. The DOSRAM described above can be used as the memory. The GPU 1212 is suitable for parallel computation of a large number of pieces of data and thus can be used for image processing or product-sum operation. When an image processing circuit or a product-sum operation circuit using the OS transistor described in the above embodiment is provided in the GPU 1212, image processing or product-sum operation can be performed with low power consumption.

Since the CPU 1211 and the GPU 1212 are provided in the same chip, a wiring between the CPU 1211 and the GPU 1212 can be shortened; accordingly, data transfer from the CPU 1211 to the GPU 1212, data transfer between memories included in the CPU 1211 and the GPU 1212, and transfer of arithmetic operation results from the GPU 1212 to the CPU 1211 after the arithmetic operation in the GPU 1212 can be performed at high speed.

The analog arithmetic unit 1213 includes one or both of an A/D (analog/digital) converter circuit and a D/A (digital/analog) converter circuit. Furthermore, the product-sum operation circuit may be provided in the analog arithmetic unit 1213.

The memory controller 1214 includes a circuit functioning as a controller of the DRAM 1221 and a circuit functioning as an interface of the flash memory 1222.

The interface 1215 includes an interface circuit for an external connection device such as a display device, a speaker, a microphone, a camera, or a controller. Examples of the controller include a mouse, a keyboard, and a game controller. As such an interface, a USB (Universal Serial Bus), an HDMI (registered trademark) (High-Definition Multimedia Interface), or the like can be used.

The network circuit 1216 includes a network circuit for a LAN (Local Area Network) or the like. The network circuit 1216 may also include a circuit for network security.

The circuits (systems) can be formed in the chip 1200 through the same manufacturing process. Therefore, even when the number of circuits needed for the chip 1200 increases, there is no need to increase the number of steps in the manufacturing process; thus, the chip 1200 can be fabricated at low cost.

The motherboard 1203 provided with the package substrate 1201 on which the chip 1200 including the GPU 1212 is mounted, the DRAMs 1221, and the flash memory 1222 can be referred to as a GPU module 1204.

The GPU module 1204 includes the chip 1200 using SoC technology, and thus can have a small size. In addition, the GPU module 1204 excels in image processing, and thus is suitably used in a portable electronic device such as a smartphone, a tablet terminal, a laptop PC, or a portable (mobile) game machine. Furthermore, the product-sum operation circuit using the GPU 1212 can execute a method such as a deep neural network (DNN), a convolutional neural network (CNN), a recurrent neural network (RNN), an autoencoder, a deep Boltzmann machine (DBM), or a deep belief network (DBN); hence, the chip 1200 can be used as an AI chip or the GPU module 1204 can be used as an AI system module.

This embodiment can be combined with any of the other embodiments as appropriate.

### Embodiment 6

This embodiment will describe an electronic component, an electronic device, a large computer, space equipment, and a data center (also referred to as a DC) in which the semiconductor device described in the above embodiment can be used. An electronic component, an electronic device, a large computer, space equipment, and a data center in which the semiconductor device of one embodiment of the present invention is used are effective in improving performance, e.g., reducing power consumption.

### [Electronic Component]

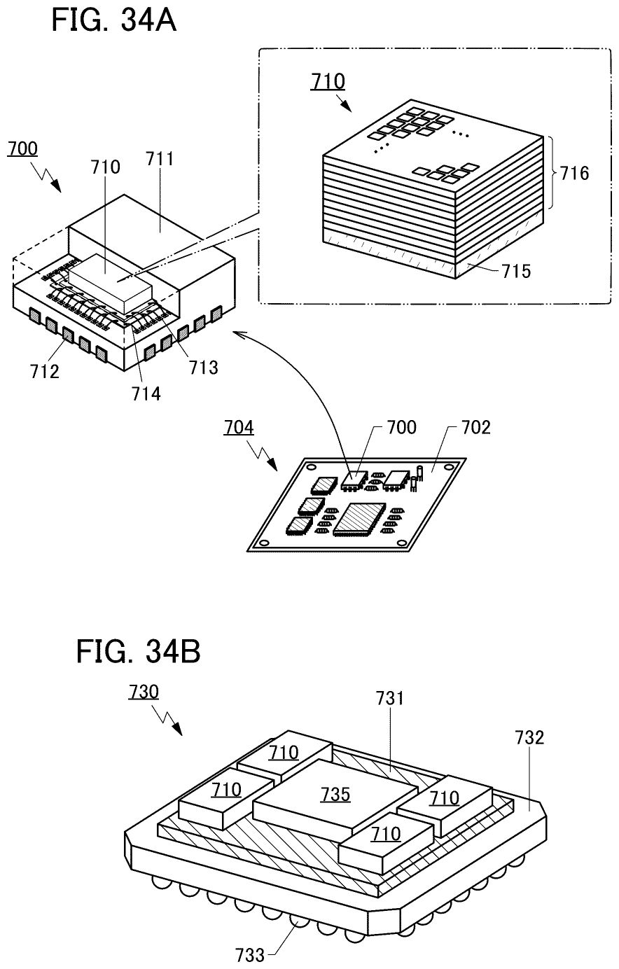

FIG. 34A is a perspective view of a substrate (a circuit board 704) on which an electronic component 700 is mounted. The electronic component 700 illustrated in FIG. 34A includes a semiconductor device 710 in a mold 711. Some components are omitted in FIG. 34A to show the inside of the electronic component 700. The electronic component 700 includes a land 712 outside the mold 711. The land 712 is electrically connected to an electrode pad 713, and the electrode pad 713 is electrically connected to the semiconductor device 710 through a wire 714. The electronic component 700 is mounted on a printed circuit board 702, for example. A plurality of such electronic components are combined and electrically connected to each other on the printed circuit board 702, which forms the circuit board 704.

The semiconductor device 710 includes a driver circuit layer 715 and a memory layer 716. The memory layer 716 has a structure in which a plurality of memory cell arrays are stacked. A stacked-layer structure of the driver circuit layer 715 and the memory layer 716 can be a monolithic stacked-layer structure. In the monolithic stacked-layer structure, layers can be connected to each other without using a through electrode technique such as a TSV (Through Silicon Via) and a bonding technique such as Cu-to-Cu direct bonding. The monolithic stacked-layer structure of the driver circuit layer 715 and the memory layer 716 enables, for example, what is called an on-chip memory structure in which a memory is directly formed on a processor. The on-chip memory structure allows an interface portion between the processor and the memory to operate at high speed.

With the on-chip memory structure, the sizes of a connection wiring and the like can be smaller than those in the case where the through electrode technique such as the TSV is employed; thus, the number of connection pins can be increased. An increase in the number of connection pins enables parallel operations, which can increase the bandwidth of the memory (also referred to as a memory bandwidth).

It is preferable that the plurality of memory cell arrays included in the memory layer 716 be formed using OS transistors and the plurality of memory cell arrays be monolithically stacked. Monolithically stacking the plurality of memory cell arrays can improve one or both of a memory bandwidth and a memory access latency. Note that a bandwidth refers to a data transfer volume per unit time, and an access latency refers to time from access to start of data transmission. In the case where the memory layer 716 is formed using Si transistors, it is difficult to obtain the monolithic stacked-layer structure as compared with the case where the memory layer 716 is formed using OS transistors. Thus, an OS transistor is advantageous over a Si transistor in the monolithic stacked-layer structure.

The semiconductor device 710 may be referred to as a die. In this specification and the like, a die refers to each of chip pieces obtained by dividing a circuit pattern formed on a circular substrate (also referred to as a wafer) or the like into dice in the manufacturing process of a semiconductor chip, for example. Examples of semiconductor materials that can be used for the die include silicon (Si), silicon carbide (SiC), and gallium nitride (GaN). A die obtained from a silicon substrate (also referred to as a silicon wafer) may be referred to as a silicon die, for example.

Next, FIG. 34B is a perspective view of an electronic component 730. The electronic component 730 is an example of a SiP (System in Package) or an MCM (Multi Chip Module). In the electronic component 730, an interposer 731 is provided over a package substrate 732 (printed circuit board), and a semiconductor device 735 and a plurality of the semiconductor devices 710 are provided over the interposer 731.

The electronic component 730 using the semiconductor device 710 as a high bandwidth memory (HBM) is illustrated as an example. The semiconductor device 735 can be used for an integrated circuit such as a CPU (Central Processing Unit), a GPU (Graphics Processing Unit), or an FPGA (Field Programmable Gate Array).

As the package substrate 732, a ceramic substrate, a plastic substrate, or a glass epoxy substrate can be used, for example. As the interposer 731, a silicon interposer or a resin interposer can be used, for example.

The interposer 731 includes a plurality of wirings and has a function of electrically connecting a plurality of integrated circuits with different terminal pitches. The plurality of wirings are provided in a single layer or multiple layers. In addition, the interposer 731 has a function of electrically connecting an integrated circuit provided on the interposer 731 to an electrode provided on the package substrate 732. Accordingly, the interposer is referred to as a “redistribution substrate” or an “intermediate substrate” in some cases. Furthermore, a through electrode is provided in the interposer 731 and the through electrode is used to electrically connect an integrated circuit and the package substrate 732 in some cases. In the case of a silicon interposer, a TSV can also be used as the through electrode.

An HBM needs to be connected to many wirings to achieve a wide memory bandwidth. Therefore, an interposer on which an HBM is mounted requires minute and densely formed wirings. For this reason, a silicon interposer is preferably used as the interposer on which an HBM is mounted.

In a SiP, an MCM, and the like using a silicon interposer, a decrease in reliability due to a difference in expansion coefficient between an integrated circuit and the interposer is less likely to occur. Furthermore, a surface of a silicon interposer has high planarity; thus, poor connection between the silicon interposer and an integrated circuit provided on the silicon interposer is less likely to occur. It is particularly preferable to use a silicon interposer for a 2.5D package (2.5-dimensional mounting) in which a plurality of integrated circuits are arranged side by side on the interposer.

Meanwhile, in the case where a plurality of integrated circuits with different terminal pitches are electrically connected to each other using a silicon interposer, a TSV, and the like, a space for the width of the terminal pitches and the like is needed. Thus, in the case where the size of the electronic component 730 is to be reduced, the width of the terminal pitches causes a problem, which sometimes makes it difficult to provide many wirings for achieving a wide memory bandwidth. For this reason, the above-described monolithic stacked-layer structure using OS transistors is suitable. A composite structure combining memory cell arrays stacked using a TSV and monolithically stacked memory cell arrays may be employed.

A heat sink (a radiator plate) may be provided to overlap with the electronic component 730. In the case of providing a heat sink, the heights of integrated circuits provided on the interposer 731 are preferably equal to each other. For example, in the electronic component 730 described in this embodiment, the heights of the semiconductor devices 710 and the semiconductor device 735 are preferably equal to each other.

To mount the electronic component 730 on another substrate, an electrode 733 may be provided on a bottom portion of the package substrate 732. FIG. 34B illustrates an example in which the electrode 733 is formed of a solder ball. Solder balls are provided in a matrix on the bottom portion of the package substrate 732, so that BGA (Ball Grid Array) mounting can be achieved. Alternatively, the electrode 733 may be formed of a conductive pin. Conductive pins are provided in a matrix on the bottom portion of the package substrate 732, so that PGA (Pin Grid Array) mounting can be achieved.

The electronic component 730 can be mounted on another substrate by any of various mounting methods not limited to BGA or PGA. Examples of a mounting method include an SPGA (Staggered Pin Grid Array), an LGA (Land Grid Array), a QFP (Quad Flat Package), a QFJ (Quad Flat J-leaded package), and a QFN (Quad Flat Non-leaded package).

### [Electronic Device]

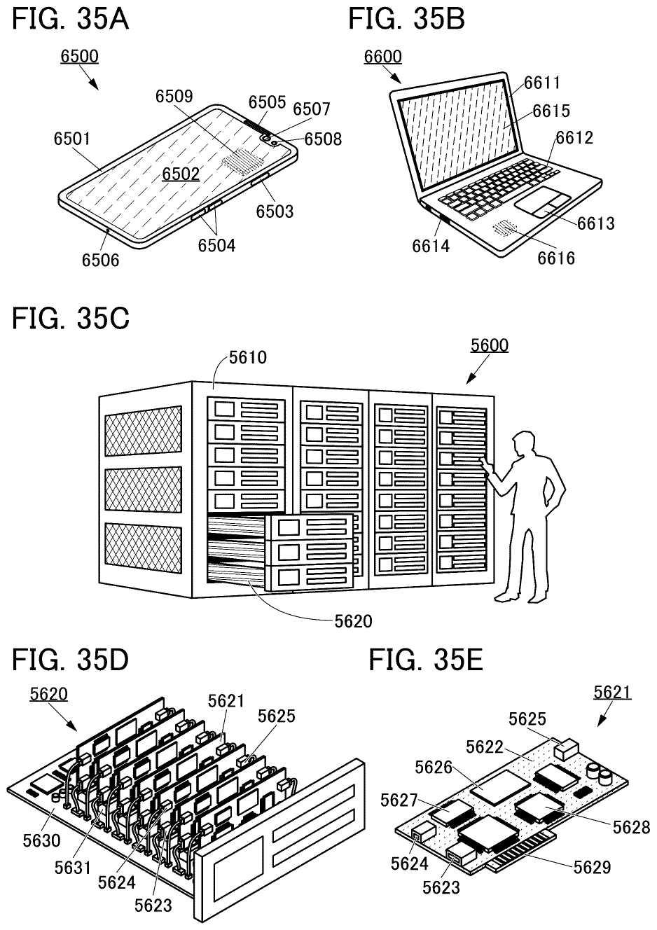

Next, FIG. 35A is a perspective view of an electronic device 6500. The electronic device 6500 illustrated in FIG. 35A is a portable information terminal that can be used as a smartphone. The electronic device 6500 includes a housing 6501, a display portion 6502, a power button 6503, buttons 6504, a speaker 6505, a microphone 6506, a camera 6507, a light source 6508, a control device 6509, and the like. One or more selected from a CPU, a GPU, and a memory device are provided as the control device 6509, for example. The semiconductor device of one embodiment of the present invention can be used for the display portion 6502, the control device 6509, and the like.

An electronic device 6600 illustrated in FIG. 35B is an information terminal that can be used as a laptop personal computer. The electronic device 6600 includes a housing 6611, a keyboard 6612, a pointing device 6613, an external connection port 6614, a display portion 6615, a control device 6616, and the like. One or more selected from a CPU, a GPU, and a memory device are provided as the control device 6616, for example. The semiconductor device of one embodiment of the present invention can be used for the display portion 6615, the control device 6616, and the like. Note that the semiconductor device of one embodiment of the present invention is preferably used for the control device 6509 and the control device 6616, in which case power consumption can be reduced.

### [Large Computer]

FIG. 35C is a perspective view of a large computer 5600. In the large computer 5600 illustrated in FIG. 35C, a plurality of rack mount computers 5620 are stored in a rack 5610. Note that the large computer 5600 may be referred to as a supercomputer.

The computer 5620 can have a structure in a perspective view of FIG. 35D, for example. In FIG. 35D, the computer 5620 includes a motherboard 5630, and the motherboard 5630 includes a plurality of slots 5631 and a plurality of connection terminals. A PC card 5621 is inserted in the slot 5631. In addition, the PC card 5621 includes a connection terminal 5623, a connection terminal 5624, and a connection terminal 5625, each of which is connected to the motherboard 5630.

The PC card 5621 illustrated in FIG. 35E is an example of a processing board provided with a CPU, a GPU, a memory device, and the like. The PC card 5621 includes a board 5622. The board 5622 includes the connection terminal 5623, the connection terminal 5624, the connection terminal 5625, a semiconductor device 5626, a semiconductor device 5627, a semiconductor device 5628, and a connection terminal 5629. Note that FIG. 35E also illustrates semiconductor devices other than the semiconductor device 5626, the semiconductor device 5627, and the semiconductor device 5628; the following description of the semiconductor device 5626, the semiconductor device 5627, and the semiconductor device 5628 can be referred to for these semiconductor devices.

The connection terminal 5629 has a shape with which the connection terminal 5629 can be inserted in the slot 5631 of the motherboard 5630, and the connection terminal 5629 functions as an interface for connecting the PC card 5621 and the motherboard 5630. An example of the standard for the connection terminal 5629 is PCIe.

The connection terminal 5623, the connection terminal 5624, and the connection terminal 5625 can each serve as, for example, an interface for performing power supply, signal input, or the like to the PC card 5621. For another example, they can each serve as an interface for outputting a signal calculated by the PC card 5621. Examples of the standard for each of the connection terminal 5623, the connection terminal 5624, and the connection terminal 5625 include USB, SATA (Serial ATA), and SCSI (Small Computer System Interface). In the case where video signals are output from the connection terminal 5623, the connection terminal 5624, and the connection terminal 5625, an example of the standard therefor is HDMI (registered trademark).

The semiconductor device 5626 includes a terminal (not illustrated) for inputting and outputting signals, and when the terminal is inserted in a socket (not illustrated) of the board 5622, the semiconductor device 5626 and the board 5622 can be electrically connected to each other.

The semiconductor device 5627 includes a plurality of terminals, and when the terminals are reflow-soldered, for example, to wirings of the board 5622, the semiconductor device 5627 and the board 5622 can be electrically connected to each other. Examples of the semiconductor device 5627 include an FPGA, a GPU, and a CPU. As the semiconductor device 5627, the electronic component 730 can be used, for example.

The semiconductor device 5628 includes a plurality of terminals, and when the terminals are reflow-soldered, for example, to wirings of the board 5622, the semiconductor device 5628 and the board 5622 can be electrically connected to each other. An example of the semiconductor device 5628 is a memory device. As the semiconductor device 5628, the electronic component 700 can be used, for example.

The large computer 5600 can also function as a parallel computer. When the large computer 5600 is used as a parallel computer, large-scale computation necessary for artificial intelligence learning and inference can be performed, for example.

### [Space Equipment]

The semiconductor device of one embodiment of the present invention can be suitably used as space equipment such as equipment that processes and stores information.

The semiconductor device of one embodiment of the present invention can include an OS transistor. A change in electrical characteristics of the OS transistor due to radiation irradiation is small. That is, the OS transistor is highly resistant to radiation and thus can be suitably used in an environment where radiation can enter. For example, the OS transistor can be suitably used in outer space.

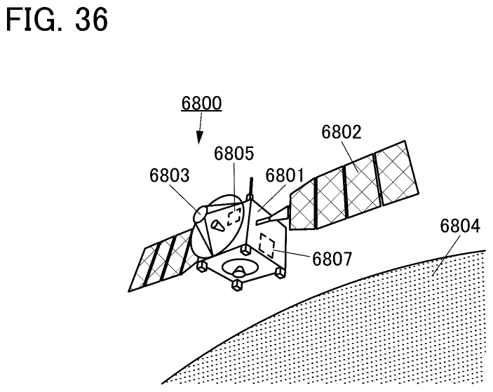

FIG. 36 illustrates an artificial satellite 6800 as an example of space equipment. The artificial satellite 6800 includes a body 6801, a solar panel 6802, an antenna 6803, a secondary battery 6805, and a control device 6807. FIG. 36 illustrates a planet 6804 in outer space, for example. Note that outer space refers to, for example, space at an altitude of 100 km or higher, and outer space in this specification can also include thermosphere, mesosphere, and stratosphere.

Although not illustrated in FIG. 36, a battery management system (also referred to as BMS) or a battery control circuit may be provided in the secondary battery 6805. The battery management system or the battery control circuit preferably includes an OS transistor, in which case power consumption is low and high reliability is achieved even in outer space.

The amount of radiation in outer space is 100 or more times that on the ground. Examples of radiation include electromagnetic waves (electromagnetic radiation) typified by X-rays and gamma rays and particle radiation typified by alpha rays, beta rays, neutron beams, proton beams, heavy-ion beams, and meson beams.

When the solar panel 6802 is illuminated with sunlight, electric power required for an operation of the artificial satellite 6800 is generated. However, for example, in the situation where the solar panel is not illuminated with sunlight or the amount of sunlight with which the solar panel is illuminated is small, the amount of generated electric power is small. Accordingly, electric power required for an operation of the artificial satellite 6800 might not be generated. In order to operate the artificial satellite 6800 even with a small amount of generated electric power, the artificial satellite 6800 is preferably provided with the secondary battery 6805. Note that a solar panel is referred to as a solar cell module in some cases.

The artificial satellite 6800 can generate a signal. The signal is transmitted through the antenna 6803, and the signal can be received by a ground-based receiver or another artificial satellite, for example. When the signal transmitted by the artificial satellite 6800 is received, the position of a receiver that receives the signal can be measured. Thus, the artificial satellite 6800 can constitute a satellite positioning system.

The control device 6807 has a function of controlling the artificial satellite 6800. The control device 6807 is formed using one or more selected from a CPU, a GPU, and a memory device, for example. Note that the semiconductor device of one embodiment of the present invention is suitably used for the control device 6807. A change in electrical characteristics due to radiation irradiation is smaller in an OS transistor than in a Si transistor. That is, the OS transistor has high reliability and thus can be suitably used even in an environment where radiation can enter.

The artificial satellite 6800 can include a sensor. For example, with a structure including a visible light sensor, the artificial satellite 6800 can have a function of sensing sunlight reflected by a ground-based object. Alternatively, with a structure including a thermal infrared sensor, the artificial satellite 6800 can have a function of sensing thermal infrared rays emitted from the surface of the earth. Thus, the artificial satellite 6800 can function as an earth observing satellite, for example.

Although the artificial satellite is described as an example of space equipment in this embodiment, one embodiment of the present invention is not limited thereto. For example, the semiconductor device of one embodiment of the present invention can be suitably used for space equipment such as a spacecraft, a space capsule, or a space probe.

As described above, the OS transistor has advantageous effects over the Si transistor, such as a wide memory bandwidth and high radiation resistance.

### [Data Center]

The semiconductor device of one embodiment of the present invention can be suitably used for a storage system in a data center or the like, for example. Long-term data management, such as guarantee of data immutability, is required for the data center. In the case where data is managed for a long term, it is necessary to increase the scale of the data center for installation of storages and servers for storing an enormous amount of data, stable electric power for data retention, cooling equipment for data retention, or the like.

With the use of the semiconductor device of one embodiment of the present invention for the storage system used in the data center, electric power required for data retention can be reduced and a semiconductor device retaining data can be downsized. Thus, downsizing of the storage system, downsizing of a power source for data retention, downscaling of the cooling equipment, and the like can be achieved. This can reduce the space of the data center.

Since the semiconductor device of one embodiment of the present invention has low power consumption, heat generation from a circuit can be reduced. Accordingly, it is possible to reduce adverse effects of the heat generation on the circuit itself, a peripheral circuit, and a module. Furthermore, the use of the semiconductor device of one embodiment of the present invention enables a data center that operates stably even in a high-temperature environment. Thus, the reliability of the data center can be increased.

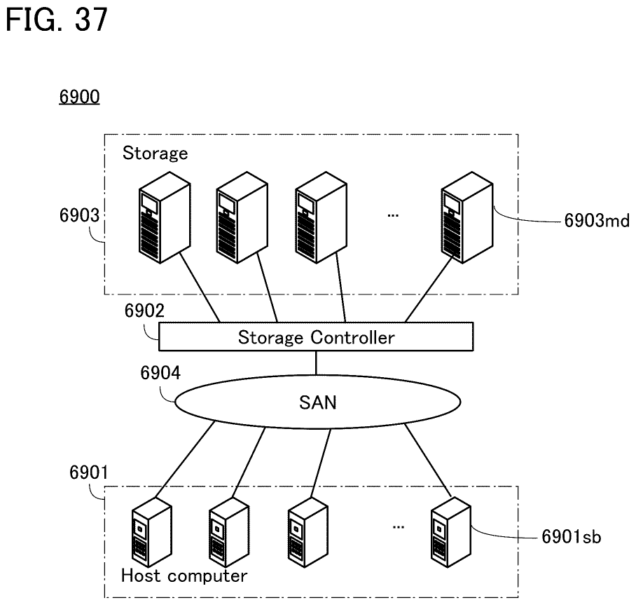

FIG. 37 illustrates a storage system that can be used in a data center. A storage system 6900 illustrated in FIG. 37 includes a plurality of servers 6901sb as a host 6901 (indicated as “Host Computer” in the diagram). The storage system 6900 includes a plurality of memory devices 6903md as a storage 6903 (indicated as “Storage” in the diagram). In the illustrated mode, the host 6901 and the storage 6903 are connected to each other through a storage area network 6904 (indicated as “SAN” in the diagram) and a storage control circuit 6902 (indicated as “Storage Controller” in the diagram).

The host 6901 corresponds to a computer that accesses data stored in the storage 6903. The host 6901 may be connected to another host 6901 through a network.

The data access speed, i.e., the time taken for storing and outputting data, of the storage 6903 is shortened by using a flash memory, but is still considerably longer than the data access speed of a DRAM that can be used as a cache memory in a storage. In the storage system, in order to solve the problem of low access speed of the storage 6903, a cache memory is normally provided in the storage to shorten the time required for data storage and output.

The above-described cache memory is used in the storage control circuit 6902 and the storage 6903. Data transmitted between the host 6901 and the storage 6903 is stored in the cache memory in the storage control circuit 6902 and the storage 6903 and then output to the host 6901 or the storage 6903.

The use of an OS transistor as a transistor for storing data in the cache memory to retain a potential corresponding to data can reduce the frequency of refreshing, so that power consumption can be reduced. Furthermore, downsizing is possible by stacking memory cell arrays.

The use of the semiconductor device of one embodiment of the present invention for one or more selected from an electronic component, an electronic device, a large computer, space equipment, and a data center will produce an effect of reducing power consumption. While the demand for energy is expected to increase with higher performance or higher integration of semiconductor devices, the emission amount of greenhouse effect gases typified by carbon dioxide (CO₂) can be reduced with the use of the semiconductor device of one embodiment of the present invention. Furthermore, the semiconductor device of one embodiment of the present invention has low power consumption and thus is effective as a global warming countermeasure.

The configuration, structure, method, or the like described in this embodiment can be used in combination with the configuration, structure, method, or the like described in any of the other embodiments and the like as appropriate.

### Embodiment 7

This embodiment will describe structure examples of a display device that can use the transistor of one embodiment of the present invention.

Since the transistor of one embodiment of the present invention can be extremely minute, a display device using the transistor of one embodiment of the present invention can have an extremely high resolution. For example, a display device of one embodiment of the present invention can be used for display portions of information terminals (wearable devices) such as watch-type and bracelet-type information terminals and display portions of devices capable of being worn on a head, such as VR devices like head-mounted displays (HMIDs) and glasses-type AR devices.

### [Display Module]

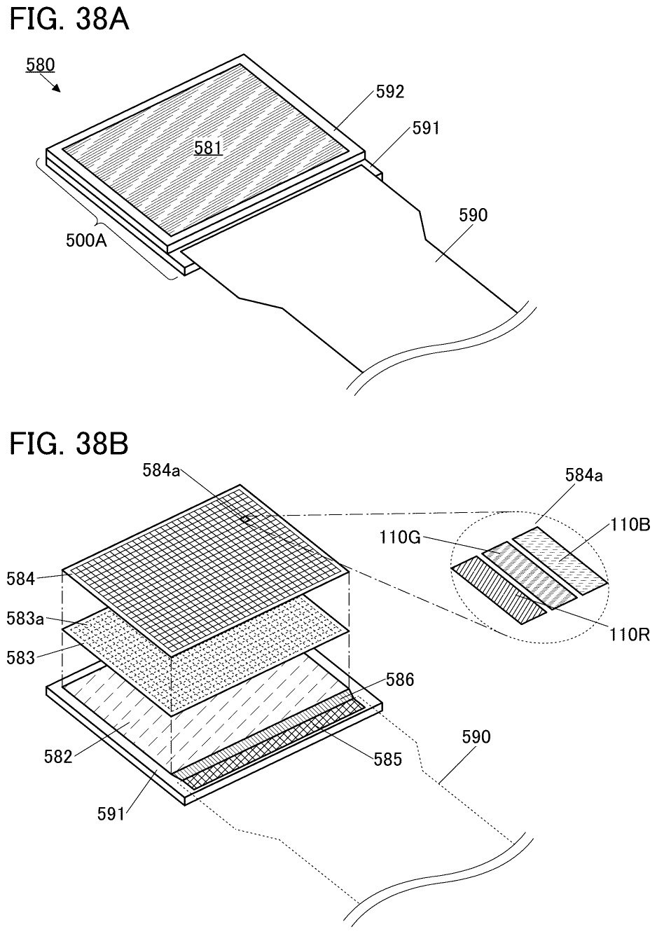

FIG. 38A is a perspective view of a display module 580. The display module 580 includes a display device 500A and an FPC 590. Note that a display panel included in the display module 580 is not limited to the display device 500A and may be either a display device 500B or a display device 500C described later.

The display module 580 includes a substrate 591 and a substrate 592. The display module 580 includes a display portion 581. The display portion 581 is a region where an image is displayed.

FIG. 38B is a perspective view schematically illustrating a structure on the substrate 591 side. Over the substrate 591, a circuit portion 582, a pixel circuit portion 583 over the circuit portion 582, and a pixel portion 584 over the pixel circuit portion 583 are stacked. A terminal portion 585 to be connected to the FPC 590 is provided over the substrate 591 in a portion that does not overlap with the pixel portion 584. The terminal portion 585 and the circuit portion 582 are electrically connected to each other through a wiring portion 586 formed of a plurality of wirings.

The pixel portion 584 includes a plurality of pixels 584a arranged periodically. An enlarged view of one pixel 584a is illustrated on the right side in FIG. 38B. The pixel 584a includes a light-emitting element 110R that emits red light, a light-emitting element 110G that emits green light, and a light-emitting element 110B that emits blue light.

The pixel circuit portion 583 includes a plurality of pixel circuits 583a arranged periodically. One pixel circuit 583a is a circuit for controlling light emission of three light-emitting devices included in one pixel 584a. One pixel circuit 583a may be provided with three circuits each controlling light emission of one light-emitting device. For example, the pixel circuit 583a can include at least one selection transistor, one current control transistor (driving transistor), and a capacitor for one light-emitting device. In that case, a gate signal is input to a gate of the selection transistor, and a source signal is input to a source of the selection transistor. Thus, an active-matrix display panel is achieved.

The circuit portion 582 includes a circuit for driving the pixel circuits 583a in the pixel circuit portion 583. For example, the circuit portion 582 preferably includes one or both of a gate line driver circuit and a source line driver circuit. The circuit portion 582 may also include at least one of an arithmetic circuit, a memory circuit, a power supply circuit, and the like. In addition, a transistor provided in the circuit portion 582 may constitute part of the pixel circuit 583a. That is, the pixel circuit 583a may be constituted by a transistor included in the pixel circuit portion 583 and a transistor included in the circuit portion 582.

The FPC 590 functions as a wiring for supplying a video signal, a power supply potential, and the like to the circuit portion 582 from the outside. An IC may be mounted on the FPC 590.

The display module 580 can have a structure in which one or both of the pixel circuit portion 583 and the circuit portion 582 are provided to be stacked below the pixel portion 584; thus, the aperture ratio (effective display area ratio) of the display portion 581 can be significantly high. For example, the aperture ratio of the display portion 581 can be greater than or equal to 40% and less than 100%, preferably greater than or equal to 50% and less than or equal to 95%, further preferably greater than or equal to 60% and less than or equal to 95%. Furthermore, the pixels 584a can be arranged extremely densely and thus the display portion 581 can have an extremely high resolution. For example, the pixels 584a are preferably arranged in the display portion 581 with a resolution higher than or equal to 2000 ppi, preferably higher than or equal to 3000 ppi, further preferably higher than or equal to 5000 ppi, still further preferably higher than or equal to 6000 ppi, and lower than or equal to 20000 ppi or lower than or equal to 30000 ppi.

Such a display module 580 has an extremely high resolution, and thus can be suitably used for a VR device such as a head-mounted display or a glasses-type AR device. For example, even with a structure in which the display portion of the display module 580 is seen through a lens, pixels of the extremely-high-resolution display portion 581 included in the display module 580 are prevented from being perceived when the display portion is magnified by the lens, so that display providing a high sense of immersion can be performed. Without being limited thereto, the display module 580 can be suitably used for electronic devices including a relatively small display portion. For example, the display module 580 can be suitably used for a display portion of a wearable electronic device such as a wristwatch.

### [Display Device 500A]

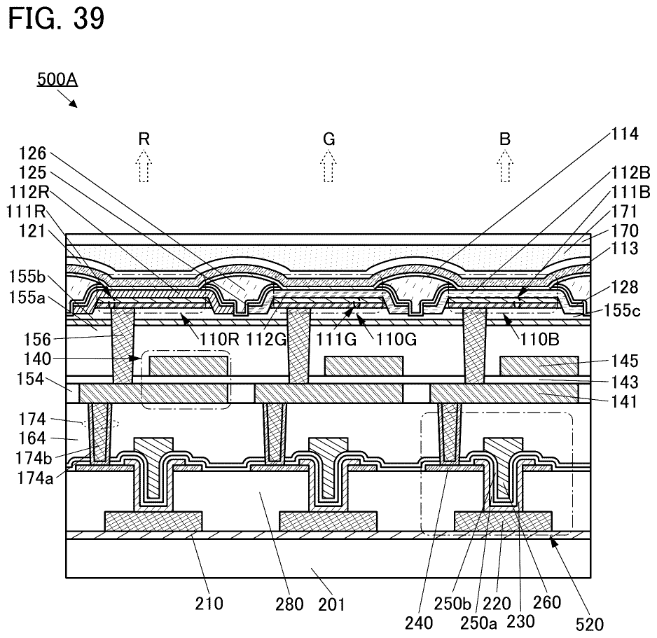

The display device 500A illustrated in FIG. 39 includes a substrate 201, the light-emitting element 110R, the light-emitting element 110G, the light-emitting element 110B, a capacitor 140, and a transistor 520.

The substrate 201 corresponds to the substrate 591 in FIG. 38A.

The transistor 520 is a vertical-channel transistor using an oxide semiconductor as a semiconductor layer where a channel is formed. The transistor 520 includes the semiconductor layer 230, the insulating layer 250a, the insulating layer 250b, the conductive layer 260, the conductive layer 240, the conductive layer 220, and the like.

As the transistor 520, a variety of transistors exemplified in Embodiment 2 or Embodiment 3 can be used.

The insulating layer 210 is provided over the substrate 201. The insulating layer 210 functions as a barrier layer that prevents diffusion of impurities such as water and hydrogen from the substrate 201 into the transistor 520 and release of oxygen from the semiconductor layer 230 to the insulating layer 210 side. As the insulating layer 210, for example, a film in which hydrogen or oxygen is less likely to diffuse than in a silicon oxide film, such as an aluminum oxide film, a hafnium oxide film, or a silicon nitride film, can be used.

The conductive layer 220 is provided over the insulating layer 210, the insulating layer 280 is provided over the insulating layer 210 and the conductive layer 220, and the conductive layer 240 is provided over the insulating layer 280. An opening is provided in the insulating layer 280, and the semiconductor layer 230, the insulating layer 250a, the insulating layer 250b, and the conductive layer 260 are provided in the opening. An insulating layer 164 is provided to cover the conductive layer 260.

The insulating layer 164 functions as an interlayer insulating layer. A barrier layer that prevents diffusion of impurities such as water and hydrogen from the insulating layer 164 or the like into the transistor 520 may be provided between the insulating layer 164 and an insulating layer 154. As the barrier layer, an insulating film similar to the insulating layer 210 can be used.

A plug 174 electrically connected to one of the conductive layers 240 is provided to be embedded in the insulating layer 164. Here, the plug 174 preferably includes a conductive layer 174a that covers the side surface of the opening in the insulating layer 164 and part of the top surface of the conductive layer 240, and a conductive layer 174b in contact with the top surface of the conductive layer 174a. In that case, for the conductive layer 174a, a conductive material that does not easily allow diffusion of hydrogen and oxygen is preferably used.

The capacitor 140 is provided over the insulating layer 164. The capacitor 140 includes a conductive layer 141, a conductive layer 145, and an insulating layer 143 positioned therebetween. The conductive layer 141 functions as one electrode of the capacitor 140, the conductive layer 145 functions as the other electrode of the capacitor 140, and the insulating layer 143 functions as a dielectric of the capacitor 140.

The conductive layer 141 is provided over the insulating layer 164 and is embedded in the insulating layer 154. The conductive layer 141 is electrically connected to the conductive layer 240 in the transistor 520 through the plug 174. The insulating layer 143 is provided to cover the conductive layer 141. The conductive layer 145 is provided in a region overlapping with the conductive layer 141 with the insulating layer 143 therebetween.

An insulating layer 155a is provided to cover the capacitor 140, an insulating layer 155b is provided over the insulating layer 155a, and an insulating layer 155c is provided over the insulating layer 155b.

An inorganic insulating film can be suitably used as each of the insulating layer 155a, the insulating layer 155b, and the insulating layer 155c. For example, it is preferable that a silicon oxide film be used as each of the insulating layer 155a and the insulating layer 155c and a silicon nitride film be used as the insulating layer 155b. This enables the insulating layer 155b to function as an etching protective film. Although this embodiment describes an example in which the insulating layer 155c is partly etched and a depressed portion is formed, the depressed portion is not necessarily provided in the insulating layer 155c.

The light-emitting element 110R, the light-emitting element 110G, and the light-emitting element 110B are provided over the insulating layer 155c.

The light-emitting element 110R includes a pixel electrode 111R, an organic layer 112R, a common layer 114, and a common electrode 113. The light-emitting element 110G includes a pixel electrode 111G, an organic layer 112G, the common layer 114, and the common electrode 113. The light-emitting element 110B includes a pixel electrode 111B, an organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can also be referred to as an EL layer and includes at least a layer containing a light-emitting organic compound (a light-emitting layer).

Since the light-emitting devices of different colors are separately formed in the display device 500A, a difference in chromaticity between light emission at low luminance and light emission at high luminance is small. Furthermore, since the organic layers 112R, 112G, and 112B are apart from each other, crosstalk generated between adjacent subpixels can be inhibited even when the display panel has a high resolution. It is thus possible to achieve a display panel that has a high resolution and high display quality.

In a region between adjacent light-emitting elements, an insulating layer 125, a resin layer 126, and a layer 128 are provided.

The pixel electrode 111R, the pixel electrode 111G, and the pixel electrode 111B of the light-emitting elements are each electrically connected to the conductive layer 240 in the transistor 520 through a plug 156 that is embedded in the insulating layer 155a, the insulating layer 155b, and the insulating layer 155c, the conductive layer 141 that is embedded in the insulating layer 154, and the plug 174. The top surface of the insulating layer 155c and the top surface of the plug 156 are level with each other. A variety of conductive materials can be used for the plugs.

A protective layer 121 is provided over the light-emitting elements 110R, 110G, and 110B. A substrate 170 is attached onto the protective layer 121 with an adhesive layer 171.

An insulating layer covering the end portion of the top surface of the pixel electrode 111 is not provided between two adjacent pixel electrodes 111. Thus, the distance between adjacent light-emitting elements can be extremely short. Accordingly, the display device can have a high resolution or a high definition.

### [Display Device 500B]

A display device whose structure is partly different from the above-described structure will be described below. Note that the above description is referred to for portions common to the above and the description is omitted in some cases.

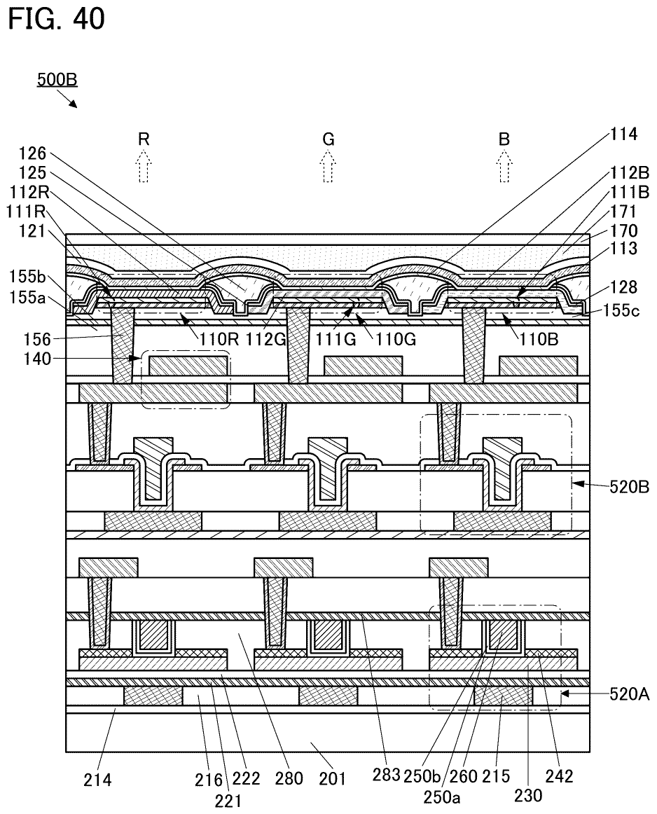

The display device 500B illustrated in FIG. 40 is an example in which a transistor 520A that is a planar transistor whose semiconductor layer is formed on a plane and a transistor 520B that is a vertical-channel transistor are stacked. The transistor 520B has a structure similar to that of the transistor 520 in the display device 500A.

The transistor 520A includes the semiconductor layer 230, the insulating layer 250a, the insulating layer 250b, the conductive layer 260, a pair of conductors 242, the insulating layer 222, the insulating layer 221, and the conductive layer 215.

The insulating layer 214 is provided over the substrate 201. The insulating layer 214 functions as a barrier layer that prevents diffusion of impurities such as water and hydrogen from the substrate 201 into the transistor 520 and release of oxygen from the semiconductor layer 230 to the insulating layer 214 side. As the insulating layer 214, for example, a film in which hydrogen or oxygen is less likely to diffuse than in a silicon oxide film, such as an aluminum oxide film, a hafnium oxide film, or a silicon nitride film, can be used.

The insulating layer 216 is provided over the insulating layer 214, the conductive layer 215 is provided to be embedded in the insulating layer 216, the insulating layer 221 is provided over the insulating layer 216 and the conductive layer 215, and the insulating layer 222 is provided over the insulating layer 221. The conductive layer 215 functions as a first gate electrode of the transistor 520A, and part of each of the insulating layer 221 and the insulating layer 222 functions as a first gate insulating layer. The top surface of the insulating layer 216 is preferably planarized.

The semiconductor layer 230 is provided over the insulating layer 222. The semiconductor layer 230 preferably includes a metal oxide (also referred to as oxide semiconductor) film exhibiting semiconductor characteristics. The pair of conductors 242 are provided over and in contact with the semiconductor layer 230, and function as a source electrode and a drain electrode.

The insulating layer 280 is provided to cover the top surfaces and the side surfaces of the pair of conductors 242, the side surface of the semiconductor layer 230, and the like. The insulating layer 280 functions as a barrier layer that prevents diffusion of impurities such as water and hydrogen into the semiconductor layer 230 and release of oxygen from the semiconductor layer 230.

An opening reaching the semiconductor layer 230 is provided in the insulating layer 280. The insulating layer 250a, the insulating layer 250b, and the conductive layer 260 are embedded in the opening. The insulating layer 250a is in contact with the top surface of the semiconductor layer 230. The conductive layer 260 functions as a second gate electrode, and the insulating layer 250a and the insulating layer 250b function as a second gate insulating layer.

The top surface of the conductive layer 260, the top surface of the insulating layer 250a, the top surface of the insulating layer 250b, and the top surface of the insulating layer 280 are subjected to planarization treatment so that the surfaces are level with each other, and the insulating layer 283 is provided to cover these surfaces. The insulating layer 283 functions as a barrier layer that prevents diffusion of impurities such as water and hydrogen into the transistor 520. As the insulating layer 283, an insulating film similar to the insulating layer 214 can be used.

The transistor 520 has a structure in which the semiconductor layer where a channel is formed is sandwiched between two gates. The two gates may be connected to each other and supplied with the same signal to drive the transistor. Alternatively, a potential for controlling the threshold voltage may be supplied to one of the two gates and a potential for driving may be supplied to the other of the two gates to control the threshold voltage of the transistor.

### [Display Device 500C]

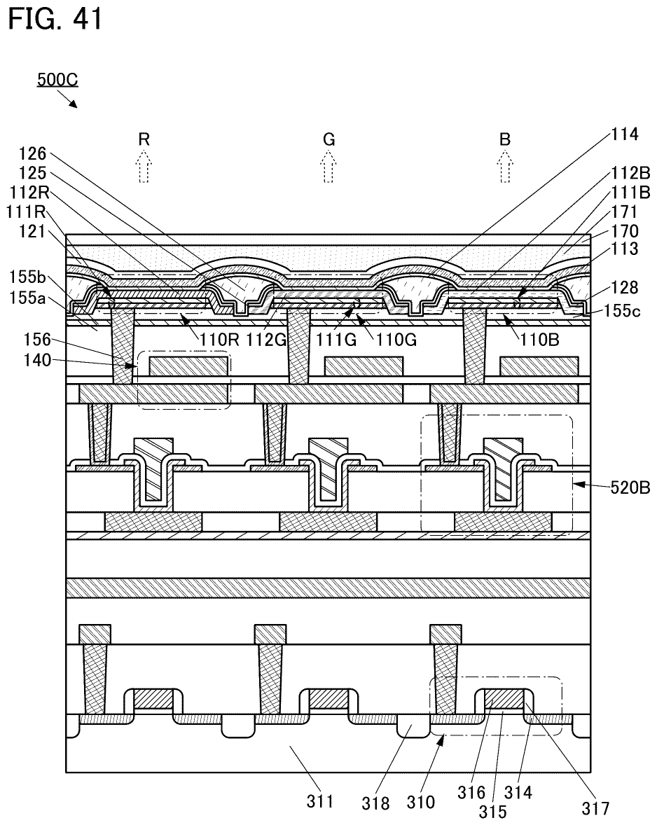

The display device 500C illustrated in FIG. 41 has a structure in which the transistor 310 whose channel is formed in a semiconductor substrate and the transistor 520 that is a vertical-channel transistor are stacked.

The transistor 310 is a transistor including a channel formation region in a substrate 311. As the substrate 311, a semiconductor substrate such as a single crystal silicon substrate can be used, for example. The transistor 310 includes part of the substrate 311, the conductive layer 316, the low-resistance regions 314, the insulating layer 315, and an insulating layer 317. The conductive layer 316 functions as a gate electrode. The insulating layer 315 is positioned between the substrate 311 and the conductive layer 316 and functions as a gate insulating layer. The low-resistance region 314 is a region where the substrate 311 is doped with an impurity, and functions as one of a source and a drain. The insulating layer 317 is provided to cover the side surface of the conductive layer 316.

An element isolation layer 318 is provided between two adjacent transistors 310 to be embedded in the substrate 311.

At least part of this embodiment can be implemented in combination with any of the other embodiments described in this specification as appropriate.

### Embodiment 8

This embodiment will describe structure examples of a display device that can be used as a display device manufactured using the transistor of one embodiment of the present invention. The display device exemplified below can be used for the pixel portion 584 in Embodiment 3, for example.

One embodiment of the present invention is a display device including a light-emitting element (also referred to as a light-emitting device). The display device includes two or more pixels of different emission colors. The pixels include light-emitting elements. The light-emitting elements each include a pair of electrodes and an EL layer therebetween. The light-emitting elements are preferably organic EL elements (organic electroluminescent elements). Two or more light-emitting elements of different emission colors include EL layers including different light-emitting materials. For example, when three kinds of light-emitting elements that emit red (R), green (G), and blue (B) light are included, a full-color display device can be achieved.

In the case of manufacturing a display device including a plurality of light-emitting elements of different emission colors, at least layers containing light-emitting materials (light-emitting layers) each need to be formed in an island shape. In the case of separately forming part or the whole of an EL layer, a method for forming an island-shaped organic film by an evaporation method using a shadow mask such as a metal mask is known. However, this method causes a deviation from the designed shape and position of the island-shaped organic film due to various influences such as the accuracy of the metal mask, the positional deviation between the metal mask and a substrate, a warp of the metal mask, and expansion of the outline of a formed film due to vapor scattering, for example; accordingly, it is difficult to achieve a high resolution and a high aperture ratio of the display device. In addition, the outline of the layer might blur during evaporation, so that the film thickness of an end portion might be reduced. That is, the film thickness of an island-shaped light-emitting layer might vary from place to place. In addition, in the case of manufacturing a display device with a large size, a high definition, or a high resolution, the manufacturing yield might be reduced because of low dimensional accuracy of the metal mask and deformation due to heat or the like. Thus, measures have been taken for a pseudo increase in resolution (also referred to as pixel density) by employing unique pixel arrangement such as PenTile arrangement.

In this specification and the like, the term “island shape” refers to a state where two or more layers formed using the same material in the same step are physically separated from each other. For example, the term “island-shaped light-emitting layer” refers to a state where the light-emitting layer and its adjacent light-emitting layer are physically separated from each other.

In one embodiment of the present invention, fine patterning of EL layers is performed by photolithography without using a shadow mask such as an FMM (Fine Metal Mask). Accordingly, it is possible to achieve a display device with a high resolution and a high aperture ratio, which has been difficult to achieve so far. Moreover, since the EL layers can be formed separately, it is possible to achieve a display device that performs extremely clear display with high contrast and high display quality. Note that fine patterning of the EL layers may be performed using both a metal mask and photolithography, for example.

In addition, part or the whole of the EL layer can be physically divided. This can inhibit leakage current flowing between adjacent light-emitting elements through a layer shared by the light-emitting elements (also referred to as a common layer). This can prevent unintended light emission due to crosstalk, so that a display device with extremely high contrast can be obtained. Specifically, a display device having high current efficiency at low luminance can be obtained.

In one embodiment of the present invention, the display device can also be obtained by combining a light-emitting element that emits white light with a color filter. In that case, light-emitting elements having the same structure can be used as light-emitting elements provided in pixels (subpixels) that emit light of different colors, which allows all the layers to be common layers. In addition, part or the whole of each EL layer may be divided by photolithography. Thus, leakage current through the common layer is inhibited; accordingly, a display device with high contrast can be achieved. In particular, when an element has a tandem structure in which a plurality of light-emitting layers are stacked with a highly conductive intermediate layer therebetween, leakage current through the intermediate layer can be effectively prevented, so that a display device with high luminance, high resolution, and high contrast can be achieved.

In the case where the EL layer is processed by a photolithography method, part of the light-emitting layer is sometimes exposed to cause deterioration. Thus, an insulating layer covering at least the side surface of the island-shaped light-emitting layer is preferably provided. The insulating layer may cover part of the top surface of the island-shaped EL layer. For the insulating layer, a material having a barrier property against water and oxygen is preferably used. For example, an inorganic insulating film that is less likely to diffuse water or oxygen can be used. This can inhibit deterioration of the EL layer and can achieve a highly reliable display device.

Moreover, between two adjacent light-emitting elements, there is a region (a depressed portion) where none of the EL layers of the light-emitting elements is provided. In the case where a common electrode or a common electrode and a common layer is/are formed to cover the depressed portion, a phenomenon where the common electrode is divided by a step at an end portion of the EL layer (such a phenomenon is also referred to as disconnection) might occur, which might cause insulation of the common electrode over the EL layer. In view of this, a structure is preferably employed in which a local gap positioned between two adjacent light-emitting elements is filled with a resin layer functioning as a planarization film (also referred to as LFP: Local Filling Planarization). The resin layer has a function of a planarization film. This structure can inhibit disconnection of the common layer or the common electrode and can achieve a highly reliable display device.

More specific structure examples of the display device of one embodiment of the present invention will be described below with reference to drawings.

### Structure Example 1

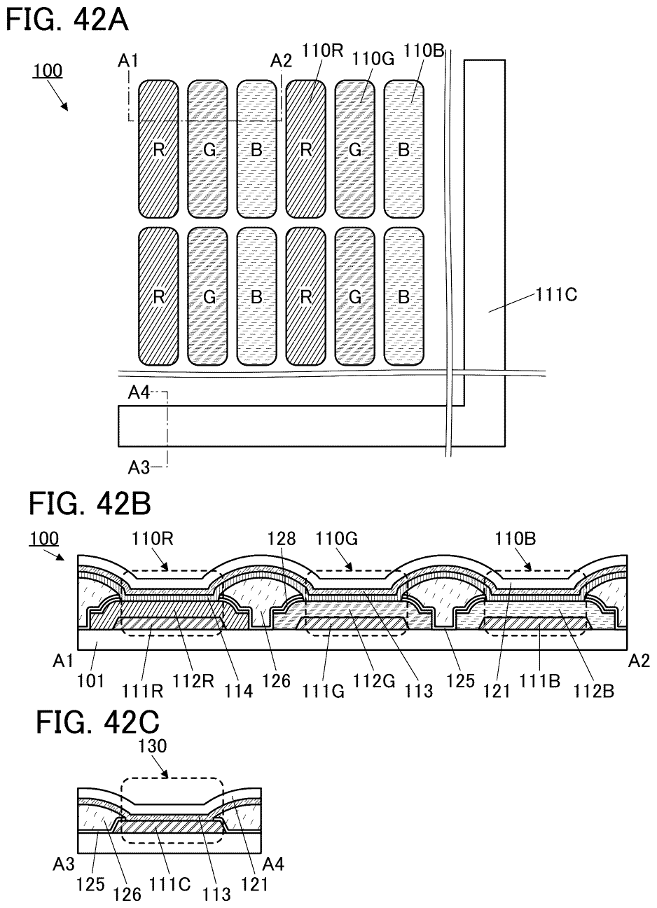

FIG. 42A is a schematic top view of a display device 100 of one embodiment of the present invention. The display device 100 includes, over a substrate 101, a plurality of the light-emitting elements 110R exhibiting red, a plurality of the light-emitting elements 110G exhibiting green, and a plurality of the light-emitting elements 110B exhibiting blue. In FIG. 42A, light-emitting regions of the light-emitting elements are denoted by R, G, and B to easily differentiate the light-emitting elements.

The light-emitting elements 110R, the light-emitting elements 110G, and the light-emitting elements 110B are arranged in a matrix. FIG. 42A illustrates what is called stripe arrangement, in which the light-emitting elements of the same color are arranged in one direction. Note that an arrangement method of the light-emitting elements is not limited thereto; an arrangement method such as S-stripe arrangement, delta arrangement, Bayer arrangement, or zigzag arrangement may be employed, or PenTile arrangement, diamond arrangement, or the like can also be used.

As each of the light-emitting elements 110R, the light-emitting elements 110G, and the light-emitting elements 110B, an OLED (Organic Light Emitting Diode) or a QLED (Quantum-dot Light Emitting Diode) is preferably used, for example. Examples of a light-emitting substance contained in the light-emitting element include a substance that emits fluorescent light (a fluorescent material), a substance that emits phosphorescent light (a phosphorescent material), and a substance that exhibits thermally activated delayed fluorescence (a thermally activated delayed fluorescent (TADF) material). As the light-emitting substance contained in the light-emitting element, not only an organic compound but also an inorganic compound (a quantum dot material or the like) can be used.

FIG. 42A also illustrates a connection electrode 111C electrically connected to the common electrode 113. The connection electrode 111C is supplied with a potential (e.g., an anode potential or a cathode potential) that is to be supplied to the common electrode 113. The connection electrode 111C is provided outside a display region where the light-emitting elements 110R and the like are arranged.

The connection electrode 111C can be provided along the outer periphery of the display region. For example, the connection electrode 111C may be provided along one side of the outer periphery of the display region, or the connection electrode 111C may be provided along two or more sides of the outer periphery of the display region. That is, in the case where the display region has a rectangular top surface shape, the top surface shape of the connection electrode 111C can be a band shape (a rectangle), an L shape, a U shape (a square bracket shape), a quadrangular shape, or the like. FIG. 42B and FIG. 42C are schematic cross-sectional views corresponding to the dashed-dotted line A1-A2 and the dashed-dotted line A3-A4 in FIG. 42A. FIG. 42B is a schematic cross-sectional view of the light-emitting element 110R, the light-emitting element 110G, and the light-emitting element 110B, and FIG. 42C is a schematic cross-sectional view of a connection portion 130 where the connection electrode 111C and the common electrode 113 are connected to each other.

The light-emitting element 110R includes the pixel electrode 111R, the organic layer 112R, the common layer 114, and the common electrode 113. The light-emitting element 110G includes the pixel electrode 111G, the organic layer 112G, the common layer 114, and the common electrode 113. The light-emitting element 110B includes the pixel electrode 111B, the organic layer 112B, the common layer 114, and the common electrode 113. The common layer 114 and the common electrode 113 are provided to be shared by the light-emitting element 110R, the light-emitting element 110G, and the light-emitting element 110B.

The organic layer 112R included in the light-emitting element 110R contains at least a light-emitting organic compound that emits red light. The organic layer 112G included in the light-emitting element 110G contains at least a light-emitting organic compound that emits green light. The organic layer 112B included in the light-emitting element 110B contains at least a light-emitting organic compound that emits blue light. Each of the organic layer 112R, the organic layer 112G, and the organic layer 112B can also be referred to as an EL layer and includes at least a layer containing a light-emitting organic compound (a light-emitting layer).

Hereinafter, the term “light-emitting element 110” is sometimes used to describe matters common to the light-emitting element 110R, the light-emitting element 110G, and the light-emitting element 110B. Similarly, in the description of matters common to components that are distinguished from each other using alphabets, such as the organic layer 112R, the organic layer 112G, and the organic layer 112B, reference numerals without alphabets are sometimes used.

The organic layer 112 and the common layer 114 can each independently include one or more of an electron-injection layer, an electron-transport layer, a hole-injection layer, and a hole-transport layer. For example, it is possible to employ a structure in which the organic layer 112 has a stacked-layer structure of a hole-injection layer, a hole-transport layer, a light-emitting layer, and an electron-transport layer from the pixel electrode 111 side and the common layer 114 includes an electron-injection layer.

The pixel electrode 111R, the pixel electrode 111G, and the pixel electrode 111B are provided for the respective light-emitting elements. The common electrode 113 and the common layer 114 are each provided as one continuous layer shared by the light-emitting elements. A conductive film having a light-transmitting property with respect to visible light is used for either the pixel electrodes or the common electrode 113, and a conductive film having a reflective property is used for the other. When the pixel electrodes have a light-transmitting property and the common electrode 113 has a reflective property, a bottom-emission display device can be obtained. By contrast, when the pixel electrodes have a reflective property and the common electrode 113 has a light-transmitting property, a top-emission display device can be obtained. Note that when both the pixel electrodes and the common electrode 113 have a light-transmitting property, a dual-emission display device can be obtained.

The protective layer 121 is provided over the common electrode 113 to cover the light-emitting element 110R, the light-emitting element 110G, and the light-emitting element 110B. The protective layer 121 has a function of preventing diffusion of impurities such as water into the light-emitting elements from the above.

The end portion of the pixel electrode 111 preferably has a tapered shape. In the case where the end portion of the pixel electrode 111 has a tapered shape, the organic layer 112 provided along the end portion of the pixel electrode 111 can also have a tapered shape. When the end portion of the pixel electrode 111 has a tapered shape, coverage with the organic layer 112 provided beyond the end portion of the pixel electrode 111 can be increased. The side surface of the pixel electrode 111 preferably has a tapered shape, in which case a foreign matter (also referred to as dust or particles, for example) in the manufacturing process is easily removed by processing such as cleaning.

The organic layer 112 is processed into an island shape by a photolithography method. Thus, an angle formed between the top surface and the side surface of the end portion of the organic layer 112 is approximately 90°. By contrast, an organic film formed using an FMM or the like has a thickness that tends to gradually decrease with decreasing distance to the end portion, and has a top surface forming a slope in an area extending greater than or equal to 1 m and less than or equal to 10 m to the end portion, for example; thus, such an organic film has a shape whose top surface and side surface are difficult to distinguish from each other.

The insulating layer 125, the resin layer 126, and the layer 128 are included between two adjacent light-emitting elements.

Between two adjacent light-emitting elements, the side surfaces of the organic layers 112 are provided to face each other with the resin layer 126 therebetween. The resin layer 126 is positioned between the two adjacent light-emitting elements and is provided to cover the end portions of the organic layers 112 and fill a region between the two organic layers 112. The resin layer 126 has a top surface with a smooth protruding shape, and the common layer 114 and the common electrode 113 are provided to cover the top surface of the resin layer 126.

The resin layer 126 functions as a planarization film that fills a gap positioned between two adjacent light-emitting elements. Providing the resin layer 126 can prevent a phenomenon in which the common electrode 113 is divided by a step at the end portion of the organic layer 112 (such a phenomenon is also referred to as disconnection) from occurring and the common electrode over the organic layer 112 from being insulated. The resin layer 126 can also be referred to as an LFP (Local Filling Planarization) layer.

An insulating layer containing an organic material can be suitably used as the resin layer 126. For the resin layer 126, an acrylic resin, a polyimide resin, an epoxy resin, an imide resin, a polyamide resin, a polyimide-amide resin, a silicone resin, a siloxane resin, a benzocyclobutene-based resin, a phenol resin, a precursor of any of these resins, or the like can be used, for example. For the resin layer 126, an organic material such as polyvinyl alcohol (PVA), polyvinylbutyral, polyvinylpyrrolidone, polyethylene glycol, polyglycerin, pullulan, water-soluble cellulose, or an alcohol-soluble polyamide resin may be used.

Alternatively, a photosensitive resin can be used for the resin layer 126. A photoresist may be used as the photosensitive resin. The photosensitive resin can be a material of positive type or a material of negative type.

The resin layer 126 may include a material absorbing visible light. For example, the resin layer 126 itself may be made of a material absorbing visible light, or the resin layer 126 may include a pigment absorbing visible light. For example, for the resin layer 126, it is possible to use a resin that can be used as a color filter transmitting red, blue, or green light and absorbing other light, a resin that contains carbon black as a pigment and functions as a black matrix, or the like.

The insulating layer 125 is provided in contact with the side surface of the organic layer 112. In addition, the insulating layer 125 is provided to cover an upper end portion of the organic layer 112. Furthermore, part of the insulating layer 125 is provided in contact with the top surface of the substrate 101.

The insulating layer 125 is positioned between the resin layer 126 and the organic layer 112 and functions as a protective film for preventing the resin layer 126 from being in contact with the organic layer 112. When the organic layer 112 and the resin layer 126 are in contact with each other, the organic layer 112 might be dissolved by an organic solvent or the like used at the time of forming the resin layer 126. Thus, providing the insulating layer 125 between the organic layer 112 and the resin layer 126 can protect the side surface of the organic layer 112.

An insulating layer including an inorganic material can be used for the insulating layer 125. For the insulating layer 125, an inorganic insulating film such as an oxide insulating film, a nitride insulating film, an oxynitride insulating film, or a nitride oxide insulating film can be used, for example. The insulating layer 125 may have a single-layer structure or a stacked-layer structure. Examples of the oxide insulating film include a silicon oxide film, an aluminum oxide film, a magnesium oxide film, an indium gallium zinc oxide film, a gallium oxide film, a germanium oxide film, an yttrium oxide film, a zirconium oxide film, a lanthanum oxide film, a neodymium oxide film, a hafnium oxide film, and a tantalum oxide film. Examples of the nitride insulating film include a silicon nitride film and an aluminum nitride film. Examples of the oxynitride insulating film include a silicon oxynitride film and an aluminum oxynitride film. Examples of the nitride oxide insulating film include a silicon nitride oxide film and an aluminum nitride oxide film. In particular, when a metal oxide film such as an aluminum oxide film or a hafnium oxide film or an inorganic insulating film such as a silicon oxide film that is formed by an ALD method is used for the insulating layer 125, it is possible to form the insulating layer 125 that has a small number of pinholes and has an excellent function of protecting the EL layer.

The insulating layer 125 can be formed by a sputtering method, a CVD method, a PLD method, an ALD method, or the like. The insulating layer 125 is preferably formed by an ALD method that provides good coverage.

In addition, a structure may be employed in which a reflective film (e.g., a metal film containing one or more selected from silver, palladium, copper, titanium, aluminum, and the like) is provided between the insulating layer 125 and the resin layer 126 so that light emitted from the light-emitting layer is reflected by the reflective film. This can improve light extraction efficiency.

The layer 128 is a remaining part of a protective layer (also referred to as a mask layer or a sacrificial layer) for protecting the organic layer 112 during etching of the organic layer 112. For the layer 128, any of the materials that can be used for the insulating layer 125 can be used. It is particularly preferable to use the same material for the layer 128 and the insulating layer 125, in which case an apparatus or the like for processing can be used in common.

In particular, since a metal oxide film such as an aluminum oxide film or a hafnium oxide film or an inorganic insulating film such as a silicon oxide film that is formed by an ALD method has a small number of pinholes, such a film has an excellent function of protecting the EL layer and can be suitably used for the insulating layer 125 and the layer 128.

The protective layer 121 can have, for example, a single-layer structure or a stacked-layer structure including at least an inorganic insulating film. Examples of the inorganic insulating film include oxide films and nitride films such as a silicon oxide film, a silicon oxynitride film, a silicon nitride oxide film, a silicon nitride film, an aluminum oxide film, an aluminum oxynitride film, and a hafnium oxide film. Alternatively, a semiconductor material or a conductive material such as indium gallium oxide, indium zinc oxide, ITO, or indium gallium zinc oxide may be used for the protective layer 121.

For the protective layer 121, a stacked film of an inorganic insulating film and an organic insulating film can be used. For example, a structure in which an organic insulating film is sandwiched between a pair of inorganic insulating films is preferable. Furthermore, the organic insulating film preferably functions as a planarization film. In that case, the top surface of the organic insulating film can be flat, whereby the coverage thereof with the inorganic insulating film can be improved to achieve higher barrier properties. The top surface of the protective layer 121 is flat, which is preferable because the influence of an uneven shape due to a component below the protective layer 121 can be reduced in the case where a component (e.g., a color filter, an electrode of a touch sensor, or a lens array) is provided above the protective layer 121.

FIG. 42C illustrates the connection portion 130 in which the connection electrode 111C and the common electrode 113 are electrically connected to each other. In the connection portion 130, an opening portion is provided in the insulating layer 125 and the resin layer 126 over the connection electrode 111C. The connection electrode 111C and the common electrode 113 are electrically connected to each other in the opening portion.

Although FIG. 42C illustrates the connection portion 130 in which the connection electrode 111C and the common electrode 113 are electrically connected to each other, the common electrode 113 may be provided over the connection electrode 111C with the common layer 114 therebetween. Particularly in the case where a carrier-injection layer is used as the common layer 114, for example, a material used for the common layer 114 has sufficiently low electrical resistivity and the common layer 114 can be formed to be thin; thus, problems do not arise in many cases even when the common layer 114 is positioned in the connection portion 130. Accordingly, the common electrode 113 and the common layer 114 can be formed with the use of the same shielding mask, so that manufacturing cost can be reduced.

### Structure Example 2

A display device having a structure partly different from that in Structure example 1 described above will be described below. Note that the above description is referred to for portions common to those in Structure example 1, and the description is omitted in some cases.

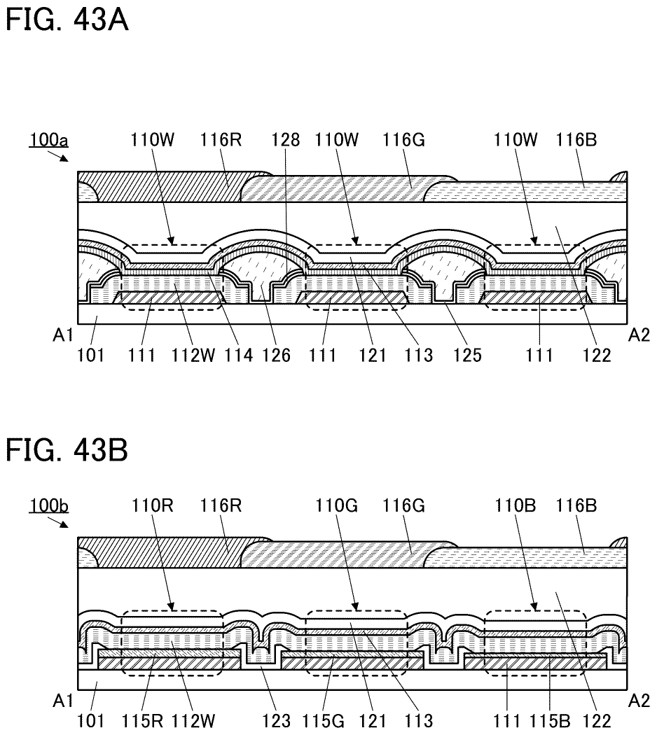

FIG. 43A is a schematic cross-sectional view of a display device 100a. The display device 100a is different from the above-described display device 100 mainly in the structure of the light-emitting element and including a coloring layer.

The display device 100a includes a light-emitting element 110W that emits white light. The light-emitting element 110W includes the pixel electrode 111, an organic layer 112W, the common layer 114, and the common electrode 113. The organic layer 112W emits white light. For example, the organic layer 112W can include two or more kinds of light-emitting materials whose emission colors are complementary colors. For example, the organic layer 112W can include a light-emitting organic compound that emits red light, a light-emitting organic compound that emits green light, and a light-emitting organic compound that emits blue light. Alternatively, the organic layer 112W may include a light-emitting organic compound that emits blue light and a light-emitting organic compound that emits yellow light.

The organic layer 112W is divided between two adjacent light-emitting elements 110W. Thus, leakage current flowing between the adjacent light-emitting elements 110W through the organic layer 112W can be inhibited and crosstalk due to the leakage current can be inhibited. Accordingly, the display device can have high contrast and high color reproducibility.

An insulating layer 122 functioning as a planarization film is provided over the protective layer 121, and a coloring layer 116R, a coloring layer 116G, and a coloring layer 116B are provided over the insulating layer 122.

An organic resin film or an inorganic insulating film with a flat top surface can be used as the insulating layer 122. The insulating layer 122 serves as a formation surface of the coloring layer 116R, the coloring layer 116G, and the coloring layer 116B; thus, with a flat top surface of the insulating layer 122, the thicknesses of the coloring layer 116R and the like can be uniform and color purity can be increased. Note that when the thicknesses of the coloring layer 116R and the like are not uniform, the amount of light absorption varies from place to place in the coloring layer 116R, which might decrease the color purity.

### Structure Example 3

FIG. 43B is a schematic cross-sectional view of a display device 100b.

The light-emitting element 110R includes the pixel electrode 111, a conductive layer 115R, the organic layer 112W, and the common electrode 113. The light-emitting element 110G includes the pixel electrode 111, a conductive layer 115G, the organic layer 112W, and the common electrode 113. The light-emitting element 110B includes the pixel electrode 111, a conductive layer 115B, the organic layer 112W, and the common electrode 113. The conductive layer 115R, the conductive layer 115G, and the conductive layer 115B each have a light-transmitting property and function as an optical adjustment layer.

A film that reflects visible light is used for the pixel electrode 111 and a film having properties of reflecting and transmitting visible light is used for the common electrode 113, so that a micro resonator (microcavity) structure can be achieved. At this time, by adjusting the thicknesses of the conductive layer 115R, the conductive layer 115G, and the conductive layer 115B to obtain optimal optical path lengths, light obtained from the light-emitting element 110R, the light-emitting element 110G, and the light-emitting element 110B can be intensified light with different wavelengths even in the case where the organic layer 112 exhibiting white light emission is used.

Furthermore, the coloring layer 116R, the coloring layer 116G, and the coloring layer 116B are provided on the optical paths of the light-emitting element 110R, the light-emitting element 110G, and the light-emitting element 110B, respectively, whereby light with high color purity can be obtained.

An insulating layer 123 that covers the end portions of the pixel electrode 111 and the conductive layer 115 is provided. The end portion of the insulating layer 123 preferably has a tapered shape. When the insulating layer 123 is provided, coverage with the organic layer 112W, the common electrode 113, the protective layer 121, and the like formed over the insulating layer 123 can be increased.

The organic layer 112W and the common electrode 113 are each provided as one continuous film shared by the light-emitting elements. Such a structure is preferable because the manufacturing process of the display device can be greatly simplified.

Here, the end portion of the pixel electrode 111 preferably has a substantially vertical shape. Accordingly, a steep portion can be formed on the surface of the insulating layer 123, and thus a thin portion can be formed in part of the organic layer 112W that covers the steep portion or part of the organic layer 112W can be divided. Consequently, leakage current generated between adjacent light-emitting elements through the organic layer 112W can be inhibited without processing the organic layer 112W by a photolithography method or the like.

The above is the description of the structure examples of the display devices.

At least part of this embodiment can be implemented in combination with any of the other embodiments described in this specification as appropriate.

### Embodiment 9

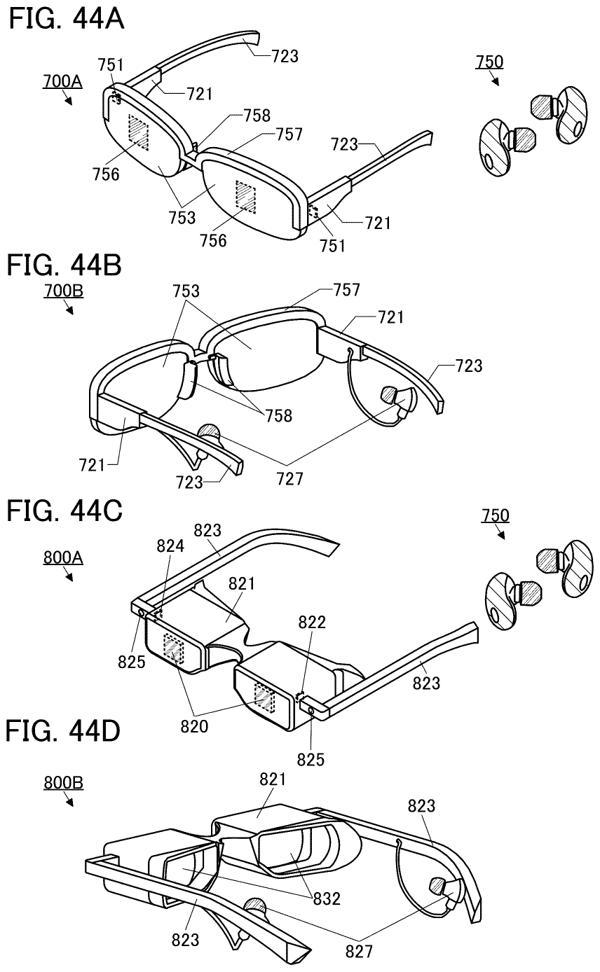

In this embodiment, electronic devices of one embodiment of the present invention will be described with reference to FIG. 44A to FIG. 46G.

Electronic devices in this embodiment each include a display panel (display device) employing the transistor of one embodiment of the present invention in a display portion. The display device of one embodiment of the present invention can easily achieve higher resolution and higher definition and can achieve high display quality. Thus, the display device of one embodiment of the present invention can be used for display portions of a variety of electronic devices.

Examples of the electronic devices include a digital camera, a digital video camera, a digital photo frame, a mobile phone, a portable game machine, a portable information terminal, and an audio reproducing device, in addition to electronic devices with a relatively large screen, such as a television device, desktop and laptop personal computers, a monitor of a computer and the like, digital signage, and a large game machine such as a pachinko machine.

In particular, the display panel of one embodiment of the present invention can have higher resolution and thus can be suitably used for an electronic device having a relatively small display portion. Examples of such an electronic device include watch-type and bracelet-type information terminals (wearable devices) and wearable devices capable of being worn on a head, such as a VR device like a head-mounted display, a glasses-type AR device, and an MR device.

The definition of the display panel of one embodiment of the present invention is preferably as high as HD (pixel count: 1280×720), FHD (pixel count: 1920×1080), WQHD (pixel count: 2560×1440), WQXGA (pixel count: 2560×1600), 4K (pixel count: 3840×2160), or 8K (pixel count: 7680×4320). In particular, a definition of 4K, 8K, or higher is preferable. In addition, the pixel density (resolution) of the display panel of one embodiment of the present invention is preferably higher than or equal to 100 ppi, further preferably higher than or equal to 300 ppi, still further preferably higher than or equal to 500 ppi, yet further preferably higher than or equal to 1000 ppi, yet still further preferably higher than or equal to 2000 ppi, yet still further preferably higher than or equal to 3000 ppi, yet still further preferably higher than or equal to 5000 ppi, yet still further preferably higher than or equal to 7000 ppi. With the use of such a display panel having one or both of high definition and high resolution, realistic sensation, sense of depth, and the like can be further increased. There is no particular limitation on the screen ratio (aspect ratio) of the display panel of one embodiment of the present invention. For example, the display panel is compatible with a variety of screen ratios such as 1:1 (a square), 4:3, 16:9, and 16:10.

The electronic device in this embodiment may include a sensor (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, electric power, radiation, a flow rate, humidity, a gradient, oscillation, odor, or infrared rays).

The electronic device in this embodiment can have a variety of functions. For example, the electronic device can have a function of displaying a variety of information (a still image, a moving image, a text image, and the like) on the display portion, a touch panel function, a function of displaying a calendar, date, time, and the like, a function of executing a variety of software (programs), a wireless communication function, and a function of reading out a program or data stored in a recording medium.

Examples of wearable devices that can be worn on a head will be described with reference to FIG. 44A to FIG. 44D. These wearable devices have one or both of a function of displaying AR contents and a function of displaying VR contents. Note that the wearable devices may have a function of displaying SR or MR contents, in addition to AR and VR contents. The electronic device having a function of displaying contents of at least one of AR, VR, SR, MR, and the like enables the user to reach a higher level of immersion.

An electronic device 700A illustrated in FIG. 44A and an electronic device 700B illustrated in FIG. 44B each include a pair of display panels 751, a pair of housings 721, a communication portion (not illustrated), a pair of wearing portions 723, a control portion (not illustrated), an image capturing portion (not illustrated), a pair of optical members 753, a frame 757, and a pair of nose pads 758.

The display panel of one embodiment of the present invention can be used as the display panels 751. Thus, the electronic device can perform display with extremely high resolution.

The electronic device 700A and the electronic device 700B can each project images displayed on the display panels 751 onto display regions 756 of the optical members 753. Since the optical members 753 have a light-transmitting property, a user can see images displayed on the display regions, which are superimposed on transmission images seen through the optical members 753. Accordingly, the electronic device 700A and the electronic device 700B are electronic devices capable of AR display.

In the electronic device 700A and the electronic device 700B, a camera capable of capturing images of the front side may be provided as the image capturing portion. Furthermore, when the electronic device 700A and the electronic device 700B are each provided with an acceleration sensor such as a gyroscope sensor, the orientation of the user's head can be sensed and an image corresponding to the orientation can be displayed on the display regions 756.

The communication portion includes a wireless communication device, and a video signal and the like can be supplied by the wireless communication device. Note that instead of the wireless communication device or in addition to the wireless communication device, a connector to which a cable for supplying a video signal and a power supply potential can be connected may be provided.

In addition, each of the electronic device 700A and the electronic device 700B is provided with a battery (not illustrated) so that charging can be performed wirelessly and/or by wire.

A touch sensor module may be provided in the housing 721. The touch sensor module has a function of detecting touch on the outer surface of the housing 721. A tap operation, a slide operation, or the like by the user can be detected with the touch sensor module, whereby a variety of processing can be executed. For example, processing such as a pause or a restart of a moving image can be executed by a tap operation, and processing such as fast forward or fast rewind can be executed by a slide operation. When the touch sensor module is provided in each of the two housings 721, the range of the operation can be increased.

Various touch sensors can be used for the touch sensor module. For example, any of touch sensors of various types such as a capacitive type, a resistive type, an infrared type, an electromagnetic induction type, a surface acoustic wave type, and an optical type can be employed. In particular, a capacitive sensor or an optical sensor is preferably used for the touch sensor module.

In the case of using an optical touch sensor, a photoelectric conversion device (also referred to as a photoelectric conversion element) can be used as a light-receiving device (also referred to as a light-receiving element). One or both of an inorganic semiconductor and an organic semiconductor can be used for an active layer of the photoelectric conversion device.

An electronic device 800A illustrated in FIG. 44C and an electronic device 800B illustrated in FIG. 44D each include a pair of display portions 820, a housing 821, a communication portion 822, a pair of wearing portions 823, a control portion 824, a pair of image capturing portions 825, and a pair of lenses 832.

The display panel of one embodiment of the present invention can be used for the display portions 820. Thus, the electronic device can perform display with extremely high resolution. This enables a user to feel a high sense of immersion.

The display portions 820 are positioned inside the housing 821 so as to be seen through the lenses 832. When the pair of display portions 820 display different images, three-dimensional display using parallax can be performed.

The electronic device 800A and the electronic device 800B can be regarded as electronic devices for VR. The user who wears the electronic device 800A or the electronic device 800B can see images displayed on the display portions 820 through the lenses 832.

The electronic device 800A and the electronic device 800B each preferably include a mechanism for laterally adjusting the positions of the lenses 832 and the display portions 820 so that the lenses 832 and the display portions 820 are positioned optimally in accordance with the positions of the user's eyes. Moreover, the electronic device 800A and the electronic device 800B each preferably include a mechanism for adjusting focus by changing the distance between the lenses 832 and the display portions 820.

The electronic device 800A or the electronic device 800B can be worn on the user's head with the wearing portions 823. FIG. 44C and the like illustrate examples in which the wearing portion 823 has a shape like a temple of glasses; however, one embodiment of the present invention is not limited thereto. The wearing portion 823 can have any shape with which the user can wear the electronic device, for example, a shape of a helmet or a band.

The image capturing portion 825 has a function of obtaining information on the external environment. Data obtained by the image capturing portion 825 can be output to the display portion 820. An image sensor can be used for the image capturing portion 825. Moreover, a plurality of cameras may be provided to cover a plurality of fields of view, such as a telescope field of view and a wide field of view.

Although an example in which the image capturing portion 825 is provided is illustrated here, a range sensor (hereinafter, also referred to as a sensing portion) capable of measuring a distance to an object just needs to be provided. That is, the image capturing portion 825 is one embodiment of the sensing portion. For the sensing portion, an image sensor or a distance image sensor such as LIDAR (Light Detection and Ranging) can be used, for example. With the use of images obtained by the camera and images obtained by the distance image sensor, more pieces of information can be obtained and a gesture operation with higher accuracy is possible.

The electronic device 800A may include a vibration mechanism that functions as bone-conduction earphones. For example, a structure including the vibration mechanism can be employed for any one or more of the display portion 820, the housing 821, and the wearing portion 823. Thus, without additionally requiring an audio device such as headphones, earphones, or a speaker, the user can enjoy a video and sound only by wearing the electronic device 800A.

The electronic device 800A and the electronic device 800B may each include an input terminal. To the input terminal, a cable for supplying a video signal from a video output device or the like, electric power for charging a battery provided in the electronic device, and the like can be connected.

The electronic device of one embodiment of the present invention may have a function of performing wireless communication with earphones 750. The earphones 750 include a communication portion (not illustrated) and have a wireless communication function. The earphones 750 can receive information (e.g., audio data) from the electronic device with the wireless communication function. For example, the electronic device 700A illustrated in FIG. 44A has a function of transmitting information to the earphones 750 with the wireless communication function. For another example, the electronic device 800A illustrated in FIG. 44C has a function of transmitting information to the earphones 750 with the wireless communication function.

The electronic device may include earphone portions. The electronic device 700B illustrated in FIG. 44B includes earphone portions 727. For example, a structure in which the earphone portions 727 and the control portion are connected to each other by wire can be employed. Part of a wiring that connects the earphone portions 727 and the control portion may be positioned inside the housing 721 or the wearing portion 723.

Similarly, the electronic device 800B illustrated in FIG. 44D includes earphone portions 827. For example, a structure in which the earphone portions 827 and the control portion 824 are connected to each other by wire can be employed. Part of a wiring that connects the earphone portions 827 and the control portion 824 may be positioned inside the housing 821 or the wearing portion 823. Alternatively, the earphone portions 827 and the wearing portions 823 may include magnets. This is preferable because the earphone portions 827 can be fixed to the wearing portions 823 with magnetic force and thus can be easily housed.

Note that the electronic device may include an audio output terminal to which earphones, headphones, or the like can be connected. The electronic device may include one or both of an audio input terminal and an audio input mechanism. As the audio input mechanism, a sound collecting device such as a microphone can be used, for example. The electronic device may have a function of what is called a headset by including the audio input mechanism.

As described above, both the glasses-type device (e.g., the electronic device 700A and the electronic device 700B) and the goggles-type device (e.g., the electronic device 800A and the electronic device 800B) are suitable as the electronic device of one embodiment of the present invention.

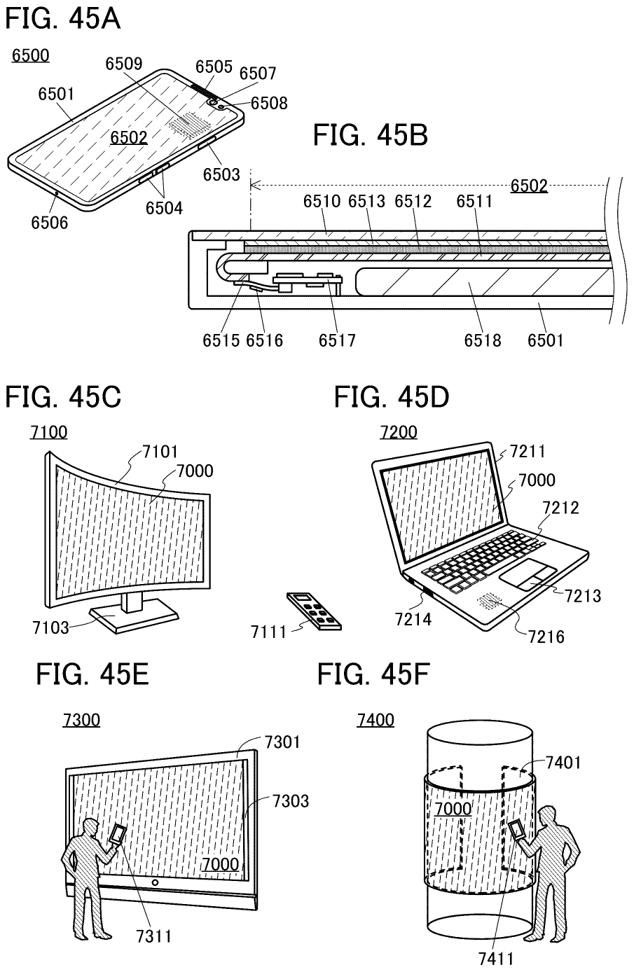

The electronic device 6500 illustrated in FIG. 45A is a portable information terminal that can be used as a smartphone.

The electronic device 6500 includes the housing 6501, the display portion 6502, the power button 6503, the buttons 6504, the speaker 6505, the microphone 6506, the camera 6507, the light source 6508, the control device 6509, and the like. The display portion 6502 has a touch panel function. Note that as the control device 6509, for example, one or more selected from a CPU, a GPU, and a memory device are included. The semiconductor device of one embodiment of the present invention can be used for the display portion 6502, the control device 6509, and the like. The semiconductor device of one embodiment of the present invention is preferably used for the control device 6509, in which case power consumption can be reduced.

The display panel of one embodiment of the present invention can be used for the display portion 6502.

FIG. 45B is a schematic cross-sectional view including the end portion of the housing 6501 on the microphone 6506 side.

A protection member 6510 having a light-transmitting property is provided on the display surface side of the housing 6501, and a display panel 6511, an optical member 6512, a touch sensor panel 6513, a printed circuit board 6517, a battery 6518, and the like are placed in a space surrounded by the housing 6501 and the protection member 6510.

The display panel 6511, the optical member 6512, and the touch sensor panel 6513 are fixed to the protection member 6510 with an adhesive layer (not illustrated).

Part of the display panel 6511 is folded back in a region outside the display portion 6502, and an FPC 6515 is connected to the part that is folded back. An IC 6516 is mounted on the FPC 6515. The FPC 6515 is connected to a terminal provided on the printed circuit board 6517.

A flexible display of one embodiment of the present invention can be used for the display panel 6511. Thus, an extremely lightweight electronic device can be achieved. Since the display panel 6511 is extremely thin, the battery 6518 with high capacity can be mounted without an increase in the film thickness of the electronic device. Moreover, part of the display panel 6511 is folded back such that a connection portion with the FPC 6515 is provided on the back side of a pixel portion, whereby an electronic device with a narrow bezel can be achieved.

FIG. 45C illustrates an example of a television device. In a television device 7100, a display portion 7000 is incorporated in a housing 7101. Here, the housing 7101 is supported by a stand 7103.

Operation of the television device 7100 illustrated in FIG. 45C can be performed with an operation switch provided in the housing 7101 and a separate remote controller 7111. Alternatively, the display portion 7000 may include a touch sensor, and the television device 7100 may be operated by touch on the display portion 7000 with a finger or the like. The remote controller 7111 may be provided with a display portion for displaying information output from the remote controller 7111. With operation keys or a touch panel provided in the remote controller 7111, channels and volume can be controlled and videos displayed on the display portion 7000 can be controlled.

Note that the television device 7100 includes a receiver, a modem, and the like. A general television broadcast can be received with the receiver. When the television device is connected to a communication network by wire or wirelessly via the modem, one-way (from a transmitter to a receiver) or two-way (between a transmitter and a receiver or between receivers, for example) information communication can be performed.

FIG. 45D illustrates an example of a laptop personal computer. A laptop personal computer 7200 includes a housing 7211, a keyboard 7212, a pointing device 7213, an external connection port 7214, a control device 7216, and the like. In the housing 7211, the display portion 7000 is incorporated. As the control device 7216, for example, one or more selected from a CPU, a GPU, and a memory device are included. The semiconductor device of one embodiment of the present invention can be used for the display portion 7000, the control device 7216, and the like. The semiconductor device of one embodiment of the present invention is preferably used for the control device 7216, in which case power consumption can be reduced.

FIG. 45E and FIG. 45F illustrate examples of digital signage.

Digital signage 7300 illustrated in FIG. 45E includes a housing 7301, the display portion 7000, a speaker 7303, and the like. The digital signage 7300 can also include an LED lamp, an operation key (including a power switch or an operation switch), a connection terminal, a variety of sensors, a microphone, and the like.

FIG. 45F illustrates digital signage 7400 attached to a cylindrical pillar 7401. The digital signage 7400 includes the display portion 7000 provided along a curved surface of the pillar 7401.

The larger display portion 7000 can provide a larger amount of information at a time. The larger display portion 7000 attracts more attention, so that the effectiveness of the advertisement can be increased, for example.

A touch panel is preferably used in the display portion 7000, in which case intuitive operation by a user is possible in addition to display of an image or a moving image on the display portion 7000. Moreover, for an application for providing information such as route information or traffic information, usability can be enhanced by intuitive operation.

As illustrated in FIG. 45E and FIG. 45F, it is preferable that the digital signage 7300 or the digital signage 7400 be capable of working with an information terminal 7311 or an information terminal 7411, such as a smartphone a user has, through wireless communication. For example, information of an advertisement displayed on the display portion 7000 can be displayed on a screen of the information terminal 7311 or the information terminal 7411. By operating the information terminal 7311 or the information terminal 7411, display on the display portion 7000 can be switched.

It is also possible to make the digital signage 7300 or the digital signage 7400 execute a game with the use of the screen of the information terminal 7311 or the information terminal 7411 as an operation means (a controller). Thus, an unspecified number of users can join in and enjoy the game concurrently.

The display panel of one embodiment of the present invention can be used for the display portion 7000 in each of FIG. 45C to FIG. 45F.

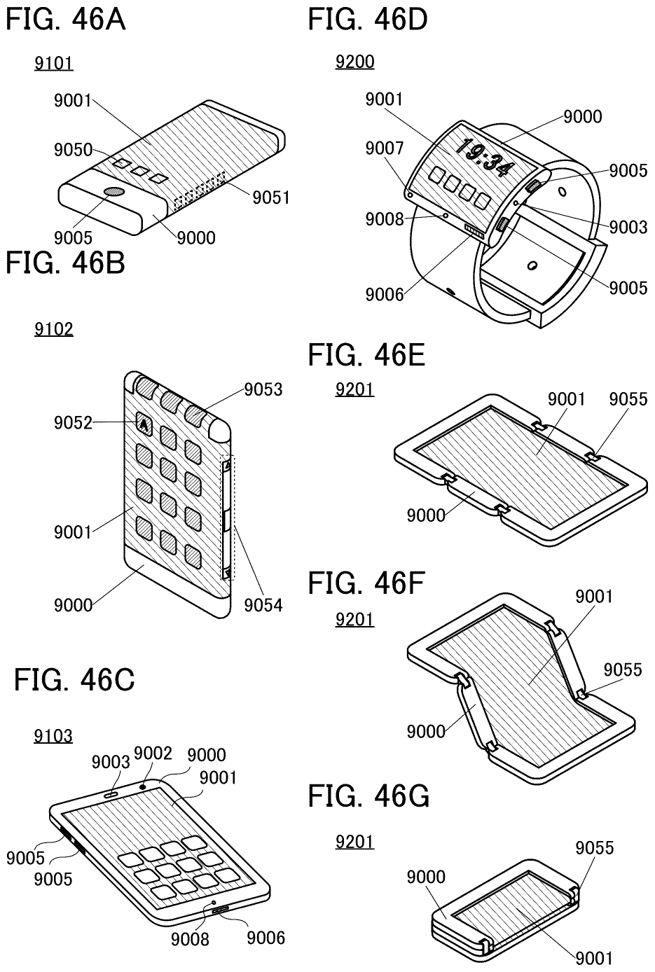

Electronic devices illustrated in FIG. 46A to FIG. 46G each include a housing 9000, a display portion 9001, a speaker 9003, an operation key 9005 (including a power switch or an operation switch), a connection terminal 9006, a sensor 9007 (a sensor having a function of sensing, detecting, or measuring force, displacement, a position, speed, acceleration, angular velocity, rotational frequency, distance, light, liquid, magnetism, temperature, a chemical substance, sound, time, hardness, an electric field, current, voltage, electric power, radiation, a flow rate, humidity, a gradient, oscillation, odor, or infrared rays), a microphone 9008, and the like.

The electronic devices illustrated in FIG. 46A to FIG. 46G have a variety of functions. For example, the electronic devices can have a function of displaying a variety of information (a still image, a moving image, a text image, and the like) on the display portion, a touch panel function, a function of displaying a calendar, date, time, and the like, a function of controlling processing with the use of a variety of software (programs), a wireless communication function, and a function of reading out and processing a program or data stored in a recording medium. Note that the functions of the electronic devices are not limited thereto, and the electronic devices can have a variety of functions. The electronic devices may each include a plurality of display portions. In addition, the electronic devices may each be provided with a camera or the like and have a function of taking a still image or a moving image and storing the taken image in a recording medium (an external recording medium or a recording medium incorporated in the camera), a function of displaying the taken image on the display portion, or the like.

The details of the electronic devices illustrated in FIG. 46A to FIG. 46G are described below.

FIG. 46A is a perspective view illustrating a portable information terminal 9101. The portable information terminal 9101 can be used as a smartphone, for example. Note that the portable information terminal 9101 may be provided with the speaker 9003, the connection terminal 9006, the sensor 9007, or the like. The portable information terminal 9101 can display text and image information on its plurality of surfaces. FIG. 46A illustrates an example in which three icons 9050 are displayed. Furthermore, information 9051 indicated by dashed rectangles can be displayed on another surface of the display portion 9001. Examples of the information 9051 include notification of reception of an e-mail, an SNS message, or an incoming call, the title and sender of an e-mail, an SNS message, or the like, the date, the time, remaining battery, and the radio field intensity. Alternatively, the icon 9050 or the like may be displayed at the position where the information 9051 is displayed.

FIG. 46B is a perspective view illustrating a portable information terminal 9102. The portable information terminal 9102 has a function of displaying information on three or more surfaces of the display portion 9001. Here, an example in which information 9052, information 9053, and information 9054 are displayed on different surfaces is illustrated. For example, a user can check the information 9053 displayed such that it can be seen from above the portable information terminal 9102, with the portable information terminal 9102 put in a breast pocket of his/her clothes. The user can see the display without taking out the portable information terminal 9102 from the pocket and decide whether to answer the call, for example.

FIG. 46C is a perspective view illustrating a tablet terminal 9103. The tablet terminal 9103 is capable of executing a variety of applications such as mobile phone calls, e-mailing, viewing and editing texts, music reproduction, Internet communication, and a computer game. The tablet terminal 9103 includes the display portion 9001, a camera 9002, the microphone 9008, and the speaker 9003 on the front surface of the housing 9000; the operation keys 9005 as buttons for operation on the left side surface of the housing 9000; and the connection terminal 9006 on the bottom surface.

FIG. 46D is a perspective view illustrating a watch-type portable information terminal 9200. The portable information terminal 9200 can be used as a Smartwatch (registered trademark), for example. The display surface of the display portion 9001 is curved, and display can be performed on the curved display surface. Furthermore, mutual communication between the portable information terminal 9200 and, for example, a headset capable of wireless communication enables hands-free calling. With the connection terminal 9006, the portable information terminal 9200 can perform mutual data transmission with another information terminal and charging. Note that the charging operation may be performed by wireless power feeding.

FIG. 46E to FIG. 46G are perspective views illustrating a foldable portable information terminal 9201. FIG. 46E is a perspective view of an opened state of the portable information terminal 9201, FIG. 46G is a perspective view of a folded state thereof, and FIG. 46F is a perspective view of a state in the middle of change from one of FIG. 46E and FIG. 46G to the other. The portable information terminal 9201 is highly portable in the folded state and is highly browsable in the opened state because of a seamless large display region. The display portion 9001 of the portable information terminal 9201 is supported by three housings 9000 joined together by hinges 9055. The display portion 9001 can be folded with a radius of curvature greater than or equal to 0.1 mm and less than or equal to 150 mm, for example.

At least part of this embodiment can be implemented in combination with any of the other embodiments described in this specification as appropriate.

### EXAMPLE

In this example, the carrier mobility of a metal oxide is described. Specifically, Hall effect measurement was performed on samples each including the metal oxide to calculate the Hall mobility and the carrier concentration. A factor affecting the carrier mobility of the metal oxide was evaluated by first-principles calculation.

Note that the mobility calculated using the result of the Hall effect measurement is referred to as Hall mobility in some cases. Here, the Hall effect measurement using the Van der Pauw method was performed.

### <Hall Mobility of Metal Oxide>

As samples used for the Hall effect measurement, eight samples (Sample 61A to Sample 64A and Sample 61B to Sample 64B) were fabricated. A method for fabricating the eight samples is described below.

First, a quartz substrate was prepared for all of the eight samples.

Then, a 35-nm-thick metal oxide film was formed over the quartz substrate by a sputtering method. In Sample 61A to Sample 64A, the metal oxide was deposited using an In—Ga—Zn oxide target (with an atomic ratio of In:Ga:Zn=1:1:1). The deposition conditions were as follows: the pressure was 0.6 Pa, the power supply was 2.5 kW, and the substrate temperature was 200° C. A mixed gas of an oxygen gas and an argon gas was used as a deposition gas, and the oxygen flow rate ratio was 50%. In Sample 61B to Sample 64B, the metal oxide was deposited using an In—Zn oxide target containing tin (an atomic ratio of In:Zn=4:1). The deposition conditions were as follows: the pressure was 0.6 Pa, the power supply was 2.5 kW, and the substrate temperature was 200° C. A mixed gas of an oxygen gas and an argon gas was used as a deposition gas, and the oxygen flow rate ratio was 10%.

Next, treatment was performed under reduced pressure (vacuum) or in a hydrogen atmosphere for one hour. The conditions of the treatment differed from sample to sample. Specifically, for Sample 61A, the treatment was performed at 250° C. under reduced pressure (vacuum). For Sample 62A to Sample 64A, the treatment was performed in a hydrogen atmosphere. The treatment temperature was set to 300° C. for Sample 62A, 350° C. for Sample 63A, and 400° C. for Sample 64A. The treatment was not performed on Sample 61B. The treatment was performed on Sample 62B to Sample 64B under reduced pressure (vacuum). The treatment temperature was set to 100° C. for Sample 62B, 150° C. for Sample 63B, and 200° C. for Sample 64B. The carrier concentration in the metal oxide can be varied by making the conditions of the treatment different from sample to sample.

In the above manner, samples (Sample 61A to Sample 64A and Sample 61B to Sample 64B) used for the Hall effect measurement were fabricated. Note that in the following description, Sample 61A to Sample 64A are referred to as a sample group 6A, and Sample 61B to Sample 64B are referred to as a sample group 6B in some cases. The metal oxide included in the sample group 6A is referred to as IGZO in some cases. The metal oxide included in the sample group 6B has a higher content percentage of In than the metal oxide included in the sample group 6A; thus, the metal oxide included in the sample group 6B is referred to as an In-rich OS in some cases. The metal oxide included in the sample group 6B is an example of the metal oxide film of one embodiment of the present invention because the sum of the content percentage of indium and the content percentage of zinc is greater than or equal to 95%.

Note that a 200-nm-thick titanium-aluminum alloy film was formed over each sample by a sputtering method in order to perform the Hall effect measurement. Note that a metal mask was used to form the titanium-aluminum alloy film at each of the four corners of the sample.

The Hall effect measurement was performed on the eight samples in increments of approximately 40° C. in the temperature range from 102° C. to 302° C. “ResiTest8300” produced by TOYO Corporation was used for the Hall effect measurement.

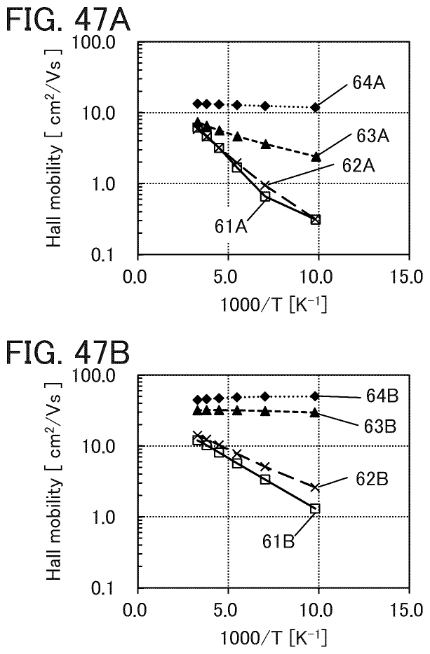

FIG. 47A and FIG. 47B show the Hall effect measurement results. FIG. 47A and FIG. 47B are diagrams each showing the temperature dependence of the Hall mobility of the metal oxide. In FIG. 47A and FIG. 47B, the vertical axis represents Hall mobility [cm²/Vs] of the metal oxide, and the horizontal axis represents a value of 1000 times the reciprocal of the measurement temperature (1000/T) [K⁻¹]. In each of FIG. 47A and FIG. 47B, the vertical axis is on a logarithmic scale.

FIG. 47A shows the results of the sample group 6A. The quadrangles in FIG. 47A show the result of Sample 61A, the crosses in FIG. 47A show the result of Sample 62A, the triangles in FIG. 47A show the result of Sample 63A, and the rhombuses in FIG. 47A show the result of Sample 64A. Note that the carrier concentration at 1000/T=3.3 K⁻¹ was 7.3×10¹⁶ cm⁻³ in Sample 61A, 3.9×10¹⁷ cm⁻³ in Sample 62A, 5.6×10¹⁸ cm⁻³ in Sample 63A, and 3.4×10¹⁹ cm⁻³ in Sample 64A.

FIG. 47B shows the results of the sample group 6B. The quadrangles in FIG. 47B show the results of Sample 61B, the crosses in FIG. 47B show the results of Sample 62B, the triangles in FIG. 47B show the results of Sample 63B, and the rhombuses in FIG. 47B show the results of Sample 64B. Note that the carrier concentration at 1000/T=3.3 K⁻¹ was 3.8×10¹⁷ cm⁻³ in Sample 61B, 7.1×10¹⁷ cm³ in Sample 62B, 7.9×10¹⁸ cm³ in Sample 63B, and 8.3×10¹⁹ cm³ in Sample 64B.

FIG. 47A and FIG. 47B confirm that the temperature dependence of Hall mobility tends to be small in the case where the carrier concentration is high. This is probably attributed to carrier degeneracy. In contrast, it was confirmed that the Hall mobility tends to increase with an increase in the measurement temperature in the case where the carrier concentration is low.

As described above, at 1000/T=3.3 K⁻¹, the carrier concentration of Sample 62A is substantially equal to the carrier concentration of Sample 61B. Thus, the Hall mobility of Sample 62A and the Hall mobility of Sample 61B are compared.

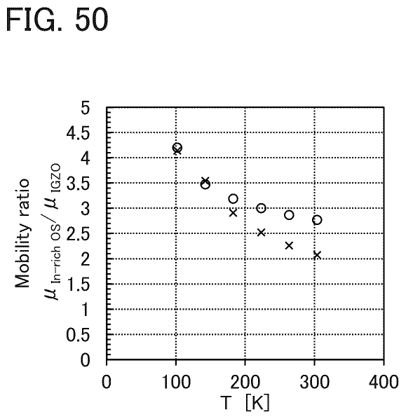

The results are shown in FIG. 50. In FIG. 50, the vertical axis represents the ratio of mobility and the horizontal axis represents the measurement temperature T [K]. The crosses in FIG. 50 show the ratio of the Hall mobility of Sample 61B to the Hall mobility of Sample 62A calculated from the results of the Hall effect measurement. Note that the circles in FIG. 50 show the ratio of mobility calculated by the first-principles calculation described later.

FIG. 50 confirms that the Hall mobility of the metal oxide (In-rich OS) included in Sample 61B is higher than that of the metal oxide (IGZO) included in Sample 62A.

In the case where the metal oxide is composed of a plurality of metal elements, one of the scattering factors that affect the carrier transfer (mobility) is randomness in the arrangement of metal atoms at cation sites (what is called cation disorder). As shown in a numerical formula (3), the mobility (μ) affected by the scattering factor derived from the cation disorder is known to be proportional to the 3/2 power of the temperature T.

$$\begin{matrix}[ Numerical Formula 3 ] & \\ μ ∝ \frac{{{ε}_{s}}^{2} {T}^{\frac{3}{3}}}{{{m}_{e}^{*}}^{\frac{1}{2}} {ρ}_{disorder} F} & ( 3 )\end{matrix}$$

In the numerical formula (3), a denotes a static permittivity, mₑ* denotes an electron effective mass, and ρ_{disorder} denotes a cation concentration in a region where cation disorder occurs. F is a term that depends on the occupancy rate of cation sites and the difference in effective valence, and is represented by a numerical formula (4). εₛ, mₑ*, ρ_{disorder}, and F are factors that affect mobility, which are derived from a metal oxide.

$$\begin{matrix}[ Numerical Formula 4 ] & \\ F = F ( {f}_{In} , {f}_{Ga} , {f}_{Zn} , {Δ Z}_{In} , {Δ Z}_{Ga} ) ≡ {f}_{In} {{f}_{Ga} ( {Δ Z}_{In} - {Δ Z}_{Ga} )}^{2} + {f}_{Zn} ( {f}_{In} {{Δ Z}_{In}}^{2} + {f}_{Ga} {{Δ Z}_{Ga}}^{2} ) & ( 4 )\end{matrix}$$

In the numerical formula (4), f_{In} is the occupancy rate of In at cation sites in a region where cation disorder occurs, f_{Ga} is the occupancy rate of Ga at the cation sites in the region where the cation disorder occurs, and f_{Zn} is the occupancy rate of Zn at the cation sites in the region where the cation disorder occurs. ΔZ_{In} is the effective valence of In when Zn is used as a reference, and ΔZ_{Ga} is the effective valence of Ga when Zn is used as a reference.

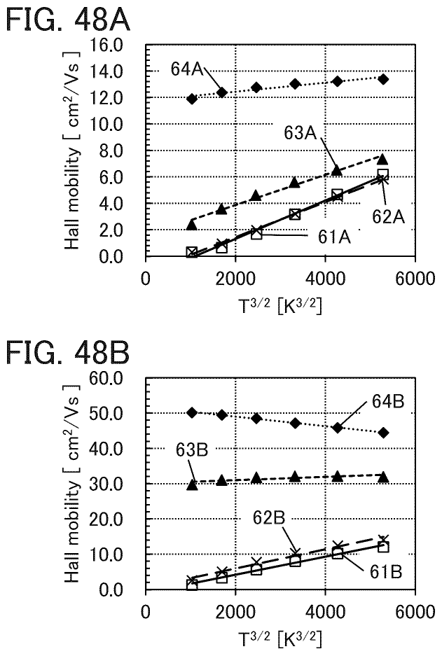

As described above, in the cation disorder model, the mobility is proportional to the 3/2 power of the temperature T. Thus, FIG. 48A shows the case where the horizontal axis of FIG. 47A showing the results of the Hall effect measurement is changed to the 3/2 power of the temperature T, and FIG. 48B shows the case where the horizontal axis of FIG. 47B showing the results of the Hall effect measurement is changed to the 3/2 power of T. In FIG. 48A and FIG. 48B, the vertical axis is on a linear scale.

FIG. 48A and FIG. 48B confirm that the Hall mobility of the sample with a low carrier concentration tends to be proportional to the 3/2 power of T. Thus, it is suggested that when the carrier concentration is low, the mobility has the same temperature dependence as the scattering factor derived from the cation disorder.

<Calculation of Factor Derived from Metal Oxide by First-Principles Calculation>

Next, calculation results of the above-described factors derived from a metal oxide (εₛ, mₑ*, ρ_{disorder}, and F) using first-principles calculation are described.

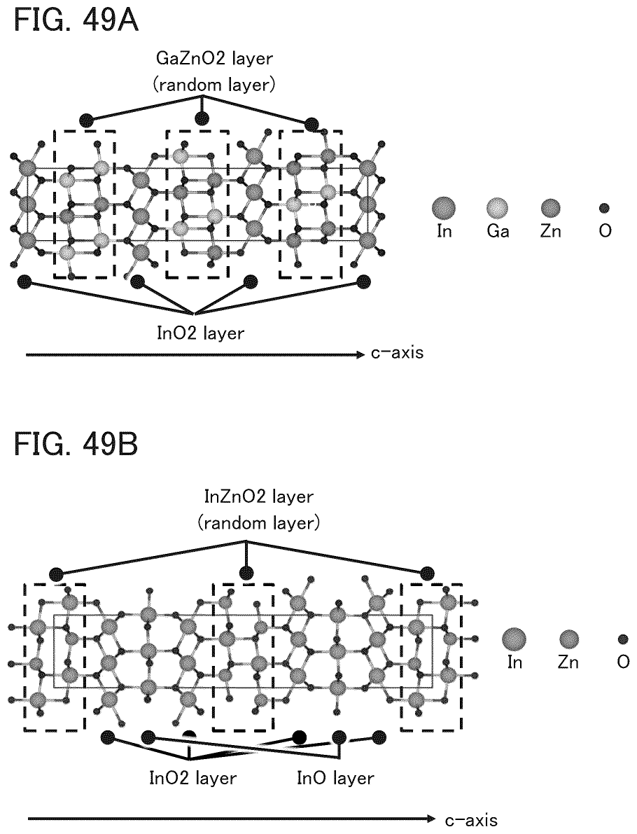

First, calculation models of metal oxides used for first-principles calculation are described. The calculation models of metal oxides are shown in FIG. 49A and FIG. 49B.

The calculation model illustrated in FIG. 49A corresponds to the metal oxide included in the sample group 6A described above. That is, the calculation model illustrated in FIG. 49A has a crystal structure of a metal oxide with an atomic ratio of In:Ga:Zn=1:1:1. The crystal structure has an alternating-layer structure of a layer containing In and O (an InO2 layer in FIG. 49A) and a layer containing Ga, Zn, and O (a GaZnO2 layer in FIG. 49A). Note that Ga and Zn are randomly placed at the cation sites in the layer containing Ga, Zn, and O. Thus, the layer containing Ga, Zn, and O is a region where cation disorder occurs and can be referred to as a random layer. Hereinafter, the calculation model illustrated in FIG. 49A is referred to as an IGZO model in some cases.

The calculation model illustrated in FIG. 49B corresponds to the metal oxide included in the sample group 6B described above. That is, the calculation model illustrated in FIG. 49B has a crystal structure of a metal oxide with an atomic ratio of In:Zn=4:1. The crystal structure has an alternating-layer structure including a first layer containing In and O (an InO2 layer in FIG. 49B), a second layer containing In and O (an InO layer in FIG. 49B), and a layer containing In, Zn, and O (an InZnO2 layer in FIG. 49B). Note that In and Zn are randomly placed at cation sites in the layer containing In, Zn, and O. Thus, the layer containing In, Zn, and O is a region where cation disorder occurs and can be referred to as a random layer. Hereinafter, the calculation model illustrated in FIG. 49B is referred to as an In-rich OS model in some cases.

According to the numerical formula (3), as the static permittivity εₛ of the metal oxide becomes higher, the mobility becomes higher. As the electron effective mass mₑ* becomes smaller, the carrier mobility of the metal oxide becomes higher. As the cation concentration ρ_{disorder} in a region where the cation disorder occurs becomes lower, the mobility becomes higher. As the term F becomes smaller, the mobility becomes higher.

According to the numerical formula (3), the mobility μ_{In-rich} of the In-rich OS model and the mobility μ_{IGZO} of the IGZO model have a relationship represented by a numerical formula (5).

$$\begin{matrix}[ Numerical Formula 5 ] & \\ \frac{{μ}_{In - rich}}{{μ}_{IGZO}} ∝ \frac{{{ε}_{s , In - rich}}^{2} {{m}_{e , IGZO}^{*}}^{\frac{1}{2}} {ρ}_{IGZO} {F}_{IGZO}}{{{ε}_{s , In - rich}}^{2} {{m}_{e , In - rich}^{*}}^{\frac{1}{2}} {ρ}_{In - rich} {F}_{In - rich}} & ( 5 )\end{matrix}$$

In the numerical formula (5), ρ_{In-rich} is the mobility of the In-rich OS, ε_{s,In-rich} is the static permittivity of the In-rich OS, m_{e,In-rich}* is the electron effective mass in the In-rich OS, ρ_{In-rich} is the cation concentration in the region of the In-rich OS where the cation disorder occurs (the InZnO2 layer in FIG. 49B), and F_{In-rich} is a term that depends on the occupancy rate of the cation sites and the difference in effective valence in the In-rich OS. Furthermore, μ_{IGZO} is the mobility of IGZO, ε_{s,IGXO} is the static permittivity of IGZO, m_{e,IGZO}* is the electron effective mass in IGZO, ρ_{IGZO} is the cation concentration in the region of IGZO where the cation disorder occurs (the GaZnO2 layer in FIG. 49A), and F_{IGZO} is a term that depends on the occupancy rate of the cation sites and the difference in effective valence in the IGZO.

Factors derived from the metal oxide (εₛ, mₑ*, ρ_{disorder}, and F) were calculated using the calculation models illustrated in FIG. 49A and FIG. 49B. Note that for calculation of the electron effective mass mₑ*, atomic-scale simulation software “QuantumATK” produced by Synopsys, Inc. was used. For calculation of the permittivity e, the cation concentration ρ, and ΔZ (ΔZ_{In} and ΔZ_{Ga}), VASP was used.

Table 1 shows the calculation results of the factors derived from the metal oxides. The term F is calculated using f_{In}, f_{Ga}, and f_{Zn} and ΔZ calculated using first-principles calculation.

TABLE 1

| | IGZO | In-rich OS |
|---|---|---|
| Model | (In:Ga:Zn = 1:1:1) | (In:Zn = 4:1) |
| mₑ*/mₑ | 0.335 | 0.347 |
| ρ [cm⁻³] | 2.38 × 10²² | 1.24 × 10²² |
| ε/ε₀ | 10.63 | 11.99 |
| F | 0.0788 | 0.0655 |
| (f_{In}, f_{Ga}, f_{Zn}) | (0, 0.5, 0.5) | (0.5, 0, 0.5) |
| ΔZ | ΔZ_{Ga} = 0.561 | ΔZ_{In} = 0.512 |

Table 1 shows that the difference between the electron effective mass m_{e,In-rich}* in the In-rich OS model and the electron effective mass m_{e,IGZO}* in the IGZO model is small. Thus, the influence of the electron effective mass on the mobility is inferred to be small. The cation concentration ρ_{In-rich} of the In-rich OS model is lower than the cation concentration μ_{IGZO} of the IGZO model. The permittivity ε_{s,In-rich} of the In-rich OS model is higher than the permittivity ε_{s,IGZO} of the IGZO model. The term F_{In-rich} of the In-rich OS model is smaller than the term F_{IGZO} of the IGZO model. The above suggests that an increase in mobility of the In-rich OS model as compared with the IGZO model is affected by the cation concentration ρ, the permittivity εₛ, and the term F.

In addition, the Hall mobility (μ_{Hall}^{CD}) in the cation disorder model is calculated by a numerical formula (6).

$$\begin{matrix}[ Numerical Formula 6 ] & \\ {μ}_{Hall}^{CD} = \frac{{2}^{\frac{9}{2}} {{πε}_{S}}^{2}}{{q}^{3} {{m}_{e}^{*}}^{\frac{1}{2}} {ρ}_{disorder} F} \frac{{( {k}_{B} T )}^{\frac{3}{2}}}{ln ( 1 + {b}^{′} ) - \frac{{b}^{′}}{1 - {b}^{′}}} \frac{Γ ( \frac{11}{2} )}{Γ ( 4 )} & ( 6 )\end{matrix}$$

In the numerical formula (6), q is a charge and k_{B} is a Boltzmann constant. Γ(z) is a gamma function and is one of functions that extend a factorial function to complex numbers. Note that in the case where n is any positive integer, the following numerical formula is satisfied.

$$[ Numerical Formula 7 ]$$

$$Γ ( \frac{1}{2} + n ) = \frac{( 2 n - 1 ) !!}{{2}^{n}} \sqrt{π}$$

$$Γ ( n ) = ( n - 1 ) !$$

$$( 2 n - 1 ) !! = ( 2 n - 1 ) \cdot ( 2 n - 3 ) \cdot ⋯ \cdot 3 \cdot 1$$

In addition, b′ is expressed as an numerical formula (8).

$$\begin{matrix}[ Numerical Formula 8 ] & \\ {b}^{′} = \frac{24 {m}_{e}^{*} {{ε}_{s} ( {k}_{B} T )}^{2}}{{𝒽}^{2} {q}^{2} n} & ( 7 )\end{matrix}$$

In the numerical formula (8), h with a bar is a reduced Planck constant (also referred to as Dirac's constant) and is a value obtained by dividing the Planck constant by 27. Furthermore, n is a carrier concentration.

The ratio of the mobility μ_{In-rich} of the In-rich OS model to the mobility μ_{IGZO} of the IGZO model was calculated using the numerical formula (6) and the numerical formula (7).

The results are shown in FIG. 50. As described above, the circles in FIG. 50 show the ratio of the mobility μ_{In-rich} in the In-rich OS model to the mobility μ_{IGZO} of the IGZO model calculated by the first-principles calculation (μ_{In-rich}/μ_{IGZO}), and the crosses in FIG. 50 show the ratio of the Hall mobility of Sample 61B to the Hall mobility of Sample 62A calculated from the Hall effect measurement results.

As shown in FIG. 50, the ratio of mobility calculated from the Hall effect measurement results is in the range of 2.1 to 4.1, and the ratio of mobility calculated by the first-principles calculation is in the range of 2.8 to 4.2. This indicates that an increase in carrier mobility of the metal oxide can be qualitatively estimated by first-principles calculation.

The above shows that the metal oxide included in the sample group 6B, which is an example of the metal oxide of one embodiment of the present invention, can have high mobility when the carrier concentration is low. That is, a transistor in which the metal oxide film of one embodiment of the present invention is used as a semiconductor layer can have a high on-state current or high field-effect mobility. Consequently, the electrical characteristics of the transistor can be increased.

### REFERENCE NUMERALS

BL: wiring, GBL: wiring, PL: wiring, VHH: wiring, VLL: wiring, WL: wiring, 31a: layer, 31b: layer, 31: layer, 32a: layer, 32b: layer, 32c: layer, 32: layer, 100a: display device, 100b: display device, 100: display device, 101: substrate, 110B: light-emitting element, 110G: light-emitting element, 110R: light-emitting element, 110W: light-emitting element, 110: light-emitting element, 111B: pixel electrode, 111C: connection electrode, 111G: pixel electrode, 111R: pixel electrode, 111: pixel electrode, 112B: organic layer, 112G: organic layer, 112R: organic layer, 112W: organic layer, 112: organic layer, 113: common electrode, 114: common layer, 115B: conductive layer, 115G: conductive layer, 115R: conductive layer, 115: conductive layer, 116B: coloring layer, 116G: coloring layer, 116R: coloring layer, 121: protective layer, 122: insulating layer, 123: insulating layer, 125: insulating layer, 126: resin layer, 128: layer, 130: connection portion, 140: capacitor, 141: conductive layer, 143: insulating layer, 145: conductive layer, 154: insulating layer, 155a: insulating layer, 155b: insulating layer, 155c: insulating layer, 156: plug, 164: insulating layer, 170: substrate, 171: adhesive layer, 174a: conductive layer, 174b: conductive layer, 174: plug, 200A: transistor, 200B: transistor, 200C: transistor, 200D: transistor, 200: transistor, 201: substrate, 207: conductive layer, 208: insulating layer, 209: conductive layer, 210: insulating layer, 212: insulating layer, 213: conductive layer, 214: insulating layer, 215a: conductive layer, 215b: conductive layer, 215: conductive layer, 216: insulating layer, 218: conductive layer, 220a: conductive layer, 220b: conductive layer, 220: conductive layer, 221: insulating layer, 222: insulating layer, 223: insulating layer, 224: insulating layer, 230a: semiconductor layer, 230b: semiconductor layer, 230c: semiconductor layer, 230: semiconductor layer, 240a: conductive layer, 240b: conductive layer, 240: conductive layer, 241: insulating layer, 242a: conductive layer, 242b: conductive layer, 242: conductive layer, 250a: insulating layer, 250b: insulating layer, 250c: insulating layer, 250d: insulating layer, 250: insulating layer, 255: insulating layer, 260a: conductive layer, 260b: conductive layer, 260: conductive layer, 271a: insulating layer, 271b: insulating layer, 275: insulating layer, 280a: insulating layer, 280b: insulating layer, 280c: insulating layer, 280: insulating layer, 281a: insulating layer, 281b: insulating layer, 281: insulating layer, 282: insulating layer, 283: insulating layer, 284: insulating layer, 285: insulating layer, 290: opening portion, 291: opening portion, 310: transistor, 311: substrate, 313: semiconductor region, 314a: low-resistance region, 314b: low-resistance region, 314: low-resistance region, 315: insulating layer, 316: conductive layer, 317: insulating layer, 318: element isolation layer, 320: insulating layer, 322: insulating layer, 324: insulating layer, 326: insulating layer, 328: conductive layer, 330: conductive layer, 350: insulating layer, 352: insulating layer, 354: insulating layer, 356: conductive layer, 400: capacitor, 410: conductive layer, 412: conductive layer, 420: conductive layer, 430: insulating layer, 450: insulating layer, 453: conductive layer, 454: insulating layer, 460a: conductive layer, 460b: conductive layer, 460: conductive layer, 500A: display device, 500B: display device, 500C: display device, 520A: transistor, 520B: transistor, 520: transistor, 580: display module, 581: display portion, 582: circuit portion, 583a: pixel circuit, 583: pixel circuit portion, 584a: pixel, 584: pixel portion, 585: terminal portion, 586: wiring portion, 590: FPC, 591: substrate, 592: substrate, 600A: memory device, 600: memory device, 610A: memory cell, 610B: memory cell, 610: memory cell, 611a: transistor, 611b: transistor, 611c: transistor, 611: transistor, 612a: capacitor, 612: capacitor, 620: memory array, 621: driver circuit, 622: PSW, 623: PSW, 631: peripheral circuit, 632: control circuit, 633: voltage generation circuit, 641: peripheral circuit, 642: row decoder, 643: row driver, 644: column decoder, 645: column driver, 646: sense amplifier, 647: input circuit, 648: output circuit, 650: functional layer, 651A: functional circuit, 651B: functional circuit, 651: functional circuit, 652a: transistor, 652b: transistor, 652: transistor, 653a: transistor, 653b: transistor, 653: transistor, 654a: transistor, 654b: transistor, 655a: transistor, 655b: transistor, 655: transistor, 670: structure body, 671A: precharge circuit, 671B: precharge circuit, 672A: switch circuit, 672B: switch circuit, 673: write/read circuit, 681_1: transistor, 681_3: transistor, 681_4: transistor, 681_6: transistor, 682_1: transistor, 682_2: transistor, 682_3: transistor, 682_4: transistor, 683A: switch, 683B: switch, 683C: switch, 683D: switch, 700A: electronic device, 700B: electronic device, 700: electronic component, 702: printed circuit board, 704: circuit board, 710: semiconductor device, 711: mold, 712: land, 713: electrode pad, 714: wire, 715: driver circuit layer, 716: memory layer, 721: housing, 723: wearing portion, 727: earphone portion, 730: electronic component, 731: interposer, 732: package substrate, 733: electrode, 735: semiconductor device, 750: earphone, 751: display panel, 753: optical member, 756: display region, 757: frame, 758: nose pad, 800A: electronic device, 800B: electronic device, 820: display portion, 821: housing, 822: communication portion, 823: wearing portion, 824: control portion, 825: image capturing portion, 827: earphone portion, 832: lens, 1001: wiring, 1002: wiring, 1003: wiring, 1004: wiring, 1005: wiring, 1006: wiring, 1200: chip, 1201: package substrate, 1202: bump, 1203: motherboard, 1204: GPU module, 1211: CPU, 1212: GPU, 1213: analog arithmetic unit, 1214: memory controller, 1215: interface, 1216: network circuit, 1221: DRAM, 1222: flash memory, 5600: large computer, 5610: rack, 5620: computer, 5621: PC card, 5622: board, 5623: connection terminal, 5624: connection terminal, 5625: connection terminal, 5626: semiconductor device, 5627: semiconductor device, 5628: semiconductor device, 5629: connection terminal, 5630: motherboard, 5631: slot, 6500: electronic device, 6501: housing, 6502: display portion, 6503: power button, 6504: button, 6505: speaker, 6506: microphone, 6507: camera, 6508: light source, 6509: control device, 6510: protection member, 6511: display panel, 6512: optical member, 6513: touch sensor panel, 6515: FPC, 6516: IC, 6517: printed circuit board, 6518: battery, 6600: electronic device, 6611: housing, 6612: keyboard, 6613: pointing device, 6614: external connection port, 6615: display portion, 6616: control device, 6800: artificial satellite, 6801: body, 6802: solar panel, 6803: antenna, 6804: planet, 6805: secondary battery, 6807: control device, 6900: storage system, 6901sb: server, 6901: host, 6902: storage control circuit, 6903md: memory device, 6903: storage, 7000: display portion, 7100: television device, 7101: housing, 7103: stand, 7111: remote controller, 7200: laptop personal computer, 7211: housing, 7212: keyboard, 7213: pointing device, 7214: external connection port, 7216: control device, 7300: digital signage, 7301: housing, 7303: speaker, 7311: information terminal, 7400: digital signage, 7401: pillar, 7411: information terminal, 9000: housing, 9001: display portion, 9002: camera, 9003: speaker, 9005: operation key, 9006: connection terminal, 9007: sensor, 9008: microphone, 9050: icon, 9051: information, 9052: information, 9053: information, 9054: information, 9055: hinge, 9101: portable information terminal, 9102: portable information terminal, 9103: tablet terminal, 9200: portable information terminal, 9201: portable information terminal

1. A metal oxide film,
wherein in the metal oxide film, a sum of a content percentage of indium and a content percentage of zinc is greater than or equal to 95%,
wherein the metal oxide film comprises a crystal,
wherein the crystal comprises a layered crystal structure,
wherein in the crystal, a ratio of a number of zinc atoms to a number of indium atoms is greater than 0 and less than 1.5, and
wherein an electron effective mass in the crystal is smaller than an electron effective mass in an indium oxide having a cubic crystal structure.

2. The metal oxide film according to claim 1,
wherein the metal oxide film comprises tin, and
wherein a content percentage of the tin is higher than or equal to 0.1% and lower than or equal to 3%.

3. A metal oxide film,
wherein in the metal oxide film, a sum of a content percentage of indium and a content percentage of zinc is greater than or equal to 95%,
wherein the metal oxide film comprises a crystal,
wherein the crystal comprises a first layer, a second layer, and a third layer positioned between the first layer and the second layer,
wherein a ratio of a number of zinc atoms to a number of indium atoms in the third layer is higher than a ratio of a number of zinc atoms to a number of indium atoms in the first layer,
wherein the ratio of the number of zinc atoms to the number of indium atoms in the third layer is higher than a ratio of a number of zinc atoms to a number of indium atoms in the second layer, and
wherein the third layer comprises one, two, or three layers.

4. The metal oxide film according to claim 3,
wherein an electron effective mass in the crystal is smaller than an electron effective mass in an indium oxide having a cubic crystal structure.

5. The metal oxide film according to claim 3,
wherein the metal oxide film comprises tin, and
wherein a content percentage of the tin is higher than or equal to 0.1% and lower than or equal to 3%.

6. A metal oxide film,
wherein in the metal oxide film, a sum of a content percentage of indium and a content percentage of zinc is greater than or equal to 95%,
wherein the metal oxide film comprises a crystal,
wherein the crystal comprises a first layer, a second layer, and a third layer positioned between the first layer and the second layer,
wherein in a HAADF-STEM image, a luminance of an atom included in the third layer is lower than a luminance of an atom included in the first layer,
wherein in the HAADF-STEM image, the luminance of the atom included in the third layer is lower than a luminance of an atom included in the second layer, and
wherein the third layer comprises one, two, or three layers.

7. The metal oxide film according to claim 6,
wherein an electron effective mass in the crystal is smaller than an electron effective mass in an indium oxide having a cubic crystal structure.

8. The metal oxide film according to claim 6,
wherein the metal oxide film comprises tin, and
wherein a content percentage of the tin is higher than or equal to 0.1% and lower than or equal to 3%.

9. A semiconductor device comprising:
a transistor and a first insulating layer,
wherein the transistor comprises a semiconductor layer, a second insulating layer, a first conductive layer, a second conductive layer, and a third conductive layer,
wherein the first insulating layer is provided over the first conductive layer,
wherein the second conductive layer is provided over the first insulating layer,
wherein an opening portion reaching the first conductive layer is provided in the first insulating layer and the second conductive layer,
wherein at least a part of the semiconductor layer is provided in the opening portion,
wherein the second insulating layer is provided over the semiconductor layer,
wherein the third conductive layer is provided over the second insulating layer, and
wherein the semiconductor layer comprises the metal oxide film according to claim 1.

10. A semiconductor device comprising:
a transistor, a first insulating layer, and a second insulating layer,
wherein the transistor comprises a semiconductor layer, a third insulating layer, a first conductive layer, a second conductive layer, and a third conductive layer,
wherein the first insulating layer is provided over the first conductive layer,
wherein the second conductive layer is provided over the first insulating layer,
wherein the second insulating layer is provided over the second conductive layer,
wherein the third conductive layer is provided over the second insulating layer,
wherein an opening portion reaching the first conductive layer is provided in the first insulating layer, the second conductive layer, the second insulating layer, and the third conductive layer,
wherein the third insulating layer is provided in the opening portion,
wherein in the opening portion, the third insulating layer comprises a region in contact with a side surface of the first insulating layer, a side surface of the second conductive layer, a side surface of the second insulating layer, and a side surface of the third conductive layer,
wherein the semiconductor layer is provided in contact with a top surface of the third conductive layer and a side surface of the third insulating layer and a top surface of the first conductive layer in the opening portion, and
wherein the semiconductor layer comprises the metal oxide film according to claim 1.

11. A semiconductor device comprising:
a transistor and a first insulating layer,
wherein the transistor comprises a semiconductor layer, a second insulating layer, a first conductive layer, a second conductive layer, and a third conductive layer,
wherein the first conductive layer and the second conductive layer are provided over the semiconductor layer,
wherein the first insulating layer is provided over the first conductive layer and the second conductive layer,
wherein an opening portion that is between the first conductive layer and the second conductive layer and reaches the semiconductor layer is provided in the first insulating layer,
wherein the second insulating layer is provided in the opening portion,
wherein the third conductive layer is provided over the second insulating layer, and
wherein the semiconductor layer comprises the metal oxide film according to claim 1.

12. The semiconductor device according to claim 11,
wherein the transistor further comprises a third insulating layer, and
wherein in the opening portion, the third insulating layer is provided in contact with a side surface of the first insulating layer, a side surface of the first conductive layer, and a side surface of the second conductive layer.

13. A semiconductor device comprising:
a transistor and a first insulating layer,
wherein the transistor comprises a semiconductor layer, a second insulating layer, a first conductive layer, a second conductive layer, and a third conductive layer,
wherein the first insulating layer is provided over the first conductive layer,
wherein the second conductive layer is provided over the first insulating layer,
wherein an opening portion reaching the first conductive layer is provided in the first insulating layer and the second conductive layer,
wherein at least a part of the semiconductor layer is provided in the opening portion,
wherein the second insulating layer is provided over the semiconductor layer,
wherein the third conductive layer is provided over the second insulating layer, and
wherein the semiconductor layer comprises the metal oxide film according to claim 3.

14. A semiconductor device comprising:
a transistor, a first insulating layer, and a second insulating layer,
wherein the transistor comprises a semiconductor layer, a third insulating layer, a first conductive layer, a second conductive layer, and a third conductive layer,
wherein the first insulating layer is provided over the first conductive layer,
wherein the second conductive layer is provided over the first insulating layer,
wherein the second insulating layer is provided over the second conductive layer,
wherein the third conductive layer is provided over the second insulating layer,
wherein an opening portion reaching the first conductive layer is provided in the first insulating layer, the second conductive layer, the second insulating layer, and the third conductive layer,
wherein the third insulating layer is provided in the opening portion,
wherein in the opening portion, the third insulating layer comprises a region in contact with a side surface of the first insulating layer, a side surface of the second conductive layer, a side surface of the second insulating layer, and a side surface of the third conductive layer,
wherein the semiconductor layer is provided in contact with a top surface of the third conductive layer and a side surface of the third insulating layer and a top surface of the first conductive layer in the opening portion, and
wherein the semiconductor layer comprises the metal oxide film according to claim 3.

15. A semiconductor device comprising:
a transistor and a first insulating layer,
wherein the transistor comprises a semiconductor layer, a second insulating layer, a first conductive layer, a second conductive layer, and a third conductive layer,
wherein the first conductive layer and the second conductive layer are provided over the semiconductor layer,
wherein the first insulating layer is provided over the first conductive layer and the second conductive layer,
wherein an opening portion that is between the first conductive layer and the second conductive layer and reaches the semiconductor layer is provided in the first insulating layer,
wherein the second insulating layer is provided in the opening portion,
wherein the third conductive layer is provided over the second insulating layer, and
wherein the semiconductor layer comprises the metal oxide film according to claim 3.

16. The semiconductor device according to claim 15,
wherein the transistor further comprises a third insulating layer, and
wherein in the opening portion, the third insulating layer is provided in contact with a side surface of the first insulating layer, a side surface of the first conductive layer, and a side surface of the second conductive layer.

17. A semiconductor device comprising:
a transistor and a first insulating layer,
wherein the transistor comprises a semiconductor layer, a second insulating layer, a first conductive layer, a second conductive layer, and a third conductive layer,
wherein the first insulating layer is provided over the first conductive layer,
wherein the second conductive layer is provided over the first insulating layer,
wherein an opening portion reaching the first conductive layer is provided in the first insulating layer and the second conductive layer,
wherein at least a part of the semiconductor layer is provided in the opening portion,
wherein the second insulating layer is provided over the semiconductor layer,
wherein the third conductive layer is provided over the second insulating layer, and
wherein the semiconductor layer comprises the metal oxide film according to claim 6.

18. A semiconductor device comprising:
a transistor, a first insulating layer, and a second insulating layer,
wherein the transistor comprises a semiconductor layer, a third insulating layer, a first conductive layer, a second conductive layer, and a third conductive layer,
wherein the first insulating layer is provided over the first conductive layer,
wherein the second conductive layer is provided over the first insulating layer,
wherein the second insulating layer is provided over the second conductive layer,
wherein the third conductive layer is provided over the second insulating layer,
wherein an opening portion reaching the first conductive layer is provided in the first insulating layer, the second conductive layer, the second insulating layer, and the third conductive layer,
wherein the third insulating layer is provided in the opening portion,
wherein in the opening portion, the third insulating layer comprises a region in contact with a side surface of the first insulating layer, a side surface of the second conductive layer, a side surface of the second insulating layer, and a side surface of the third conductive layer,
wherein the semiconductor layer is provided in contact with a top surface of the third conductive layer and a side surface of the third insulating layer and a top surface of the first conductive layer in the opening portion, and
wherein the semiconductor layer comprises the metal oxide film according to claim 6.

19. A semiconductor device comprising:
a transistor and a first insulating layer,
wherein the transistor comprises a semiconductor layer, a second insulating layer, a first conductive layer, a second conductive layer, and a third conductive layer,
wherein the first conductive layer and the second conductive layer are provided over the semiconductor layer,
wherein the first insulating layer is provided over the first conductive layer and the second conductive layer,
wherein an opening portion that is between the first conductive layer and the second conductive layer and reaches the semiconductor layer is provided in the first insulating layer,
wherein the second insulating layer is provided in the opening portion,
wherein the third conductive layer is provided over the second insulating layer, and
wherein the semiconductor layer comprises the metal oxide film according to claim 6.

20. The semiconductor device according to claim 19,
wherein the transistor further comprises a third insulating layer, and
wherein in the opening portion, the third insulating layer is provided in contact with a side surface of the first insulating layer, a side surface of the first conductive layer, and a side surface of the second conductive layer.
